(19) United States
(12) Patent Application Publication
(10) Pub. No.: US 2025/0234779 A1
(43) Pub. Date: Jul. 17, 2025

(54) LIGHT EMITTING ELEMENT, AND DISPLAY DEVICE INCLUDING THE LIGHT EMITTING ELEMENT

(71) Applicant: Samsung Display Co., Ltd., Yongin-si (KR)

(72) Inventors: TAEIL KIM, Yongin-si (KR); JUNHA PARK, Yongin-si (KR); MinJae SUNG, Yongin-si (KR); MUN-KI SIM, Yongin-si (KR); MINJUNG JUNG, Yongin-si (KR); Seonhyoung HUR, Yongin-si (KR)

(73) Assignee: Samsung Display Co., Ltd., Yongin-si (KR)

(21) Appl. No.: 19/021,562

(22) Filed: Jan. 15, 2025

Related U.S. Application Data
(63) Continuation-in-part of application No. 18/951,942, filed on Nov. 19, 2024.

(30) Foreign Application Priority Data
Jan. 11, 2024 (KR) 10-2024-0004578

(51) Int. Cl. H10K 85/60; C09K 11/02; C09K 11/06; H10K 50/12; H10K 50/13; H10K 85/30; H10K 85/40; H10K 101/20

(52) U.S. Cl. CPC H10K 85/658; C09K 11/02; C09K 11/06; H10K 85/346; H10K 85/40; H10K 85/615; H10K 85/622; H10K 85/626; H10K 85/654; H10K 85/6572; H10K 85/6574; C09K 2211/1007; C09K 2211/1018; H10K 50/12; H10K 50/13; H10K 2101/20

(57) ABSTRACT

Embodiments provide a light emitting element and a display device that includes the light emitting element. The light emitting element includes a first electrode, a first emission layer disposed on the first electrode and including a (1-1)-th compound, a second emission layer disposed on the first emission layer and including a (2-1)-th compound, and a second electrode disposed on the second emission layer, wherein the (2-1)-th compound has a lowest excited triplet energy level (T1) in a range of about 1.5 eV to about 2.1 eV. The (1-1)-th compound is represented by Formula 1, the (2-1)-th compound is represented by Formula 2, and Formula 1 and Formula 2 are each described in the specification.

### CROSS-REFERENCE TO RELATED APPLICATION(S)

This is a continuation-in-part application of U.S. patent application Ser. No. 18/951,942 filed Nov. 19, 2024 (now pending), the disclosure of which is incorporated herein by reference in its entirety. U.S. patent application Ser. No. 18/951,942 claims priority to and benefits of Korean Patent Application No. 10-2024-0004578 under 35 U.S.C. § 119, filed on Jan. 11, 2024, in the Korean Intellectual Property Office, the entire contents of which are incorporated herein by reference.

### BACKGROUND

### 1. Technical Field

The disclosure relates to a light emitting element, and a display device including the light emitting element.

### 2. Description of the Related Art

Ongoing development continues for an organic electroluminescence display as an image display. Unlike a liquid crystal display, an organic electroluminescence display is a so-called self-luminescent display in which holes and electrons respectively injected from a first electrode and a second electrode recombine in an emission layer, so that a light-emitting material, which includes an organic compound, in the emission layer emits light to achieve display.

In the application of an organic electroluminescence element to a display device, there is a persistent demand for an organic electroluminescence element having a low driving voltage, high luminous efficiency, and a long service life. Continuous development is required on materials for an organic electroluminescence element that are capable of stably achieving such characteristics.

In order to implement a highly efficient organic electroluminescence element, technologies pertaining to phosphorescence emission, which uses triplet state energy, or pertaining to fluorescence, which uses triplet-triplet annihilation (TTA) in which singlet excitons are generated by the collision of triplet excitons, are being developed. Research and development are presently directed thermally activated delayed fluorescence (TADF) materials that use delayed fluorescence phenomenon.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting element in which luminescence characteristics and an element service life are improved.

The disclosure also provides a display device including the light emitting element in which the luminous efficiency and service life are improved, thereby having excellent display quality.

According to an embodiment, a light emitting element may include a first electrode, a first emission layer disposed on the first electrode and including a (1-1)-th compound represented by Formula 1, a second emission layer disposed on the first emission layer and including a (2-1)-th compound represented by Formula 2, and a second electrode disposed on the second emission layer, wherein the (2-1)-th compound may have a lowest excited triplet energy level (T1) in a range of about 1.5 eV to about 2.1 eV:

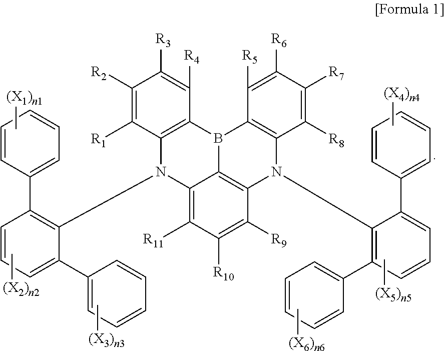

In Formula 1, R₁ to R₁₁ may each independently be a hydrogen atom, a deuterium atom, a halogen atom, a cyano group, a hydroxy group, a substituted or unsubstituted oxy group, a substituted or unsubstituted thio group, a substituted or unsubstituted selenyl group, a substituted or unsubstituted tellanyl group, a substituted or unsubstituted boron group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring; X₁ to X₆ may each independently be a hydrogen atom, a deuterium atom, a halogen atom, a cyano group, a hydroxy group, a substituted or unsubstituted oxy group, a substituted or unsubstituted thio group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring; n1, n3, n4, and n6 may each independently be an integer from 0 to 5; and n2 and n5 may each independently be an integer from 0 to 3.

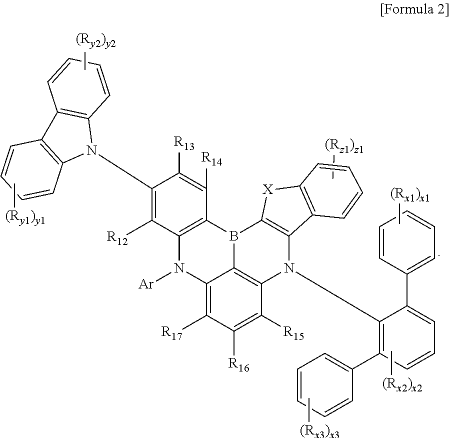

In Formula 2, X may be O, S, Se, or Te; Ar may be a substituted or unsubstituted aryl group having 6 to 30 ring-forming carbon atoms or a substituted or unsubstituted heteroaryl group having 2 to 30 ring-forming carbon atoms; R₁₂ to R₁₇ and Rₓ₁ to Rₓ₃ may each independently be a hydrogen atom, a deuterium atom, a halogen atom, a cyano group, a hydroxy group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; R_{y1}, R_{y2}, and R_{z1} may each independently be a hydrogen atom, a deuterium atom, a halogen atom, a cyano group, a hydroxy group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring; x1 and x3 may each independently be an integer from 0 to 5; x2 may be an integer from 0 to 3; and y1, y2, and z1 may each independently be an integer from 0 to 4.

In an embodiment, the light emitting element may further include a hole transport region disposed between the first electrode and the first emission layer, and an electron transport region disposed between the second emission layer and the second electrode.

In an embodiment, the first emission layer may emit fluorescence by thermally activated delayed fluorescence (TADF), and the second emission layer may emit fluorescence by triplet-triplet annihilation (TTA).

In an embodiment, the second emission layer may be directly disposed on the first emission layer, and the first emission layer and the second emission layer may each independently emit fluorescence having a central wavelength in a range of about 430 nm to about 490 nm.

In an embodiment, the (1-1)-th compound may have a lowest excited triplet energy level (T1) in a range of about 2.5 eV to about 3.1 eV.

In an embodiment, the first emission layer may include a first light emitting host, and a first light emitting dopant that is doped into the first light emitting host and includes the (1-1)-th compound; the second emission layer may include a second light emitting host. and a second light emitting dopant that is doped into the second light emitting host and includes the (2-1)-th compound; and a material included in the first light emitting host may be different from a material included in the second light emitting host.

In an embodiment, the first emission layer may further include at least one of a (1-2)-th compound represented by Formula HT-1, a (1-3)-th compound represented by Formula ET-1; and a (1-4)-th compound represented by Formula D-1:

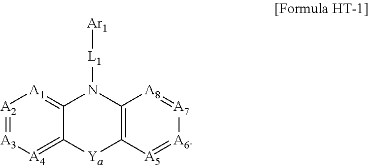

In Formula HT-1, A₁ to A₈ may each independently be N or C(R₅₁); L₁ may be a direct linkage, a substituted or unsubstituted arylene group having 6 to 30 ring-forming carbon atoms, or a substituted or unsubstituted heteroarylene group having 2 to 30 ring-forming carbon atoms; Yₐ may be a direct linkage, C(R₅₂)(R₅₃), or Si(R₅₄)(R₅₅); Ar₁ may be a substituted or unsubstituted aryl group having 6 to 30 ring-forming carbon atoms or a substituted or unsubstituted heteroaryl group having 2 to 30 ring-forming carbon atoms, and R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring.

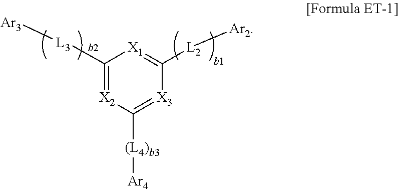

In Formula ET-1, at least one of X₁ to X₃ may each be N; the remainder of X₁ to X₃ may each independently be C(R₅₆); R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms; b1 to b3 may each independently be an integer from 0 to 10; Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; and L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms.

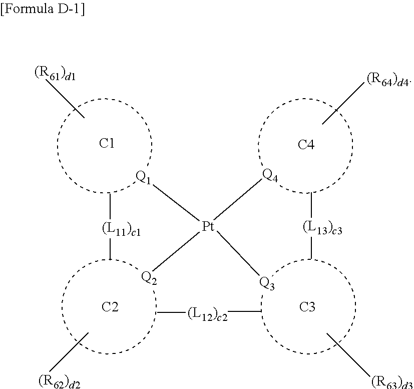

In Formula D-1, Q₁ to Q₄ may each independently be C or N; C1 to C4 may each independently be a substituted or unsubstituted hydrocarbon ring having 5 to 30 ring-forming carbon atoms or a substituted or unsubstituted heterocycle having 2 to 30 ring-forming carbon atoms; L₁₁ to L₁₃ may each independently be a direct linkage, *—O—*, *—S—*,

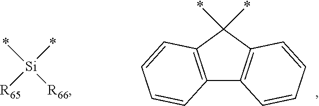

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms; c1 to c3 may each independently be 0 or 1; R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring; and d1 to d4 may each independently be an integer from 0 to 4.

In an embodiment, the first emission layer may include the (1-1)-th compound, the (1-2)-th compound, the (1-3)-th compound, and the (1-4)-th compound.

In an embodiment, the second emission layer may further include a (2-2)-th compound represented by Formula E-1:

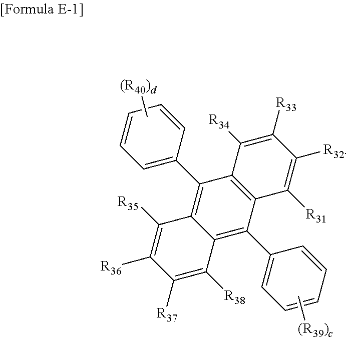

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

In an embodiment, the second emission layer may consist of the (2-1)-th compound and the (2-2)-th compound.

In an embodiment, the (1-1)-th compound may be represented by one of Formula 1-1 to Formula 1-3:

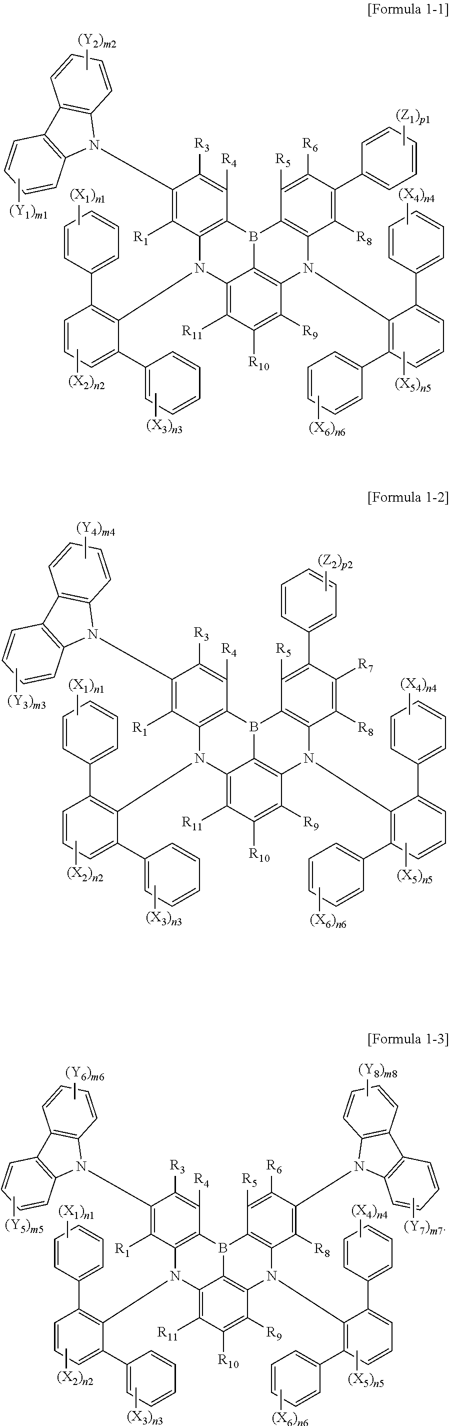

In Formula 1-1 to Formula 1-3, Y₁ to Y₈, Z₁, and Z₂ may each independently be a hydrogen atom, a deuterium atom, a halogen atom, a cyano group, a hydroxy group, a substituted or unsubstituted oxy group, a substituted or unsubstituted thio group, a substituted or unsubstituted selenyl group, a substituted or unsubstituted tellanyl group, a substituted or unsubstituted germyl group, a substituted or unsubstituted boron group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring; m1 to m8 may each independently be an integer from 0 to 4; p1 and p2 may each independently be an integer from 0 to 5; and R₁, R₃ to R₁₁, X₁ to X₆, and n1 to n6 may be the same as defined in Formula 1.

In an embodiment, the (1-1)-th compound may be represented by Formula 1-4:

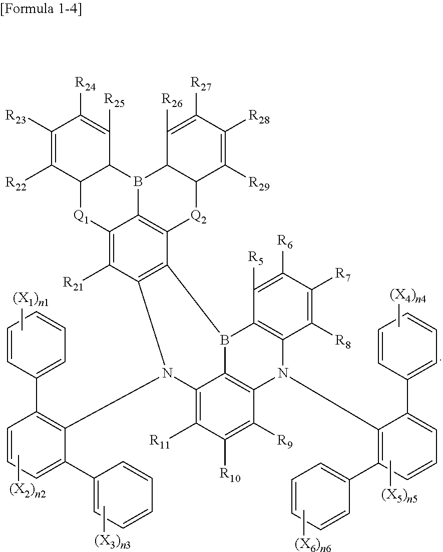

In Formula 1-4, Q₁ and Q₂ may each independently be O, S, Se, Te, or N(R₃₀); R₂₁ to R₃₀ may each independently be a hydrogen atom, a deuterium atom, a halogen atom, a cyano group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring; and R₅ to R₁₁, X₁ to X₆, and n1 to n6 may be the same as defined in Formula 1.

In an embodiment, the (1-1)-th compound may be represented by one of Formula 1-5 to Formula 1-11:

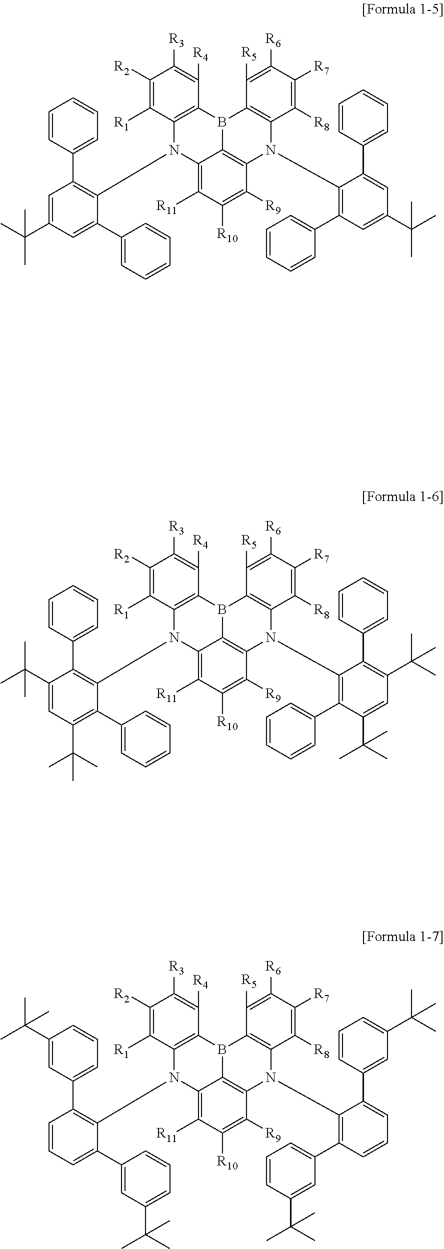

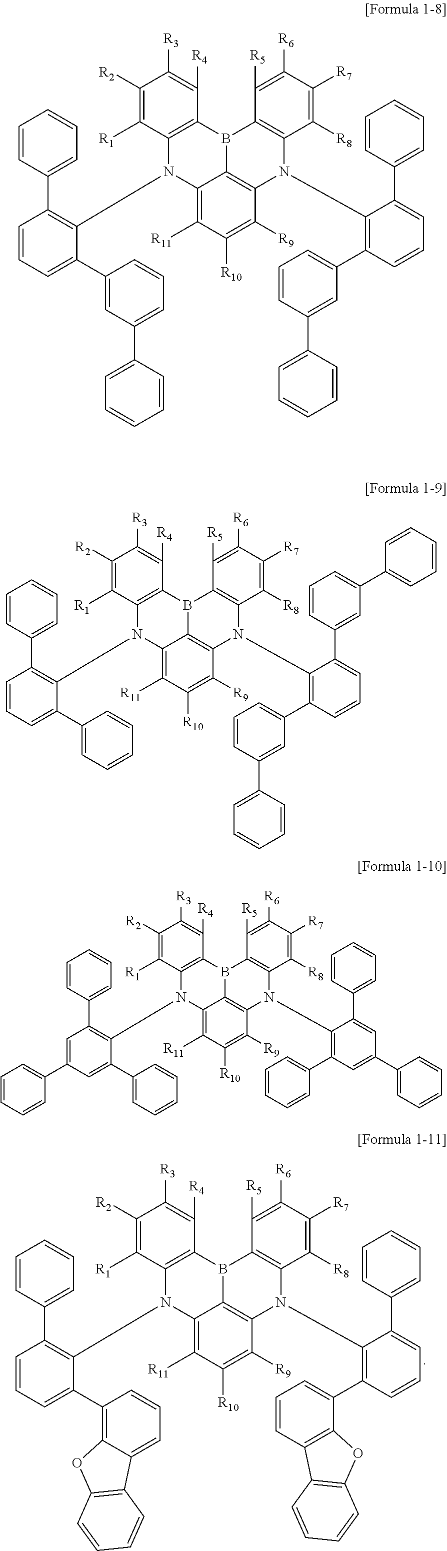

In Formula 1-5 to Formula 1-11, R₁ to R₁₁ may be the same as defined in Formula 1.

In an embodiment, in Formula 1, R₁₀ may be a group represented by one of Formula 3-1 to Formula 3-6:

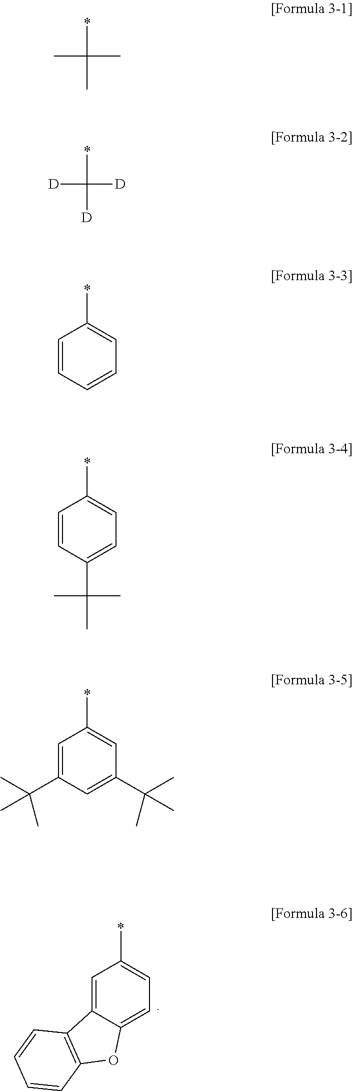

In Formula 3-1 to Formula 3-6, *— represents a bond to Formula 1, and D represents a deuterium atom.

In an embodiment, in Formula 2, at least one of R₁₆, R_{y1}, R_{y2}, R_{z1}, and Ar may each independently be a group represented by one of Formula 4-1 to Formula 4-4:

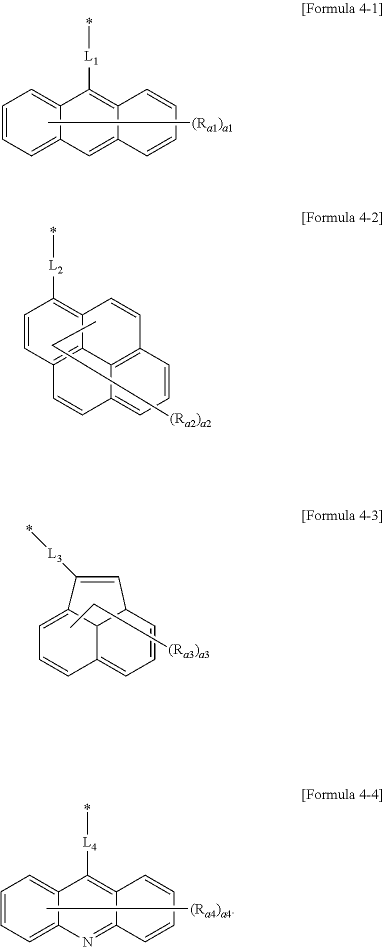

In Formula 4-1 to Formula 4-4, L₁ to L₄ may each independently be a direct linkage or a substituted or unsubstituted arylene group having 6 to 30 ring-forming carbon atoms; Rₐ₁ to Rₐ₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring; a1 and a2 may each independently be an integer from 0 to 9; a3 may be an integer from 0 to 7; a4 may be an integer from 0 to 8, and *— represents a bond to Formula 2.

In an embodiment, in Formula 4-1 to Formula 4-4, L₁ to L₄ may each independently be a direct linkage, a substituted or unsubstituted phenylene group, or a substituted or unsubstituted biphenylene group; and Rₐ₁ to Rₐ₄ may each independently be a hydrogen atom or a substituted or unsubstituted phenyl group.

In an embodiment, the (2-1)-th compound may be represented by Formula 2-1:

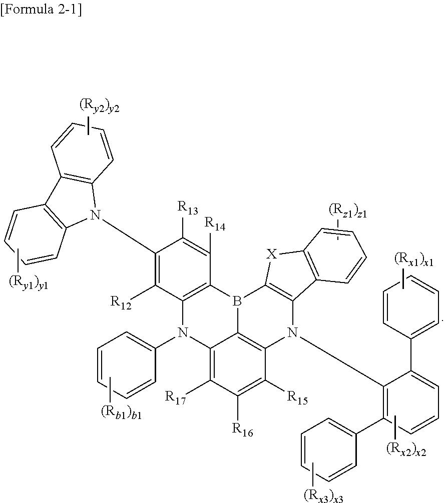

In Formula 2-1 above, R_{b1} may be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms; at least one of R_{y1}, R_{y2}, R_{z1}, and R_{b1} may each independently be a group represented by one of Formula 4-1 to Formula 4-4; b1 may be an integer from 0 to 5; and X, R₁₂ to R₁₇, Rₓ₁ to Rₓ₃, R_{y1}, R_{y2}, R_{z1}, x1 to x3, y1, y2, and z1 may be the same as defined in Formula 2.

In an embodiment, the (2-1)-th compound may be represented by one of Formula 2-2 to

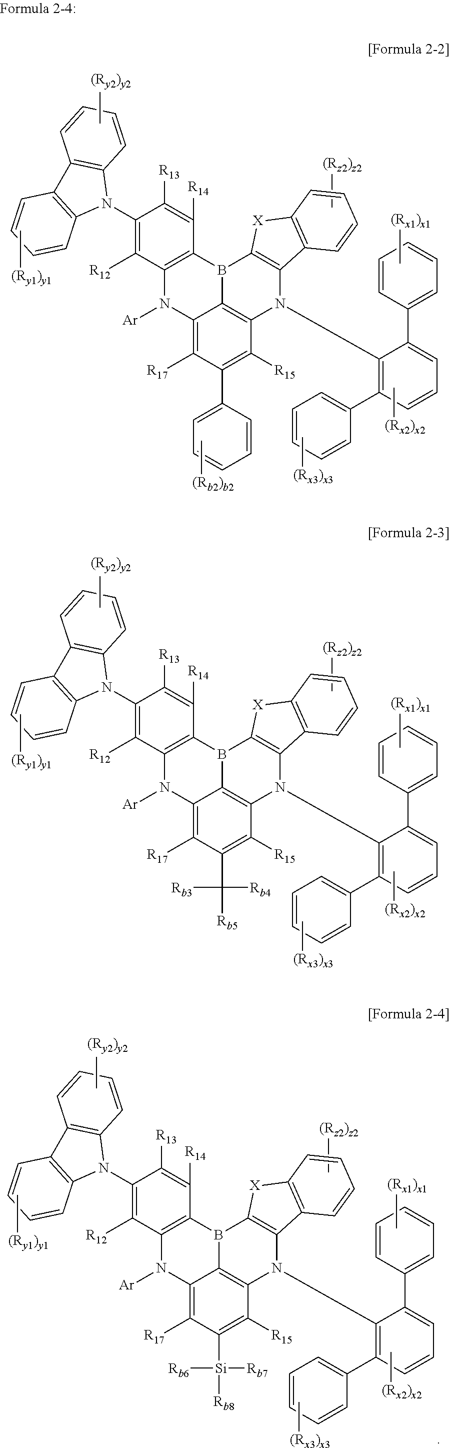

In Formula 2-2 to Formula 2-4, R_{b2} to R_{b8} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms; b2 may be an integer from 0 to 5; X, Ar, R₁₂ to R₁₅, R₁₇, Rₓ₁ to Rₓ₃, R_{y1}, R_{y2}, R_{z1}, x1 to x3, y1, y2, and z1 may be the same as defined in Formula 2, when the (2-1)-th compound is represented by Formula 2-2, at least one of R_{y1}, R_{y2}, R_{z1}, and R_{b2} may each independently be a group represented by one of Formula 4-1 to Formula 4-4; when the (2-1)-th compound is represented by Formula 2-3, at least one of R_{y1}, R_{y2}, R_{z1}, R_{b3}, R_{b4}, and R_{b5} may each independently be a group represented by one of Formula 4-1 to Formula 4-4; and when the (2-1)-th compound is represented by Formula 2-4, at least one of R_{y1}, R_{y2}, R_{z1}, R_{b6}, R_{b7}, and R_{b8} may each independently be a group represented by one of Formula 4-1 to Formula 4-4.

In an embodiment, the (2-1)-th compound may be represented by Formula 2-5:

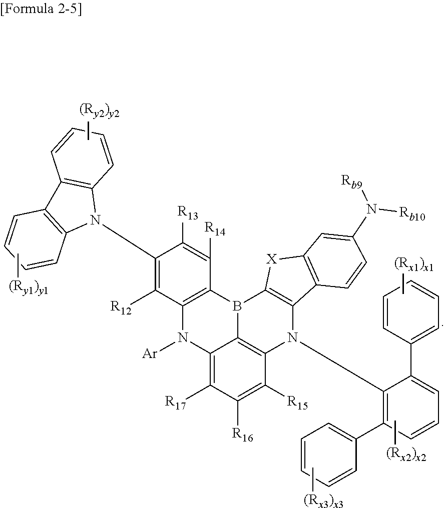

In Formula 2-5, R_{b9} and R_{b10} may each independently be a hydrogen atom, a deuterium atom, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring; at least one of R_{y1}, R_{y2}, R_{z1}, R_{b9}, and R_{b10} may each independently be a group represented by one of Formula 4-1 to Formula 4-4; and X, Ar, R₁₂ to R₁₇, Rₓ₁ to Rₓ₃, R_{y1}, R_{y2}, x1 to x3, y1, and y2 may be the same as defined in Formula 2.

In an embodiment, the (2-1)-th compound may be represented by one of Formula 2-6 to Formula 2-8:

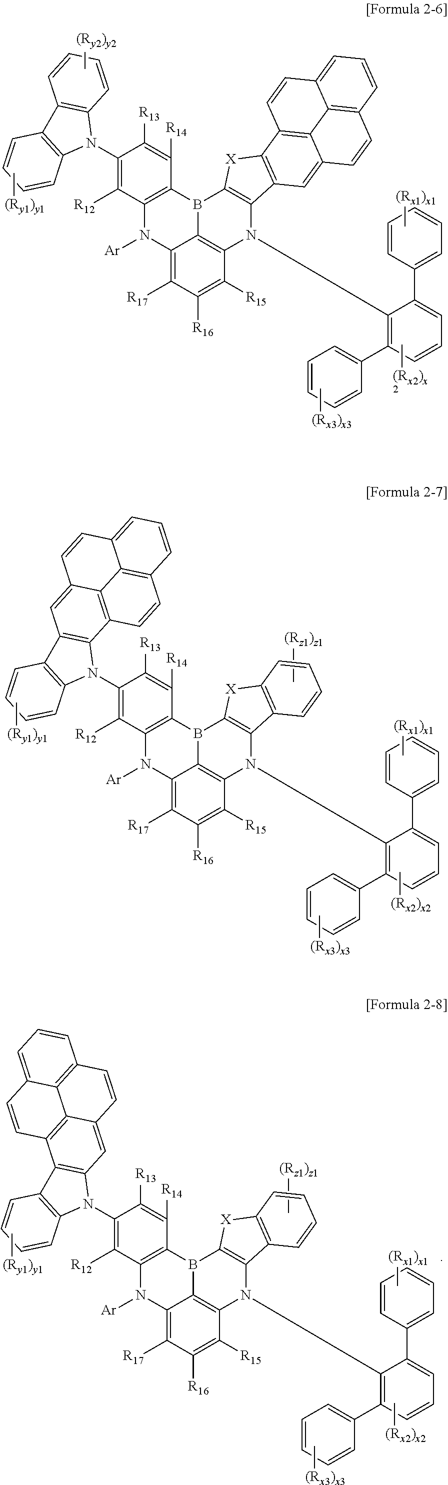

In Formula 2-6 to Formula 2-8, X, Ar, R₁₂ to R₁₇, Rₓ₁ to Rₓ₃, R_{y1}, R_{y2}, R_{z1}, x1 to x3, y1, y2, and z1 may be the same as defined in Formula 2.

In an embodiment, the (1-1)-th compound may include at least one compound selected from Compound Group 1-1, which is explained below.

In an embodiment, the (2-1)-th compound may include at least one compound selected from Compound Group 2-1, which is explained below.

According to embodiment, a display device may include a circuit layer disposed on a base layer, and a display element layer disposed on the circuit layer and including a light emitting element, wherein

the light emitting element may include a first electrode, a first emission layer disposed on the first electrode and including a (1-1)-th compound represented Formula 1, a second emission layer disposed on the first emission layer and including a (2-1)-th compound represented by Formula 2, and a second electrode disposed on the second emission layer; and the (2-1)-th compound may have a lowest excited triplet energy level (T1) in a range of about 1.5 eV to about 2.1 eV.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display device according to an embodiment;

FIG. 2 is a schematic cross-sectional view of a portion of a display device according to the embodiment;

FIG. 3 is a schematic cross-sectional view of a light emitting element according to an embodiment;

FIG. 4 is a schematic cross-sectional view of a light emitting element according to an embodiment;

FIG. 5 is a schematic cross-sectional view of a light emitting element according to an embodiment;

FIG. 6 is a schematic cross-sectional view of a light emitting element according to an embodiment;

FIG. 7 is a schematic cross-sectional view of a display device according to an embodiment;

FIG. 8 is a schematic cross-sectional view of a display device according to an embodiment;

FIG. 9 is a schematic cross-sectional view of a display device according to an embodiment;

FIG. 10 is a schematic cross-sectional view of a display device according to an embodiment; and

FIG. 11 is a schematic diagram of an interior of a vehicle in which display devices according to embodiments are disposed.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within +20%, ±10%, or +5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, a silyl group, an oxy group, a thio group, a germyl group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the term “bonded to an adjacent group to form a ring” may refer to a group that is bonded to an adjacent group to form a substituted or unsubstituted hydrocarbon ring or a substituted or unsubstituted heterocycle. A hydrocarbon ring may be aliphatic or aromatic. A heterocycle may be aliphatic or aromatic. The hydrocarbon ring and the heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent that is substituted for an atom which is substituted with a corresponding substituent, or as a substituent that is sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification and claims, terminology such as “(1-1)-th” may be read as “first-first” and is used for the sake of textual efficiency. The numbers within the parentheses are used to stand in the place of ordinal numbers. For example, “(1-3)-th” may be read as “first-third”, and “(2-2)-th” may be read as “second-second”.

In the specification, examples of a halogen atom may include a fluorine atom, a chlorine atom, a bromine atom, and an iodine atom.

In the specification, an alkyl group may be linear or branched. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, a cycloalkyl group may be a cyclic alkyl group. The number of carbon atoms in a cycloalkyl group may be 3 to 50, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments are not limited thereto.

In the specification, an alkenyl group may be a hydrocarbon group that includes at least one carbon-carbon double bond in the middle or at a terminus of an alkyl group having 2 or more carbon atoms. An alkenyl group may be linear or branched. The number of carbon atoms in an alkenyl group is not particularly limited, and may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but embodiments are not limited thereto.

In the specification, an alkynyl group may be a hydrocarbon group that includes at least one carbon-carbon triple bond in the middle or at a terminus of an alkyl group having 2 or more carbon atoms. An alkynyl group may be linear or branched. The number of carbon atoms in an alkynyl group is not particularly limited, and may be 2 to 30, 2 to 20, or 2 to 10. Examples of an alkynyl group may include an ethynyl group, a propynyl group, etc., but embodiments are not limited thereto.

In the specification, a hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, an acenaphthyl group, a benzofluoranthenyl group, a chrysenyl group, etc., but embodiments are not limited thereto.

In the specification, a fluorenyl group may be substituted, and two substituents may be bonded to each other to form a spiro structure. Examples of a substituted fluorenyl group may include the groups shown below. However, embodiments are not limited thereto.

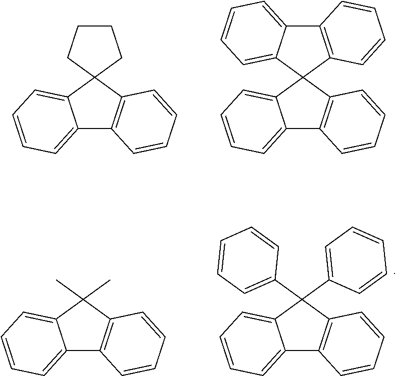

In the specification, a heterocyclic group may be any functional group or substituent derived from a ring that includes at least one of B, O, N, P, Si, S, Se, Te as a heteroatom. A heterocyclic group may be aliphatic or aromatic. An aromatic heterocyclic group may be a heteroaryl group. An aliphatic heterocycle and an aromatic heterocycle may each independently be monocyclic or polycyclic.

If a heterocyclic group include two or more heteroatoms, the two or more heteroatoms may be the same as or different from each other. The number of ring-forming carbon atoms in a heterocyclic group may be 2 to 60, 2 to 30, 2 to 20, or 2 to 10.

Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a benzothienocarbazole group, a benzothienoindole group, a benzodibenzothiophene group, a thienothiophene group, an indolodibenzothiophene group, a benzoselenophene group, a dibenzoselenophene group, a benzoselenophenocarbazole group, a benzoselenophenoindole group, a benzotellurophene group, a dibenzotellurophene group, a benzotellurophenocarbazole group, a benzotellurophenoindole group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of an aryl group may be applied to an arylene group, except that an arylene group is a divalent group. In the specification, the above description of a heteroaryl group may be applied to a heteroarylene group, except that a heteroarylene group is a divalent group.

In the specification, a silyl group may be an alkylsilyl group or an arylsilyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in a carbonyl group is not particularly limited, and may be 1 to 40, 1 to 30, or 1 to 20. For example, a carbonyl group may have one of the following structures, but embodiments are not limited thereto.

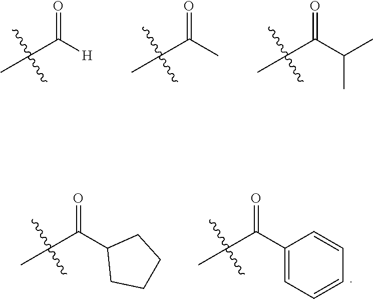

In the specification, the number of carbon atoms in a sulfinyl group or a sulfonyl group is not particularly limited, and may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or to an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments are not limited thereto.

In the specification, an oxy group may be an oxygen atom that is bonded to an alkyl group or to an aryl group as defined above. An oxy group may be an alkoxy group or an aryl oxy group.

An alkoxy group may be linear, branched, or cyclic. The number of carbon atoms in an alkoxy group is not particularly limited, and may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group may be a boron atom that is bonded to an alkyl group or to an aryl group as defined above. A boron group may be an alkyl boron group or an aryl boron group. Examples of a boron group may include a dimethylboron group, a trimethylboron group, a t-butyldimethylboron group, a diphenylboron group, a phenylboron group, etc., but embodiments are not limited thereto.

In the specification, the number of carbon atoms in an amine group is not particularly limited, and may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, etc., but embodiments are not limited thereto.

In the specification, a selenyl group may be an alkyl selenyl group or an aryl selenyl group. A selenyl group may be a selenium atom that is bonded to an alkyl group or to an aryl group as defined above. Examples of a selenyl group may include a methylselenyl group, an ethylselenyl group, a propylselenyl group, a pentylselenyl group, a hexylselenyl group, an octylselenyl group, a dodecylselenyl group, a cyclopentylselenyl group, a cyclohexylselenyl group, a phenylselenyl group, a naphthylselenyl group, or the like, but embodiments are not limited thereto.

In the specification, a tellanyl group may be an alkyl tellanyl group or an aryl tellanyl group. A tellanyl group may be a tellurium atom that is bonded to an alkyl group or to an aryl group as defined above. Examples of a tellanyl group may include a methyltellanyl group, an ethyltellanyl group, a propyltellanyl group, a pentyltellanyl group, a hexyltellanyl group, an octyltellanyl group, a dodecyltellanyl group, a cyclopentyltellanyl group, a cyclohexyltellanyl group, a phenyltellanyl group, a naphthyltellanyl group, or the like, but embodiments are not limited thereto.

In the specification, a germyl group may be an alkyl germyl group or an aryl germyl group. A germyl group may be a germanium atom that is bonded to an alkyl group or to an aryl group as defined above. Examples of a germyl group may include a methylgermyl group, an ethylgermyl group, a propylgermyl group, a pentylgermyl group, a hexylgermyl group, an octylgermyl group, a dodecylgermyl group, a cyclopentylgermyl group, a cyclohexylgermyl group, a phenylgermyl group, a naphthylgermyl group, or the like, but embodiments are not limited thereto.

In the specification, an alkyl group within an alkylthio group, an alkylsulfoxy group, an alkylaryl group, an alkylamino group, an alkyl boron group, an alkyl silyl group, or an alkyl amine group may be the same as an example of an alkyl group as described above.

In the specification, an aryl group within an aryloxy group, an arylthio group, an arylsulfoxy group, an arylamino group, an arylboron group, an arylsilyl group, or an arylamine group may be the same as an example of an aryl group as described above.

In the specification, a direct linkage may be a single bond.

In the specification, the symbols

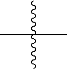

and —* each represent a bond to a neighboring atom in a corresponding formula or moiety.

Hereinafter, embodiments will be described with reference to the accompanying drawings.

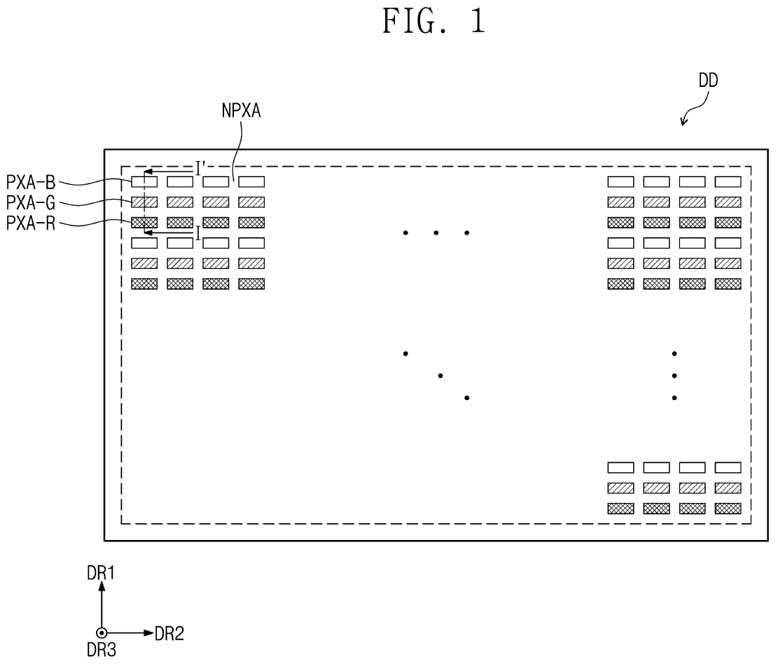

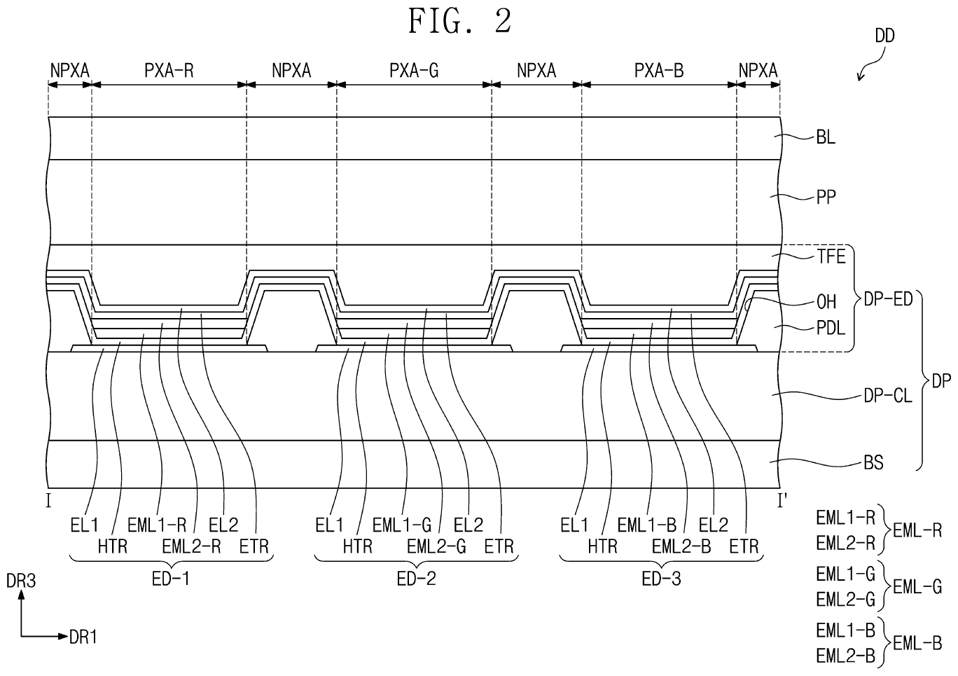

FIG. 1 is a schematic plan view of a display device DD according to an embodiment. FIG. 2 is a schematic cross-sectional view of the display device DD. FIG. 2 is a schematic cross-sectional view of a portion of the display device DD taken along virtual line I-I′ of FIG. 1.

The display device DD may include a display panel DP and an optical layer PP disposed on the display panel DP. The display panel DP includes light emitting elements ED-1, ED-2, and ED-3. The display device DD may include multiples of the light emitting elements ED-1, ED-2, and ED-3. The optical layer PP may be disposed on the display panel DP to control light that is reflected at the display panel DP from an external light. The optical layer PP may include, for example, a polarization layer or a color filter layer. Although not shown in the drawings, in an embodiment, the optical layer PP may be omitted from the display device DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display device layer DP-ED and the base substrate BL. The filling layer (not shown) may be an organic material layer. The filling layer (not shown) may include at least one of an acrylic-based resin, a silicone-based resin, and an epoxy-based resin.

The display panel DP may include a base layer BS, a circuit layer DP-CL provided on the base layer BS, and the display device layer DP-ED. The display device layer DP-ED may include a pixel defining film PDL, light emitting elements ED-1, ED-2, and ED-3 disposed between portions of the pixel defining film PDL, and an encapsulation layer TFE disposed on the light emitting elements ED-1, ED-2, and ED-3.

The base layer BS may provide a base surface on which the display device layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting elements ED-1, ED-2, and ED-3 of the display device layer DP-ED.

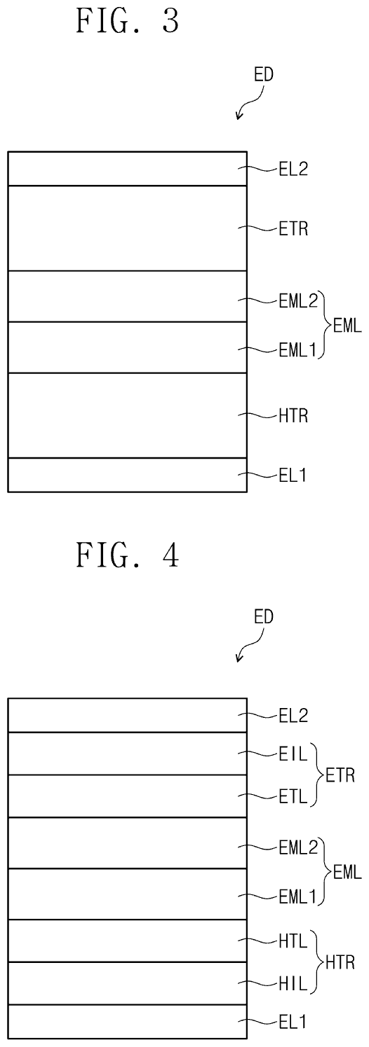

The light emitting elements ED-1, ED-2, and ED-3 may each have a structure of a light emitting element ED of an embodiment according to any of FIGS. 3 to 6, which will be described later. The light emitting elements ED-1, ED-2, and ED-3 may each include a first electrode EL1, a hole transport region HTR, emission layers EML-R, EML-G, and EML-B, an electron transport region ETR, and a second electrode EL2.

The emission layers EML-R, EML-G, and EML-B may include a red emission layer EML-R, a green emission layer EML-G, and a blue emission layer EML-B. The red emission layer EML-R, the green emission layer EML-G, and the blue emission layer EML-B may respectively correspond to the red emission region PXA-R, the green emission region PXA-G, and the blue emission region PXA-B. The red emission layer EML-R may include a first red emission layer EML1-R and a second red emission layer EML2-R that are stacked, the green emission layer EML-G may include a first green emission layer EML1-G and a second green emission layer EML2-G that are stacked, and the blue emission layer EML-B may include a first blue emission layer EML1-B and a second blue emission layer EML2-B that are stacked. The stacked structure of the emission layers EML-R, EML-G, and EML-B will be described later together with FIG. 3.

FIG. 2 illustrates an embodiment in which the emission layers EML-R, EML-G, and EML-B of the light emitting elements ED-1, ED-2, and ED-3 are disposed in openings OH defined in the pixel defining film PDL, and the hole transport region HTR, the electron transport region ETR, and the second electrode EL2 are each provided as a common layer in the entire light emitting elements ED-1, ED-2, and ED-3. However, embodiments are not limited thereto. Although not shown in FIG. 2, the hole transport region HTR and the electron transport region ETR may each be provided by being patterned in the openings OH defined in the pixel defining film PDL. For example, in an embodiment, the hole transport region HTR, the emission layers EML-R, EML-G, and EML-B, and the electron transport region ETR of the light emitting elements ED-1, ED-2, and ED-3 may each be provided by being patterned through an inkjet printing method.

The encapsulation layer TFE may cover the light emitting elements ED-1, ED-2, and ED-3. The encapsulation layer TFE may seal the display device layer DP-ED. The encapsulation layer TFE may be a thin film encapsulation layer. The encapsulation layer TFE may be formed of a single layer or of multiple layers. The encapsulation layer TFE may include at least one insulation layer. The encapsulation layer TFE according to an embodiment may include at least one inorganic film (hereinafter, an encapsulation-inorganic film). The encapsulation layer TFE according to an embodiment may also include at least one organic film (hereinafter, an encapsulation-organic film) and at least one encapsulation-inorganic film.

The encapsulation-inorganic film protects the display device layer DP-ED from moisture and/or oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region that emits light respectively generated by the light emitting elements ED-1, ED-2, and ED-3. The light emitting regions PXA-R, PXA-G, and PXA-B may be spaced apart from each other in a plan view.

The light emitting regions PXA-R, PXA-G, and PXA-B may be regions that are separated from each other by the pixel defining film PDL. The non-light emitting regions NPXA may be areas between the adjacent light emitting regions PXA-R, PXA-G, and PXA-B, and which may correspond to the pixel defining film PDL. In an embodiment, the light emitting regions PXA-R, PXA-G, and PXA-B may each correspond to a pixel. The pixel defining film PDL may separate the light emitting elements ED-1, ED-2, and ED-3. The emission layers EML-R, EML-G, and EML-B of the light emitting elements ED-1, ED-2, and ED-3 may be disposed in openings OH defined in the pixel defining film PDL and separated from each other.

The light emitting regions PXA-R, PXA-G, and PXA-B may be arranged into groups according to the color of light generated from the light emitting elements ED-1, ED-2, and ED-3. In the display device DD according to an embodiment illustrated in FIGS. 1 and 2, three light emitting regions PXA-R, PXA-G, and PXA-B, which respectively emit red light, green light, and blue light, are illustrated as an example. For example, the display device DD may include a red light emitting region PXA-R, a green light emitting region PXA-G, and a blue light emitting region PXA-B, which are distinct from each other.

In the display device DD according to an embodiment, the light emitting elements ED-1, ED-2, and ED-3 may emit light having wavelengths that are different from each other. For example, in an embodiment, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may respectively correspond to the first light emitting element ED-1, the second light emitting element ED-2, and the third light emitting element ED-3.

However, embodiments are not limited thereto, and the first to third light emitting elements ED-1, ED-2, and ED-3 may emit light in a same wavelength range, or at least one light emitting element may emit light in a wavelength range that is different from the remainder. For example, the first to third light emitting elements ED-1, ED-2, and ED-3 may each emit blue light.

The light emitting regions PXA-R, PXA-G, and PXA-B in the display device DD according to an embodiment may be arranged in a stripe configuration. Referring to FIG. 1, the red light emitting regions PXA-R, the green light emitting regions PXA-G, and the blue light emitting regions PXA-B may be respectively arranged along a second directional axis DR2. In another embodiment, the red light emitting region PXA-R, the green light emitting region PXA-G, and the blue light emitting region PXA-B may be arranged in this repeating order along a first directional axis DR1.

FIGS. 1 and 2 illustrate that the light emitting regions PXA-R, PXA-G, and PXA-B all have a similar area, but embodiments are not limited thereto. In an embodiment, the light emitting regions PXA-R, PXA-G, and PXA-B may be different in size or shape from each other, according to a wavelength range of emitted light. The areas of the light emitting regions PXA-R, PXA-G, and PXA-B may be areas in a plan view that are defined by the first directional axis DR1 and the second directional axis DR2.

An arrangement of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations, according to the display quality characteristics that are required for the display device DD. For example, the light emitting regions PXA-R, PXA-G, and PXA-B may be arranged in a pentile configuration (such as PenTile®) or in a diamond configuration (such as Diamond Pixel®).

The areas of the light emitting regions PXA-R, PXA-G, and PXA-B may be different in size from each other. For example, in an embodiment, an area of a green light emitting region PXA-G may be smaller than an area of a blue light emitting region PXA-B, but embodiments are not limited thereto.

Hereinafter, FIG. 3 to FIG. 6 are each a schematic cross-sectional view of a light emitting element according to an embodiment. According to an embodiment as shown in FIG. 3, a light emitting element ED may include a first electrode EL1, a hole transport region HTR, an emission layer EML, an electron transport region ETR, and a second electrode EL2, which are stacked in that order. In the light emitting element ED according to an embodiment, the emission layer EML may include a first emission layer EML1 and a second emission layer EML2, which are stacked.

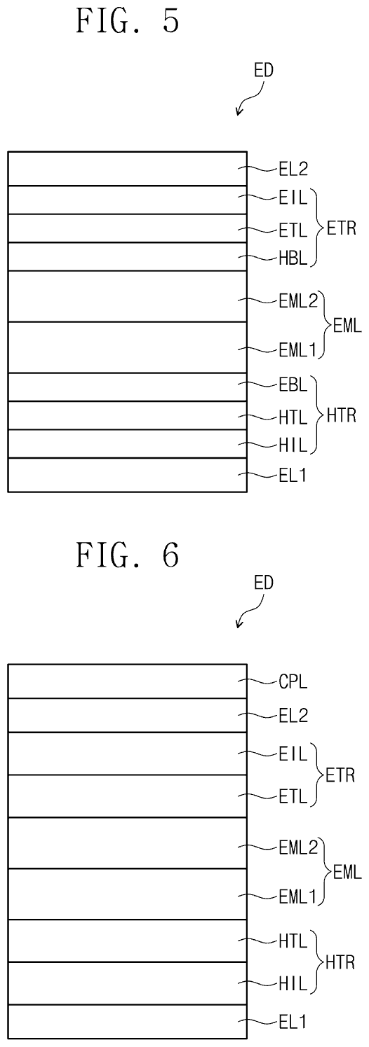

In comparison to FIG. 3, FIG. 4 is a schematic cross-sectional view of a light emitting element ED according to an embodiment, in which a hole transport region HTR includes a hole injection layer HIL and a hole transport layer HTL, and an electron transport region ETR includes an electron injection layer EIL and an electron transport layer ETL. In comparison to FIG. 3, FIG. 5 is a schematic cross-sectional view of a light emitting element ED according to an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 4, FIG. 6 is a schematic cross-sectional view of a light emitting element ED according to an embodiment that further includes a capping layer CPL disposed on the second electrode EL2.

The first electrode EL1 has conductivity. The first electrode EL1 may be formed of a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, and Zn, or may include an oxide thereof, a compound thereof, or a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another embodiment, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layered structure of ITO/Ag/ITO, but embodiments are not limited thereto. In an embodiment, the first electrode EL1 may include the above-described metal materials, combinations of at least two of the above-described metal materials, oxides of the above-described metal materials, or the like. A thickness of the first electrode EL1 may be in a range of about 700 Å to about 10,000 Å. For example, the thickness of the first electrode EL1 may be in a range of about 1,000 Å to about 3,000 Å.

The hole transport region HTR may be provided on the first electrode EL1. The hole transport region HTR may include at least one of a hole injection layer HIL, a hole transport layer HTL, a buffer layer (not shown), an emission-auxiliary layer (not shown), and an electron blocking layer EBL. A thickness of the hole transport region HTR may be, for example, in a range of about 50 Å to about 15,000 Å.

The hole transport region HTR may have a structure consisting of a layer consisting of a single material, a structure consisting of a layer including different materials, or a structure including multiple layers including different materials.

In embodiments, the hole transport region HTR may have a single layer structure of a hole injection layer HIL or a hole transport layer HTL, or may have a single layer structure formed of a hole injection material and a hole transport material. In embodiments, the hole transport region HTR may have a single layer structure formed of different materials, or may have a structure in which a hole injection layer HIL/hole transport layer HTL, a hole injection layer HIL/hole transport layer HTL/buffer layer (not shown), a hole injection layer HIL/buffer layer (not shown), a hole transport layer HTL/buffer layer (not shown), or a hole injection layer HIL/hole transport layer HTL/electron blocking layer EBL are stacked in its respective stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the hole transport region HTR may include a compound represented by Formula H-1:

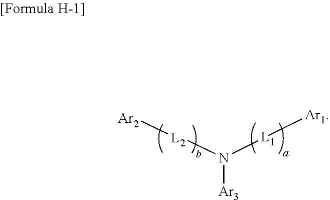

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. When a or b is 2 or greater, multiple L₁ groups or multiple L₂ groups may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In Formula H-1, Ar₃ may be a substituted or unsubstituted aryl group having 6 to 30 ring-forming carbon atoms or a substituted or unsubstituted heteroaryl group having 2 to 30 ring-forming carbon atoms.

In an embodiment, the compound represented by Formula H-1 may be a monoamine compound. In another embodiment, the compound represented by Formula H-1 may be a diamine compound in which at least one of Ar₁ to Ar₃ includes an amine group as a substituent. In an embodiment, the compound represented by Formula H-1 may be a carbazole-based compound in which at least one of Ar₁ and Ar₂ includes a substituted or unsubstituted carbazole group, or may be a fluorene-based compound in which at least one of Ar₁ and Ar₂ includes a substituted or unsubstituted fluorene group.

The compound represented by Formula H-1 may be any compound selected from Compound Group H. However, the compounds listed in Compound Group H are only examples, and the compounds represented by Formula H-1 are not limited to Compound Group H:

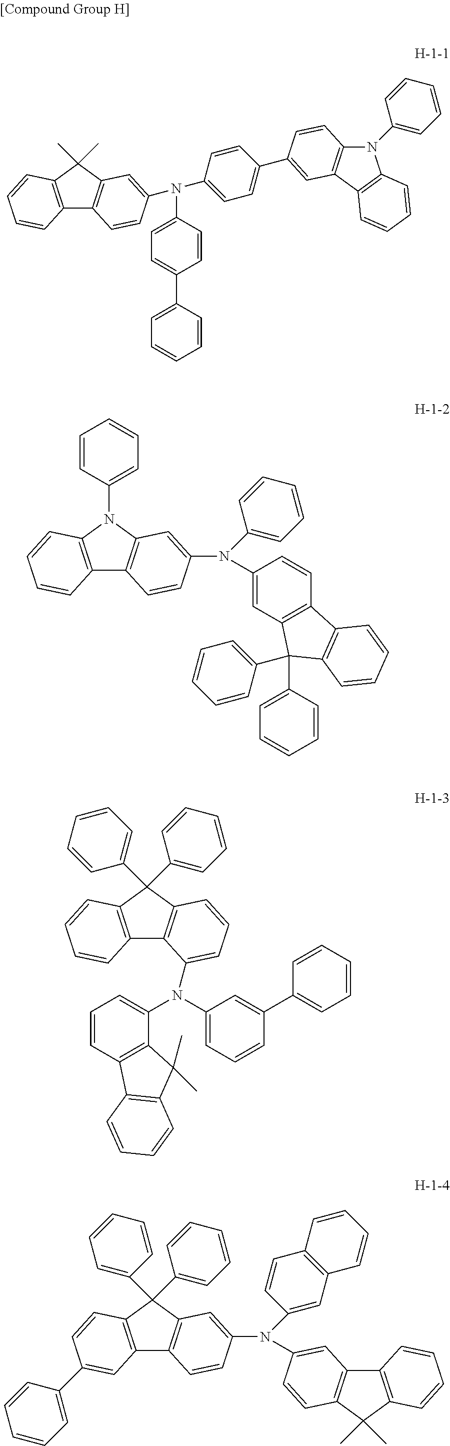 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

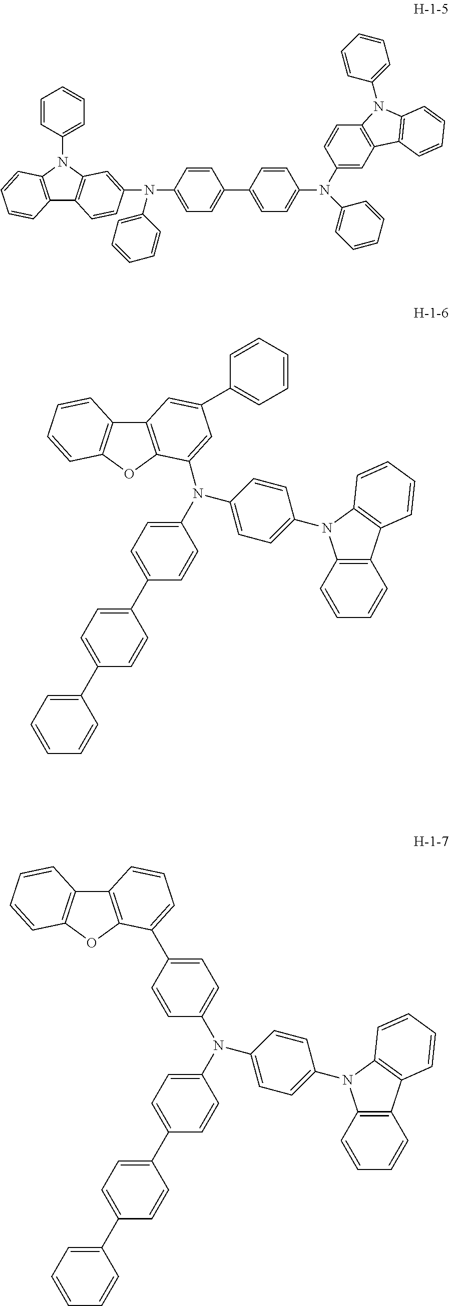 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

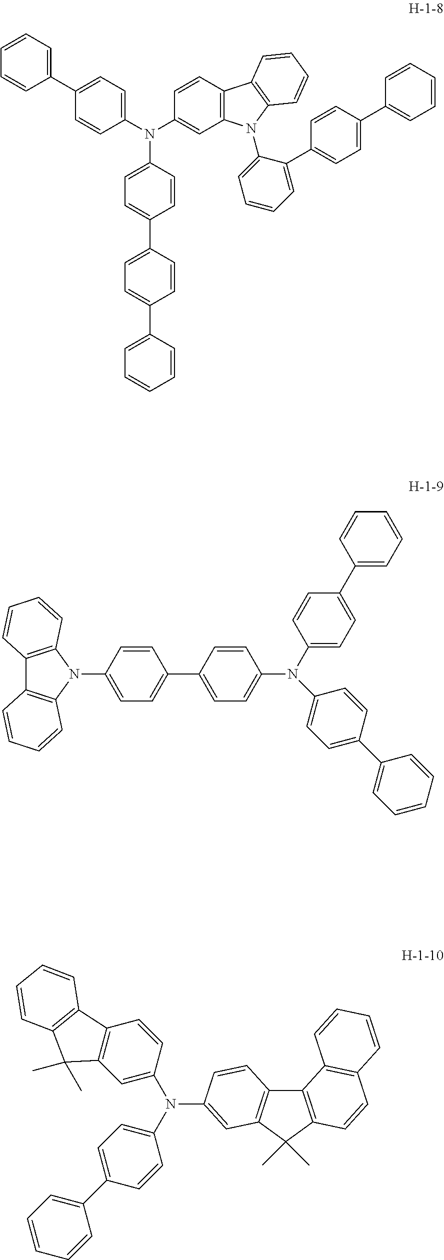 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

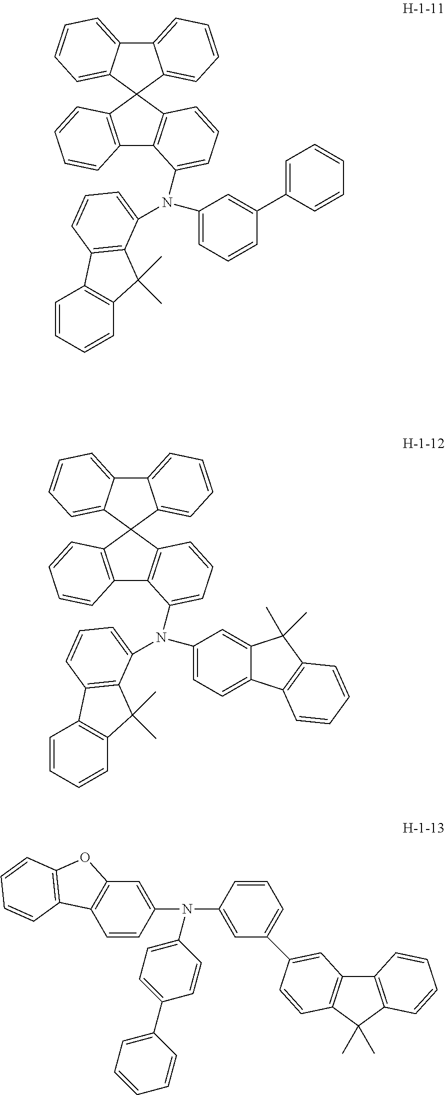 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

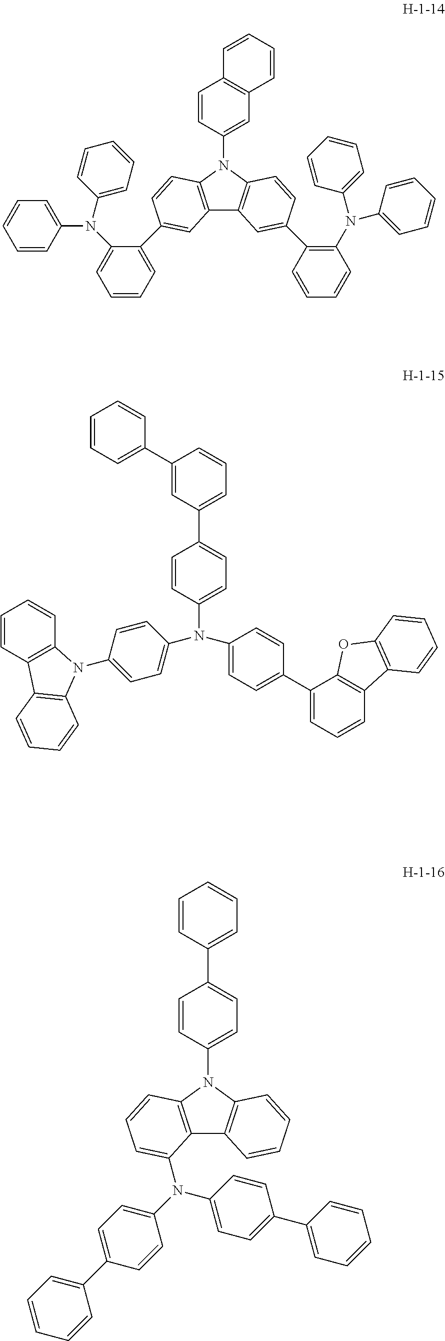 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

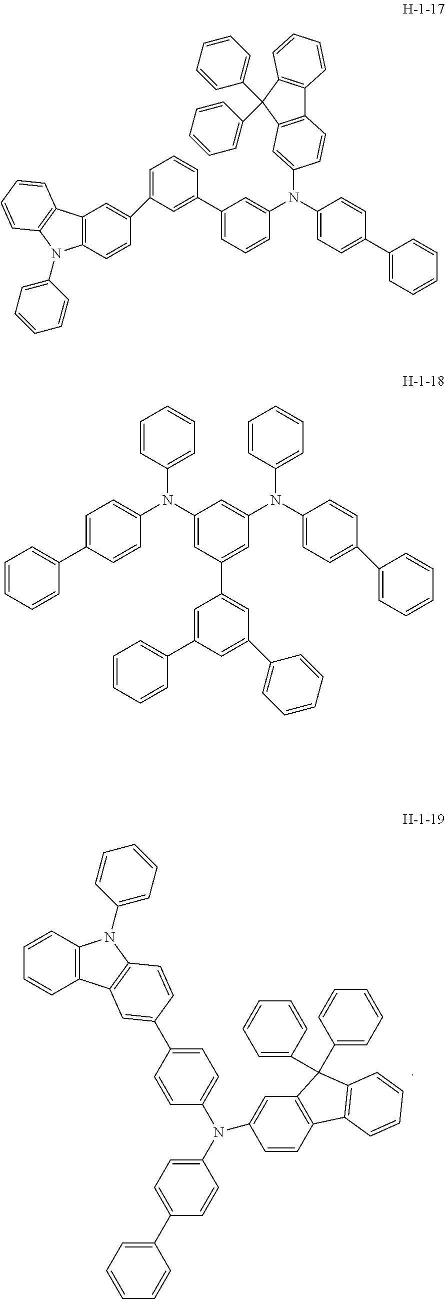 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzene sulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[11,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine](TAPC), 4,4′-bis[N,N′-(3-tolyl)amino]-3,3′-dimethylbiphenyl (HMTPD), 1,3-bis(N-carbazolyl)benzene (mCP), etc.

In an embodiment, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, and an electron blocking layer EBL.

A thickness of the hole transport region HTR may be in a range of about 100 Å to about 10,000 Å. For example, the thickness of the hole transport region HTR may be in a range of about 100 Å to about 5,000 Å. When the hole transport region HTR includes a hole injection layer HIL, the hole injection layer HIL may have a thickness in a range of about 30 Å to about 1,000 Å. When the hole transport region HTR includes a hole transport layer HTL, the hole transport layer HTL may have a thickness in a range of about 250 Å to about 1,000 Å. When the hole transport region HTR includes an electron blocking layer EBL, the electron blocking layer EBL may have a thickness in a range of about 10 Å to about 1,000 Å. If the thicknesses of the hole transport region HTR, the hole injection layer HIL, the hole transport layer HTL and the electron blocking layer EBL satisfy the above-described ranges, satisfactory hole transport properties may be achieved without a substantial increase in driving voltage.

The hole transport region HTR may further include a charge generating material to increase conductivity, in addition to the above-described materials. The charge generating material may be dispersed uniformly or non-uniformly in the hole transport region HTR. The charge generating material may be, for example, a p-dopant. The p-dopant may include at least one of a metal halide, a quinone derivative, a metal oxide, and a cyano group-containing compound, but embodiments are not limited thereto. For example, the p-dopant may include a metal halide compound such as CuI or RbI, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino[2,3-f: 2′,3′-h]quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of a buffer layer (not shown) and an electron blocking layer EBL, in addition to a hole injection layer HIL and a hole transport layer HTL. The buffer layer (not shown) may compensate for a resonance distance according to a wavelength of light emitted from an emission layer EML and may thus increase light emission efficiency. A material that may be included in the hole transport region HTR may be used as a material in the buffer layer (not shown). The electron blocking layer EBL may prevent the injection of electrons from an electron transport region ETR to the hole transport region HTR.

The emission layer EML may be provided on the hole transport region HTR.

The emission layer EML may be formed by using various methods such as a vacuum deposition method, a spin coating method, a casting method, a Langmuir-Blodgett (LB) method, an inject printing method, a laser printing method, and a laser induced thermal imaging (LITI) method.

The emission layer EML may have a structure that includes multiple layers. The emission layer EML may include a first emission layer EML1 and a second emission layer EML2. In the specification, the emission layer EML is shown to have a two-layer structure, but embodiments are not limited thereto. In embodiments, the emission layer EML may further include a single third emission layer (not shown) or multiple third emission layers (not shown), which may be disposed on a lower portion of the first emission layer EML1, on an upper portion of the second emission layer EML2, or between the first emission layer EML1 and the second emission layer EML2.

The emission layer EML may have a thickness, for example, in a range of about 100 Å to about 1,000 Å. The first emission layer EML1 may have a thickness in a range of about 50 Å to about 500 Å. For example, the first emission layer EML1 may have a thickness in a range of about 50 Å to about 300 Å. The second emission layer EML2 may have a thickness in a range of about 50 Å to about 500 Å. For example, the second emission layer EML2 may have a thickness in a range of about 50 Å to about 200 Å.

In an embodiment, the first emission layer EML1 may emit delayed fluorescence. For example, the first emission layer EML1 may emit fluorescence by thermally activated delayed fluorescence (TADF).

The first emission layer EML1 may include a (1-1)-th compound. The (1-1)-th compound according to an embodiment may have a lowest triplet energy (T1) in a range of about 2.5 eV to about 3.1 eV. For example, the (1-1)-th compound may have a lowest triplet energy (T1) in a range of about 2.5 eV to about 2.8 eV. The first emission layer EML1 may include the (1-1)-th compound as a dopant. The (1-1)-th compound according to an embodiment may be a thermally activated delayed fluorescence dopant material in the first emission layer EML1.

The (1-1)-th compound according to an embodiment may include a structure in which first to third aromatic rings are fused via a boron atom, a first nitrogen atom, and a second nitrogen atom. The first to third aromatic rings may each be linked to the boron atom, the first aromatic ring and the third aromatic ring may be linked to each other via the first nitrogen atom, and the second aromatic ring and the third aromatic ring may be linked to each other via the second nitrogen atom. In an embodiment, the first to third aromatic rings may be 6-membered aromatic hydrocarbon rings. For example, the first to third aromatic rings may each be a benzene ring. In the specification, a pentacyclic fused structure formed by the boron atom, the first nitrogen atom, the second nitrogen atom, and the first to third aromatic rings that are fused via the boron atom, the first nitrogen atom, and the second nitrogen atom may be referred to as a “first fused ring core.”

The (1-1)-th compound according to an embodiment may be represented by Formula 1:

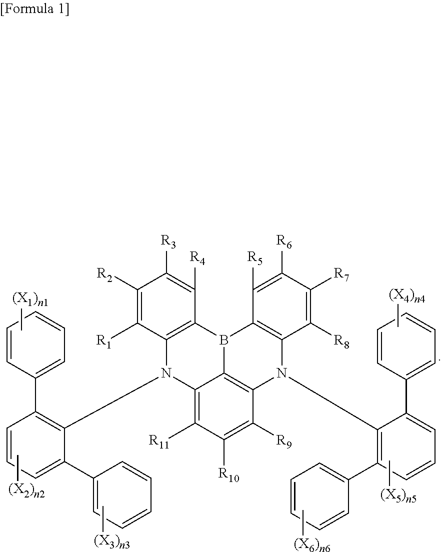

The (1-1)-th compound represented by Formula 1 may have a structure in which three aromatic rings are fused via a boron atom, a first nitrogen atom, and a second nitrogen atom.

In Formula 1, R₁ to R₁₁ may each independently be a hydrogen atom, a deuterium atom, a halogen atom, a cyano group, a hydroxy group, a substituted or unsubstituted oxy group, a substituted or unsubstituted thio group, a substituted or unsubstituted selenyl group, a substituted or unsubstituted tellanyl group, a substituted or unsubstituted boron group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, R₁, R₃ to R₅, R₈, R₉, and R₁₁ may each independently be a hydrogen atom or a deuterium atom; R₂, R₆, and R₇ may each independently be a hydrogen atom, a deuterium atom, a substituted or unsubstituted aryl group having 6 to 30 ring-forming carbon atoms, or a substituted or unsubstituted carbazole group; and R₁₀ may be a substituted or unsubstituted t-butyl group, a substituted or unsubstituted phenyl group, or a substituted or unsubstituted dibenzofuran group.

For example, R₂ and R₄ may each independently be an oxy group, a thio group, a selenyl group, a tellanyl group, or an amine group that is substituted with a phenyl group, etc.; R₃ may be a substituted or unsubstituted boron group; and when R₂, R₃, and R₄ are bonded to each other, Formula 1 may provide four additional fused rings linked to the first fused ring core via the boron atom of R₃ and the two heteroatoms of R₂ and R₄.

In Formula 1, X₁ to X₆ may each independently be a hydrogen atom, a deuterium atom, a halogen atom, a cyano group, a hydroxy group, a substituted or unsubstituted oxy group, a substituted or unsubstituted thio group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, X₁ to X₆ may each independently be a hydrogen atom, a deuterium atom, a substituted or unsubstituted t-butyl group, or a substituted or unsubstituted phenyl group. For example, Formula 1 may include multiple X₆ groups, one of the X₆ groups may be an unsubstituted oxy group, the remainder of the X₆ groups may include an unsubstituted phenyl group, and when two X₆ groups are bonded to each other, the (1-1)-th compound represented by Formula 1 may include a diphenyldibenzofuran moiety.

In Formula 1, n1, n3, n4, and n6 may each independently be an integer from 0 to 5. If n1, n3, n4, and n6 are each 0, the (1-1)-th compound may not be substituted with X₁, X₃, X₄, and X₆, respectively. A case where n1, n3, n4, and n6 are each 5 and five groups of each of X₁, X₃, X₄, and X₆ are all hydrogen atoms may be the same as a case where n1, n3, n4, and n6 are each 0. If n1, n3, n4, and n6 are each 2 or greater, multiple groups of each of X₁, X₃, X₄, and X₆ may all be the same, or at least one thereof may be different from the remainder.

In Formula 1, n2 and n5 may each independently be an integer from 0 to 3. If n2 and n5 are each 0, the (1-1)-th compound may not be substituted with X₂ and X₅, respectively. A case where n2 and n5 are each 3 and three groups of each of X₂ and X₅ are all hydrogen atoms may be the same as a case where n2 and n5 are each 0. If n2 and n5 are each 2 or greater, multiple X₂ groups and multiple X₅ groups may all be the same, or at least one thereof may be different from the remainder.

In the specification, in Formula 1, the benzene ring that includes R₁ to R₄ as substituents may correspond to the aforementioned first aromatic ring, the benzene ring that includes R₅ to R₈ as substituents may correspond to the aforementioned second aromatic ring, and the benzene ring that includes R₉ to R₁₁ as substituents may correspond to the aforementioned third aromatic ring. The nitrogen atoms in Formula 1 may correspond to the first nitrogen atom and the second nitrogen atom, respectively, as described above.

In an embodiment, the (1-1)-th compound represented by Formula 1 may be represented by one of Formula 1-1 to Formula 1-3:

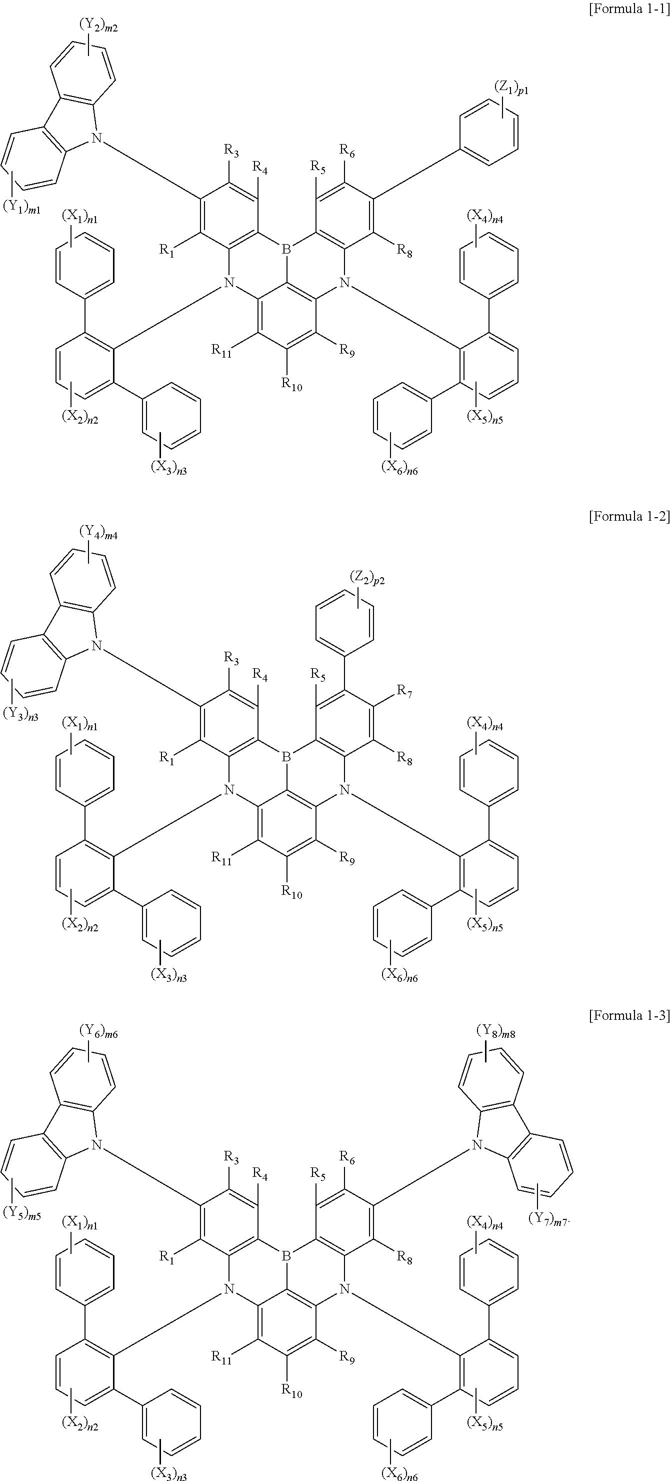

Formula 1-1 and Formula 1-3 each represent a case where R₂ and R₇ in Formula 1 are further defined, and Formula 1-2 represents a case where R₂ and R₆ in Formula 1 are further defined.

In Formula 1-1 to Formula 1-3, Y₁ to Y₈, Z₁, and Z₂ may each independently be a hydrogen atom, a deuterium atom, a halogen atom, a cyano group, a hydroxy group, a substituted or unsubstituted oxy group, a substituted or unsubstituted thio group, a substituted or unsubstituted selenyl group, a substituted or unsubstituted tellanyl group, a substituted or unsubstituted germyl group, a substituted or unsubstituted boron group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, Y₁ to Y₈, Z₁, and Z₂ may each independently be a hydrogen atom, a deuterium atom, a substituted or unsubstituted silyl group, a substituted or unsubstituted t-butyl group, a substituted or unsubstituted phenyl group, a substituted or unsubstituted biphenyl group, or a substituted or unsubstituted carbazole group. For example, two Y₁ groups may be bonded to each other to form a ring. As another example, one Y₁ group may be an unsubstituted oxy group or an unsubstituted thio group, another Y₁ group may be an unsubstituted phenyl group, and the two Y₁ groups may be bonded to each other so that the (1-1)-th compound represented by Formula 1-1 may include a benzothienocarbazole moiety or a benzofurocarbazole moiety.

In Formula 1-1 to Formula 1-3, m1 to m8 may each independently be an integer from 0 to 4. If m1 to m8 are each 0, the (1-1)-th compound may not be substituted with Y₁ to Y₈, respectively. A case where m1 to m8 are each 4 and four groups of each of Y₁ to Y₈ are all hydrogen atoms may be the same as a case where m1 to m8 are each 0. When m1 to m8 are each 2 or greater, multiple groups of each of Y₁ to Y₈ may all be the same, or at least one thereof may be different from the remainder.

In Formula 1-1 and Formula 1-2, p1 and p2 may each independently be an integer from 0 to 5. If p1 and p2 are each 0, the (1-1)-th compound may not be substituted with Z₁ and Z₂, respectively. A case where p1 and p2 are each 3 and three Z₁ groups and three Z₂ groups are all hydrogen atoms may be the same as a case where p1 and p2 are each 0. If p1 and p2 are each 2 or greater, multiple Z₁ groups and multiple Z₂ groups may all be the same, or at least one thereof may be different from the remainder.

In Formula 1-1 to Formula 1-3, R₁, R₃ to R₁₁, X₁ to X₆, and n1 to n6 may be the same as defined in Formula 1.

In an embodiment, the (1-1)-th compound represented by Formula 1 may be represented by Formula 1-4:

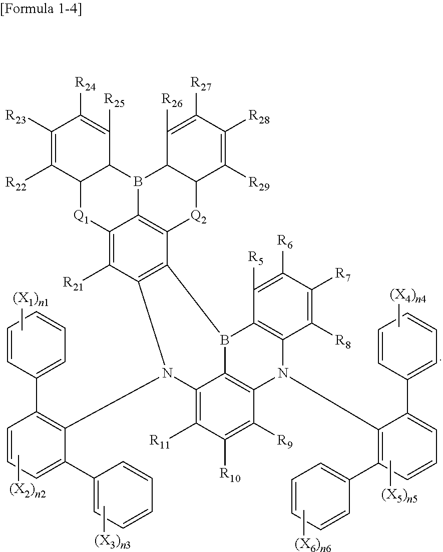

Formula 1-4 represents a case where R₁ to R₄ in Formula 1 are further defined. Formula 1-4 represents a case where four rings are additionally fused to the first fused ring core from substituents represented by R₁ to R₄.

In Formula 1-4, Q₁ and Q₂ may each independently be O, S, Se, Te, or N(R₃₀).

In Formula 1-4, R₂₁ to R₃ may each independently be a hydrogen atom, a deuterium atom, a halogen atom, a cyano group, a substituted or unsubstituted alkyl group having 1 to 20 carbon group, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, R₂₁, R₂₂, R₂₅, R₂₆, R₂₉, and R₃₀ may each independently be a hydrogen atom or a deuterium atom; and R₂₃, R₂₄, R₂₇, and R₂₈ may each independently be a hydrogen atom, a deuterium atom, a substituted or unsubstituted phenyl group, or a substituted or unsubstituted carbazole group. For example, when Q₁ is N(R₃₀), R₃₀ may be a substituted or unsubstituted phenyl group, and R₂₂ and R₃₀ may be bonded to each other, such that Formula 1-4 may have a structure that includes an additional ring that is fused to the four fused rings formed from R₁ to R₄.

In Formula 1-4, R₅ to R₁₁, X₁ to X₆, and n1 to n6 may be the same as defined in Formula 1.

In an embodiment, the (1-1)-th compound represented by Formula 1 may be represented by one of Formula 1-5 to 1-11:

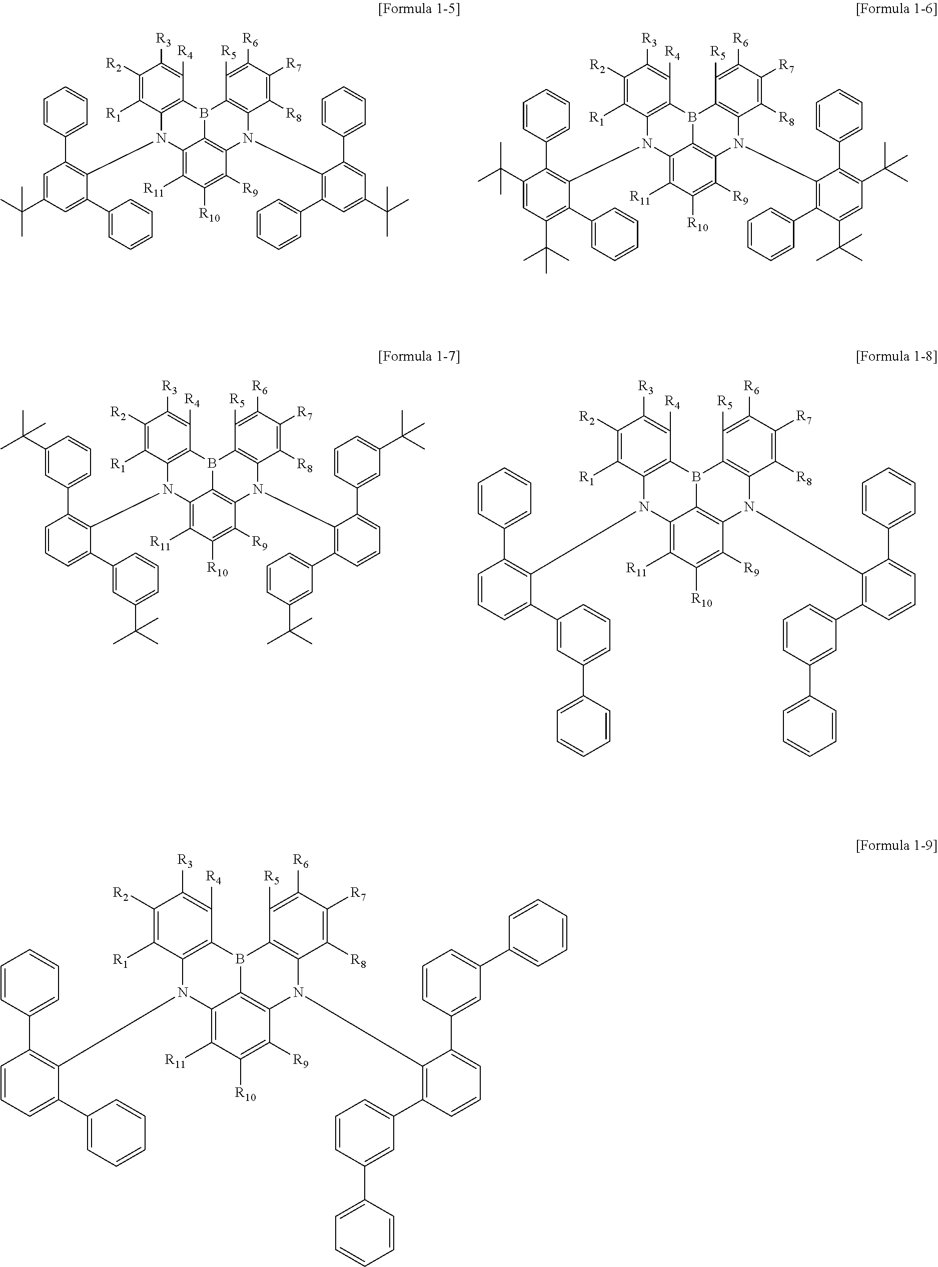

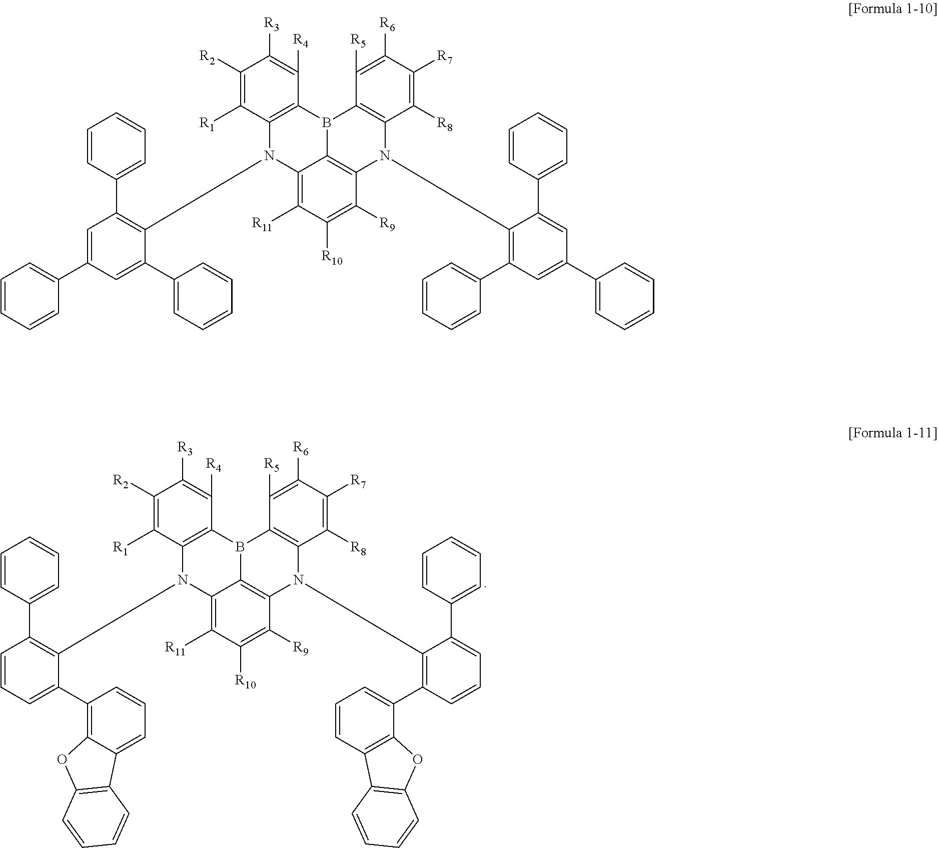

Formula 1-5 to Formula 1-11 each represent a case where X₁ to X₆ in Formula 1 are further defined.

In Formula 1-5 to Formula 1-11, R₁ to R₁₁ may be the same as defined in Formula 1.

In an embodiment, in Formula 1, R₁₀ may be a group represented by one of Formula 3-1 to Formula 3-6:

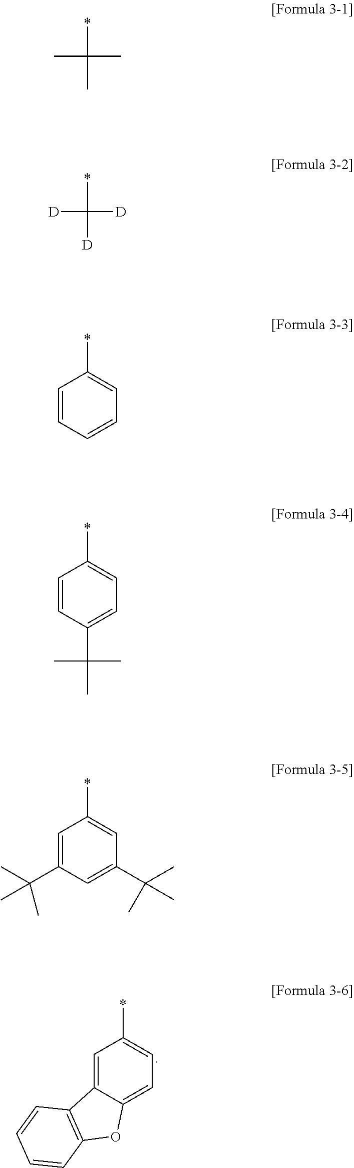

In Formulae 3-1 to 3-6, *— represents a bond to Formula 1.

In Formulae 3-1 and 3-6, D represents a deuterium atom.

In an embodiment, the (1-1)-th compound represented by Formula 1 may be any compound selected from Compound Group 1-1. In an embodiment, in the light emitting element ED, the first emission layer EML1 may include at least one (1-1)-th compound selected from Compound Group 1-1:

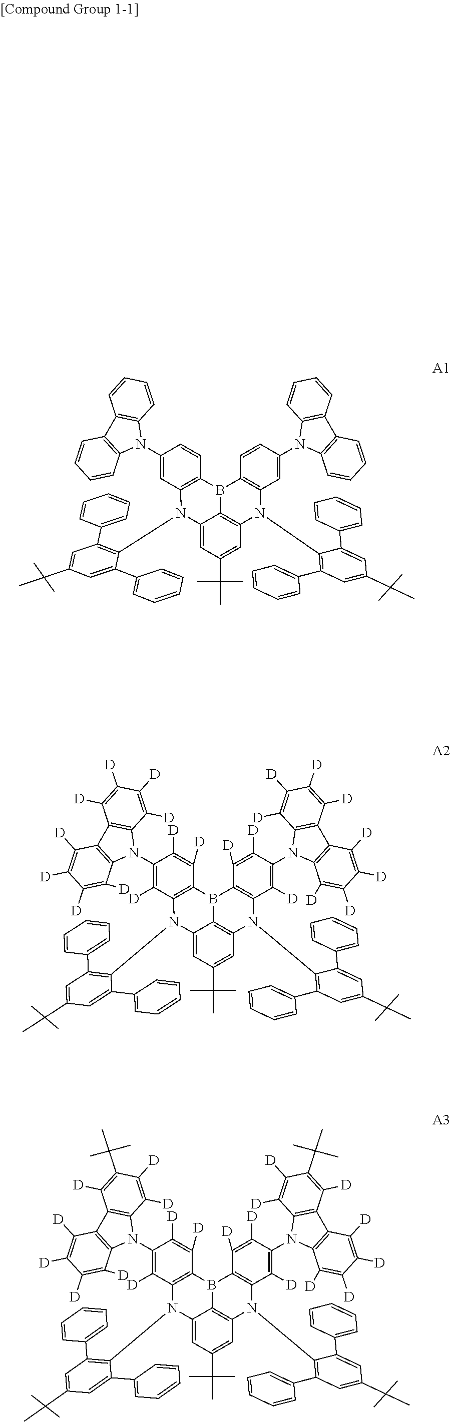

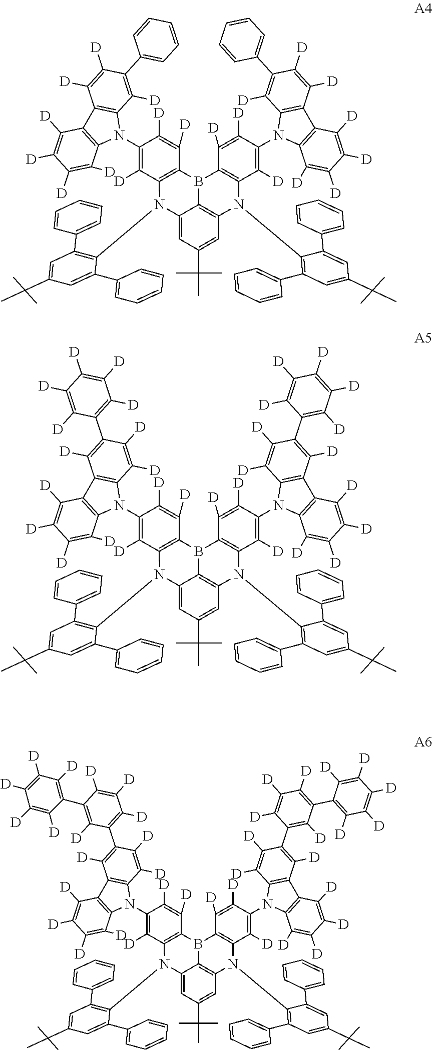

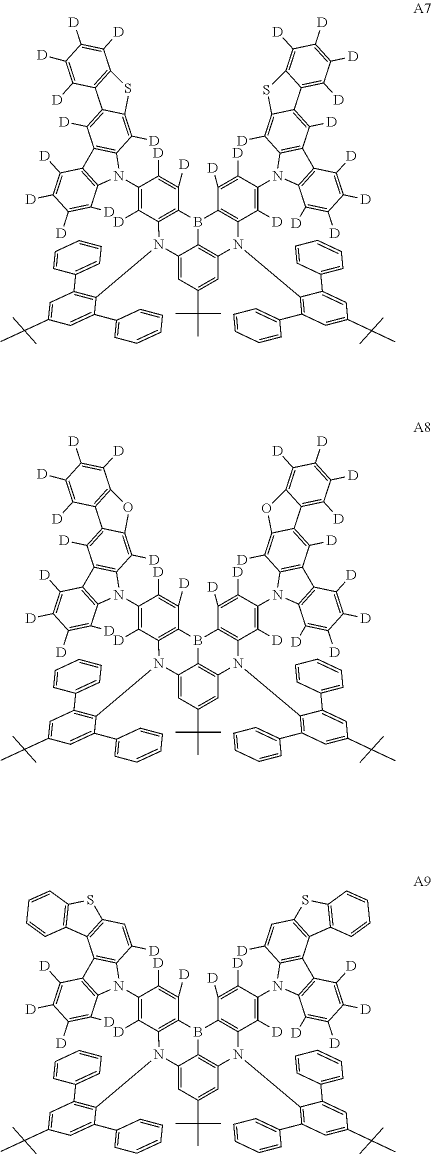

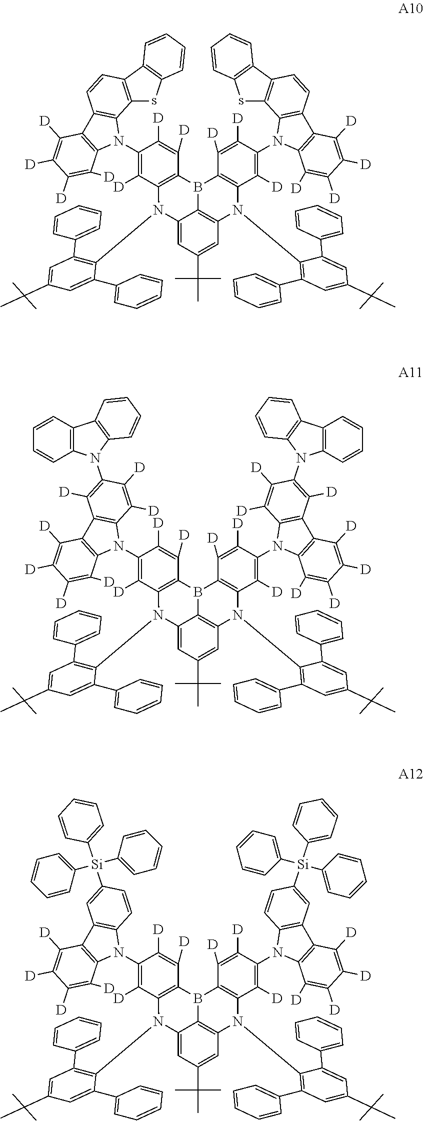

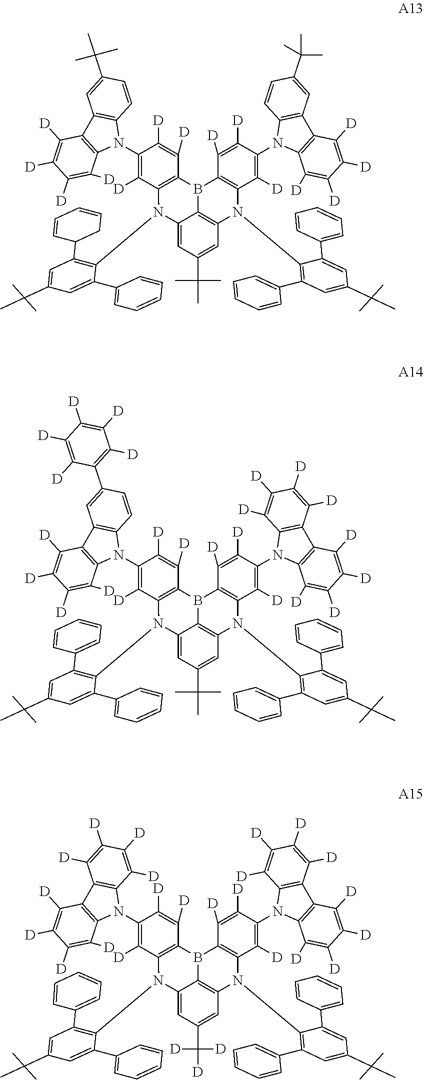

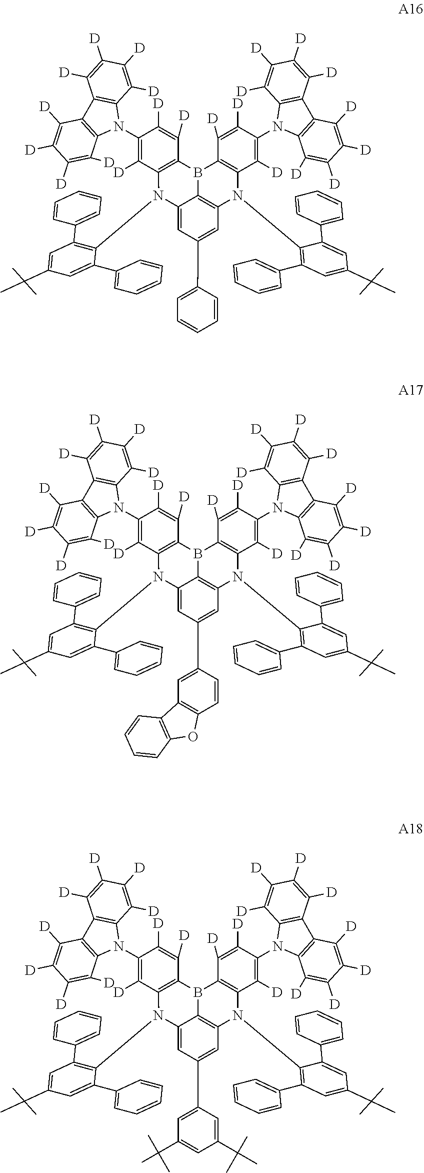

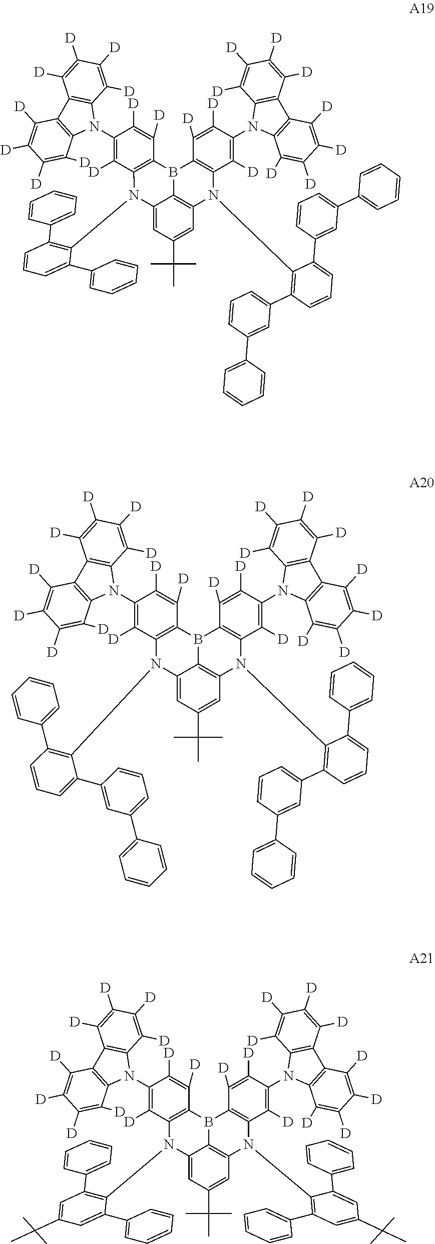

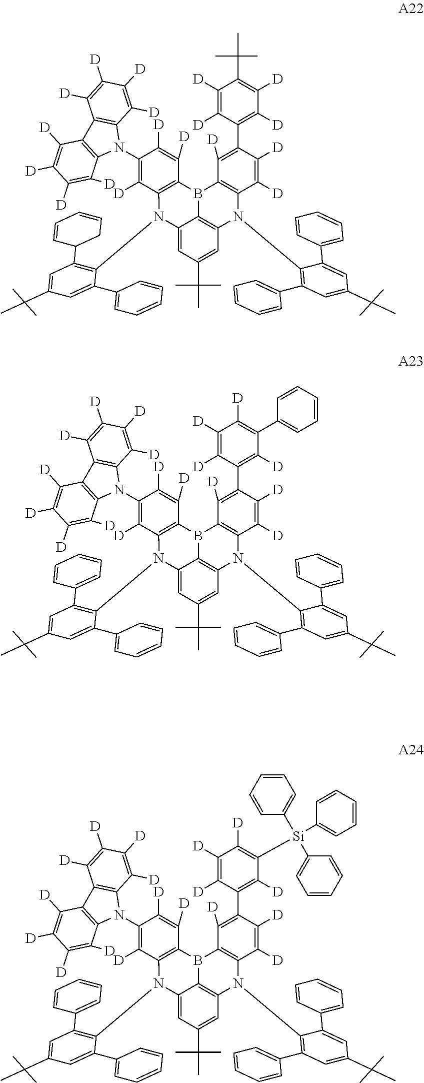

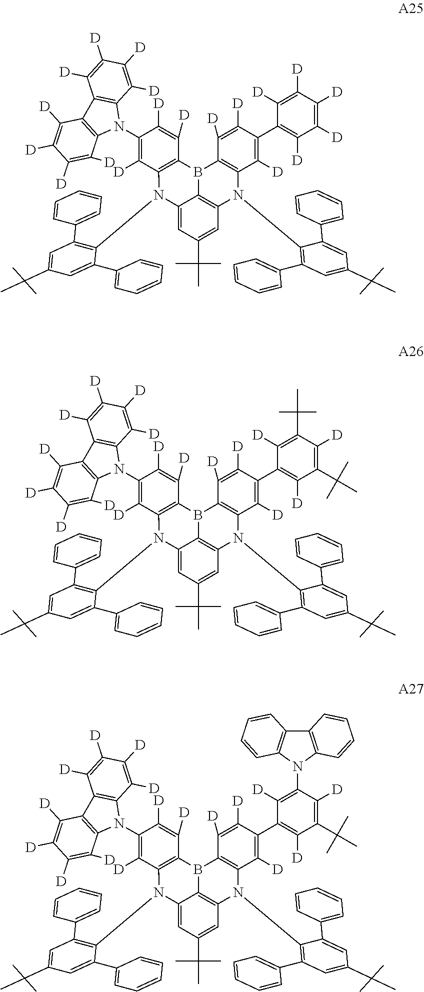

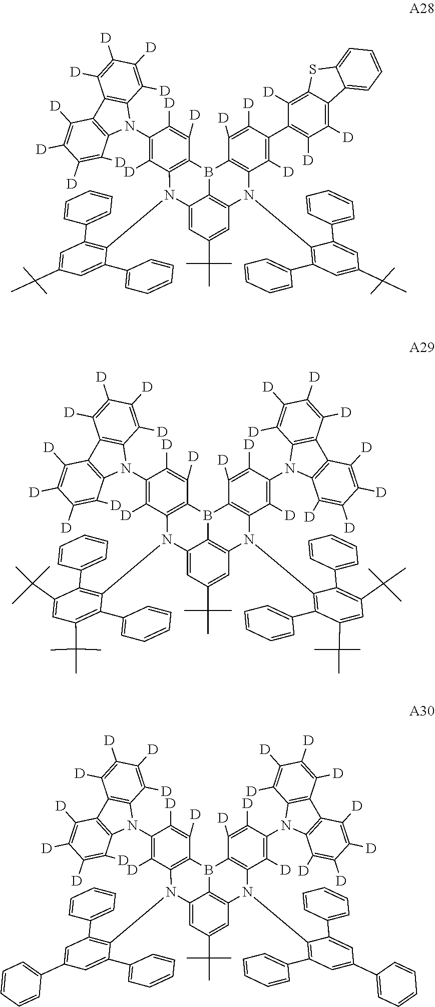

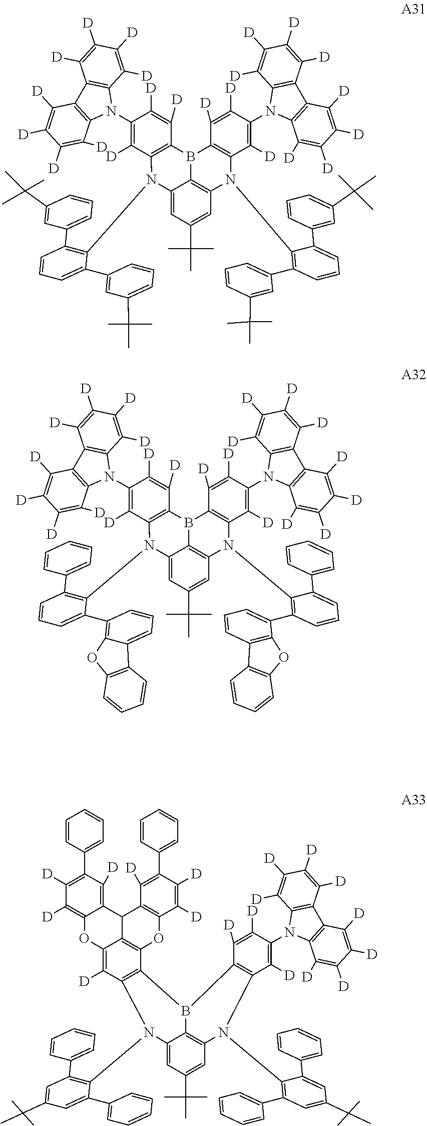

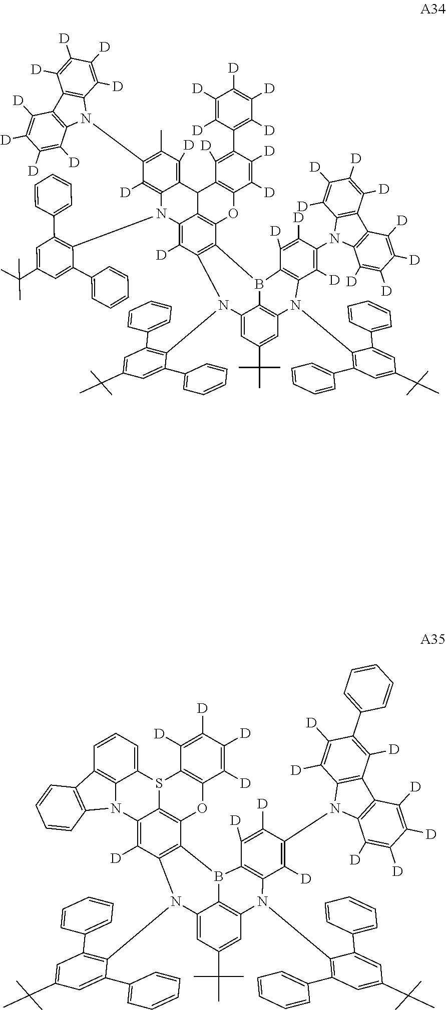

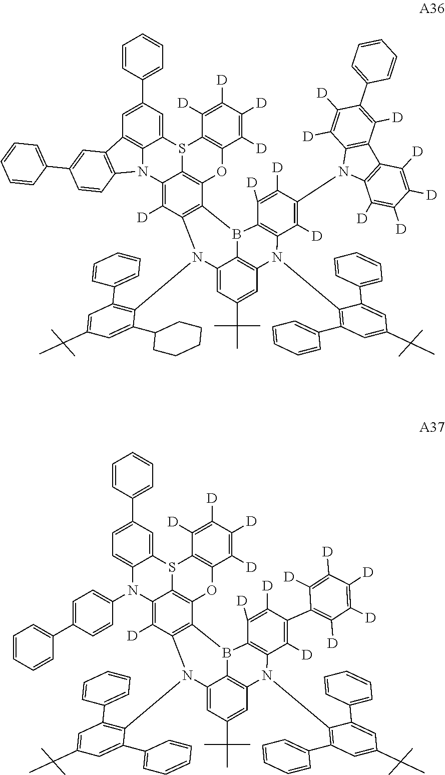

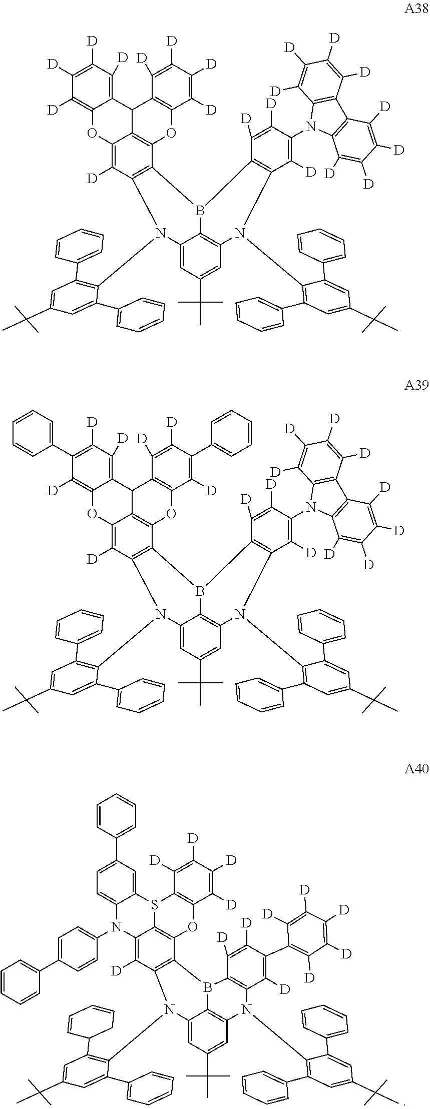

In Compound Group 1-1, D represents a deuterium atom.

The first emission layer EML1 according to an embodiment may include the (1-1)-th compound represented by Formula 1, thereby improving luminescence characteristics.

The (1-1)-th compound represented by Formula 1 includes a first fused ring core in which first to third aromatic rings are fused via the boron atom, the first nitrogen atom, and the second nitrogen atom, and the (1-1)-th compound includes a terphenyl substituent linked to each of the first nitrogen atom and the second nitrogen atom. Accordingly, in the (1-1)-th compound according to an embodiment, the empty p-orbital of the boron atom may be protected through a steric hindrance effect, and the trigonal planar structure of the boron atom may be effectively maintained. Accordingly, the (1-1)-th compound according to an embodiment may have improved material stability, thereby preventing material deterioration. Since the (1-1)-th compound inhibits intermolecular interaction, it is possible to reduce the incidence of phenomena such as aggregation, intermolecular excimer formation, or intermolecular exciplex formation, and thus luminous efficiency of the light emitting element including the (1-1)-th compound may be increased.

An emission spectrum of the (1-1)-th compound represented by Formula 1 may have a FWQM (full-width at quarter maximum) in a range of about 10 nm to about 50 nm. For example, the emission spectrum of the (1-1)-th compound represented by Formula 1 may have a FWQM in a range of about 20 nm to about 40 nm. When the emission spectrum of the (1-1)-th compound represented by Formula 1 FWQM is within any of the above ranges, luminous efficiency may be improved when the (1-1)-th compound is applied to a light emitting element.

The (1-1)-th compound according to an embodiment may be included in the emission layer EML1. The first emission layer EML1 may include a first light emitting host and a first light emitting dopant that is doped into the first light emitting host. The first light emitting dopant may include the (1-1)-th compound. The first emission layer EML1 according to an embodiment may emit fluorescence by thermally activated delayed fluorescence, and the (1-1)-th compound included in the first emission layer EML1 may be used as a thermally activated delayed fluorescence dopant. For example, in the light emitting element ED, the first emission layer EML1 may include, as a thermally activated delayed fluorescence dopant, at least one (1-1)-th compound selected from Compound Group 1 as described above.

The (1-1)-th compound represented by Formula 1 may be a luminescent material having a central wavelength in a range of about 430 nm to about 490 nm. For example, the (1-1)-th compound represented by Formula 1 may be a blue thermally activated delayed fluorescence dopant. However, embodiments are not limited thereto, and the (1-1)-th compound may be used as a dopant material that emits light in various wavelength regions, such as a red emitting dopant or a green emitting dopant.

The first emission layer EML1 of the light emitting element ED may emit blue light. For example, the first emission layer EML1 of the light emitting element ED may emit blue light having a wavelength equal to or less than about 490 nm. In an embodiment, the first emission layer EML1 may emit fluorescence having a central wavelength in a range of about 430 nm to about 490 nm. However, embodiments are not limited thereto, and the first emission layer EML1 may emit green light or red light.

In an embodiment, the first emission layer EML1 may include multiple compounds. The first emission layer EML1 may include the (1-1)-th compound represented by Formula 1, and may further include at least one of a (1-2)-th compound represented by Formula HT-1, a (1-3)-th compound represented by Formula ET-1, and a (1-4)-th compound represented by Formula D-1. For example, the first emission layer EML1 may include the (1-1)-th compound represented by Formula 1, the (1-2)-th compound represented by Formula HT-1, the (1-3)-th compound represented by Formula ET-1, and the (1-4)-th compound represented by Formula D-1. In an embodiment, the first emission layer EML1 may consist of the (1-1)-th compound represented by Formula 1, the (1-2)-th compound represented by Formula HT-1, the (1-3)-th compound represented by Formula ET-1, and the (1-4)-th compound represented by Formula D-1.

In an embodiment, the first emission layer EML1 may include the (1-2)-th compound represented by Formula HT-1. In an embodiment, the first emission layer EML1 may include a first light emitting host, and the first light emitting host may include the (1-2)-th compound. In an embodiment, the (1-2)-th compound may be used as a hole transporting host material in the first emission layer EML1.

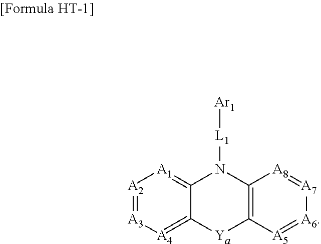

In Formula HT-1, A₁ to A₈ may each independently be N or C(R₅₁). For example, A₁ to A₈ may each independently be C(R₅₁). As another example, one of A₁ to A₈ may be N, and the remainder of A₁ to A₈ may each independently be C(R₅₁).

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, or a substituted or unsubstituted divalent carbazole group, etc., but embodiments are not limited thereto.

In Formula HT-1, Yₐ may be a direct linkage, C(R₅₂)(R₅₃), or Si(R₅₄)(R₅₅). For example, the two benzene rings that are linked to the nitrogen atom in Formula HT-1 may be linked to each other via a direct linkage

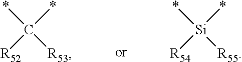

In Formula HT-1, when Yₐ is a direct linkage, the (1-2)-th compound represented by Formula HT-1 may include a carbazole moiety.

In Formula HT-1, Ar₁ may be a substituted or unsubstituted aryl group having 6 to 30 ring-forming carbon atoms or a substituted or unsubstituted heteroaryl group having 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, etc., but embodiments are not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, R₅₁ to R₅₅ may each independently be a hydrogen atom or a deuterium atom. For example, R₅₁ to R₅₅ may each independently be an unsubstituted methyl group or an unsubstituted phenyl group.

In an embodiment, the (1-2)-th compound represented by Formula HT-1 may be selected from Compound Group 1-2. In an embodiment, in the light emitting element ED, the (1-2)-th compound may include at least one compound selected from Compound Group 1-2:

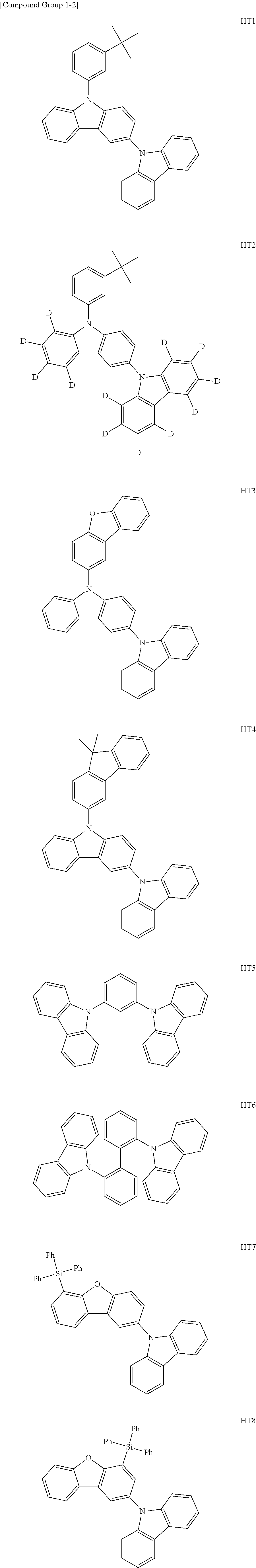

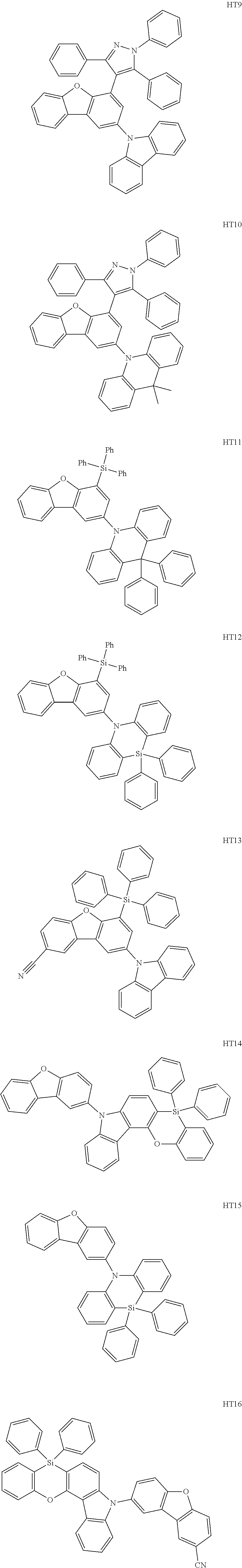

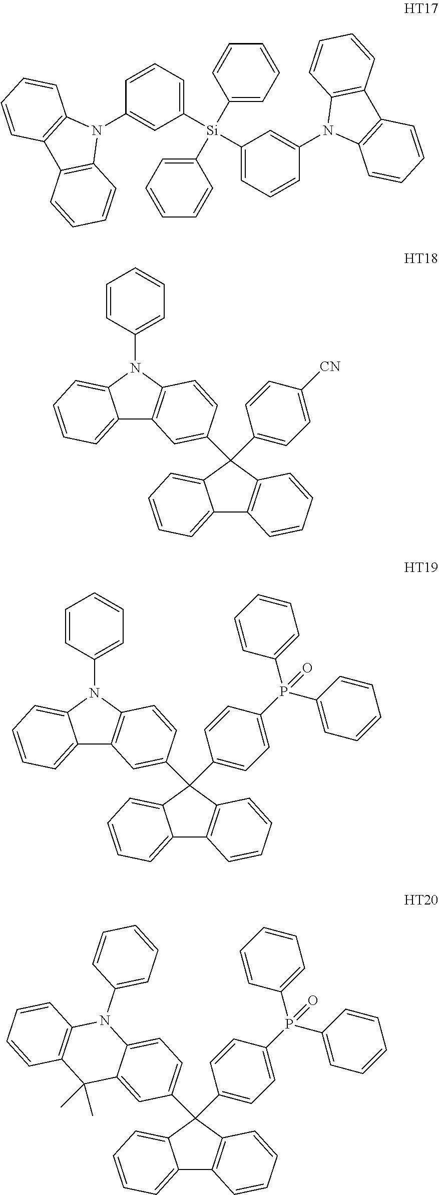 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21]

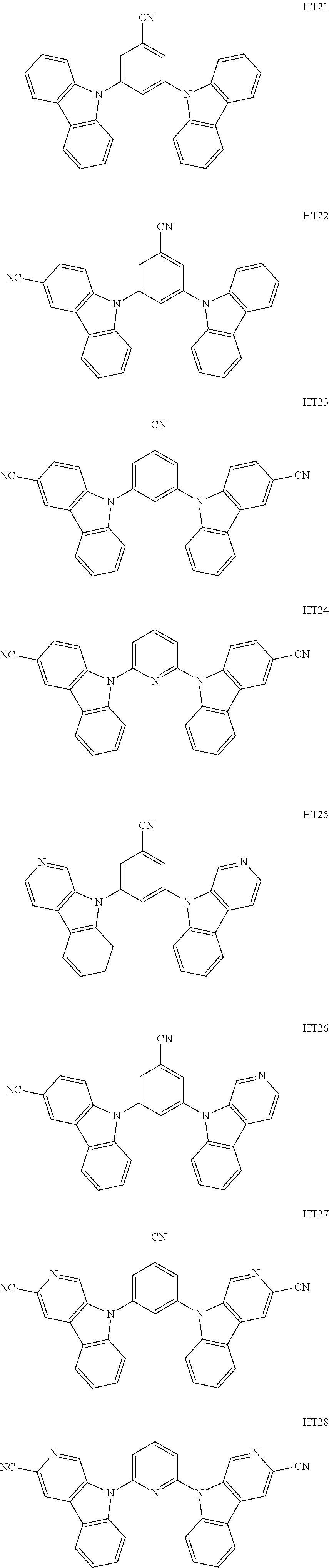

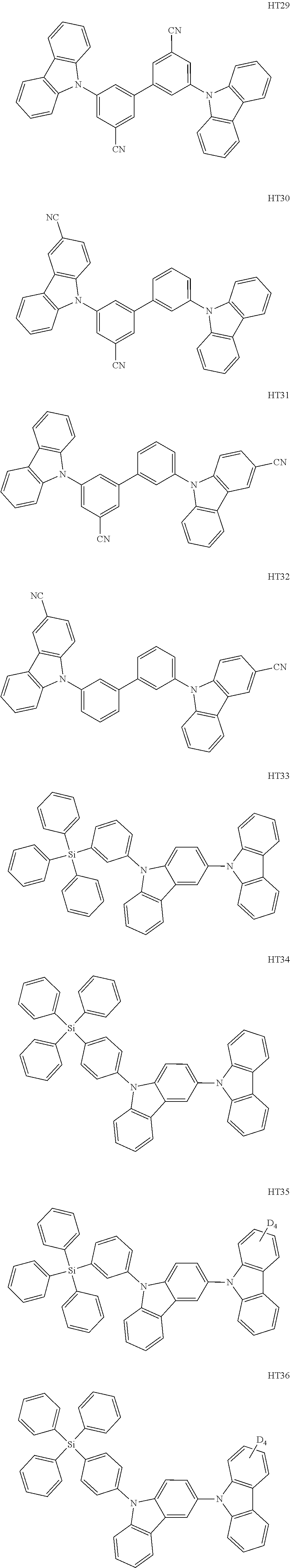

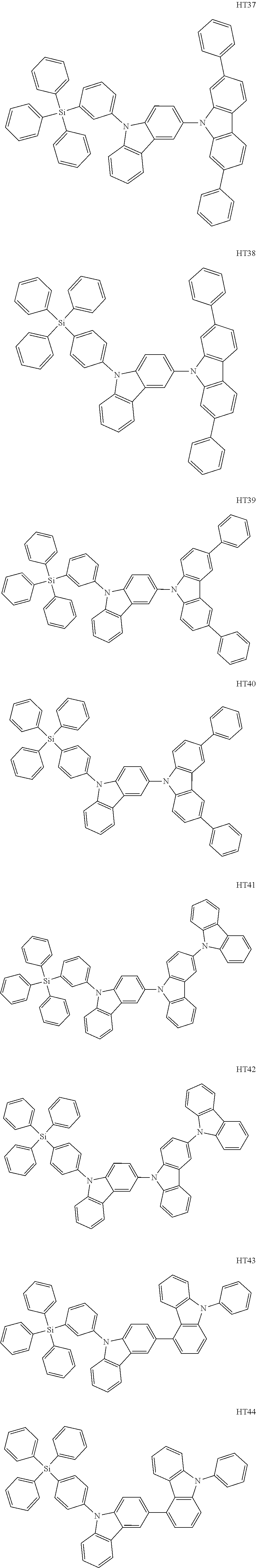

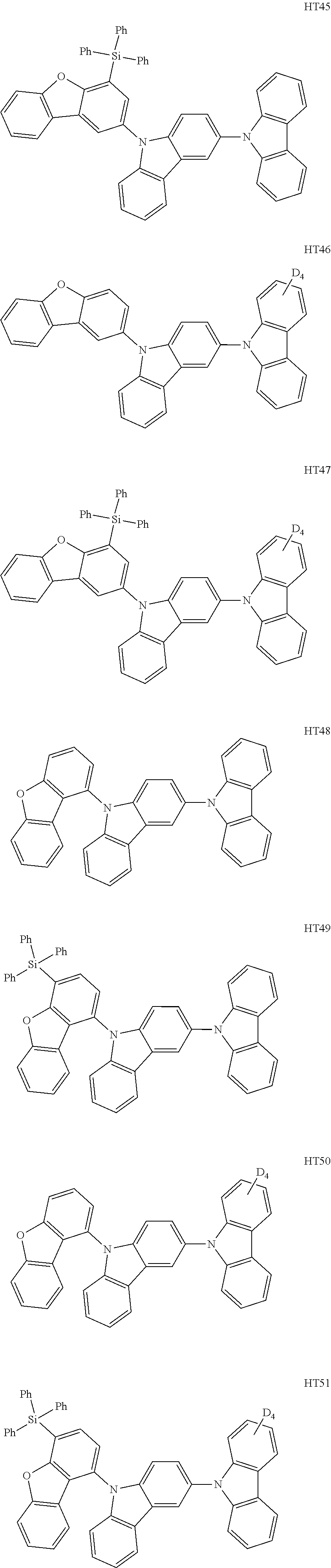

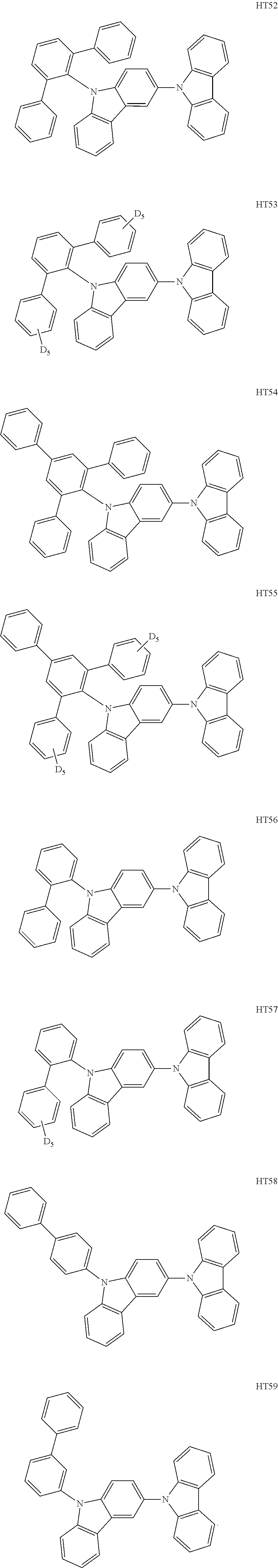

In Compound Group 1-2, D represents a deuterium atom, and Ph represents a substituted or unsubstituted phenyl group. For example, in Compound Group 2, Ph may represent an unsubstituted phenyl group.

In an embodiment, the first emission layer EML1 may include the (1-3)-th compound represented by Formula ET-1. In an embodiment, the first emission layer EML1 may include a first light emitting host, and the first light emitting host may include the (1-3)-th compound. In an embodiment, the (1-3)-th compound may be used as an electron transporting host material in the first emission layer EML1.

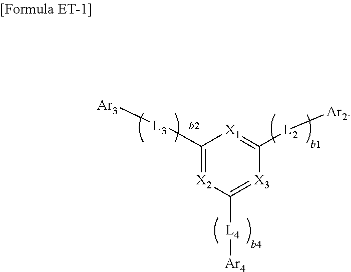

In Formula ET-1, at least one of X₁ to X₃ may each be N, and the remainder of X₁ to X₃ may each independently be C(R₅₆). For example, one of X₁ to X₃ may be N, and the remainder of X₁ to X₃ may each independently be C(R₅₆). Thus the (1-3)-th compound represented by Formula ET-1 may include a pyridine moiety. As another example, two of X₁ to X₃ may each be N, and the remainder of X₁ to X₃ may be C(R₅₆). Thus, the (1-3)-th compound represented by Formula ET-1 may include a pyrimidine moiety. As yet another example, X₁ to X₃ may each be N. Thus the (1-3)-th compound represented by Formula ET-1 may include a triazine moiety.

In Formula ET-1, R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer from 0 to 10.

In Formula ET-1, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may each independently be a substituted or unsubstituted phenyl group or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. When b1 to b3 are each 2 or greater, multiple groups of each of L₂ to L₄ may each independently be a substituted or unsubstituted arylene group having 6 to 30 ring-forming carbon atoms or a substituted or unsubstituted heteroarylene group having 2 to 30 ring-forming carbon atoms.

In an embodiment, the (1-3)-th compound represented by Formula ET-1 may be selected from Compound Group 1-3. In an embodiment, in the light emitting element ED, the (1-3)-th compound may include at least one compound selected from Compound Group 1-3:

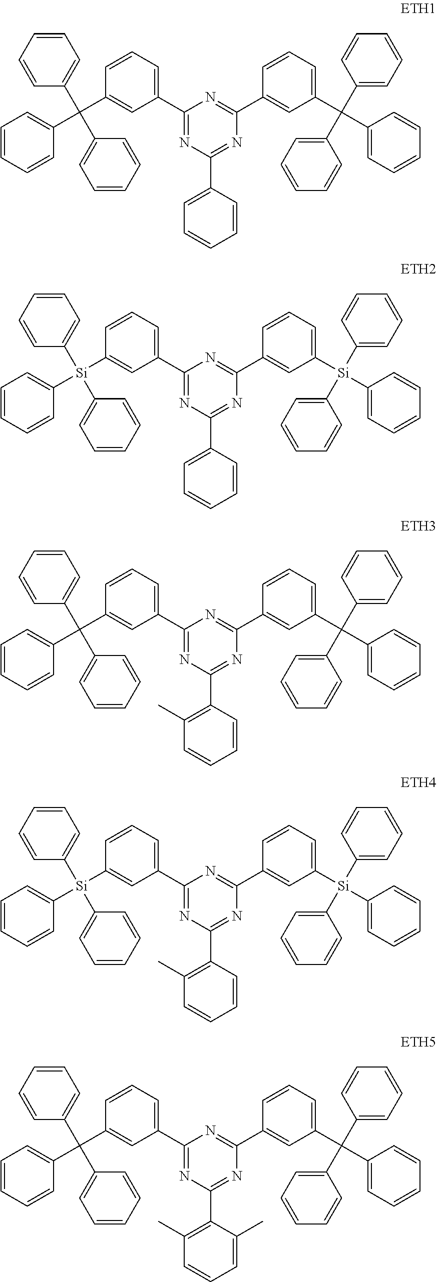

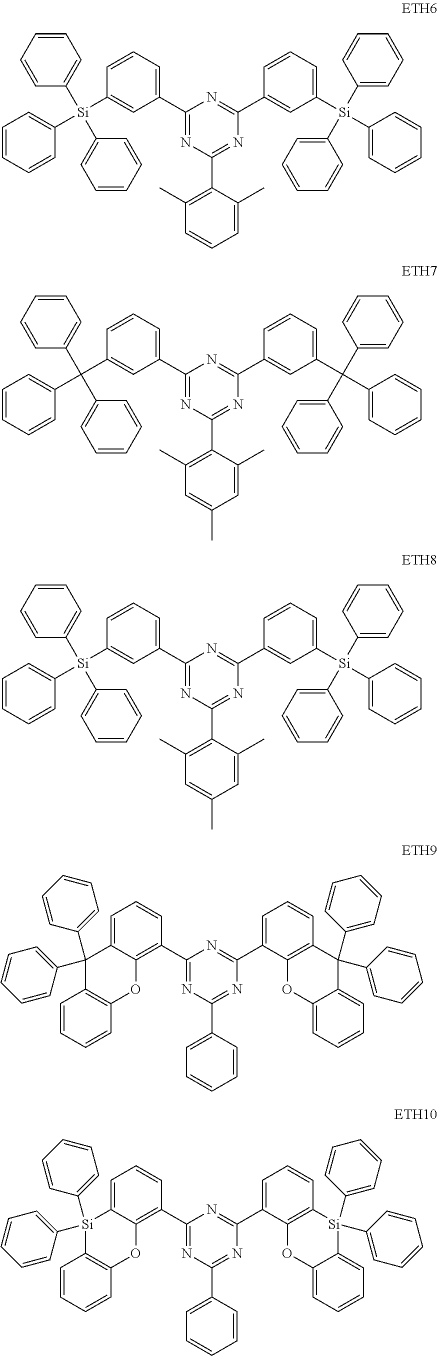

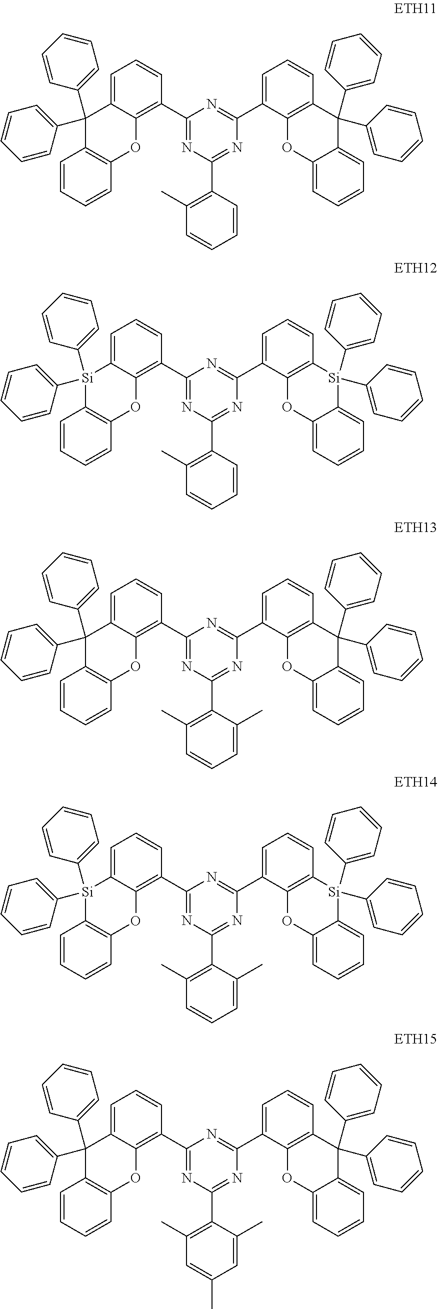

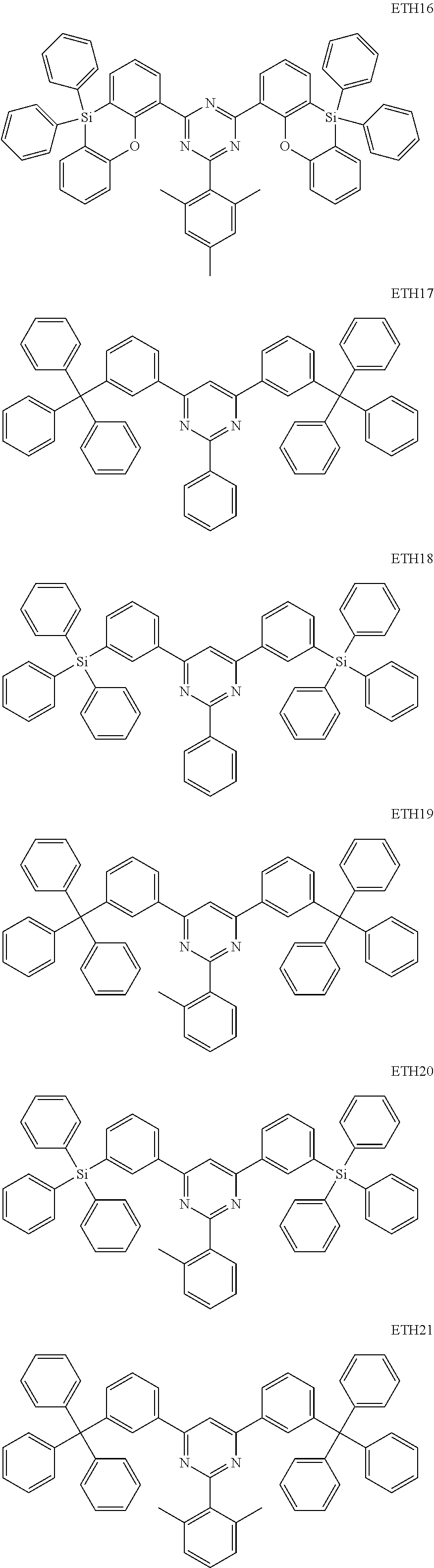

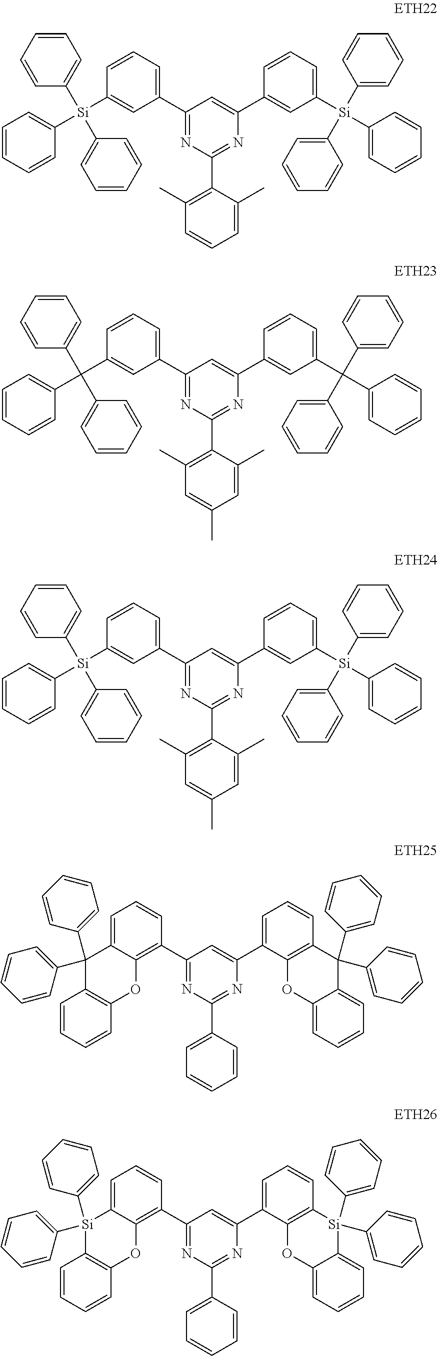

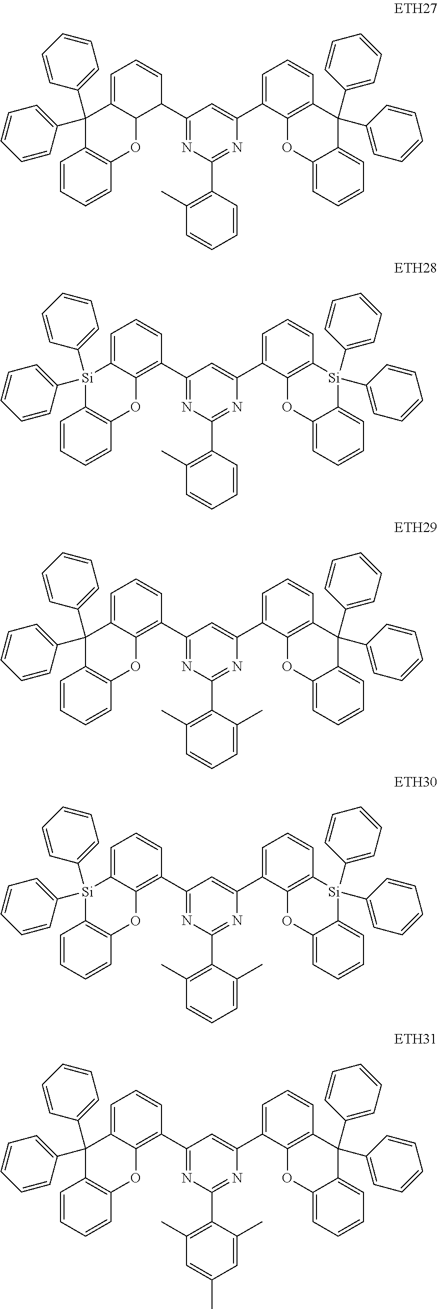

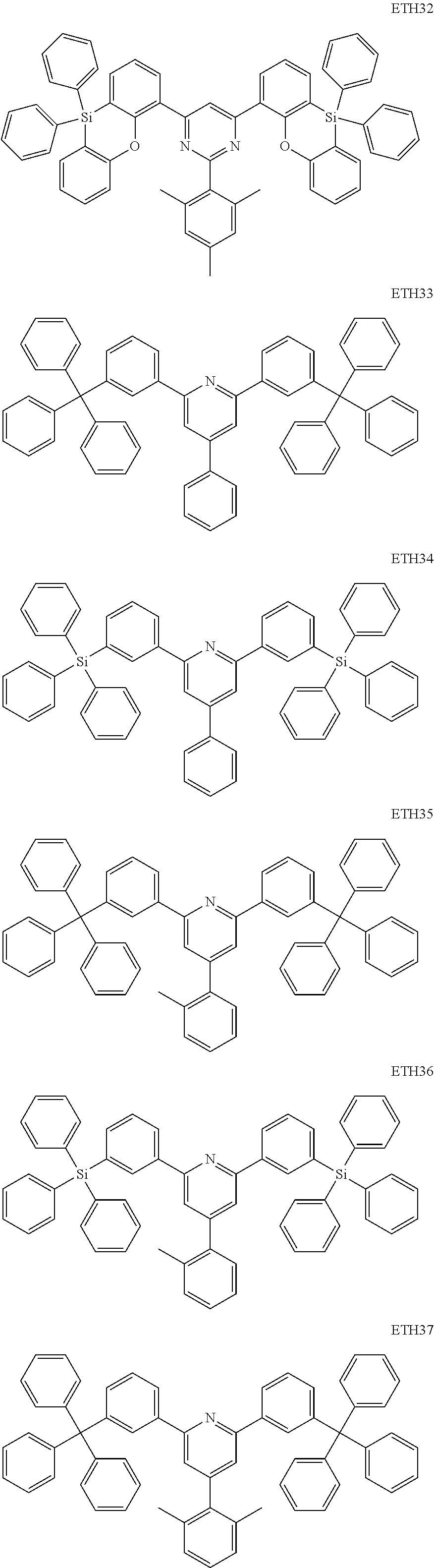

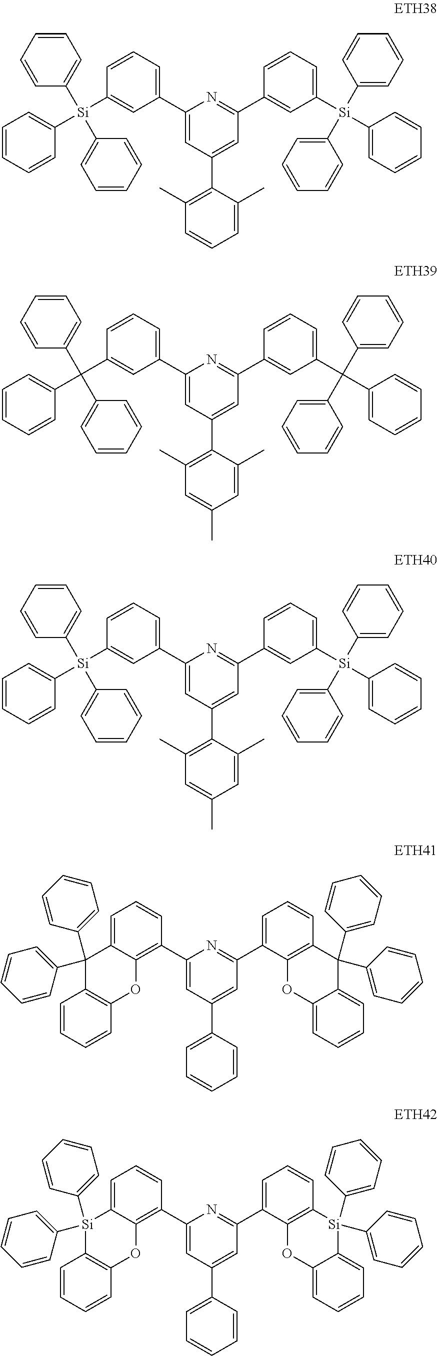

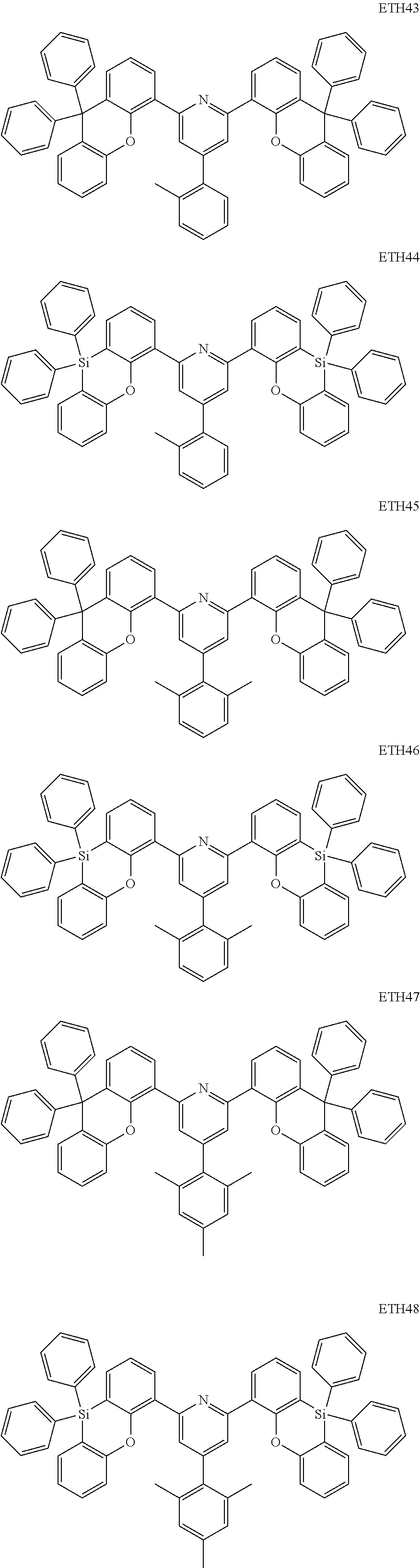

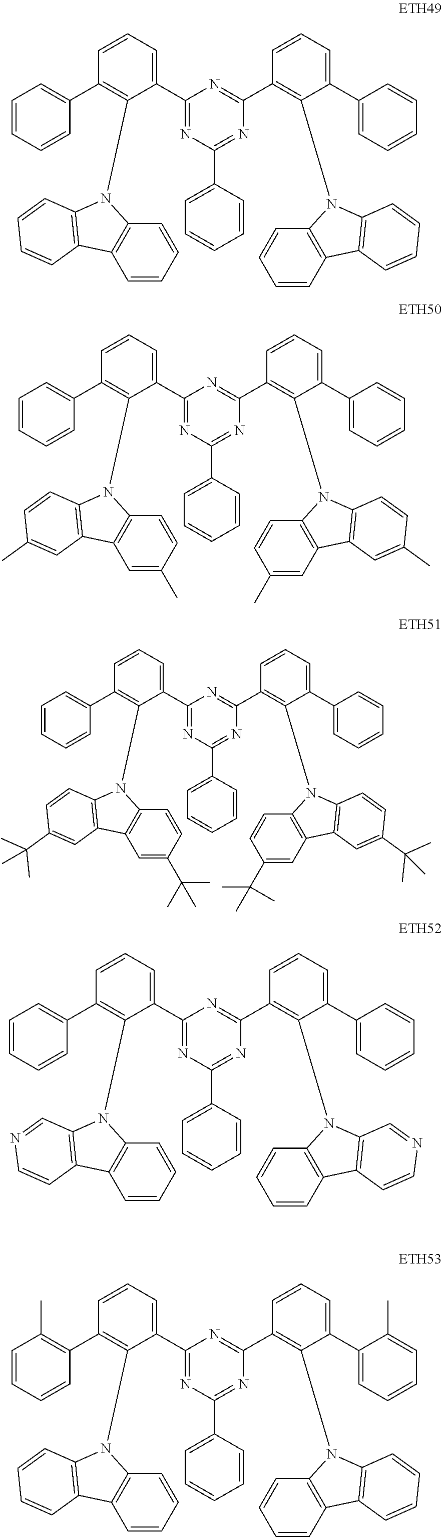

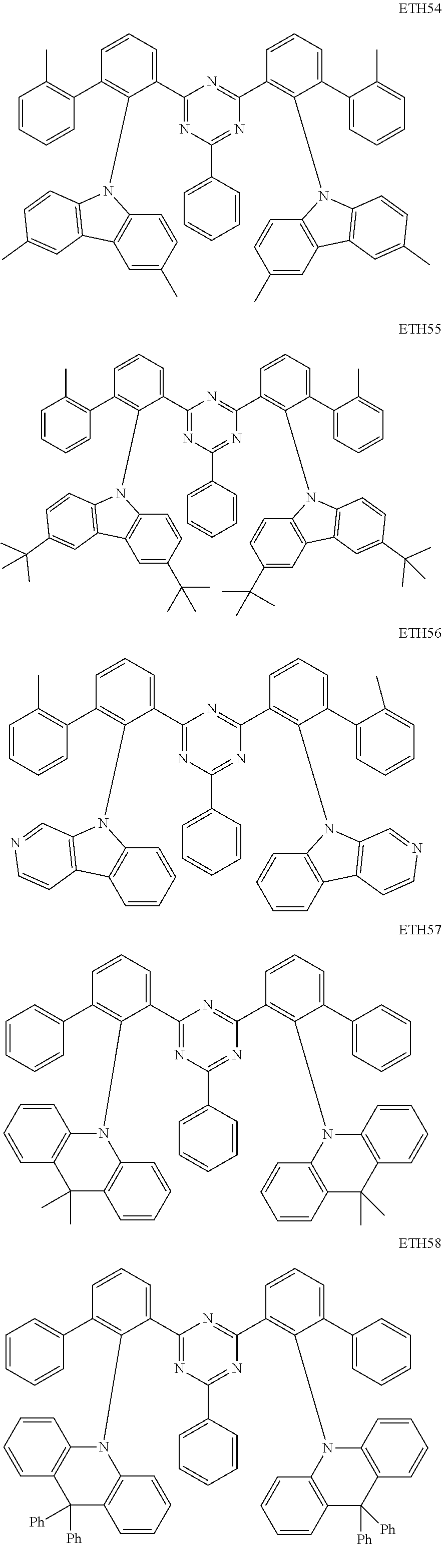

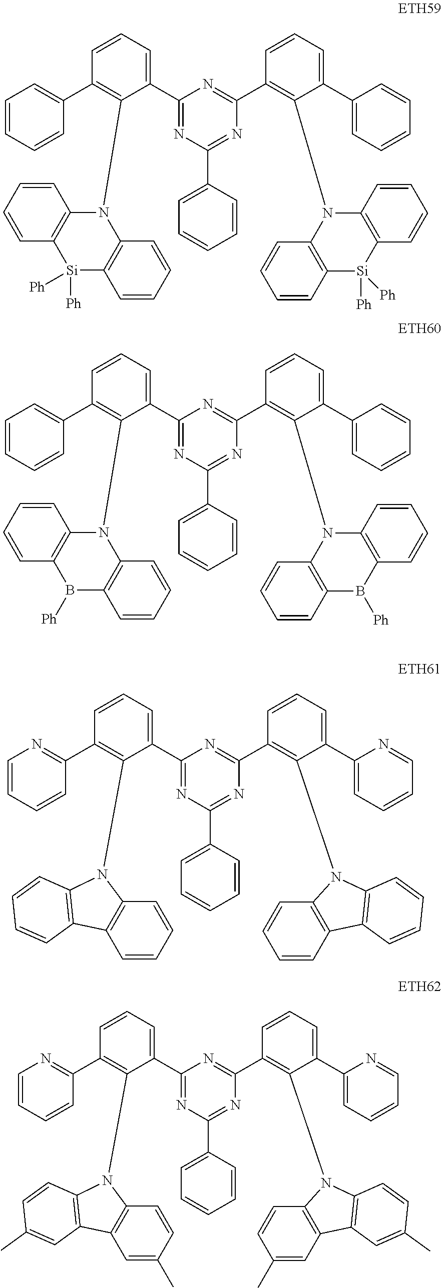

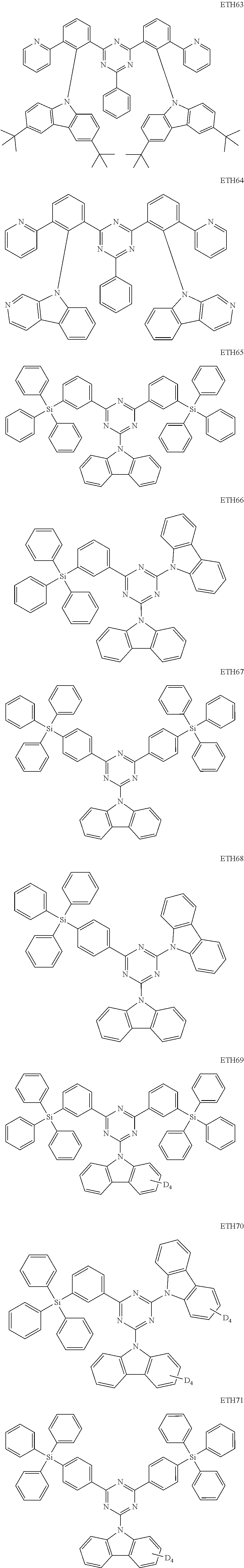

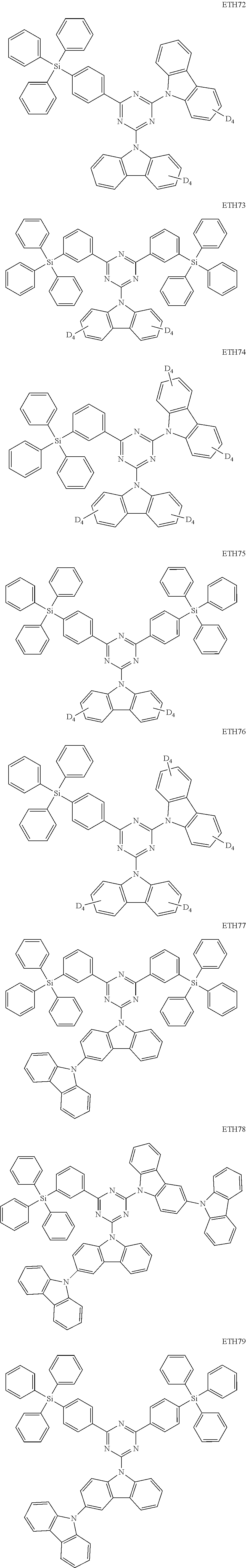

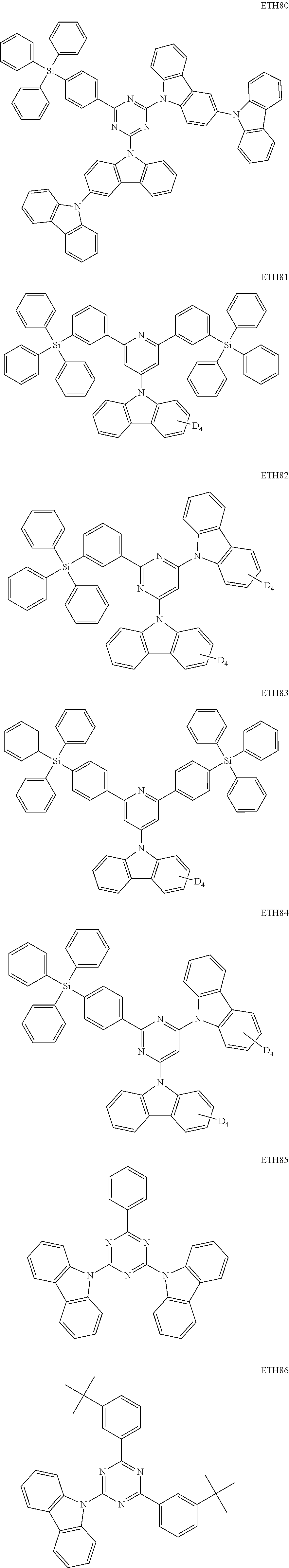

In Compound Group 1-3, D represents a deuterium atom, and Ph represents an unsubstituted phenyl group.

In an embodiment, the first emission layer EML1 may include the (1-2)-th compound and the (1-3)-th compound, and the (1-2)-th compound, and the (1-3)-th compound may form an exciplex. In the first emission layer EML1, an exciplex may be formed by a hole transporting host including the (1-2)-th compound and an electron transporting host including the (1-3)-th compound. A triplet energy level of the exciplex formed by a hole transporting host and an electron transporting host may correspond to a difference between a lowest unoccupied molecular orbital (LUMO) energy level of the electron transporting host and a highest occupied molecular orbital (HOMO) energy level of the hole transporting host.

For example, an absolute value of a triplet energy level (T1) of the exciplex formed by the hole transporting host and the electron transporting host may be in a range of about 2.4 eV to about 3.0 eV. The triplet energy level of the exciplex may be a value that is smaller than an energy gap of each host material. The exciplex may have a triplet energy level equal to or less than about 3.0 eV, which is an energy gap between the hole transporting host and the electron transporting host.

In an embodiment, the first emission layer EML1 may further include a (1-4)-th compound, in addition to the (1-1)-th compound, the (1-2)-th compound, and the (1-3)-th compound as described above. The (1-4)-th compound may be used as a phosphorescent sensitizer in the first emission layer EML1. The first emission layer EML1 may emit light by transferring energy from the (1-4)-th compound to the (1-1)-th compound.

In an embodiment, the first emission layer EML1 may further include, as a (1-4)-th compound, an organometallic complex that includes platinum (Pt) as a central metal atom and ligands linked to the central metal atom. In an embodiment, the first emission layer EML1 may further include a (1-4)-th compound represented by Formula D-1:

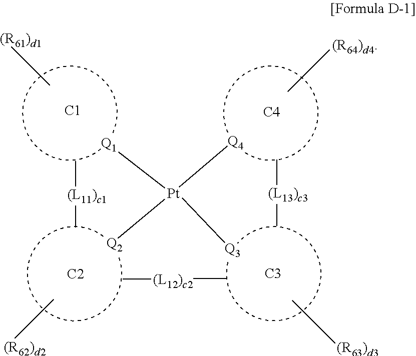

In Formula D-1, Q₁ to Q₄ may each independently be C or N.

In Formula D-1, C1 to C4 may each independently be a substituted or unsubstituted hydrocarbon ring having 5 to 30 ring-forming carbon atoms or a substituted or unsubstituted heterocycle having 2 to 30 ring-forming carbon atoms.

In Formula D-1, L₁₁ to L₁ may each independently be a direct linkage, *—O—*, *—S—*,

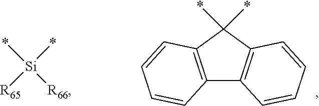

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, —* represents a bond to one of C1 to C4.

In Formula D-1, c1 to c3 may each independently be 0 or 1. If c1 is 0, C1 and C2 may not be directly linked to each other. If c2 is 0, C2 and C3 may not be directly linked to each other. If c3 is 0, C3 and C4 may not be directly linked to each other.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, R₆₁ to R₆₆ may each independently be a substituted or unsubstituted methyl group or a substituted or unsubstituted t-butyl group.

In Formula D-1, d1 to d4 may each independently be an integer from 0 to 4. If d1 to d4 are each 0, the (1-4)-th compound may not be substituted with R₆₁ to R₆₄, respectively. A case where d1 to d4 are each 4 and four groups of each of R₆₁ to R₆₄ are all hydrogen atoms may be the same as a case where d1 to d4 are each 0. When d1 to d4 are each 2 or more, multiple groups of each of R₆₁ to R₆₄ may all be the same, or at least one thereof may be different from the remainder.

In an embodiment, in Formula D-1, C1 to C4 may each independently be a substituted or unsubstituted hydrocarbon ring or a substituted or unsubstituted heterocycle that is represented by one of Formula C-1 to Formula C-4:

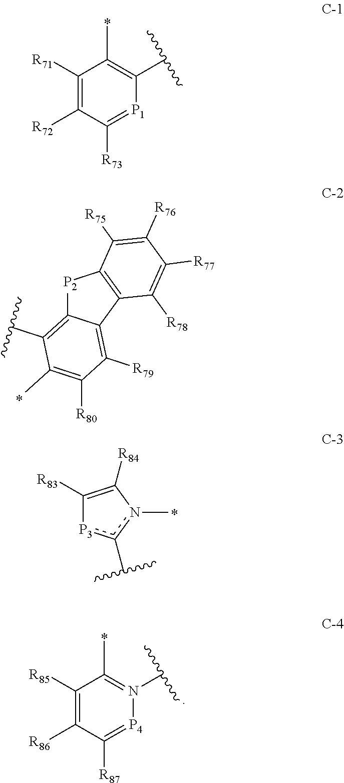

In Formula C-1 to Formula C-4, P₁ may be C—* or C(R₇₄), P₂ may be N—* or N(R₅₁), P₃ may be N—* or N(R₅₂), and P₄ may be C—* or C(R₈₈).

In Formula C-1 to Formula C-4, R₇₁ to R₈₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

In Formula C-1 to Formula C-4,

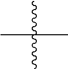

represents a bond to Pt, which is a central metal atom, and —* represents a bond to a neighboring cyclic group (C1 to C4) or to a linking moiety (L₁₁ to L₁₃).

In an embodiment, first emission layer EML1 may include the (1-1)-th compound represented by Formula 1, and at least one of the (1-2)-th compound, the (1-3)-th compound, and the (1-4)-th compound. In an embodiment, the emission layer EML may include the (1-1)-th compound, the (1-2)-th compound, and the (1-3)-th compound. In the emission layer EML, the (1-2)-th compound and the (1-3)-th compound may form an exciplex, and energy may be transferred from the exciplex to the (1-1)-th compound, thereby emitting light.

In another embodiment, the emission layer EML may include the (1-1)-th compound, the (1-2)-th compound, the (1-3)-th compound, and the (1-4)-th compound. In the emission layer EML, the (1-2)-th compound and the (1-3)-th compound may form an exciplex, and energy may be transferred from the exciplex to the (1-4)-th compound and to the (1-1)-th compound, thereby emitting light. In an embodiment, the (1-4)-th compound may be a sensitizer. In the light emitting element ED, the (1-4)-th compound included in the emission layer EML may serve as a sensitizer that transfers energy from the first light emitting host (for example, an exciplex host) to the (1-1)-th compound, which is a first light emitting dopant. The (1-4)-th compound, which serves as an auxiliary dopant, may accelerate energy transfer to the (1-1)-th compound, which serves as the first light emitting dopant, thereby increasing an emission ratio of the (1-1)-th compound. Therefore, the first emission layer EML1 may exhibit improved luminous efficiency. When energy transfer to the (1-1)-th compound increases, excitons formed in the first emission layer EML1 may not accumulate and may rapidly emit light, so that deterioration of the light emitting element ED may be reduced. Accordingly, the service life of the light emitting element ED may increase.

The light emitting element ED may include the (1-1)-th compound, the (1-2)-th compound, the (1-3)-th compound, and the (1-4)-th compound, and the first emission layer EML1 may include a combination of two host materials and two dopant materials. In the light emitting element ED, the first emission layer EML1 may include the (1-2)-th compound and the (1-3)-th compound, which are two different hosts, the (1-1)-th compound that emits delayed fluorescence, and the (1-4)-th compound that includes an organometallic complex, so that the light emitting element ED may exhibit excellent luminous efficiency characteristics.

In an embodiment, the (1-4)-th compound represented by Formula D-1 may be selected from Compound Group 1-4. In an embodiment, in the light emitting element ED, the (1-4)-th compound may include at least one compound selected from Compound Group 1-4:

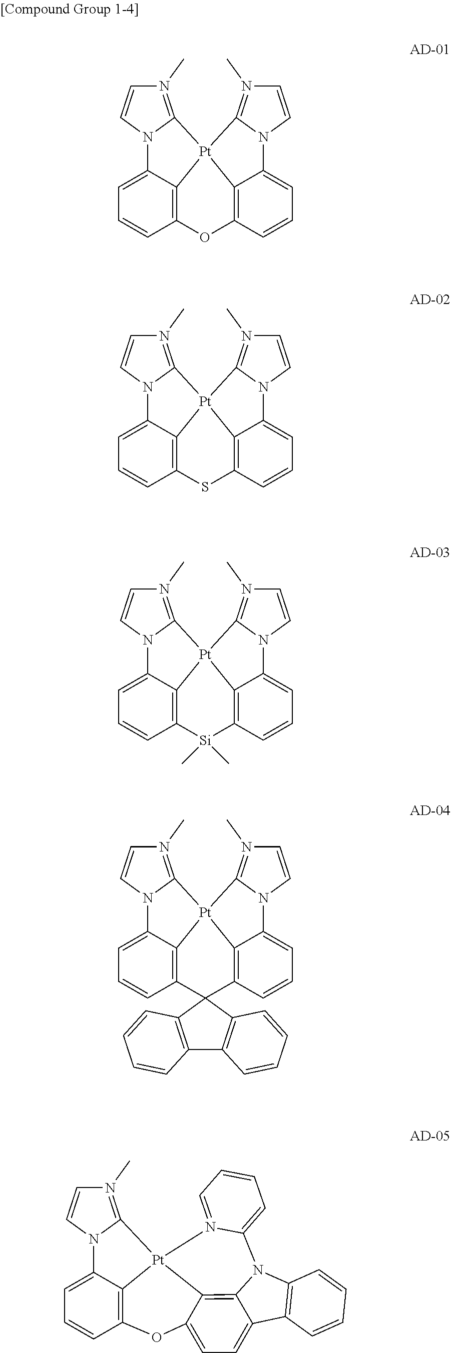

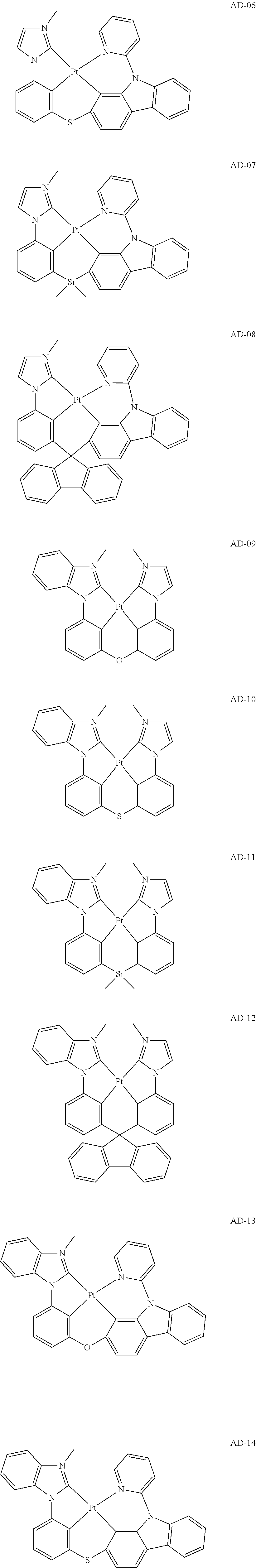

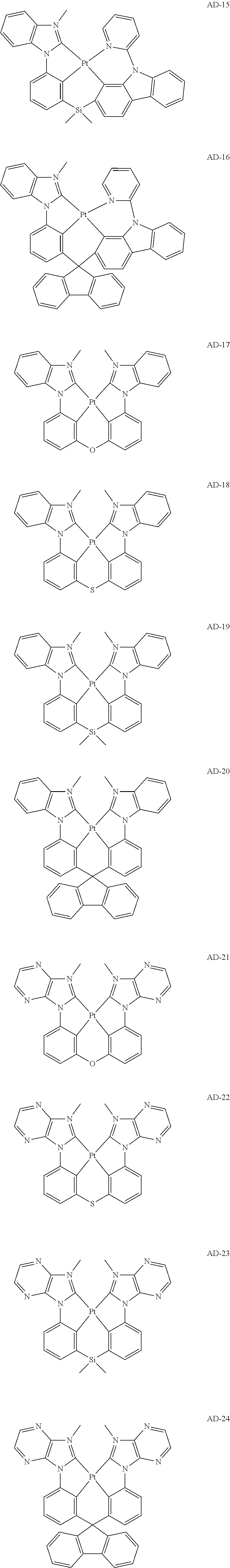

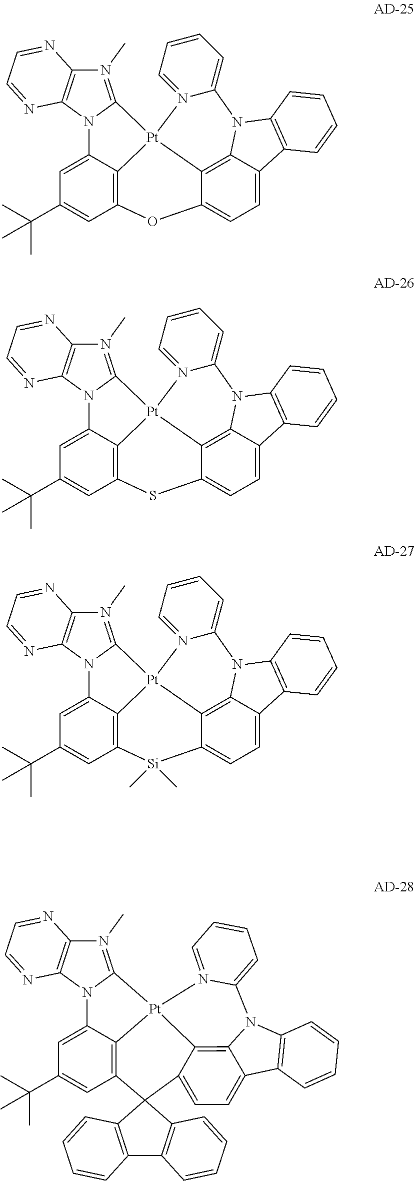

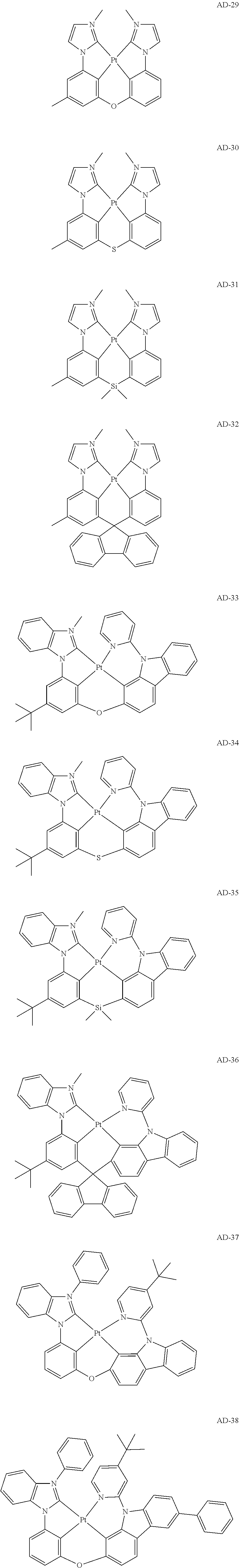

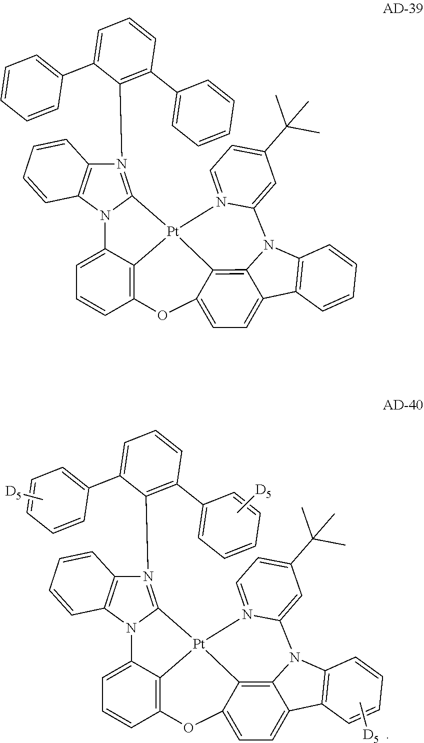

In Compound Group 1-4, D represents a deuterium atom.

In the light emitting element ED, when the first emission layer EML1 includes the (1-1)-th compound, the (1-2)-th compound, the (1-3)-th compound, and the (1-4)-th compound, an amount of the (1-1)-th compound may be in a range of about 0.1 wt % to about 5 wt %, with respect to a total weight of the (1-1)-th compound, the (1-2)-th compound, the (1-3)-th compound, and the (1-4)-th compound. However, embodiments are not limited thereto. When an amount of the (1-1)-th compound satisfies the range described above, energy transfer from the (1-2)-th compound and the (1-3)-th compound to the (1-1)-th compound may increase, and thus luminous efficiency and element service life may increase.

In the first emission layer EML1, a combined amount of the (1-2)-th compound and the (1-3)-th compound may be in a range of about 65 wt % to about 95 wt %, with respect to a total weight of the (1-1)-th compound, the (1-2)-th compound, the (1-3)-th compound, and the (1-4)-th compound.

Within the combined amount of the (1-2)-th compound and the (1-3)-th compound in the first emission layer EML1, a weight ratio of the (1-2)-th compound to the (1-3)-th compound may be in a range of about 3:7 to about 7:3.

When the amounts of the (1-2)-th compound and the (1-3)-th compound satisfy the above-described ranges and ratios, charge balance characteristics in the first emission layer EML1 may be improved, and thus luminous efficiency and element service life may increase. When the amounts of the (1-2)-th compound and the (1-3)-th compound deviate from the above-described ranges and ratios, charge balance in the first emission layer EML1 may not be achieved, so that luminous efficiency may be reduced and the element may readily deteriorate.

An amount of the (1-4)-th compound in the first emission layer EML1 may be in a range of about 10 wt % to about 30 wt %, with respect to a total weight of the (1-1)-th compound, the (1-2)-th compound, the (1-3)-th compound, and the (1-4)-th compound. However, embodiments are not limited thereto. When an amount of the (1-4)-th compound satisfies the above-described range, energy delivery from a host (for example, an exciplex host) to the (1-1)-th compound, which is a light emitting dopant, may increase, so that an emission ratio may improve. Accordingly, luminous efficiency of the first emission layer EML1 may improve. When the amounts of (1-1)-th compound, the (1-2)-th compound, the (1-3)-th compound, and the (1-4)-th compound included in the first emission layer EML1 satisfy the above-described ranges and ratios, excellent luminous efficiency and long service life may be achieved.

In an embodiment, the second emission layer EML2 may emit delayed fluorescence. For example, the second emission layer EML2 may emit fluorescence by triplet-triplet annihilation (TTA). The second emission layer EML2 may emit fluorescence by a phenomenon in which singlet excitons are generated by the collision of triplet excitons.

The second emission layer EML2 may include a (2-1)-th compound. The (2-1)-th compound according to an embodiment may have a lowest triplet energy (T1) in a range of about 1.5 eV to about 2.1 eV. The second emission layer EML2 may include the (2-1)-th compound as a dopant. The (2-1)-th compound according to an embodiment may be a dopant material that emits fluorescence by triplet-triplet annihilation (TTA) in the second emission layer EML2.

The (2-1)-th compound according to an embodiment may include a structure in which a first aromatic ring, a second aromatic ring, and a first heterocycle are fused via a boron atom, a first nitrogen atom, and a second nitrogen atom. The first aromatic ring, the second aromatic ring, and the first heterocycle may each be linked to the boron atom, the first aromatic ring and the second aromatic ring may be linked to each other via the first nitrogen atom, and the first heterocycle and the second aromatic ring may be linked to each other via the second nitrogen atom.

In an embodiment, the first and second aromatic rings may be 6-membered aromatic hydrocarbon rings. For example, the first and second aromatic rings may each be a benzene ring. In an embodiment, the first heterocycle may be a structure in which a 5-membered ring that includes a first heteroatom and a 6-membered aromatic hydrocarbon ring are fused. For example, the first heterocycle may be a benzofuran group, a benzothiophene group, a benzoselenophene group, or a benzotellurophene group. In the specification, a hexacyclic fused structure formed by the boron atom, the first nitrogen atom, the second nitrogen atom, the first and second aromatic rings, and the first heterocycle that are fused via the boron atom, the first nitrogen atom, and the second nitrogen atom may be referred to as a “second fused ring core.”

The (2-1)-th compound according to an embodiment may be represented by Formula 2:

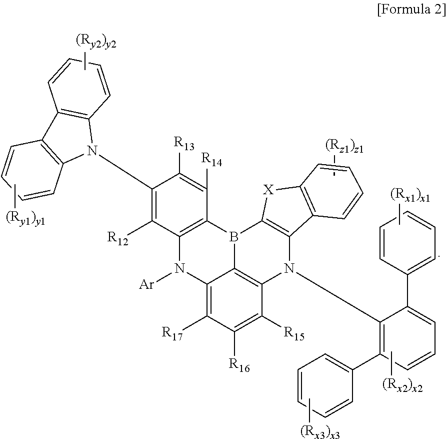

The (2-1)-th compound represented by Formula 2 may have a structure in which two aromatic rings and a heterocycle are fused via a boron atom, a first nitrogen atom, and a second nitrogen atom.

In Formula 2, X may be O, S, Se, or Te.

In Formula 2, Ar₁ may be a substituted or unsubstituted aryl group having 6 to 30 ring-forming carbon atoms or a substituted or unsubstituted heteroaryl group having 2 to 30 ring-forming carbon atoms. For example, Ar₁ may be a substituted or unsubstituted phenyl group, a substituted or unsubstituted biphenyl group, a substituted or unsubstituted terphenyl group, a substituted or unsubstituted anthracenyl group, a substituted or unsubstituted pyrenyl group, a substituted or unsubstituted acenaphthylene group, or a substituted or unsubstituted acridyl group.

In Formula 2, R₁₂ to R₁₇ and Rₓ₁ to Rₓ₃ may each independently be a hydrogen atom, a deuterium atom, a halogen atom, a cyano group, a hydroxy group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₁₂ to R₁₄, R₁₅, and R₁₇ may each independently be a hydrogen atom or a deuterium atom; R₁₆ may be a substituted or unsubstituted t-butyl group, a substituted or unsubstituted phenyl group, a substituted or unsubstituted naphthyl group, a substituted or unsubstituted anthracenyl group, a substituted or unsubstituted pyrenyl group, a substituted or unsubstituted acenaphthylene group, or a substituted or unsubstituted acridyl group; and Rₓ₁ to Rₓ₃ may each independently be a hydrogen atom, a deuterium atom, or an unsubstituted t-butyl group.

In Formula 2, R_{y1}, R_{y2}, and R_{z1} may each independently be a hydrogen atom, a deuterium atom, a halogen atom, a cyano group, a hydroxy group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, R_{y1}, R_{y2}, and R_{z1} may each independently be a hydrogen atom, a deuterium atom, a substituted or unsubstituted amine group, a substituted or unsubstituted t-butyl group, a substituted or unsubstituted anthracenyl group, a substituted or unsubstituted pyrenyl group, a substituted or unsubstituted acenaphthylene group, or a substituted or unsubstituted acridyl group.

For example, two R_{y1} groups may be bonded to each other to form a ring. The two R_{y1} groups may each independently be a substituted or unsubstituted alkyl group having 1 to 20 carbon atoms or a substituted or unsubstituted alkenyl group having 2 to 20 carbon atoms, and when the two R_{y1} groups are bonded to each other, the (2-1)-th compound represented by Formula 2 may include a benzo ring substituted with R_{y1} that further includes a pyrene substituent.

In Formula 2, x1 and x3 may each independently be an integer from 0 to 5. If x1 and x3 are each 0, the (2-1)-th compound may not be substituted with Rₓ₁ and Rₓ₃, respectively. A case where x1 and x3 are each 5 and five Rₓ₁ groups and five Rₓ₃ groups are all hydrogen atoms may be the same as a case where x1 and x3 are each 0. If x1 and x3 are each 2 or greater, multiple Rₓ₁ groups and multiple Rₓ₃ groups may all be the same, or at least one thereof may be different from the remainder.

In Formula 1, x2 may be an integer from 0 to 3. If x2 is 0, the (2-1)-th compound may not be substituted with Rₓ₂. A case where x2 is 3 and three Rₓ₂ groups are all hydrogen atoms may be the same as a case where x2 is 0. If x2 is 2 or greater, multiple Rₓ₂ groups may all be the same, or at least one Rₓ₂ group may be different from the remainder.

In Formula 2, y1, y2, and z1 may each independently be an integer from 0 to 4. If y1, y2, and z1 are each 0, the (2-1)-th compound may not be substituted with R_{y1}, R_{y2}, and R_{z1}, respectively. A case where y1, y2, and z1 are each 4 and four groups of each of R_{y1}, R_{y2}, and R_{z1} are all hydrogen atoms may be the same as a case where y1, y2, and z1 are each 0. If y1, y2, and z1 are each 2 or greater, multiple groups of each of R_{y1}, R_{y2}, and R_{z1} may all be the same, or at least one thereof may be different from the remainder.

In the specification, in Formula 2, the benzene ring that includes R₁₂ to R₁₄ as substituents may correspond to the aforementioned first aromatic ring, the benzene ring that includes R₁₅ to R₁₇ as substituents may correspond to the aforementioned second aromatic ring, and the heterocycle that includes R_{z1} as a substituent and contains X as a ring-forming atom may correspond to the aforementioned first heterocycle. The nitrogen atoms that share boron as a ring-forming atom in Formula 2 may correspond to the first nitrogen atom and the second nitrogen atom, respectively, and X may correspond to the first heteroatom.

In an embodiment, in Formula 2, at least one of R₁₆, R_{y1}, R_{y2}, R_{z1}, and Ar₁ may each independently be a group represented by one of Formula 4-1 to Formula 4-4:

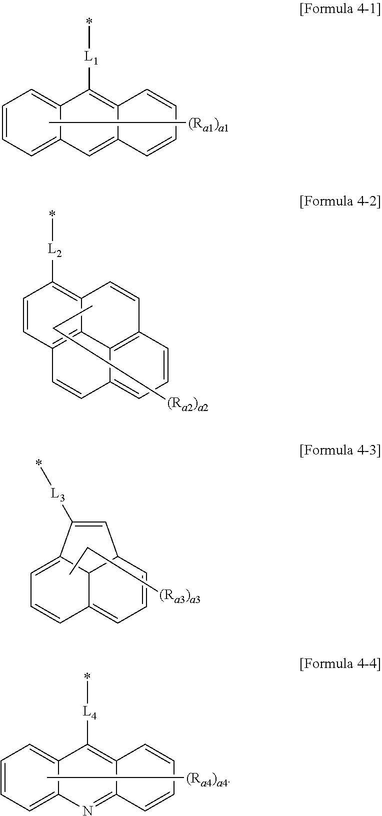

In Formula 4-1 to Formula 4-4, L₁ to L₄ may each independently be a direct linkage or a substituted or unsubstituted arylene group having 6 to 30 ring-forming carbon atoms. In an embodiment, in Formula 4-1 to Formula 4-4, L₁ to L₄ may each independently be a direct linkage, a substituted or unsubstituted phenylene group, or a substituted or unsubstituted biphenylene group.

In Formula 4-1 to Formula 4-4, Rₐ₁ to Rₐ₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. In an embodiment, in Formula 4-1 to Formula 4-4, Rₐ₁ to Rₐ₄ may each independently be a hydrogen atom or a substituted or unsubstituted phenyl group.

In Formula 4-1 and Formula 4-2, a1 and a2 may each independently be an integer from 0 to 9. If a1 and a2 are each 0, the (2-1)-th compound may not be substituted with Rₐ₁ and Rₐ₂, respectively. A case where a1 and a2 are each 9 and nine Rₐ₁ groups and nine Rₐ₂ groups are all hydrogen atoms may be the same as a case where a1 and a2 are each 0. If a1 and a2 are each 2 or greater, multiple Rₐ₁ groups and multiple Rₐ₂ groups may all be the same, or at least one thereof may be different from the remainder.

In Formula 4-3, a3 may be an integer from 0 to 7. If a3 is 0, the (2-1)-th compound may not be substituted with Rₐ₃. A case where a3 is 7 and seven Rₐ₃ groups are all hydrogen atoms may be the same as a case where a3 is 0. If a3 is 2 or greater, multiple Rₐ₃ groups may all be the same, or at least one Rₐ₃ group may be different from the remainder.

In Formula 4-4, a4 may be an integer from 0 to 8. If a4 is 0, the (2-1)-th compound may not be substituted with Rₐ₄. A case where a4 is 8 and eight Rₐ₄ groups are all hydrogen atoms may be the same as a case where a4 is 0. If a4 is 2 or greater, multiple Rₐ₄ groups may all be the same, or at least one Rₐ₄ group may be different from the remainder.

In Formulae 4-1 to 4-4, *— represents a bond to Formula 2.

In an embodiment, the (2-1)-th compound represented by Formula 2 may be represented by Formula 2-1:

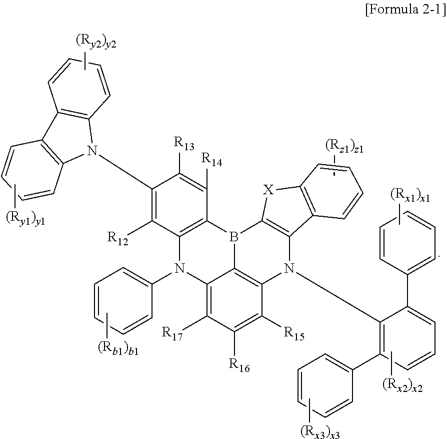

Formula 2-1 represents a case where Ar₁ in Formula 2 is further defined.

In Formula 2-1, R_{b1} may be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R_{b1} may be a hydrogen atom, a deuterium atom, a substituted or unsubstituted phenyl group, a substituted or unsubstituted biphenyl group, a substituted or unsubstituted anthracenyl group, a substituted or unsubstituted pyrenyl group, a substituted or unsubstituted acenaphthylene group, or a substituted or unsubstituted acridyl group.

In Formula 2-1, at least one of R_{y1}, R_{y2}, R_{z1}, and R_{b1} may each independently be a groups represented by one of Formula 4-1 to Formula 4-4. For example, one of R_{y1}, R_{y2}, R_{z1}, and R_{b1} may be a group represented by one of Formula 4-1 to Formula 4-4.

In Formula 2-1, b1 may be an integer from 0 to 5. If b1 is 0, the (2-1)-th compound may not be substituted with R_{b1}. A case where b1 is 5 and five R_{b1} groups are all hydrogen atoms may be the same as a case where b1 is 0. If b1 is 2 or greater, multiple R_{b1} groups may all be the same, or at least one R_{b1} group may be different from the remainder.

In Formula 2-1, X, R₁₂ to R₁₇, Rₓ₁ to Rₓ₃, R_{y1}, R_{y2}, R_{z1}, x1 to x3, y1, y2, and z1 may be the same as defined in Formula 2.

In an embodiment, the (2-1)-th compound represented by Formula 2 may be represented by one of Formula 2-2 to Formula 2-4:

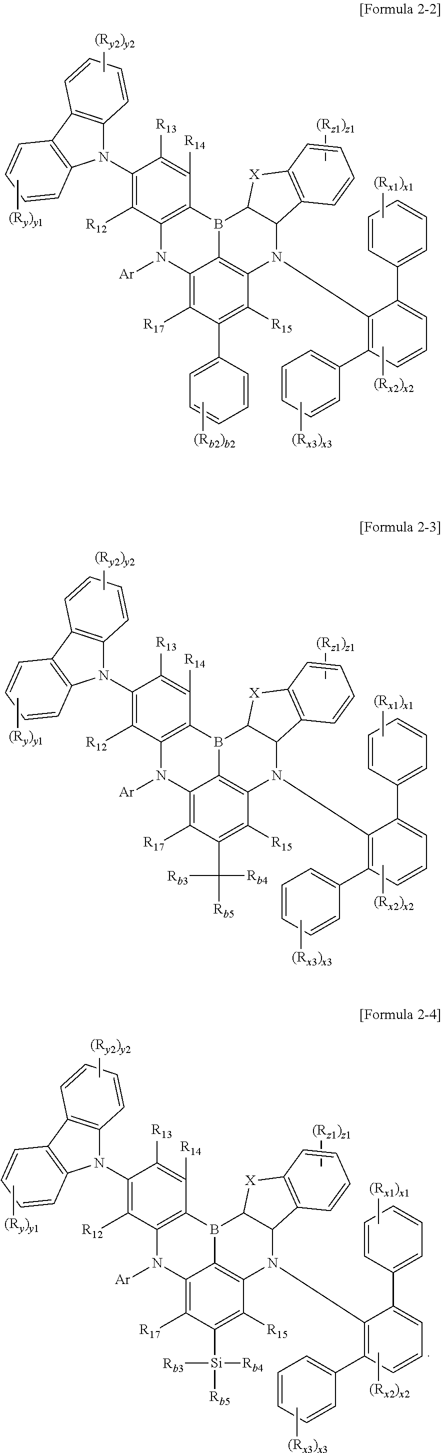

Formula 2-2 to Formula 2-4 each represent a case where R₁₆ in Formula 2 is further defined.

In Formula 2-1, R_{b2} to R_{b}8 may each independently be a hydrogen atom, a deuterium atom, a substituted or unsubstituted alkyl group having 1 to 20 carbon group, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R_{b2} to R_{b8} may each independently be a hydrogen atom, a deuterium atom, a substituted or unsubstituted phenyl group, a substituted or unsubstituted biphenyl group, a substituted or unsubstituted anthracenyl group, a substituted or unsubstituted pyrenyl group, a substituted or unsubstituted acenaphthylene group, or a substituted or unsubstituted acridyl group.

In Formula 2-2, b2 may be an integer from 0 to 5. If b2 is 0, the (2-1)-th compound may not be substituted with R_{b2}. A case where b2 is 5 and five R_{b2} groups are all hydrogen atoms may be the same as a case where b2 is 0. If b2 is 2 or greater, multiple R_{b2} groups may all be the same, or at least one R_{b2} group may be different from the remainder.

In Formula 2-2, at least one of R_{y1}, R_{y2}, R_{z1}, and R_{b2} may each independently be a group represented by one of Formula 4-1 to Formula 4-4. For example, one of R_{y1}, R_{y2}, R_{z1}, and R_{b2} may be a group represented by one of Formula 4-1 to Formula 4-4.

In Formula 2-3, at least one of R_{y1}, R_{y2}, R_{z1}, R_{b3}, R_{b4}, and R_{b8} may each independently be a group represented by one of Formula 4-1 to Formula 4-4. For example, one of R_{y1}, R_{y2}, R_{z1}, R_{b3}, R_{b4}, and R_{b5} may be a group represented by one of Formula 4-1 to Formula 4-4.

In Formula 2-4, at least one of R_{y1}, R_{y2}, R_{z1}, R_{b6}, R_{b7}, and R_{b8} may each independently be a group represented by one of Formula 4-1 to Formula 4-4. For example, one of R_{y1}, R_{y2}, R_{z1}, R_{b6}, R_{b7}, and R_{b8} may be a group represented by one of Formula 4-1 to Formula 4-4.

In Formula 2-2 to Formula 2-4, X, Ar, R₁₂ to R₁₅, R₁₇, Rₓ₁ to Rₓ₃, R_{y1}, R_{y2}, R_{z1}, x1 to x3, y1, y2, and z1 may be the same as defined in Formula 2.

In an embodiment, the (2-1)-th compound represented by Formula 2 may be represented by Formula 2-5:

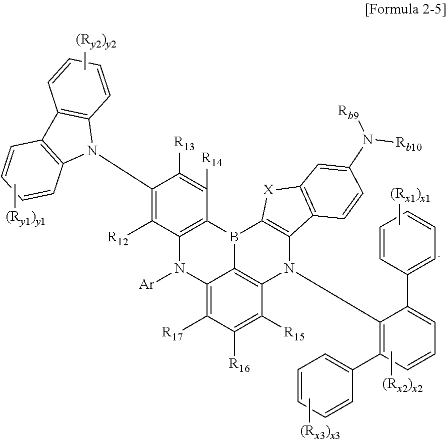

Formula 2-5 represents a case where in Formula 2, R_{z1} is further defined and z1 is 1.

In Formula 2-5, R_{b9} and R_{b10} may each independently be a hydrogen atom, a deuterium atom, a substituted or unsubstituted alkyl group having 1 to 20 carbon group, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, R_{b9} and R_{b10} may each independently be a hydrogen atom, a deuterium atom, a substituted or unsubstituted phenyl group, a substituted or unsubstituted biphenyl group, a substituted or unsubstituted anthracenyl group, a substituted or unsubstituted pyrenyl group, a substituted or unsubstituted acenaphthylene group, or a substituted or unsubstituted acridyl group.

For example, when R_{b9} and R_{b10} are each an unsubstituted phenyl group, and R_{b9} and R_{b10} may be bonded to each other to form a ring with the nitrogen atom to which they are linked in Formula 2-5, the (2-1)-th compound represented by Formula 2-5 may include another carbazole group bonded to the second fused ring core.

In Formula 2-5, at least one of R_{y1}, R_{y2}, R_{z1}, R_{b9}, and R_{b10} may each independently be a group represented by one of Formula 4-1 to Formula 4-4. For example, one of R_{y1}, R_{y2}, R_{z1}, R_{b9}, and R_{b10} may be a group represented by one of Formula 4-1 to Formula 4-4.

In Formula 2-5, X, Ar, R₁₂ to R₁₇, Rₓ₁ to Rₓ₃, R_{y1}, R_{y2}, x1 to x3, y1, and y2 may be the same as defined in Formula 2.

In an embodiment, the (2-1)-th compound represented by Formula 2 may be represented by one of Formula 2-6 to Formula 2-8:

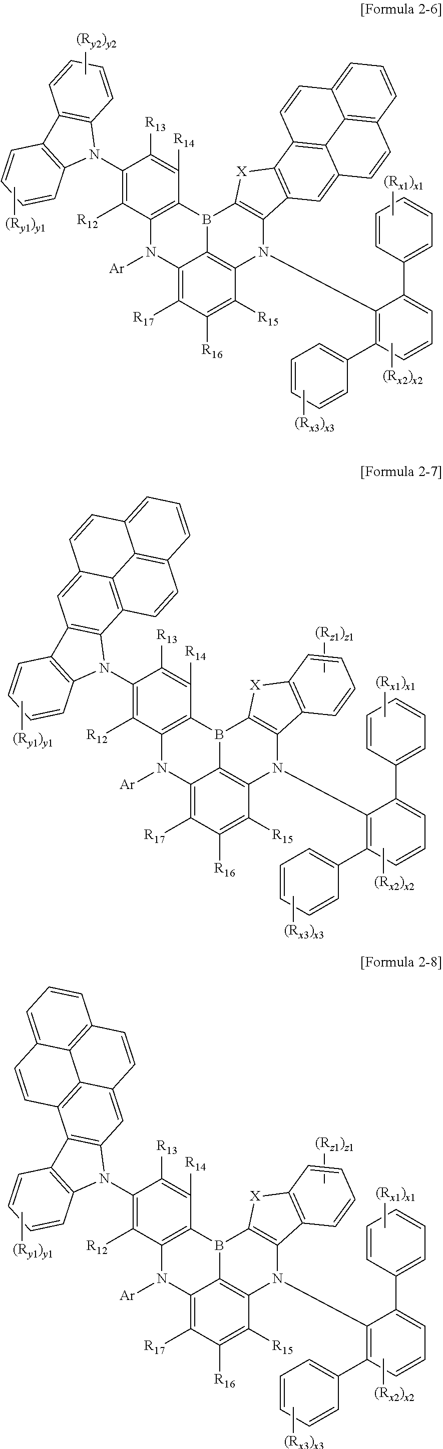

Formula 2-6 represents a case where R_{z1} in Formula 2 is further defined. Formula 2-7 and Formula 2-8 each represent a case where R_{y1} in Formula 2 is further defined.

In Formula 2-6 to Formula 2-8, X, Ar, R₁₂ to R₁₇, Rₓ₁ to Rₓ₃, R_{y1}, R_{y2}, R_{z1}, x1 to x3, y1, y2, and z1 may be the same as defined in Formula 2.

In an embodiment, (2-1)-th compound represented by Formula 2 may be any compound selected from Compound Group 2-1. In an embodiment, in the light emitting element ED, the second emission layer EML2 may include at least one (2-1)-th compound selected from Compound Group 2-1:

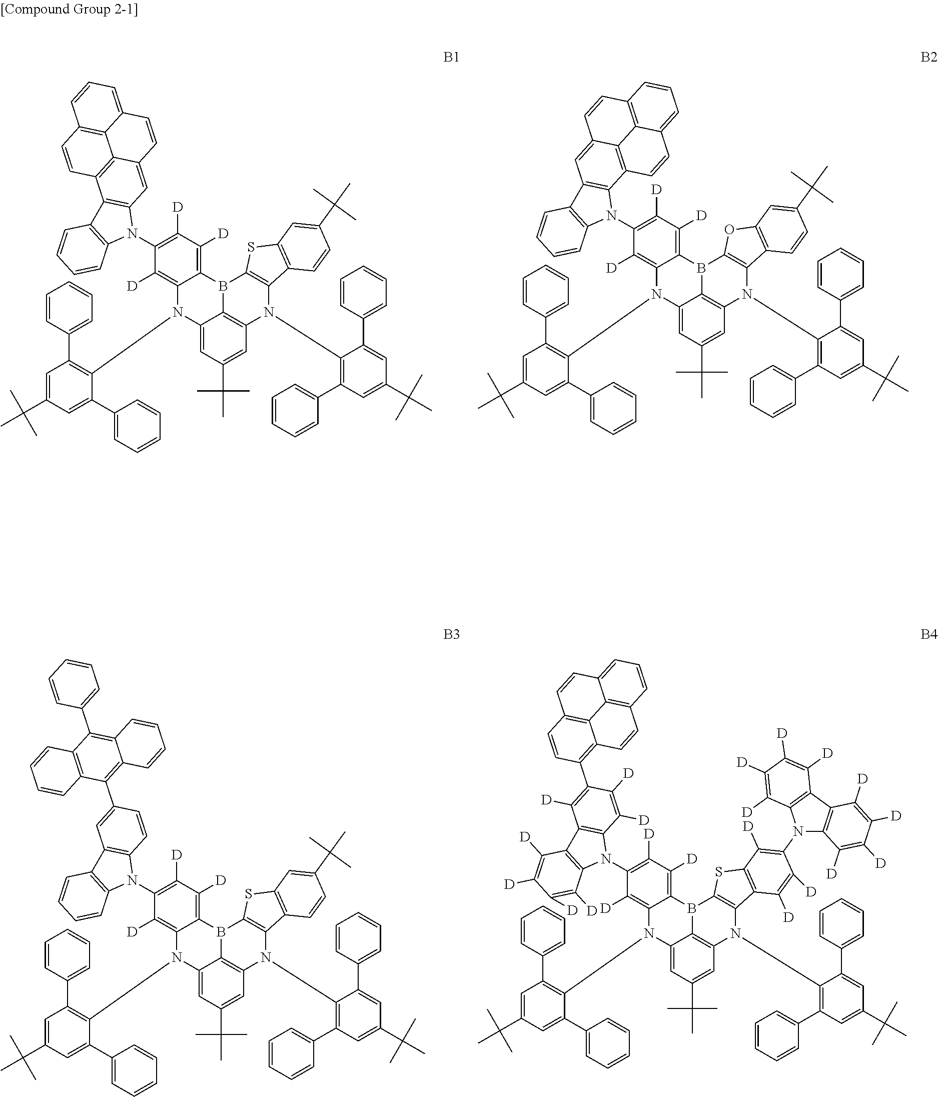

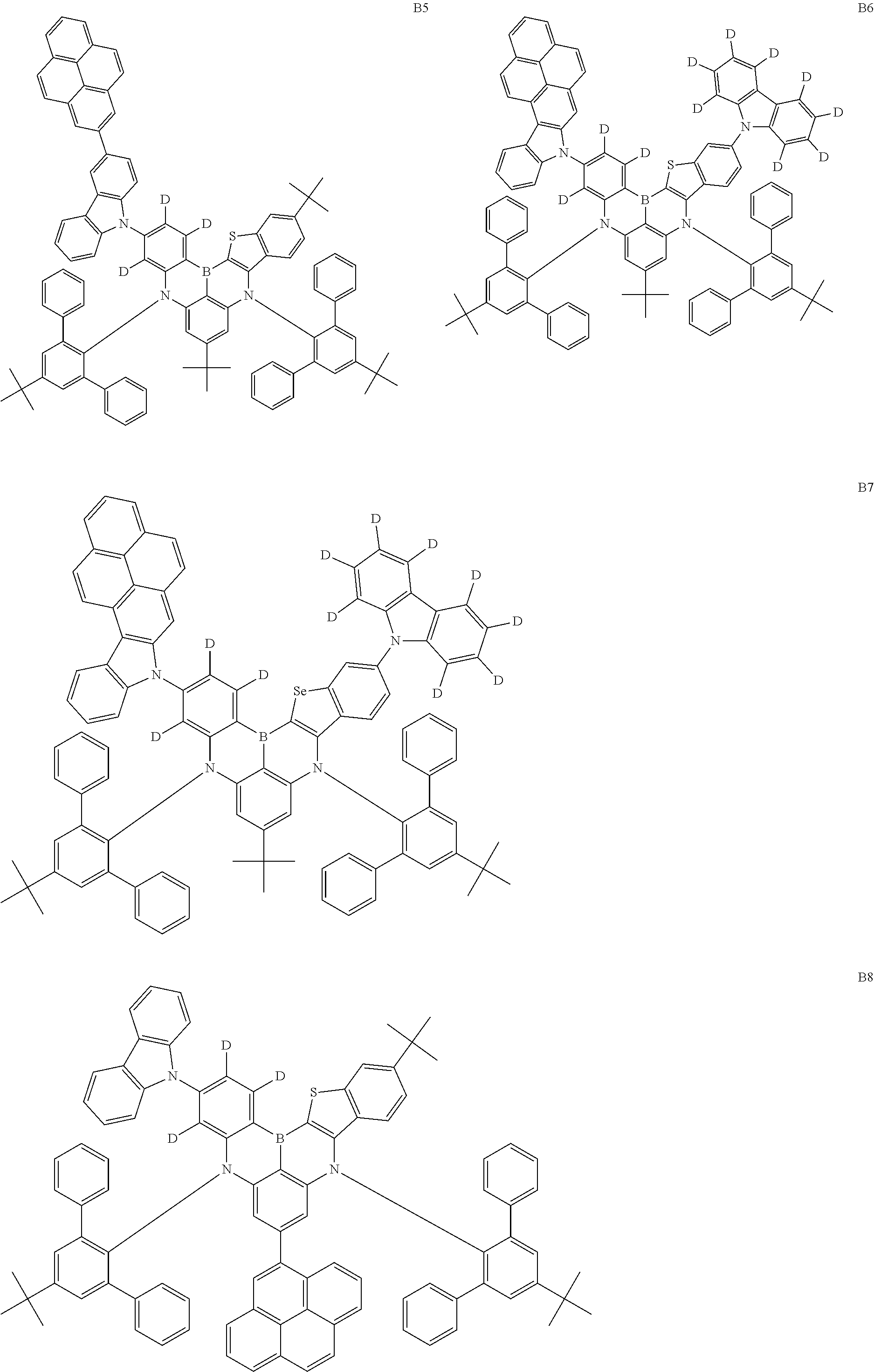

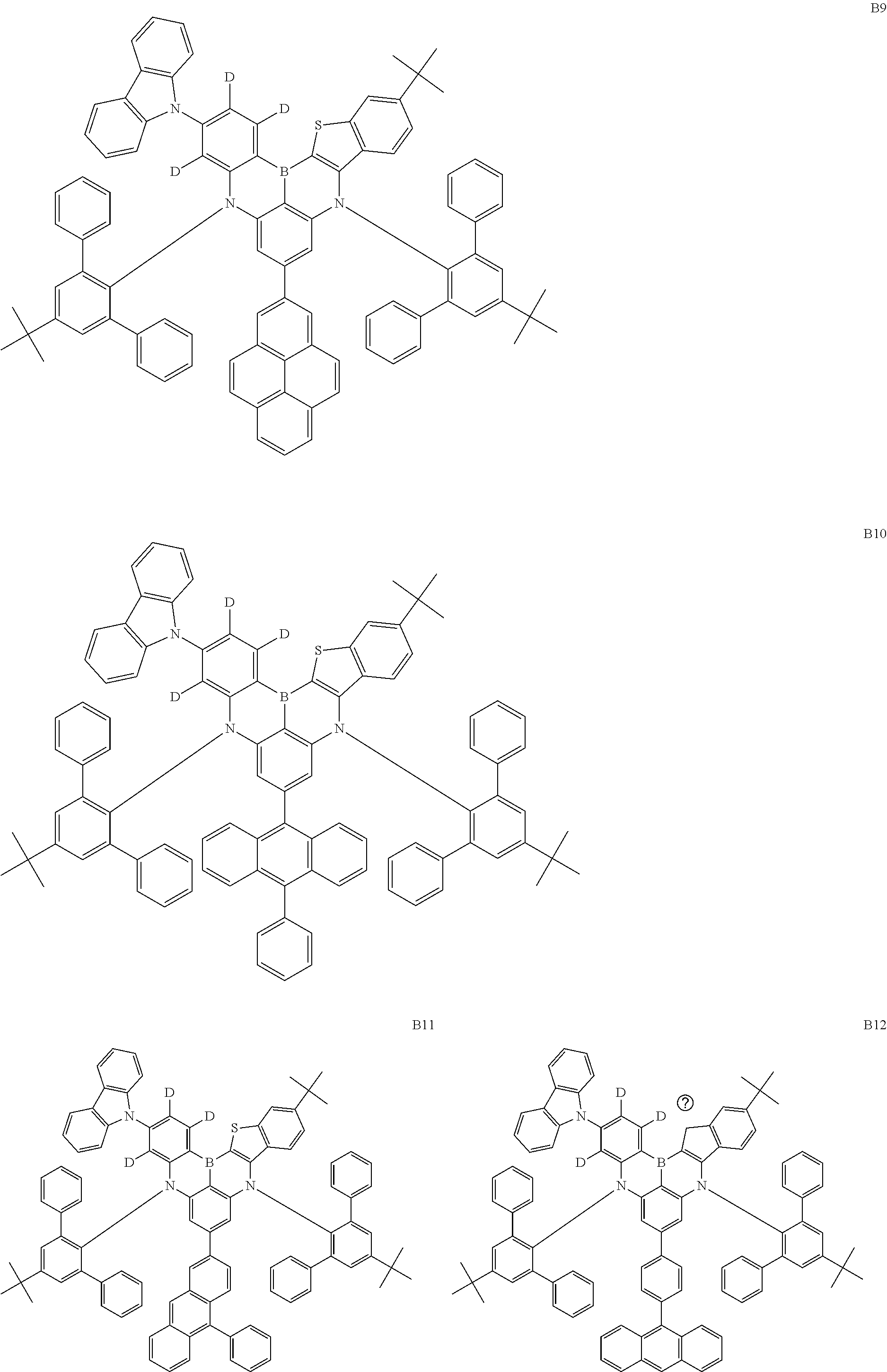

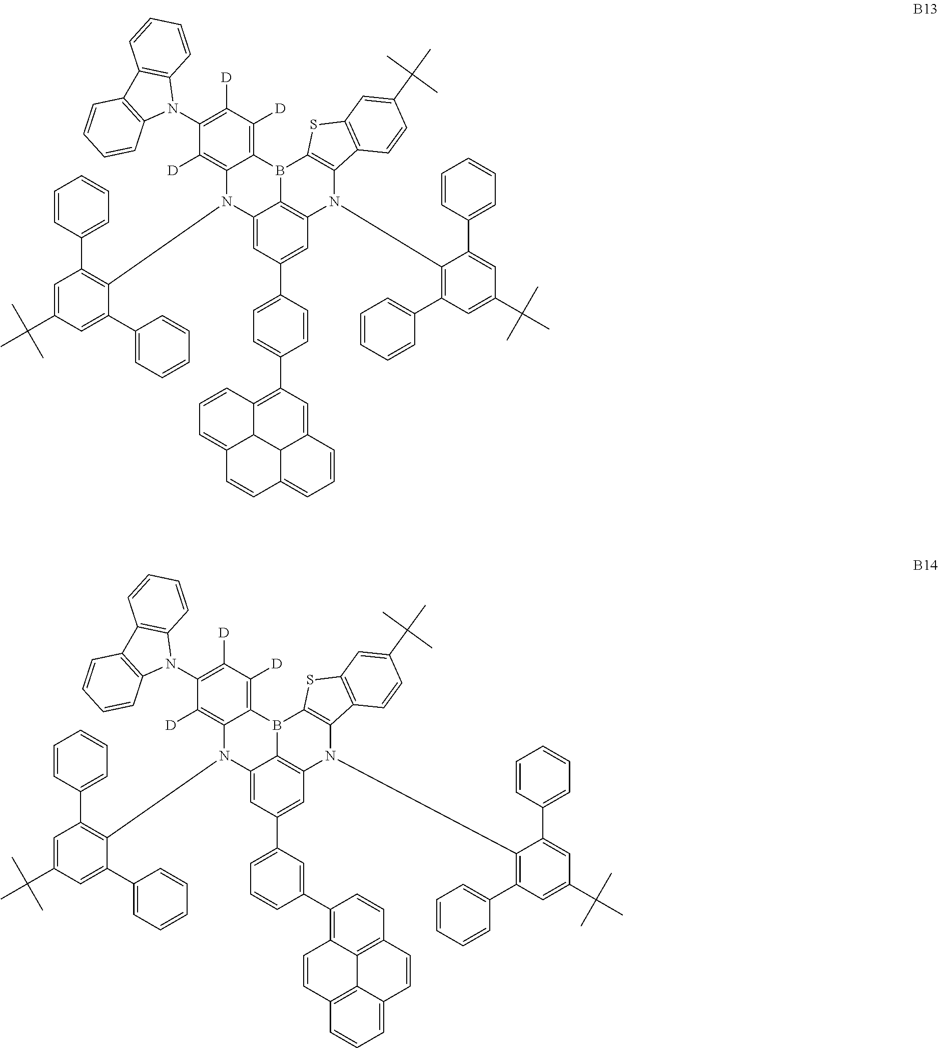

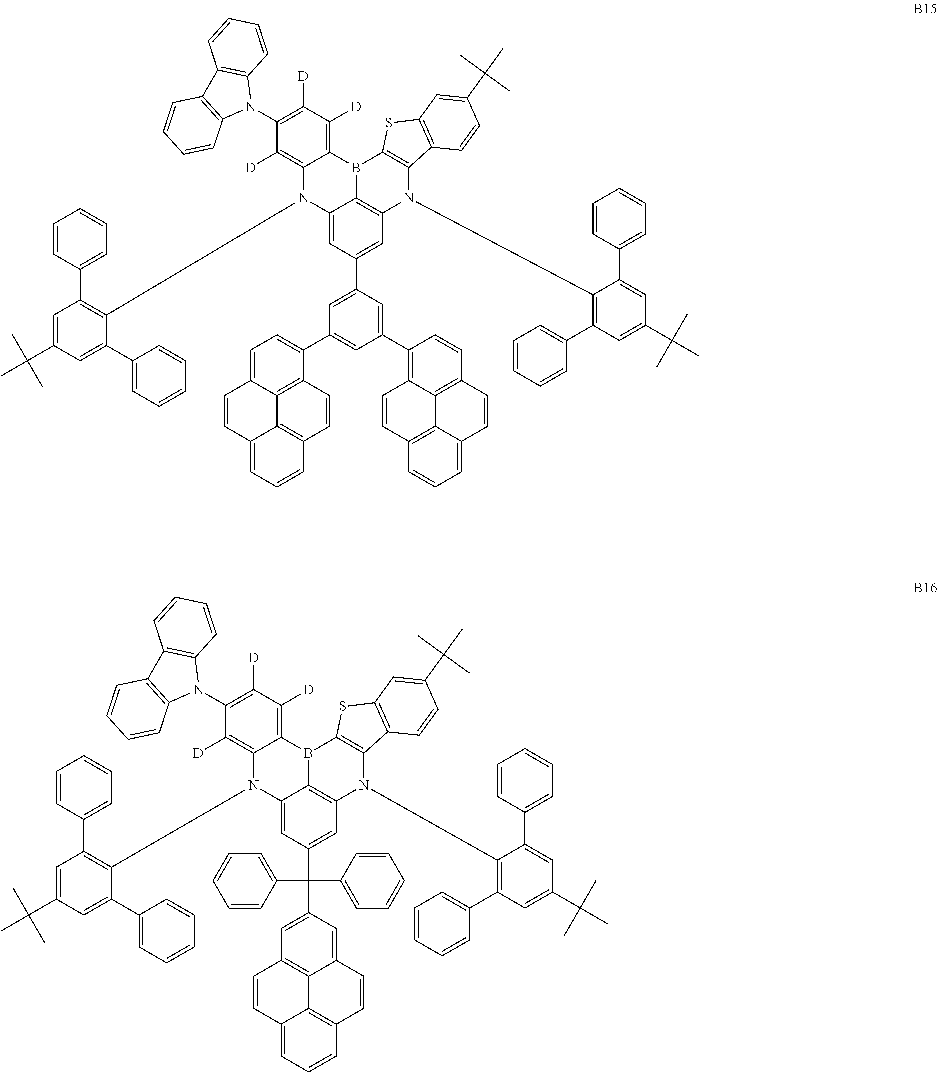

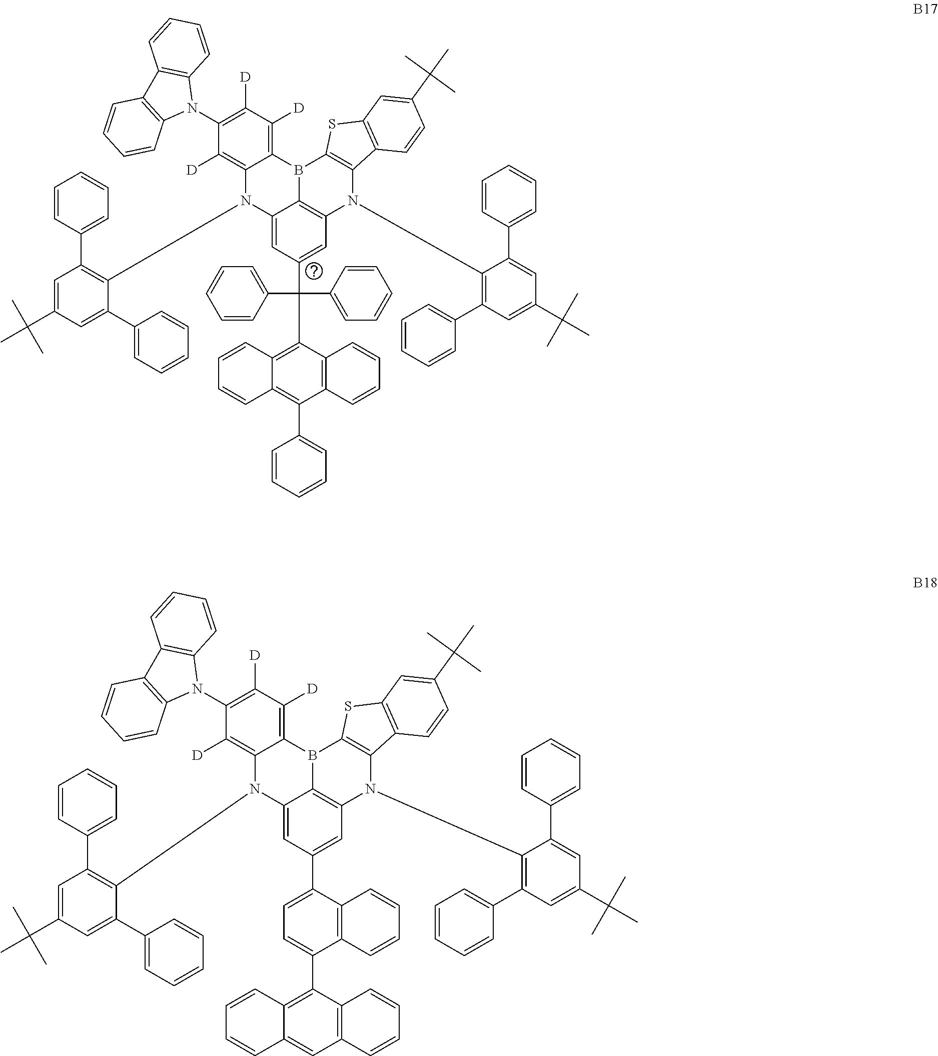

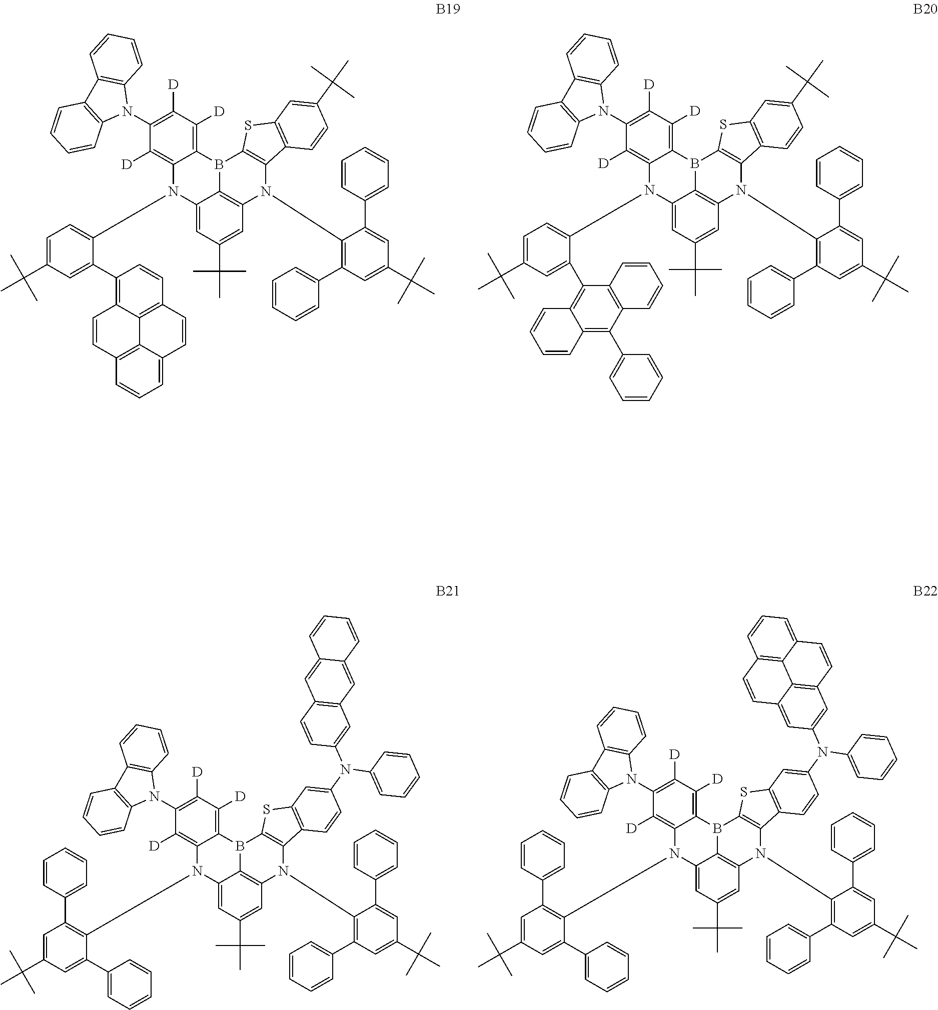

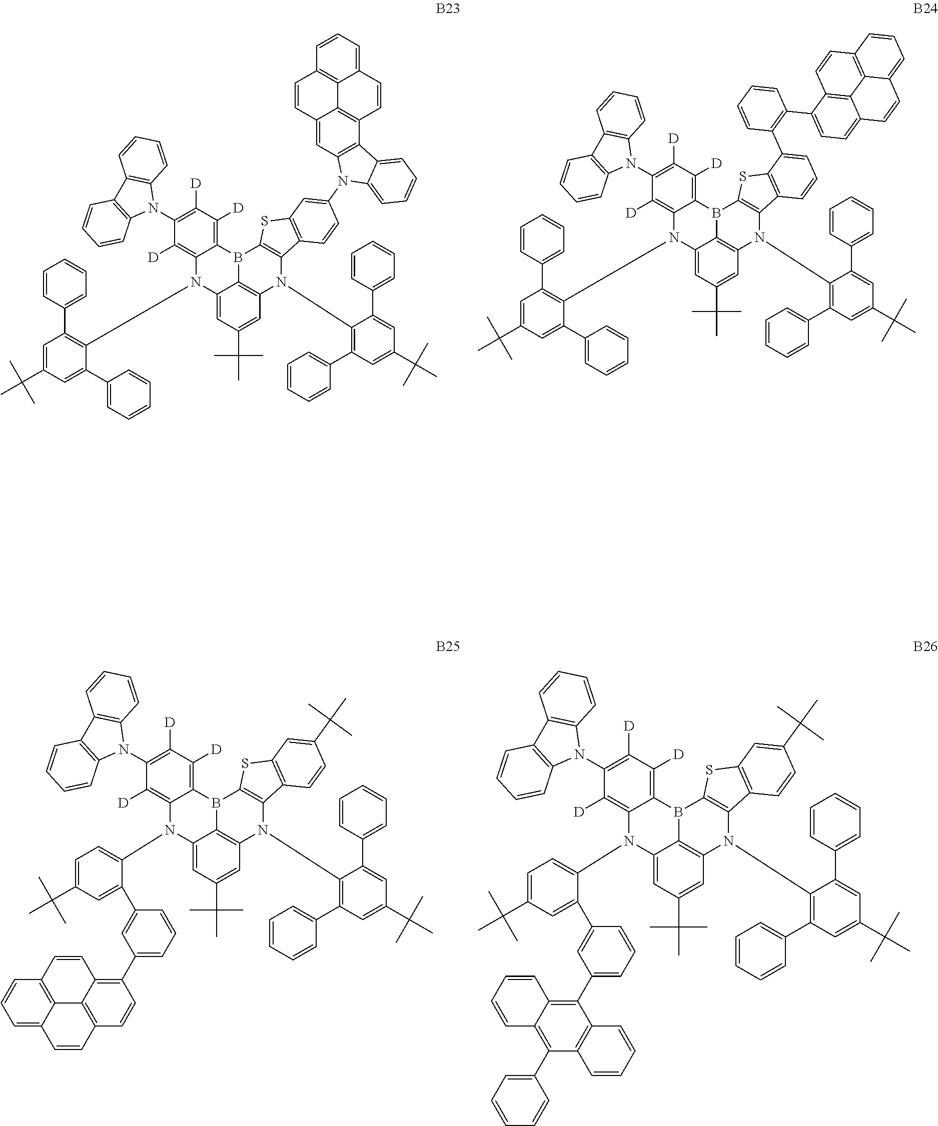

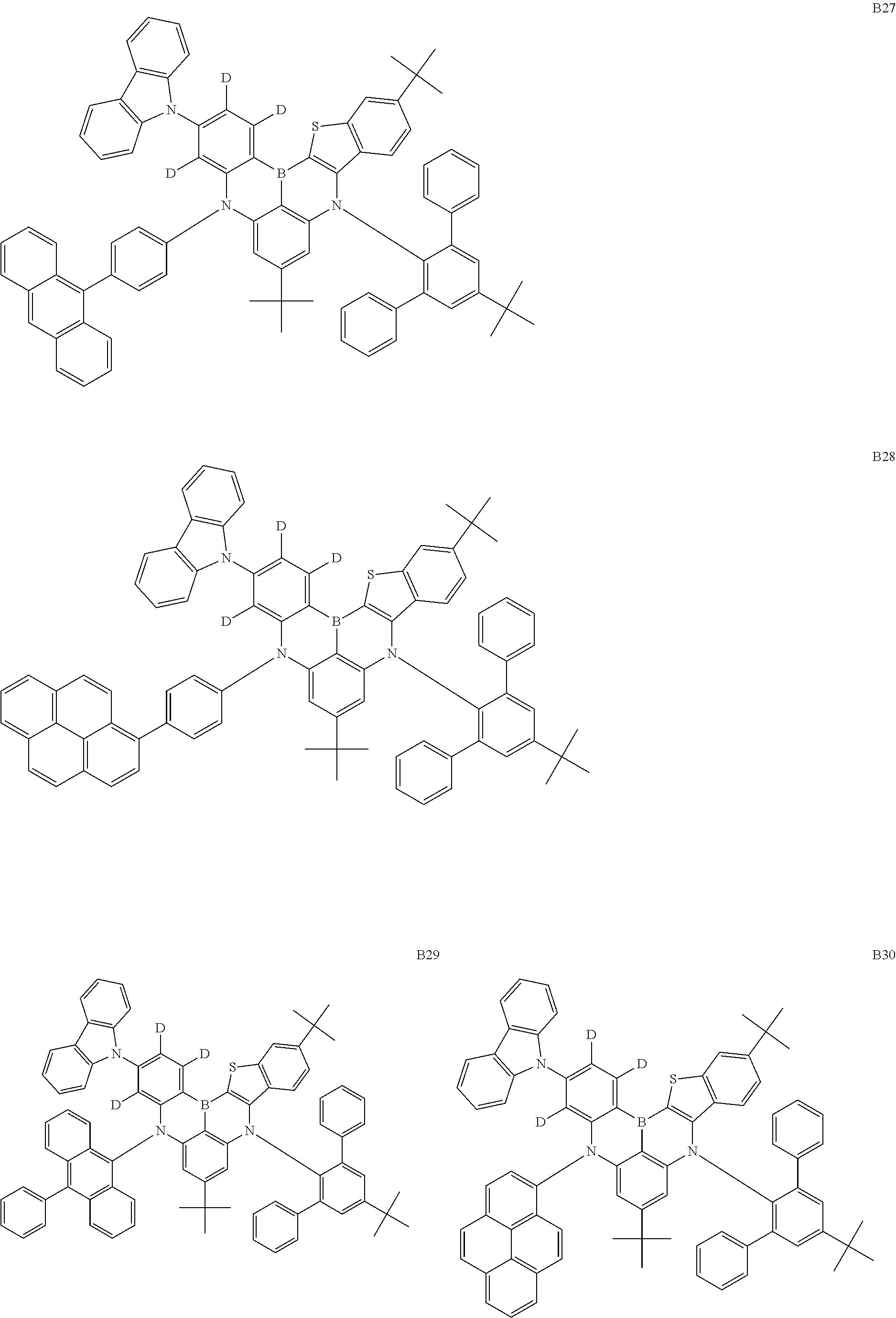

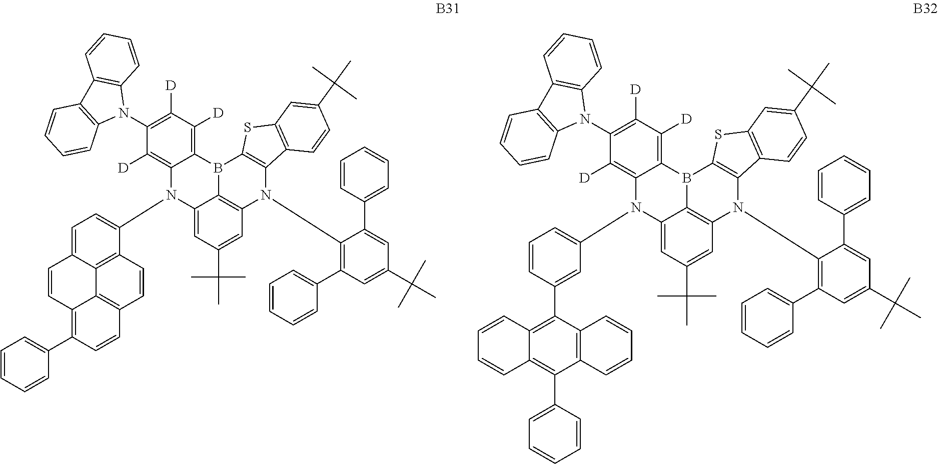 [SMILES: [2H]c1c([2H])c(-n2c3ccccc3c3ccccc32)c([2H])c2c1B1c3sc4cc(C(C)(C)C)ccc4c3N(c3c(-c4ccccc4)cc(C(C)(C)C)cc3-c3ccccc3)c3cc(C(C)(C)C)cc(c31)N2c1ccc2ccc3c(-c4ccccc4)ccc4ccc1c2c43 ; [2H]c1c([2H])c(-n2c3ccccc3c3ccccc32)c([2H])c2c1B1c3sc4cc(C(C)(C)C)ccc4c3N(c3c(-c4ccccc4)cc(C(C)(C)C)cc3-c3ccccc3)c3cc(C(C)(C)C)cc(c31)N2c1cccc(-c2c3ccccc3c(-c3ccccc3)c3ccccc23)c1]

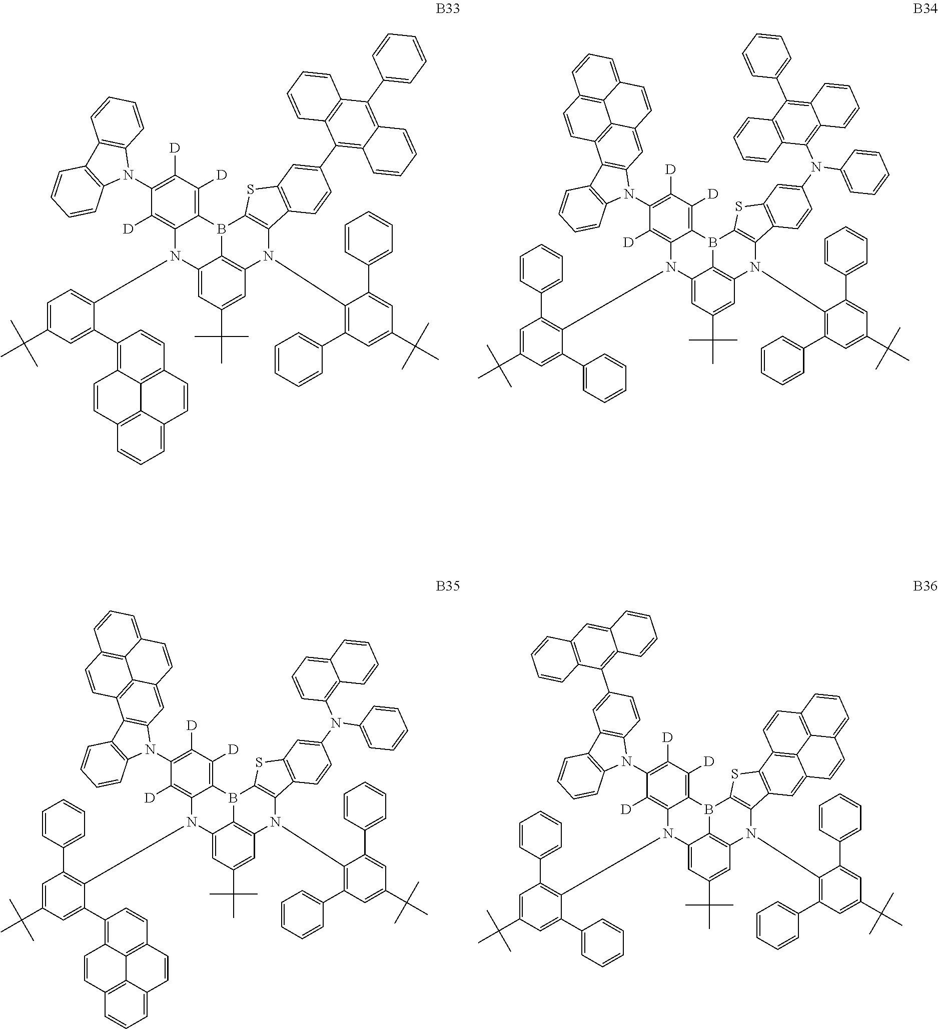

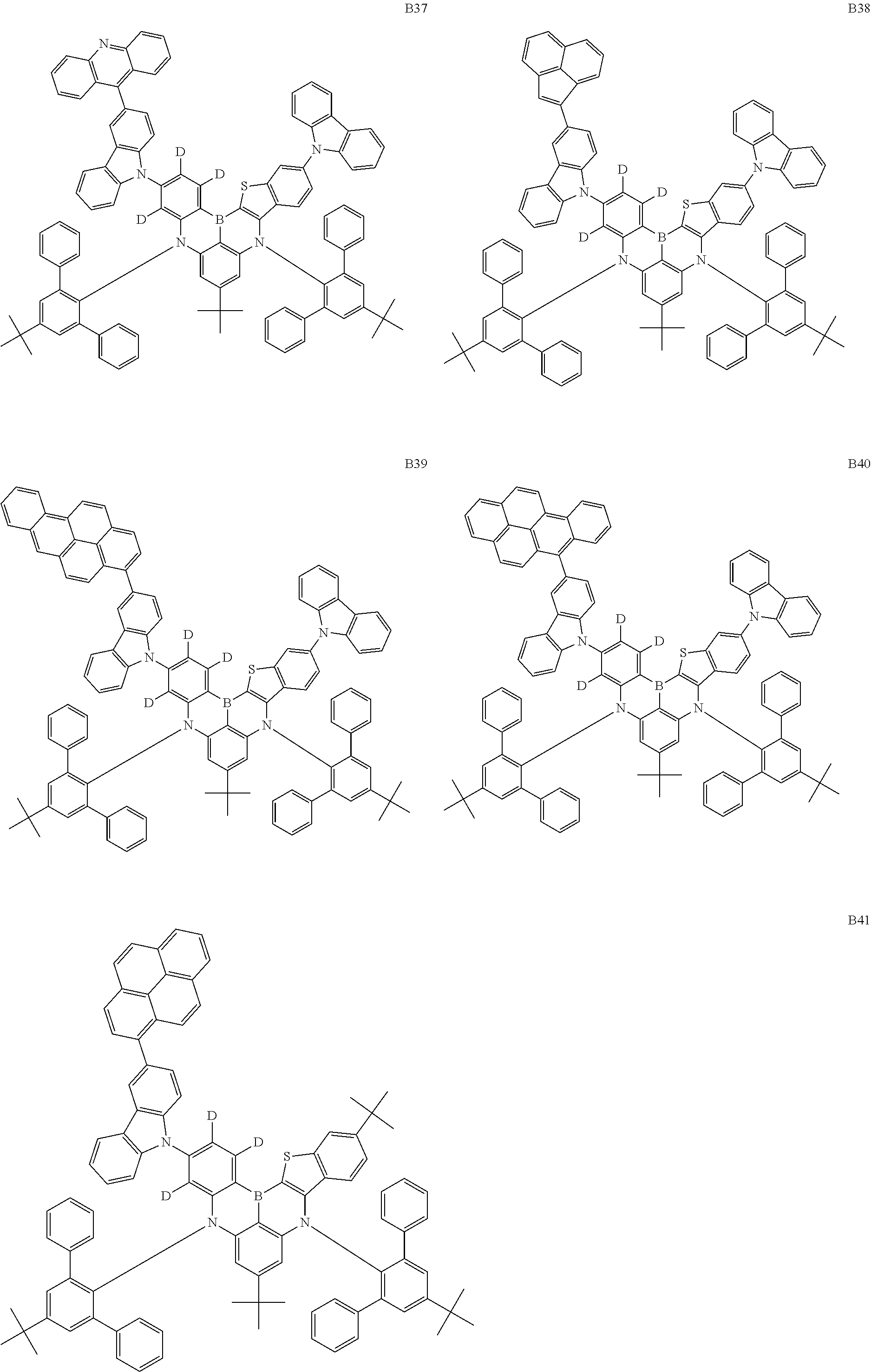

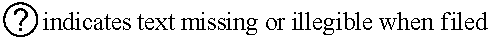

In Compound Group 2-1, D represents a deuterium atom.

The second emission layer EML2 according to an embodiment may include the (2-1)-th compound represented by Formula 2, thereby improving luminescence characteristics, and achieving a long service life.

The (2-1)-th compound represented by Formula 2 includes a second fused ring core in which the first and second aromatic rings and the first heterocycle are fused via the boron atom, the first nitrogen atom, and the second nitrogen atom, and the (2-1)-th compound includes a carbazole substituent linked to the first aromatic ring and a terphenyl substituent linked to the second nitrogen atom. Accordingly, in the (2-1)-th compound according to an embodiment, the empty p-orbital of the boron atom may be protected through a steric hindrance effect, and the trigonal planar structure of the boron atom may be effectively maintained. Accordingly, the (2-1)-th compound according to an embodiment may have improved material stability, thereby preventing material deterioration. Since the (2-1)-th compound inhibits intermolecular interaction, it is possible to reduce the incidence of phenomena such as aggregation, intermolecular excimer formation, or intermolecular exciplex formation, and thus the luminous efficiency of the light emitting element including the (2-1)-th compound may be increased.

The emission layer EML according to an embodiment includes the first emission layer EML1 that emits light by thermally activated delayed fluorescence and the second emission layer EML2 that emits light by triplet-triplet annihilation, so that the service life characteristics of the light emitting element including the emission layer EML may be increased. The first emission layer EML1 emits light by thermally activated delayed fluorescence through reverse inter-system crossing (RISC) of between a lowest triplet energy (T1) and a lowest singlet energy (S1), wherein triplet excitons may accumulate according to a rate of the RISC. The second emission layer EML2 emits light by triplet-triplet annihilation through the collision of triplet excitons. Triplet-triplet energy transfer, such as Dexter energy transfer, may occur between the first emission layer EML1 and the second emission layer EML2, and triplet excitons that are transferred to the host of the second emission layer EML2 may generate singlet excitons through triplet-triplet annihilation, and singlet excitons may be transferred to the dopant of the second emission layer EML2 to emit light. Since a lowest excited triplet energy (T1) of the (2-1)-th compound included in the second emission layer EML2 according to an embodiment is in a range of about 1.5 eV to about 2.1 eV, Dexter energy transfer to the second emission layer EML2 may be predominant as compared to a nonradiative decay of triplet excitons in the first emission layer EML1. When including only the first emission layer EML1 that emits light by thermally activated delayed fluorescence, efficiency and service life of the light emitting element may deteriorate due to the accumulation of triplet excitons, whereas the emission layer EML according to an embodiment further includes the second emission layer EML2, thereby increasing service life characteristics of the light emitting element and improving the reliability of a display device.

An emission spectrum of the (2-1)-th compound represented by Formula 2 may have a full-width at quarter maximum (FWQM) in a range of about 10 nm to about 50 nm. For example, an emission spectrum of the (2-1)-th compound represented by Formula 2 may have a FWQM in a range of about 20 nm to about 40 nm. The emission spectrum of the (2-1)-th compound represented by Formula 2 may exhibit a FWQM within the range described above, thereby improving luminous efficiency when applied to an element.

The second emission layer EML2 may include the (2-1)-th compound according to an embodiment. The second emission layer EML2 may include a second light emitting host, and a second light emitting dopant that is doped into the second light emitting host. The second light emitting dopant may include the (2-1)-th compound according to an embodiment. The second emission layer EML2 may emit fluorescence by triplet-triplet annihilation, and the (2-1)-th compound included in the second emission layer EML2 may be used as a delayed fluorescence dopant that uses triplet-triplet annihilation. For example, in the light emitting element ED, the second emission layer EML2 may include, as a delayed fluorescence dopant, at least one (2-1)-th compound selected from Compound Group 2-1 as described above.

The (2-1)-th compound represented by Formula 2 may be a luminescent material having a central wavelength in a range of about 430 nm to about 490 nm. For example, the (2-1)-th compound represented by Formula 2 may be a delayed fluorescence dopant that uses triplet-triplet annihilation. However, embodiments are not limited thereto, and the (2-1)-th compound may be used as a dopant material that emits light in various wavelength regions, such as a red emitting dopant a green emitting dopant.

The color of light emitted from the second emission layer EML2 of the light emitting element ED may be substantially the same as or similar to the color of light emitted from the first emission layer EML1. For example, the first emission layer EML1 may emit blue light, and the second emission layer EML2 may emit blue light. The first emission layer EML1 and the second emission layer EML2 of the light emitting element ED may each emit blue light having a wavelength range equal to or less than about 490 nm. However, embodiments are not limited thereto, and the first emission layer EML1 and the second emission layer EML2 may each independently emit green light or red light.

In an embodiment, the second emission layer EML2 may include multiple compounds.

The second emission layer EML2 may include the (2-1)-th compound represented by Formula 2, and may further include a (2-2)-th compound represented by Formula E-1. For example, the second emission layer EML2 may include the (2-1)-th compound represented by Formula 2 and the (2-2)-th compound represented by Formula E-1. In an embodiment, the second emission layer EML2 may consist of the (2-1)-th compound represented by Formula 2 and the (2-2)-th compound represented by Formula E-1.

In an embodiment, the second emission layer EML2 may include the (2-2)-th compound represented by Formula E-1. In an embodiment, the second emission layer EML2 may include a second light emitting host, and the second light emitting host may include the (2-2)-th compound.

In an embodiment, the (2-2)-th compound may be used as a fluorescence host material in the second emission layer EML2.

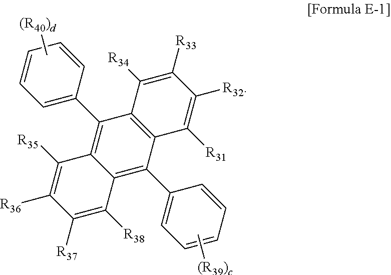

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

In an embodiment, the (2-2)-th compound represented by Formula E-1 may be any compound selected from Compound E1 to Compound E19. In an embodiment, in the light emitting element ED, the (2-2)-th compound may include at least one compound selected from Compound E1 to Compound E19:

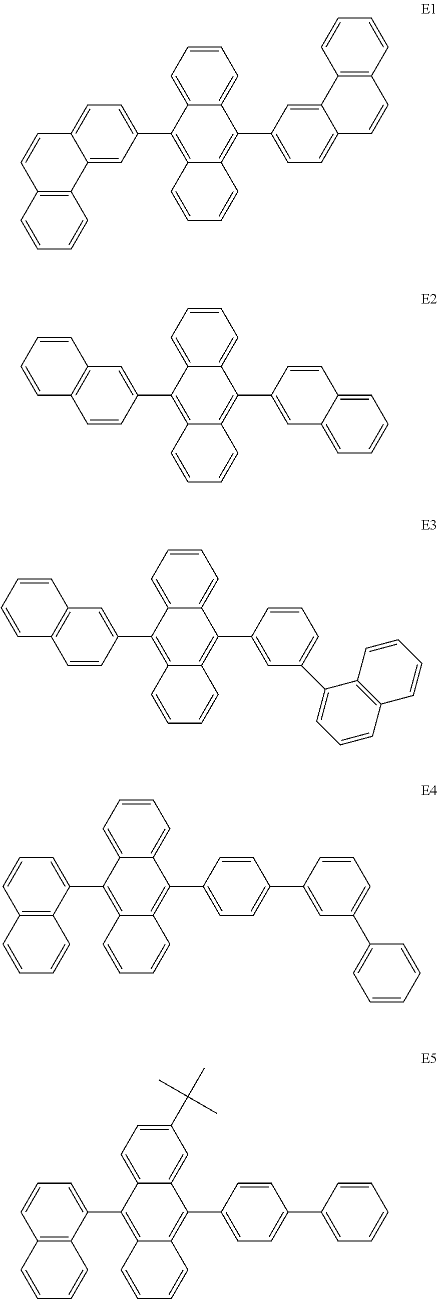

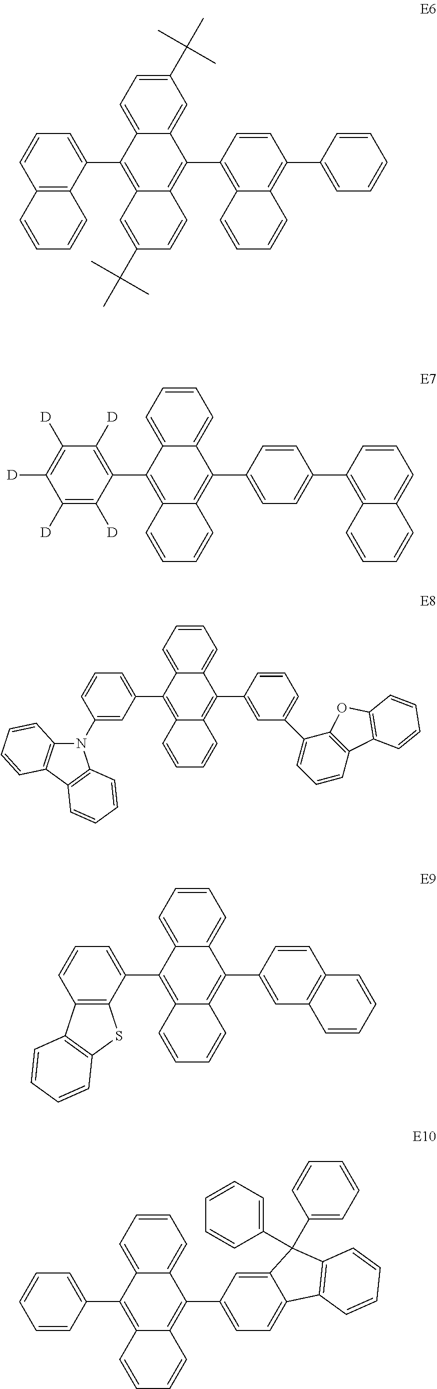

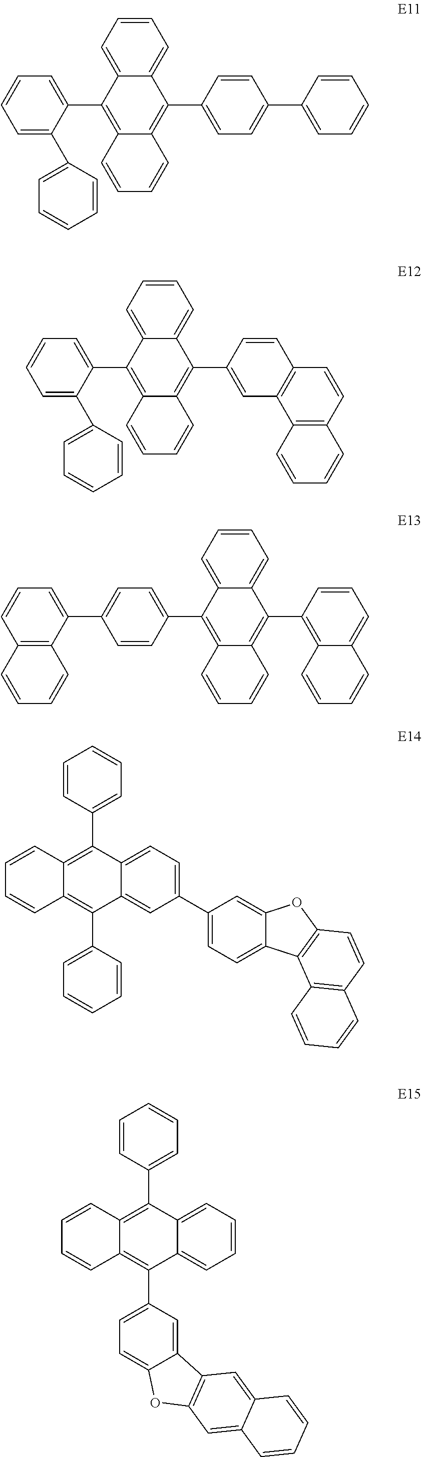

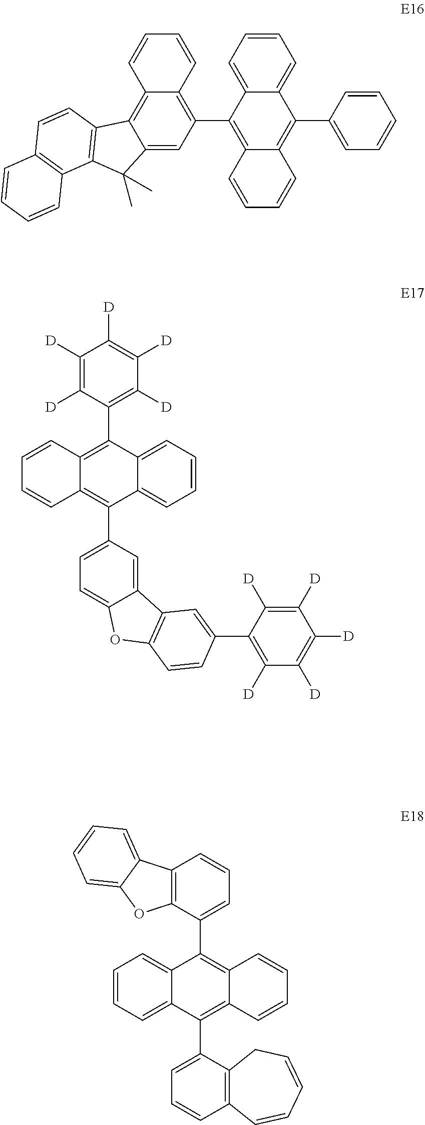

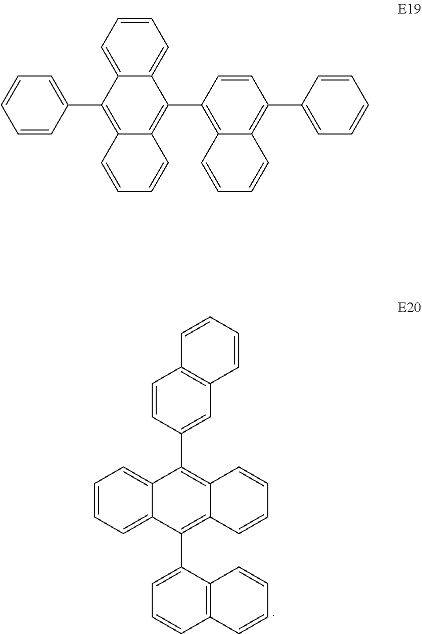

In the light emitting element ED according to an embodiment as illustrated in each of FIGS. 3 to 6, the emission layer EML may include the (1-1)-th compound and (2-1)-th compound as described above, and the emission layer EML may further include a host of the related art and a dopant of the related art, in addition to the (1-1)-th compound and the (2-1)-th compound.

In an embodiment, the emission layer EML may further include a compound represented by Formula E-2a or Formula E-2b. The compound represented by Formula E-2a or Formula E-2b may be used as a phosphorescent host material.

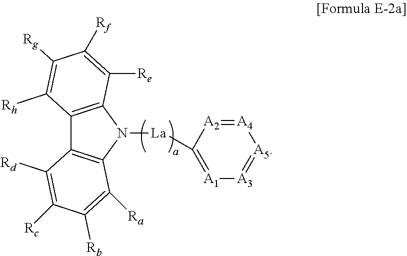

In Formula E-2a, a may be an integer from 0 to 10; and Lₐ may be a direct linkage, a substituted or unsubstituted arylene group having 6 to 30 ring-forming carbon atoms, or a substituted or unsubstituted heteroarylene group having 2 to 30 ring-forming carbon atoms. When a is 2 or greater, multiple Lₐ groups may each independently be a substituted or unsubstituted arylene group having 6 to 30 ring-forming carbon atoms or a substituted or unsubstituted heteroarylene group having 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, Rₐ to Rᵢ may be bonded to an adjacent group to form a hydrocarbon ring or a heterocycle containing N, O, S, etc., as a ring-forming atom.

In Formula E-2a, two or three of A₁ to A₅ may each be N, and the remainder of A₁ to A₅ may each independently be C(Rᵢ).

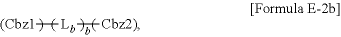

In Formula E-2b, Cbz1 and Cbz2 may each independently be an unsubstituted carbazole group or a carbazole group substituted with an aryl group having 6 to 30 ring-forming carbon atoms. In Formula E-2b, L_{b} may be a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10. When b is 2 or more, multiple L_{b} groups may each independently be a substituted or unsubstituted arylene group having 6 to 30 ring-forming carbon atoms or a substituted or unsubstituted heteroarylene group having 2 to 30 ring-forming carbon atoms.

In an embodiment, the compound represented by Formula E-2a or Formula E-2b may be any compound selected from Compound Group E-2. However, the compounds listed in Compound Group E-2 are only examples, and the compound represented by Formula E-2a or Formula E-2b is not limited to Compound Group E-2:

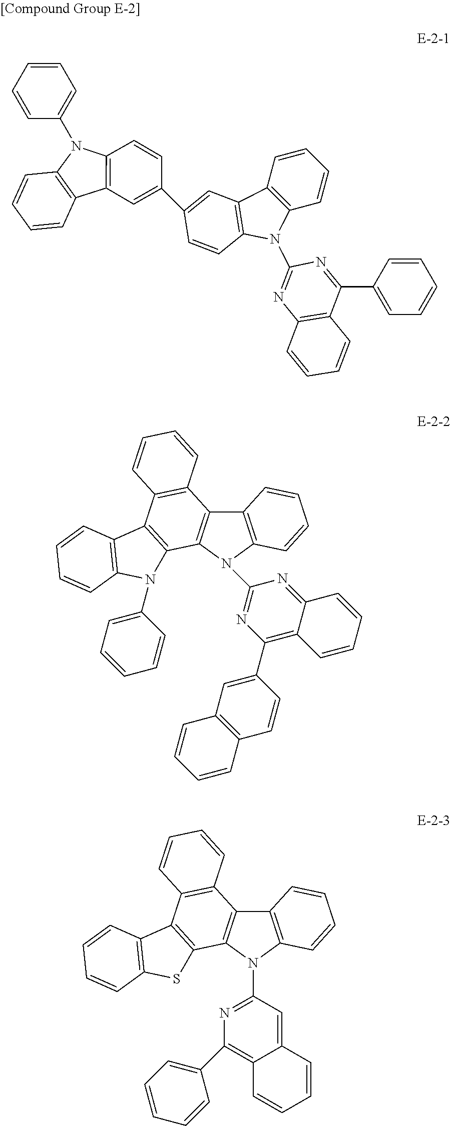 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)cc3ccccc23)cc1]

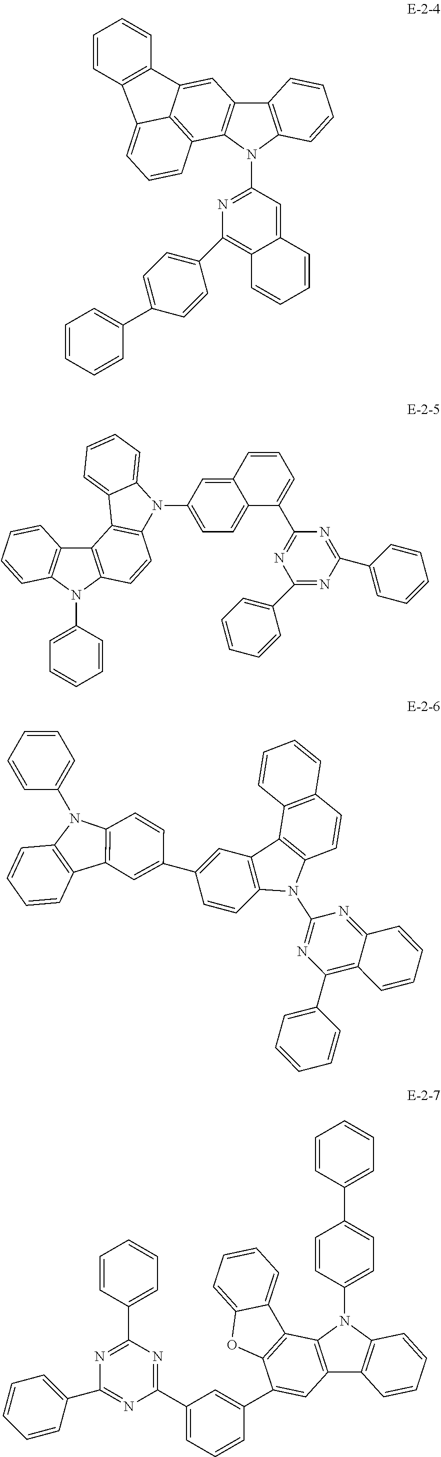 [SMILES: c1ccc(-c2ccc(-c3nc(-n4c5ccccc5c5cc6c7c(cccc7c54)-c4ccccc4-6)cc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1]

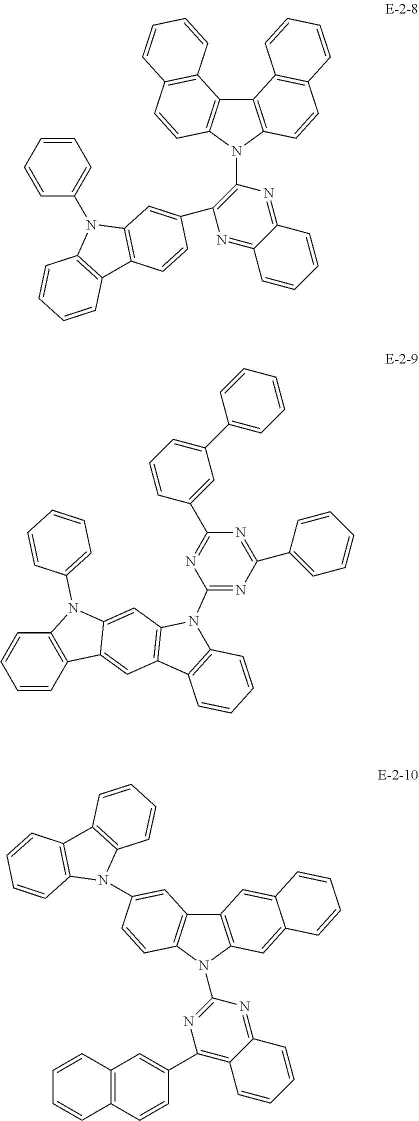 [SMILES: c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1]

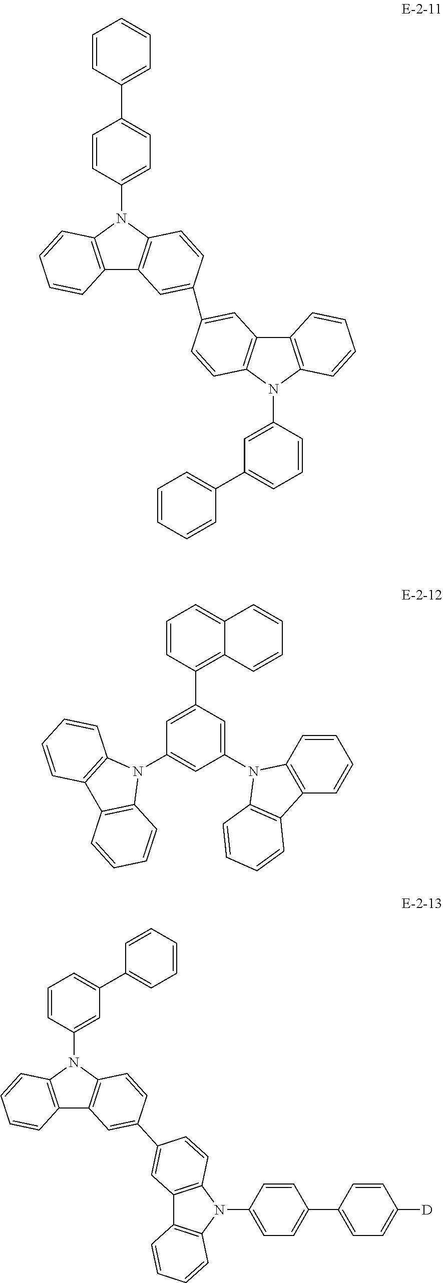 [SMILES: c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1]

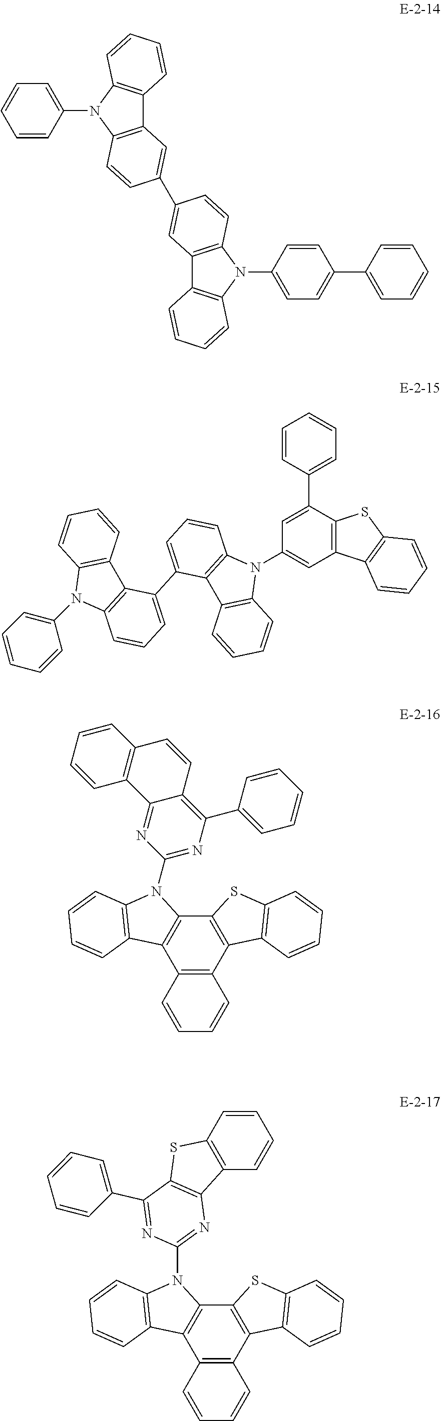 [SMILES: c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1 ; c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1]

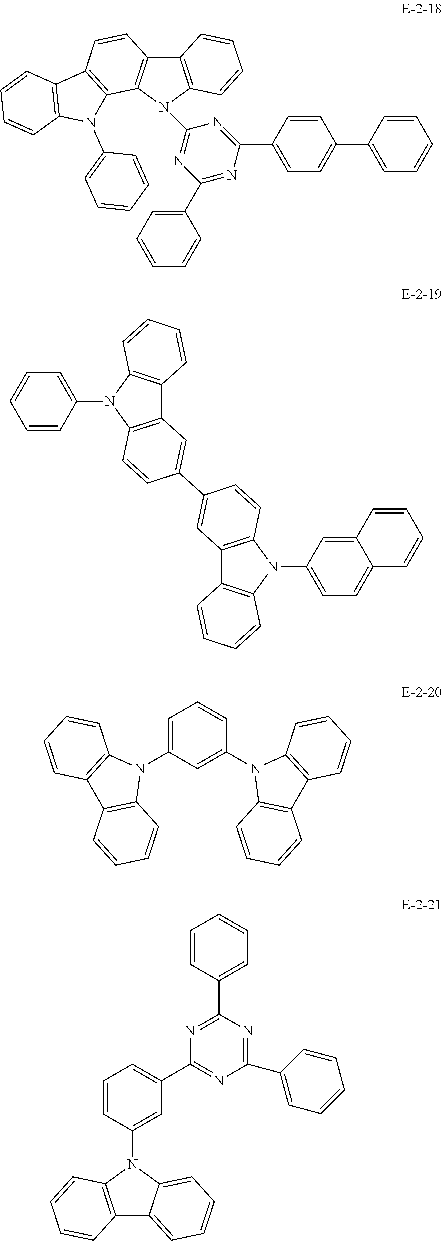 [SMILES: c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1]

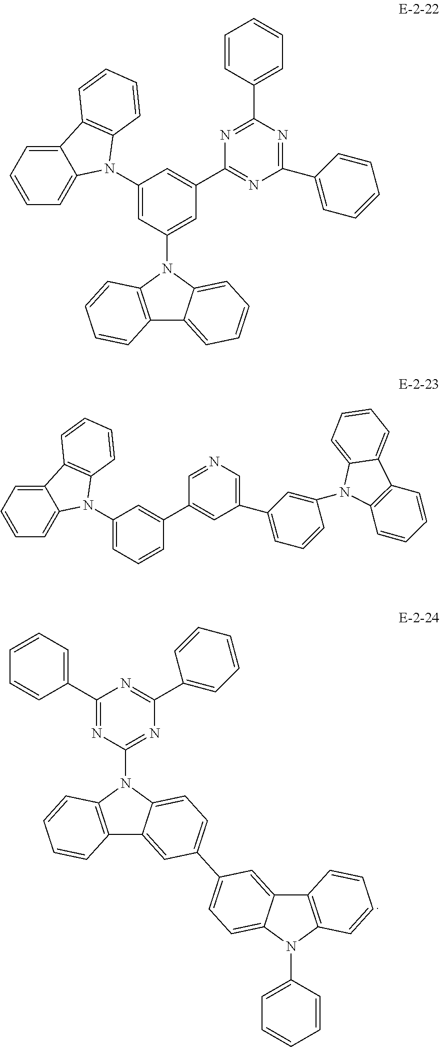 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material of the related art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), and 1,3,5-tris(1-phenyl-1H-benzo[d]imidazole-2-yl)benzene (TPBi). However, embodiments are not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), etc. may be used as a host material.

In an embodiment, the emission layer EML may include a compound represented by Formula M-a. The compound represented by Formula M-a may be used as a phosphorescent dopant material.

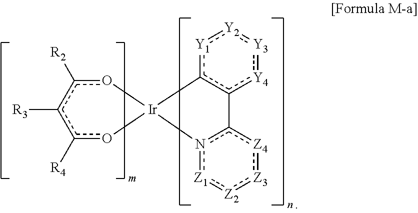

In Formula M-a, Y₁ to Y₄ and Z₁ to Z₄ may each independently be C(R₁) or N; R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. In Formula M-a, m may be 0 or 1, and n may be 2 or 3. In Formula M-a, when m is 0, n may be 3, and when m is 1, n may be 2.

In an embodiment, the compound represented by Formula M-a may be any compound selected from Compound M-a1 to Compound M-a25. However, Compounds M-a1 to M-a25 are only examples, and the compound represented by Formula M-a is not limited to Compounds M-a1 to M-a25:

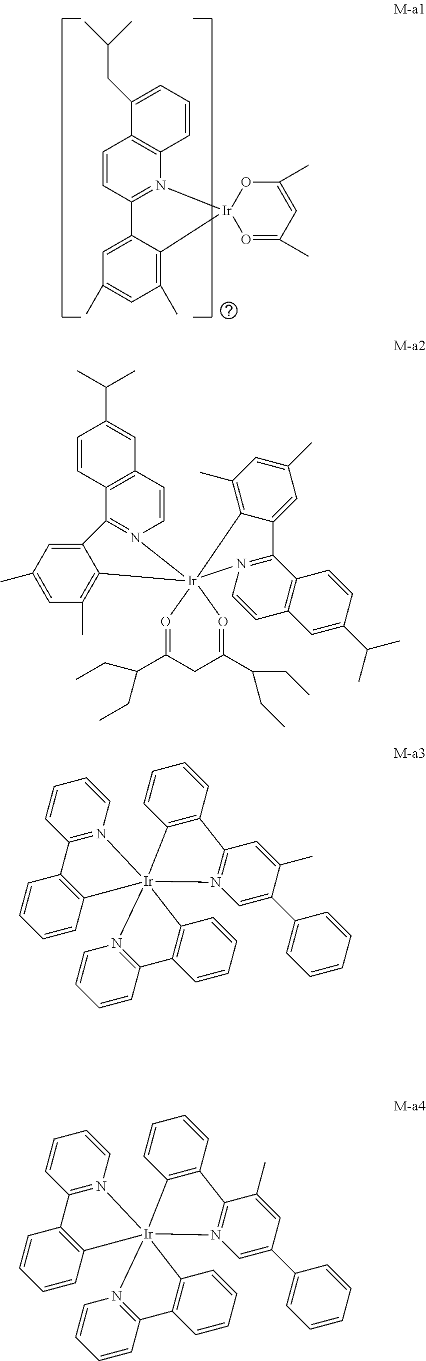

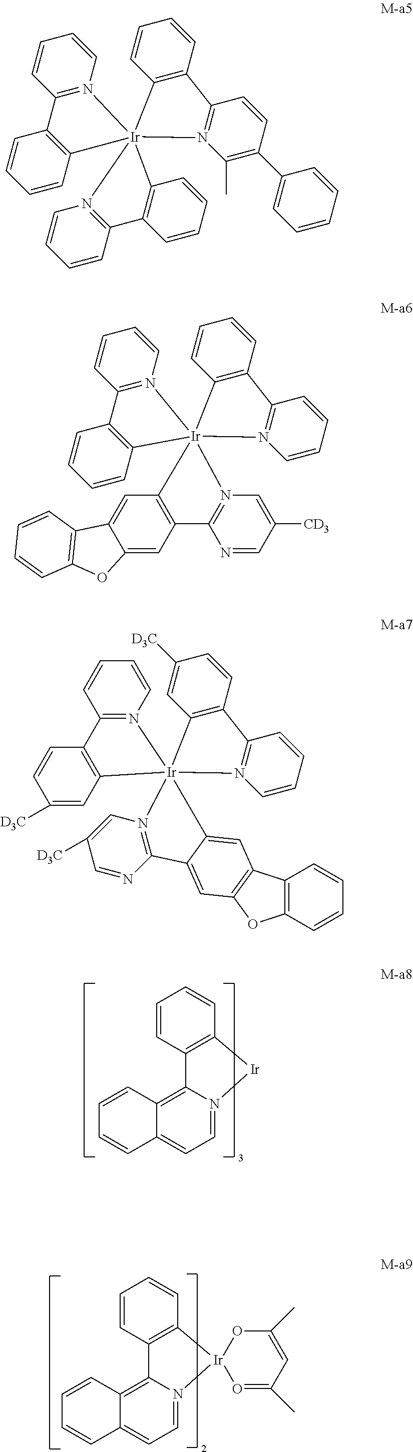

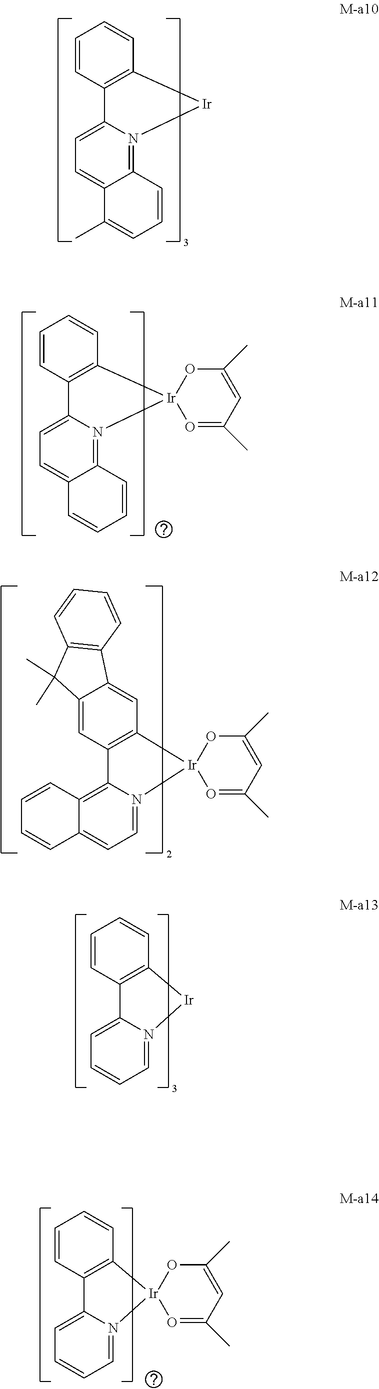

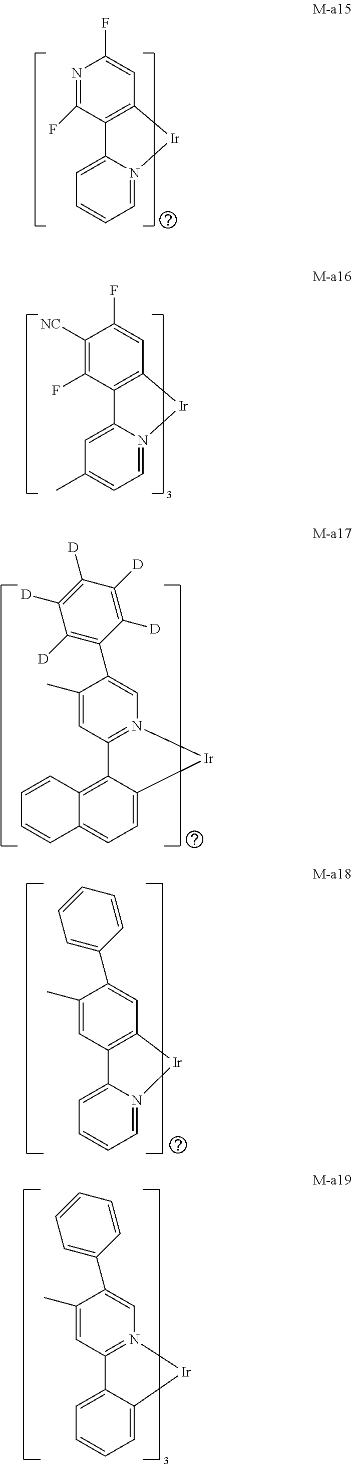

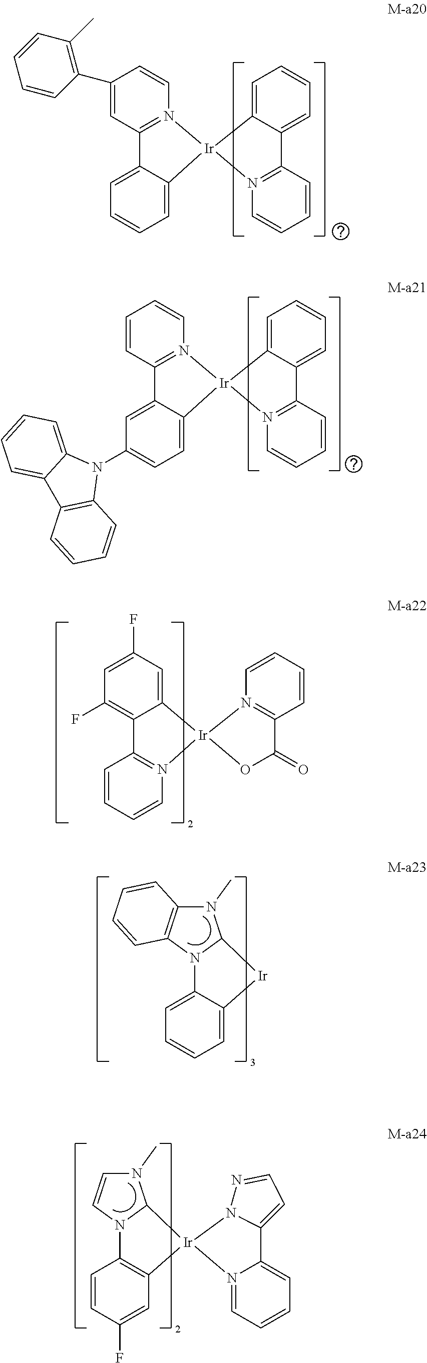

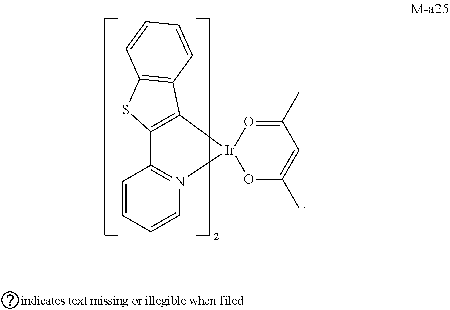

In an embodiment, the emission layer EML may include a compound represented by one of Formula F-a to Formula F-c. The compound represented by one of Formula F-a to Formula F-c may be used as a fluorescence dopant material.

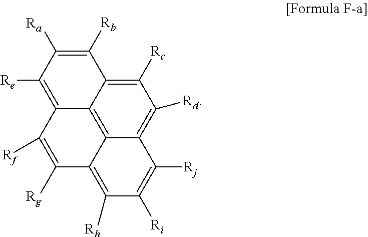

In Formula F-a, two of Rₐ to Rⱼ may each independently be substituted with a group represented by *—NAr₁Ar₂. The remainder of Rₐ to Rⱼ that are not substituted with the group represented by *—NAr₁Ar₂ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In group represented by *—NAr₁Ar₂, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ and Ar₂ may each independently be a heteroaryl group containing O or S as a ring-forming atom.

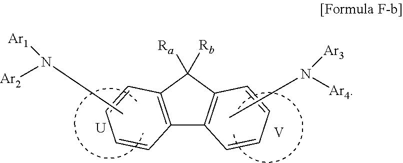

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or be bonded to an adjacent group to form a ring. In Formula F-b, Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ to Ar₄ may each independently be a heteroaryl group containing O or S as a ring-forming atom.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms.

In Formula F-b, the number of rings represented by U and V may each independently be 0 or 1. When the number of U or V is 1, a fused ring may be present at a portion respectively indicated by U or V, and when the number of U or V is 0, a fused ring may not be present at the portion respectively indicated by U or V. When the number of U is 0 and the number of V is 1, or when the number of U is 1 and the number of V is 0, a fused ring having a fluorene core of Formula F-b may be a cyclic compound having four rings. When the number of U and V is each 0, a fused ring having a fluorene core of Formula F-b may be a cyclic compound having three rings. When the number of U and V is each 1, a fused ring having a fluorene core of Formula F-b may be a cyclic compound having five rings.

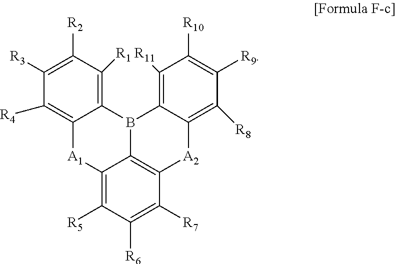

In Formula F-c, A₁ and A₂ may each independently be O, S, Se, or N(Rₘ); and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

In Formula F-c, A₁ and A₂ may each independently be bonded to a substituent of an adjacent ring to form a fused ring. For example, when A₁ and A₂ are each independently N(Rₘ), A₁ may be bonded to R₄ or R₅ to form a fused ring, and/or A₂ may be bonded to R₇ or R₈ to form a fused ring.

In an embodiment, the emission layer EML may further include, as a dopant material of the related art, a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and 4,4′-bis[2-(4-(N,N-diphenylamino)phenyl)vinyl]biphenyl (DPAVBi)), perylene or a derivative thereof (e.g., 2,5,8,11-tetra-t-butylperylene (TBP)), pyrene or a derivative thereof (e.g., 1,1-dipyrene, 1,4-dipyrenylbenzene, 1,4-bis(N,N-diphenylamino)pyrene), etc.

The emission layer EML may further include a phosphorescence dopant material of the related art. For example, a metal complex containing iridium (Ir), platinum (Pt), osmium (Os), gold (Au), titanium (Ti), zirconium (Zr), hafnium (Hf), europium (Eu), terbium (Tb), or thulium (Tm) may be used as a phosphorescent dopant. For example, iridium(III) bis(4,6-difluorophenylpyridinato-N,C2) (FIrpic), bis(2,4-difluorophenylpyridinato)-tetrakis(1-pyrazolyl)borate iridium(III) (Fir6), or platinum octaethyl porphyrin (PtOEP) may be used as a phosphorescent dopant. However, embodiments are not limited thereto.

In an embodiment, the emission layer EML may include a quantum dot. The quantum dot may include a Group II-VI compound, a Group III-VI compound, a Group I-III-IV compound, a Group III-V compound, a Group III-II-V compound, a Group IV-VI compound, a Group IV element, a Group IV compound, or a combination thereof.

Examples of a Group II-VI compound may include: a binary compound such as CdSe, CdTe, CdS, ZnS, ZnSe, ZnTe, ZnO, HgS, HgSe, HgTe, MgSe, MgS, and a mixture thereof; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; a quaternary compound such as HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof; and any combination thereof.

Examples of a Group III-VI compound may include: a binary compound such as In₂S3 or In₂Se₃; a ternary compound such as InGaS₃ or InGaSe₃; and any combination thereof.

Examples of a Group 1-II-VI compound may include: a ternary compound such as AgInS, AgInS₂, CuInS, CuInS₂, AgGaS₂, CuGaS₂ CuGaO₂, AgGaO₂, AgAlO₂, and a mixture thereof; a quaternary compound such as AgInGaS₂ or CuInGaS₂; and any combination thereof.

Examples of a Group III-V compound may include: a binary compound such as GaN, GaP, GaAs, GaSb, AlN, AlP, AlAs, AlSb, InN, InP, InAs, InSb, and a mixture thereof; a ternary compound such as GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof; and any combination thereof. In an embodiment, a Group III-V compound may further include a Group II element. Examples of a Group III-II-V compound may include InZnP, etc.

Examples of a Group IV-VI compound may include: a binary compound such as SnS, SnSe, SnTe, PbS, PbSe, PbTe, and a mixture thereof; a ternary compound such as SnSeS, SnSeTe, SnSTe, PbSeS, PbSeTe, PbSTe, SnPbS, SnPbSe, SnPbTe, and a mixture thereof; a quaternary compound such as SnPbSSe, SnPbSeTe, SnPbSTe, and a mixture thereof; and any combination thereof. Examples of a Group IV element may include Si, Ge, and a mixture thereof. Examples of a Group IV compound may include a binary compound such as SiC, SiGe, and a mixture thereof.

Each element included in a compound, such as a binary compound, a ternary compound, or a quaternary compound, may be present in a particle at a uniform concentration distribution or at a non-uniform concentration distribution. For example, a formula may indicate the elements that are included in a compound, and an elemental ratio of the compound may vary. For example, AgInGaS₂ may indicate AgInₓGa₁₋ₓS2 (where x is a real number between 0 and 1).

In an embodiment, a quantum dot may have a single structure in which the concentration of each element included in the quantum dot is uniform. In another embodiment, a quantum dot may have a core-shell structure in which a quantum dot material surrounds another quantum dot. For example, a material included in the core may be different from a material included in the shell.

The shell of a quantum dot may serve as a protection layer that prevents chemical deformation of the core to maintain semiconductor properties, and/or may serve as a charging layer that imparts electrophoretic properties to the quantum dot. The shell may have a single-layered structure or a multilayered structure. An interface between the core and the shell may have a concentration gradient in which the concentration of an element that is present in the shell decreases towards the core.

In embodiments, the quantum dot may have a core/shell structure as described above that includes a core containing nanocrystals and a shell surrounding the core. Examples of a shell of a quantum dot may include a metal oxide, a non-metal oxide, a semiconductor compound, or a combination thereof.

Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; and a ternary compound such as MgAl₂O₄, CoFe₂O₄, NiFe₂O₄, or CoMn₂O₄, but embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width at half maximum (FWHM) of an emission wavelength spectrum equal to or less than about 45 nm. For example, the quantum dot may have a FWHM of an emission wavelength spectrum equal to or less than about 40 nm. For example, the quantum dot may have a FWHM of an emission wavelength spectrum equal to or less than about 30 nm. Color purity or color reproducibility may be improved in any of the above ranges. Light emitted through a quantum dot may be emitted in all directions, so that a wide viewing angle may be improved.

The form of a quantum dot is not particularly limited and may be any form that is used in the related art. For example, a quantum dot may have a spherical shape, a pyramidal shape, a multi-arm shape, or a cubic shape, or the quantum dot may be in the form of nanoparticles, nanotubes, nanowires, nanofibers, nanoplate particles, etc.

As a size of a quantum dot is adjusted or an elemental ratio in a quantum dot compound is adjusted, an energy band gap may be controlled accordingly, so that light of various wavelength ranges may be provided by a quantum dot emission layer. Therefore, by using quantum dots as described above (for example, using different sizes of quantum dots or having different elemental ratios in a quantum dot compound), a light emitting element that emits light in various wavelengths may be implemented. For example, a size of the quantum dot or an elemental ratio of a quantum dot compound may be adjusted to emit red light, green light, and/or blue light. For example, quantum dots may be configured to emit white light by combining various colors of light.

In the light emitting elements ED according to embodiments as shown in each of FIGS. 3 to 6, the electron transport region ETR may be provided on the emission layer EML. The electron transport region ETR may include at least one of a hole blocking layer HBL, an electron transport layer ETL, and an electron injection layer EIL, but embodiments are not limited thereto.

The electron transport region ETR may have a structure consisting of a layer consisting of a single material, a structure consisting of a layer including different materials, or a structure including multiple layers including different materials.

For example, the electron transport region ETR may have a single layer structure of an electron injection layer EIL or an electron transport layer ETL, or may have a single-layered structure formed of an electron injection material and an electron transport material. In embodiments, the electron transport region ETR may have a single-layered structure formed of different materials, or may have a structure in which an electron transport layer ETL/electron injection layer EIL, or a hole blocking layer HBL/electron transport layer ETL/electron injection layer EIL are stacked in its respective stated order from the emission layer EML, but embodiments are not limited thereto. The electron transport region ETR may have a thickness, for example, in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the electron transport region ETR may include a compound represented by Formula ET-2:

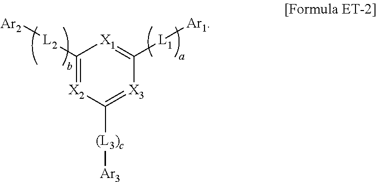

In Formula ET-2, at least one of X₁ to X₃ may each be N; and the remainder of X₁ to X₃ may each independently be C(Ra). In Formula ET-2, Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-2, Ar to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer from 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are each 2 or more, multiple groups of each of L₁ to L₃ may each independently be a substituted or unsubstituted arylene group having 6 to 30 ring-forming carbon atoms or a substituted or unsubstituted heteroarylene group having 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tri s(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butyiphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), or a mixture thereof.

In an embodiment, the electron transport region ETR may include at least one compound selected from Compound ET1 to Compound ET36:

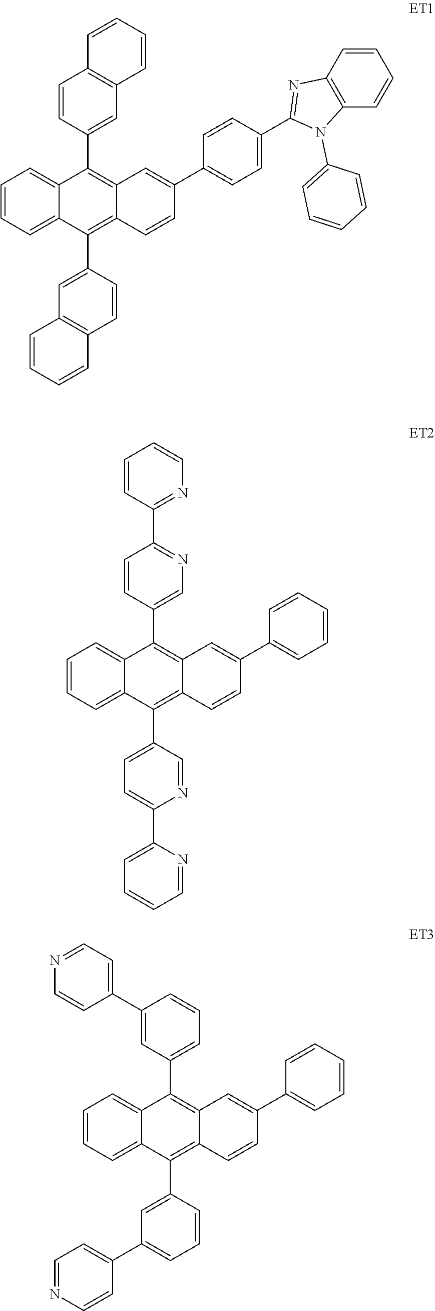 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

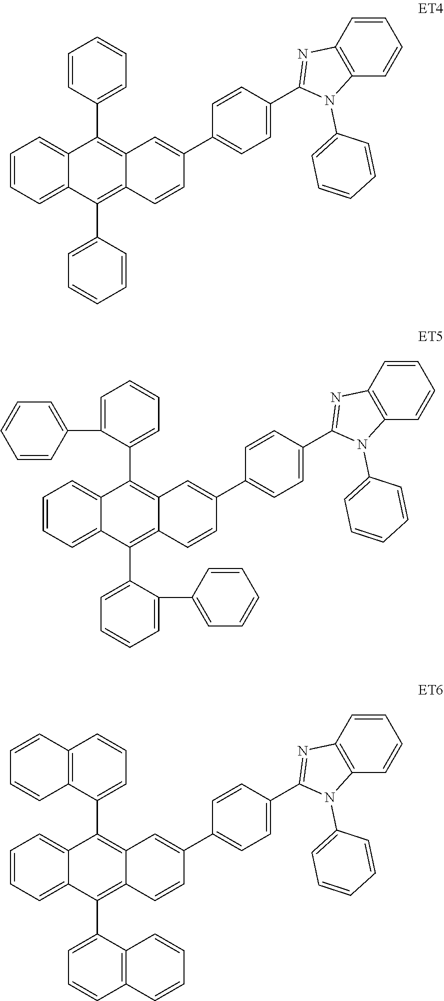 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

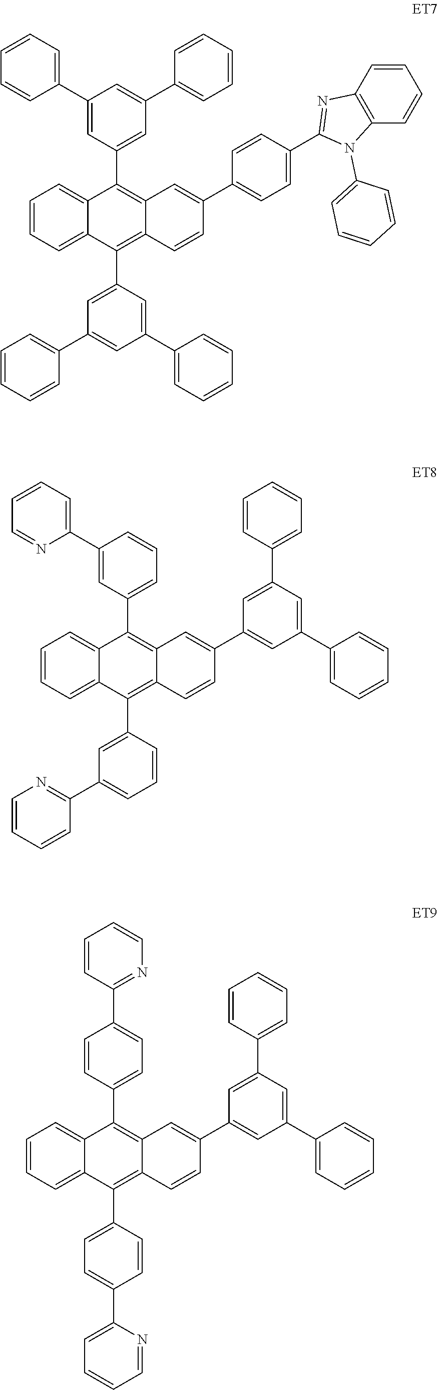 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

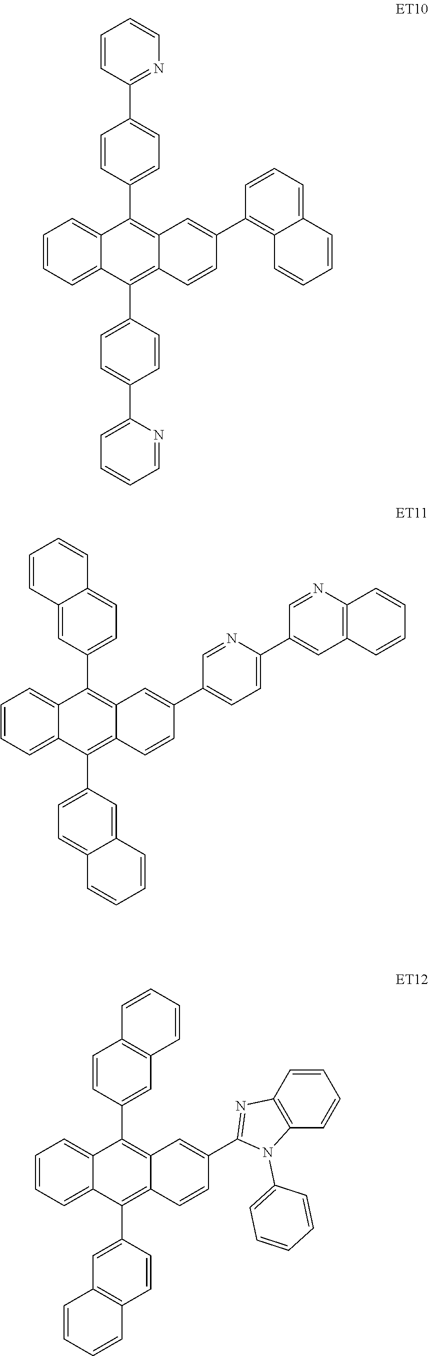 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

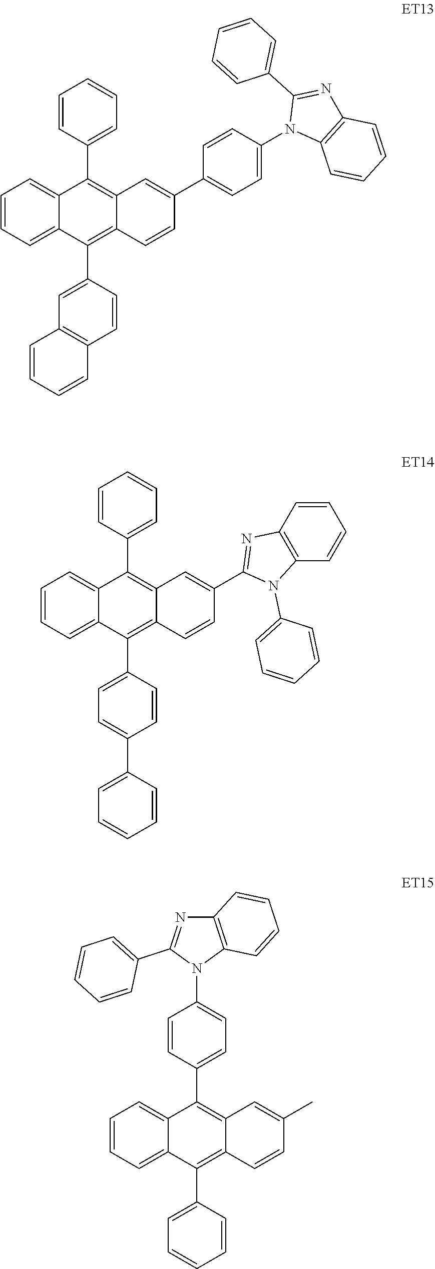 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

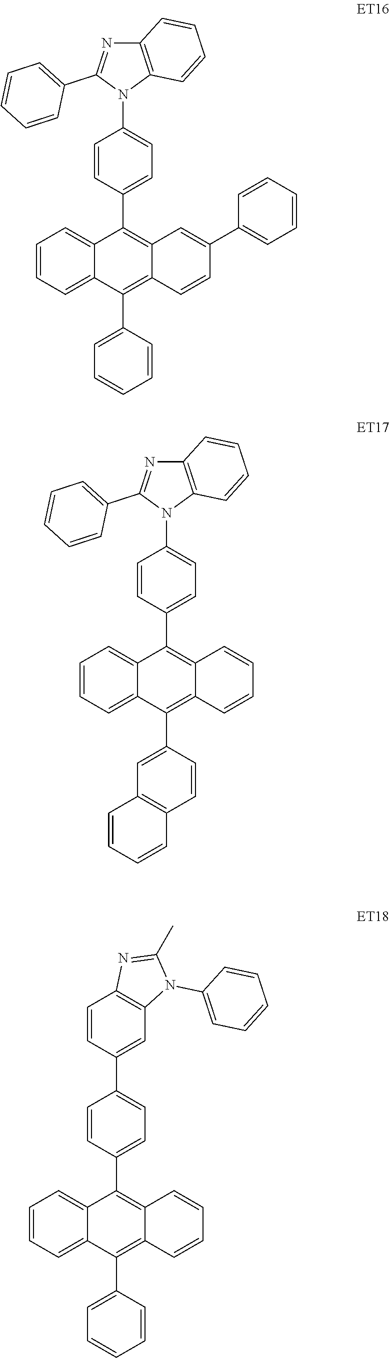 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

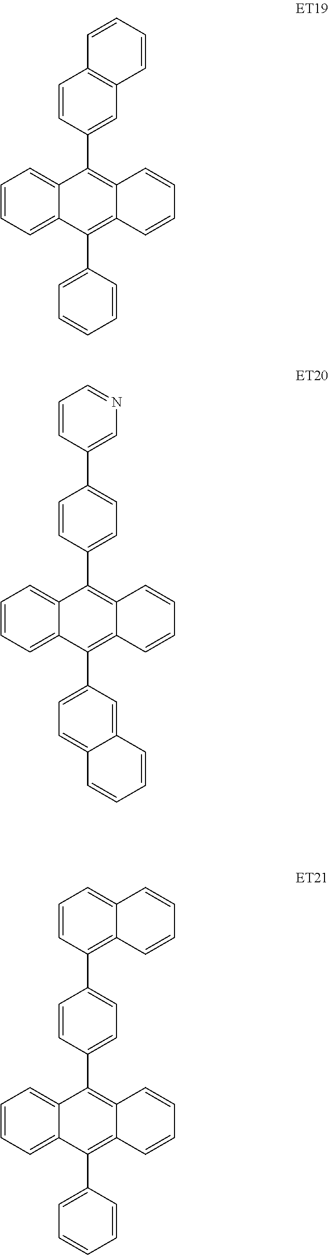

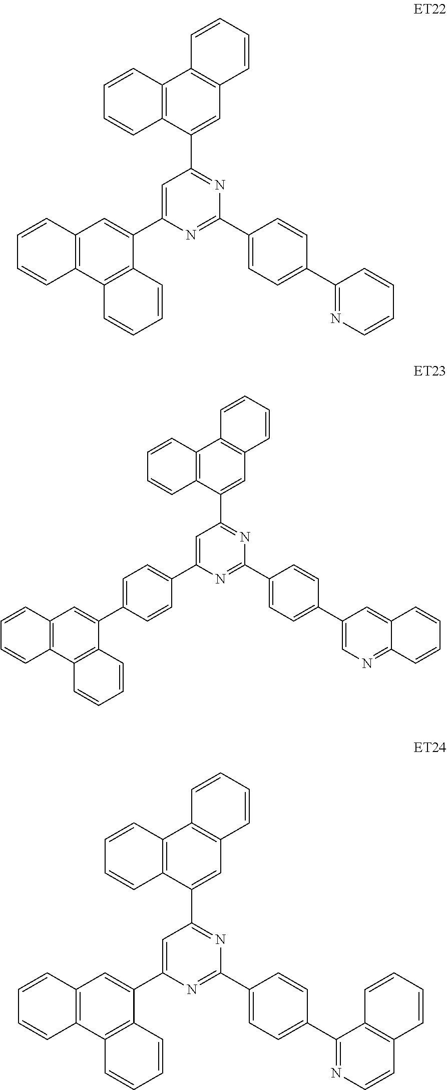 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

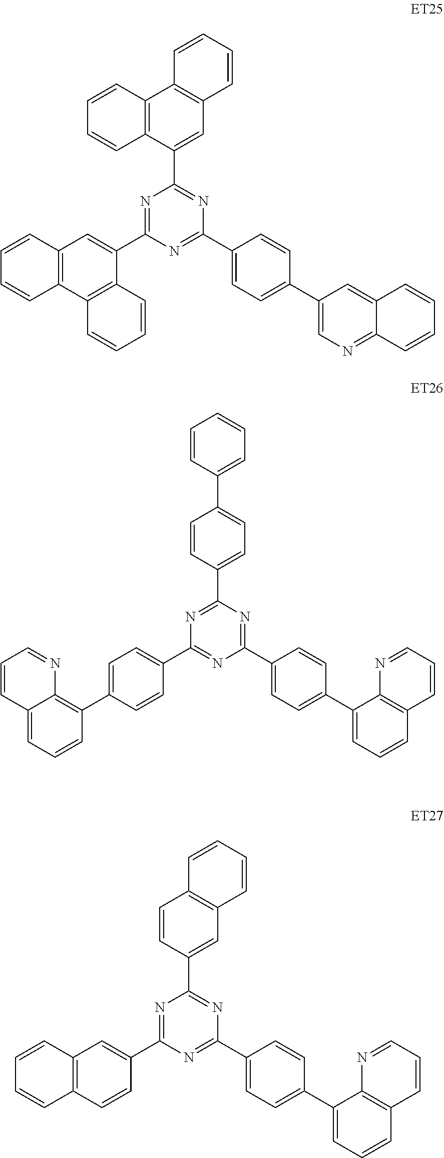 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

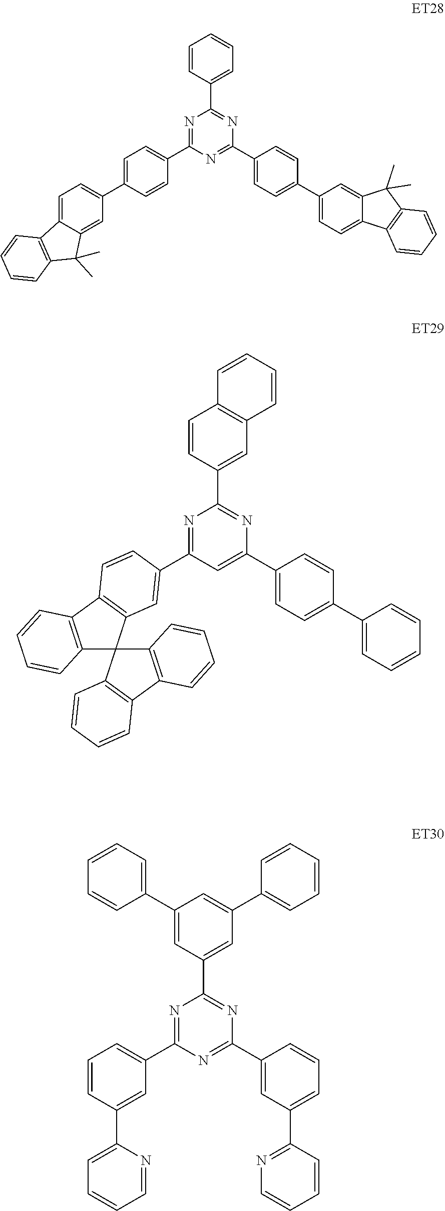 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

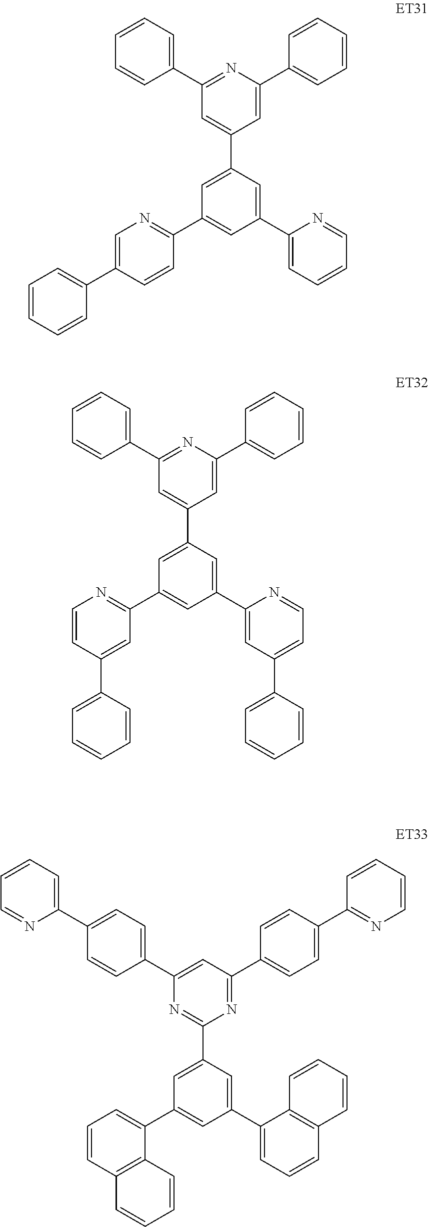 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

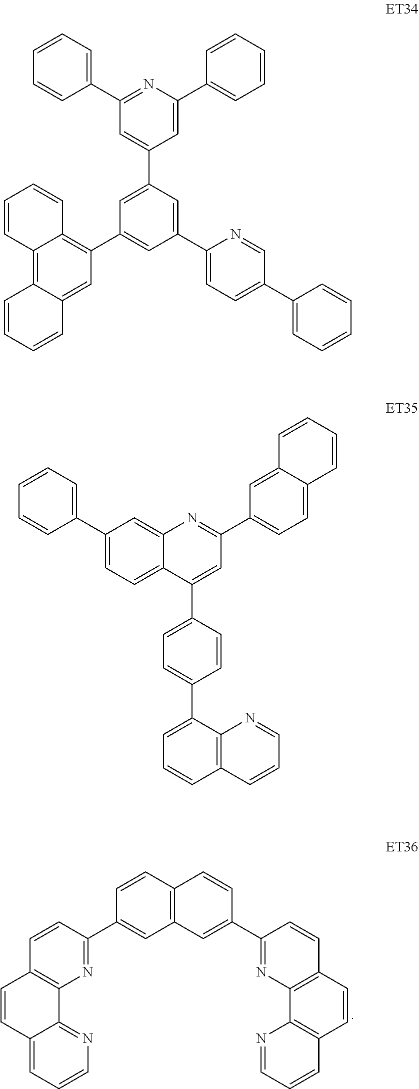 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In an embodiment, the electron transport region ETR may include: a metal halide such as LiF, NaCl, CsF, RbCl, RbI, CuI, and KI; a lanthanide such as Yb; or a co-deposited material of a metal halide and a lanthanide. For example, the electron transport region ETR may include KJ:Yb, RbJ:Yb, LiF:Yb, etc., as a co-deposited material. The electron transport region ETR may include a metal oxide such as Li₂O or BaO, or 8-hydroxyl-lithium quinolate (Liq), etc., but embodiments are not limited thereto. The electron transport region ETR may also be formed of a mixture of an electron transport material and an insulating organometallic salt. The organometallic salt may be a material having an energy band gap equal to or greater than about 4 eV. For example, the organometallic salt may include a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), and 4,7-diphenyl-1,10-phenanthroline (Bphen) in addition to the above-described materials, but embodiments are not limited thereto.

The electron transport region ETR may include the above-described compounds of the electron transport region in at least one of an electron injection layer EIL, an electron transport layer ETL, and a hole blocking layer HBL.

When the electron transport region ETR includes an electron transport layer ETL, the electron transport layer ETL may have a thickness in a range of about 100 Å to about 1,000 Å. For example, the electron transport layer ETL may have a thickness in a range of about 150 Å to about 500 Å. If the thickness of the electron transport layer ETL satisfies the aforementioned range, satisfactory electron transport characteristics may be obtained without a substantial increase in driving voltage. When the electron transport region ETR includes an electron injection layer EIL, the electron injection layer EIL may have a thickness in a range of about 1 Å to about 100 Å. For example, the electron injection layer EIL may have a thickness in a range of about 3 Å to about 90 Å. If the thickness of the electron injection layer EIL satisfies the above-described range, satisfactory electron injection characteristics may be obtained without a substantial increase in driving voltage.

The second electrode EL2 may be provided on the electron transport region ETR. The second electrode EL2 may be a common electrode. The second electrode EL2 may be a cathode or an anode, but embodiments are not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgYb).

In an embodiment, the second electrode EL2 may have a multilayer structure including a reflective film or a transflective film formed of the above-described materials, and a transparent conductive film formed of ITO, IZO, ZnO, ITZO, etc. For example, the second electrode EL2 may include the above-described metal materials, combinations of at least two of the above-described metal materials, oxides of the above-described metal materials, or the like.

Although not shown in the drawings, the second electrode EL2 may be electrically connected to an auxiliary electrode. If the second electrode EL2 is electrically connected to an auxiliary electrode, resistance of the second electrode EL2 may decrease.

In an embodiment, the light emitting element ED may further include a capping layer CPL disposed on the second electrode EL2. The capping layer CPL may have a multilayered structure or a single-layered structure.

In an embodiment, the capping layer CPL may include an organic layer or an inorganic layer. For example, when the capping layer CPL contains an inorganic material, the inorganic material may include an alkaline metal compound (e.g., LiF), an alkaline earth metal compound (e.g., MgF₂), SiON, SiNₓ, SiO_{y}, etc.

For example, when the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., or may include an epoxy resin, or an acrylate such as methacrylate. However, embodiments are not limited thereto, and the capping layer CPL may include at least one of Compounds P1 to P5:

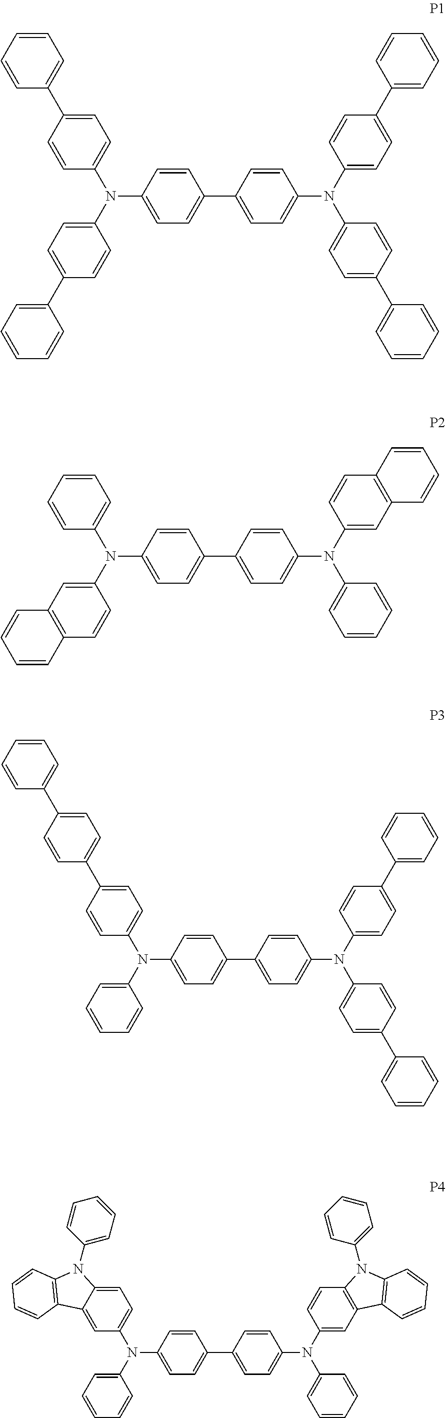 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

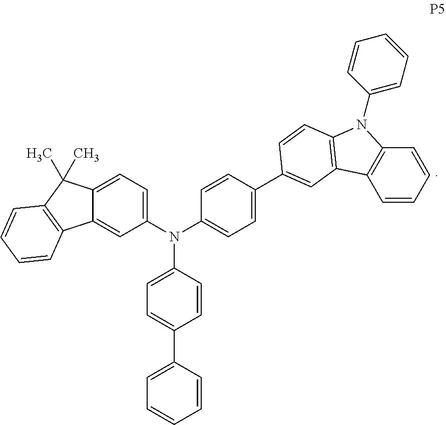 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be equal to or greater than about 1.6. For example, the refractive index of the capping layer CPL may be equal to or greater than about 1.6, with respect to light in a wavelength range of about 550 nm to about 660 nm.

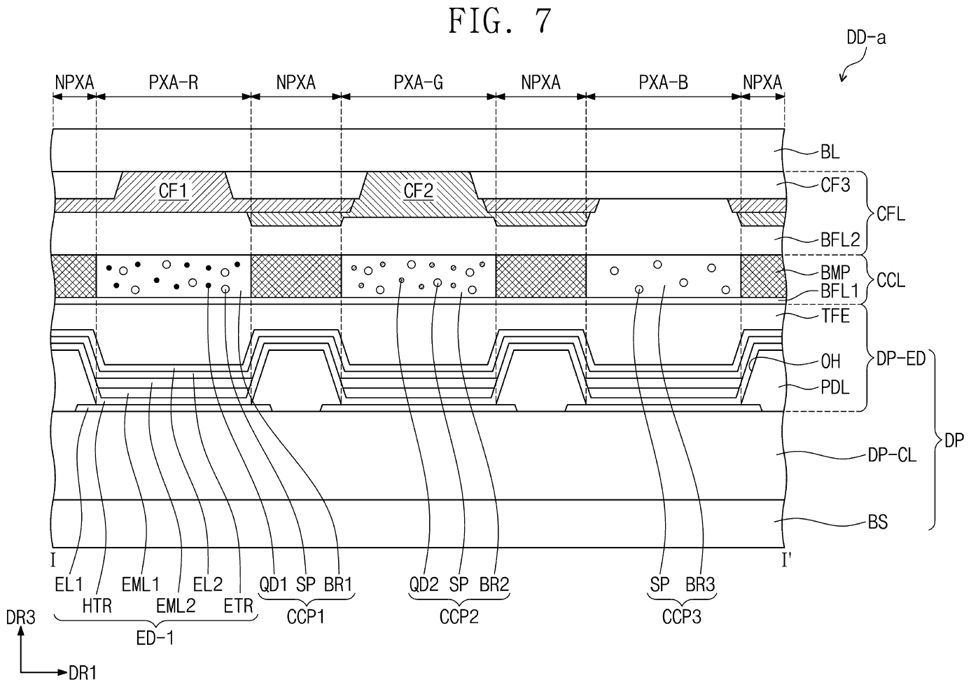

FIGS. 7 to 10 are each a schematic cross-sectional view of a display device according to an embodiment. In the descriptions of the display devices according to embodiments as shown in FIGS. 7 to 10, the features which have been described above with respect to FIGS. 1 to 6 will not be described again, and the differing features will be explained.

Referring to FIG. 7, the display device DD-a according to an embodiment may include a display panel DP including a display device layer DP-ED, a light control layer CCL disposed on the display panel DP, and a color filter layer CFL. In an embodiment shown in FIG. 7, the display panel DP may include a base layer BS, a circuit layer DP-CL provided on the base layer BS, and the display device layer DP-ED, and the display device layer DP-ED may include a light emitting element ED.

The light emitting element ED may include a first electrode EL1, a hole transport region HTR disposed on the first electrode EL1, a first emission layer EML1 disposed on the hole transport region HTR, a second emission layer EML2 disposed on the first emission layer EML1, an electron transport region ETR disposed on the second emission layer EML2, and a second electrode EL2 disposed on the electron transport region ETR. In embodiments, a structure of the light emitting element ED shown in FIG. 7 may be the same as a structure of a light emitting element according to one of FIGS. 3 to 6 as described above.

The first emission layer EML1 of the light emitting element ED-1 included in the display device DD according to an embodiment may include the (1-1)-th compound as described above, and the second emission layer EML2 may include the (2-1)-th compound as described above.

Referring to FIG. 7, the first emission layer EML1 and the second emission layer EML2 may be disposed as a stacked structure in an opening OH defined in a pixel defining film PDL.

For example, the first emission layer EML1 and the second emission layer EML2, which are each divided by the pixel defining film PDL and provided to correspond to each of the light emitting regions PXA-R, PXA-G, and PXA-B, may emit light in a same wavelength range. In the display device DD-a, the first emission layer EML1 and the second emission layer EML2 may each emit blue light. Although not shown in the drawings, in an embodiment, the first emission layer EML1 and the second emission layer EML2 may each be provided as a common layer for all of the light emitting regions PXA-R, PXA-G, and PXA-B.

The light control layer CCL may be disposed on the display panel DP. The light control layer CCL may include a light conversion body. The light conversion body may be a quantum dot, a phosphor, or the like. The light conversion body may convert the wavelength of a provided light and emit the resulting light. For example, the light control layer CCL may be a layer that includes a quantum dot or a layer that includes a phosphor.

The light control layer CCL may include light control parts CCP1, CCP2, and CCP3. The light control parts CCP1, CCP2, and CCP3 may be spaced apart from each other.

Referring to FIG. 7, divided patterns BMP may be disposed between the light control parts CCP1, CCP2, and CCP3, which are spaced apart from each other, but embodiments are not limited thereto. In FIG. 7, it is shown that the divided patterns BMP do not overlap the light control parts CCP1, CCP2, and CCP3, but the edges of the light control parts CCP1, CCP2, and CCP3 may overlap at least a portion of the divided patterns BMP.

The light control layer CCL may include a first light control part CCP1 containing a first quantum dot QD1 that converts first color light provided from the light emitting element ED into second color light, a second light control part CCP2 containing a second quantum dot QD2 that converts the first color light into third color light, and a third light control part CCP3 that transmits the first color light.

In an embodiment, the first light control part CCP1 may provide red light, which is the second color light, and the second light control part CCP2 may provide green light, which is the third color light. The third light control part CCP3 may provide blue light by transmitting the blue light that is the first color light provided from the light emitting element ED. For example, the first quantum dot QD1 may be a red quantum dot, and the second quantum dot QD2 may be a green quantum dot. The quantum dots QD1 and QD2 may each be a quantum dot as described above.

The light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include any quantum dot but may include the scatterer SP.

The scatterer SP may be inorganic particles. For example, the scatterer SP may include at least one of TiO₂, ZnO, A12O₃, SiO₂, and hollow silica. The scatterer SP may include one of TiO₂, ZnO, A12O₃, SiO₂, and hollow silica, or may be a mixture of at least two materials selected from TiO₂, ZnO, A12O₃, SiO₂, and hollow silica.

The first light control part CCP1, the second light control part CCP2, and the third light control part CCP3 may include base resins BR1, BR2, and BR3, in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may include various resin compositions, which may be referred to as a binder. For example, the base resins BR1, BR2, and BR3 may be acrylic-based resins, urethane-based resins, silicone-based resins, epoxy-based resins, etc. The base resins BR1, BR2, and BR3 may each be a transparent resin. In an embodiment, the first base resin BR1, the second base resin BR2, and the third base resin BR3 may be the same as or different from each other.

The light control layer CCL may include a barrier layer BFL1. The barrier layer BFL1 may prevent the penetration of moisture and/or oxygen (hereinafter, referred to as ‘moisture/oxygen’). The barrier layer BFL1 may block the light control parts CCP1, CCP2, and CCP3 from exposure to moisture/oxygen. The barrier layer BFL1 may cover the light control parts CCP1, CCP2, and CCP3. In an embodiment, the barrier layer BFL2 may be provided between the light control parts CCP1, CCP2, and CCP3, and the color filter layer CFL.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film that secures light transmittance, etc. The barrier layers BFL1 and BFL2 may each independently further include an organic film. The barrier layers BFL1 and BFL2 may be formed of a single layer or of multiple layers.

In the display device DD-a, the color filter layer CFL may be disposed on the light control layer CCL. In an embodiment, the color filter layer CFL may be directly disposed on the light control layer CCL. For example, the barrier layer BFL2 may be omitted.

The color filter layer CFL may include color CF1, CF2, and CF3. The color filter layer CFL may include a first filter CF1 that transmits second color light, a second filter CF2 that transmits third color light, and a third filter CF3 that transmits first color light. For example, the first filter CF1 may be a red filter, the second filter CF2 may be a green filter, and the third filter CF3 may be a blue filter. The filters CF1, CF2, and CF3 may each include a polymeric photosensitive resin and a pigment or dye. The first filter CF1 may include a red pigment or dye, the second filter CF2 may include a green pigment or dye, and the third filter CF3 may include a blue pigment or dye.

However, embodiments are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be provided as separate filters and may be provided as a unitary filter.

Although not shown in the drawings, in an embodiment, the color filter layer CFL may further include a light shielding part (not shown). The light shielding part (not shown) may be a black matrix. The light shielding part (not shown) may include an organic light shielding material or an inorganic light shielding material, each including a black pigment or a black dye. The light shielding part (not shown) may prevent light leakage, and may separate boundaries between adjacent filters CF1, CF2, and CF3.

The first filter CF1, the second filter CF2, and the third filter CF3 may be disposed to respectively correspond to the red light emitting region PXA-R, the green light emitting region PXA-G, and the blue light emitting region PXA-B.

A base substrate BL may be disposed on the color filter layer CFL. The base substrate BL may provide a base surface on which the color filter layer CFL, the light control layer CCL, and the like are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

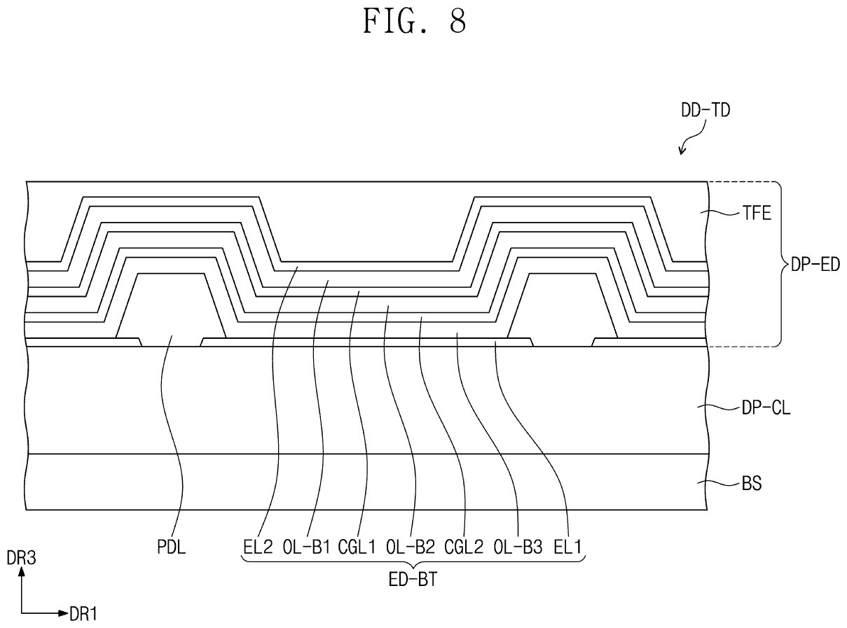

FIG. 8 is a schematic cross-sectional view of a portion of a display device according to an embodiment. In the display device DD-TD according to an embodiment, a light emitting element ED-BT may include light emitting structures OL-B1, OL-B2, and OL-B3. The light emitting element ED-BT may include a first electrode EL1 and a second electrode EL2 that face each other, and light emitting structures OL-B1, OL-B2, and OL-B3 stacked in a thickness direction between the first electrode EL1 and the second electrode EL2. The light emitting structures OL-B1, OL-B2, and OL-B3 may each include a hole transport region HTR, the first and second emission layers EML1 and EML2 (see FIG. 7), and an electron transport region ETR, which may be disposed in that order between the first electrode EL1 and the second electrode EL2.

Thus, the light emitting element ED-BT included in the display device DD-TD may be a light emitting element having a tandem structure that includes multiple first emission layers EML1 and multiple second emission layers EML2.

In an embodiment shown in FIG. 8, light emitted from the light emitting structures OL-B1, OL-B2, and OL-B3 may each be blue light. However, embodiments are not limited thereto, and the light emitted from each of the light emitting structures OL-B1, OL-B2, and OL-B3 may have wavelength ranges that are different from each other. For example, the light emitting element ED-BT that includes the light emitting structures OL-B1, OL-B2, and OL-B3, which emit light having wavelength ranges that are different from each other, may emit white light.

Charge generation layers CGL1 and CGL2 may each be disposed between two adjacent light emitting structures among the light emitting structures OL-B1, OL-B2, and OL-B3. Charge generation layers CGL1 and CGL2 may each independently include a p-type charge generation layer and/or an n-type charge generation layer.

The light emitting structures OL-B1, OL-B2, and OL-B3 included in the display device DD-TD may each include the first emission layer EML1 (see FIG. 7) that includes the (1-1)-th compound as described above, and the second emission layer EML2 (see FIG. 7) that includes the (2-1)-th compound as described above.

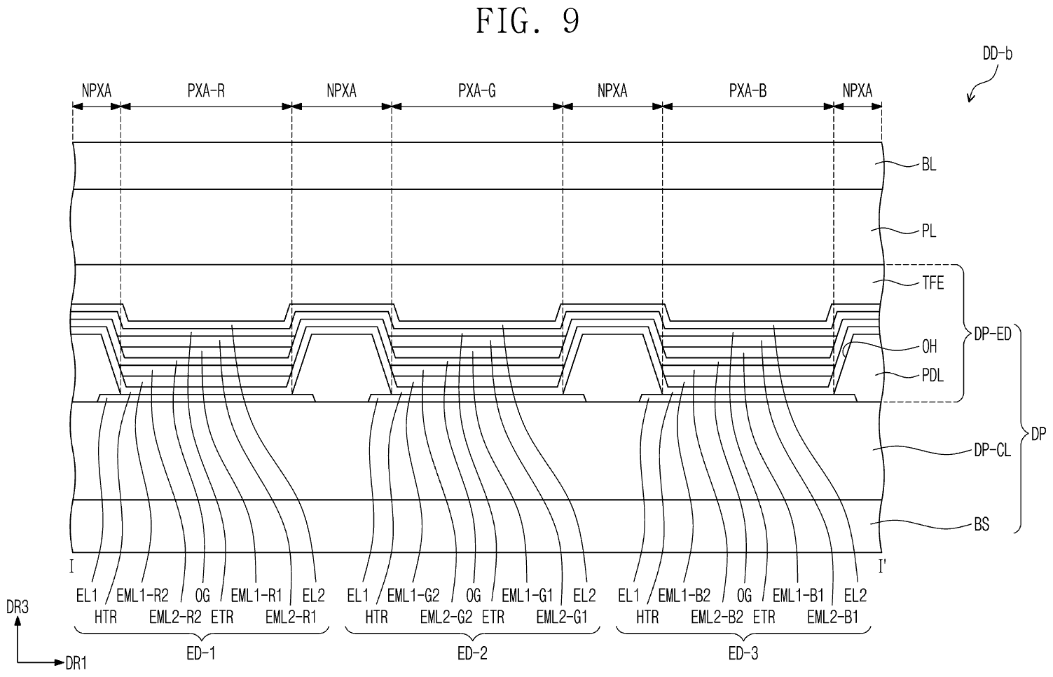

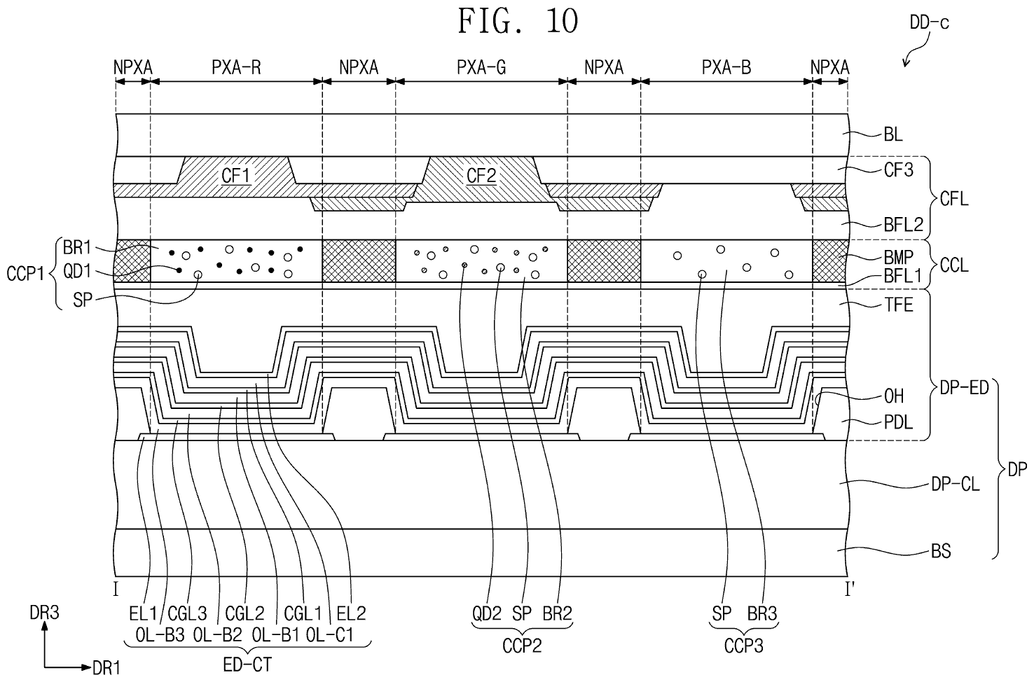

FIG. 9 is a schematic cross-sectional view of a display device DD-b according to an embodiment. FIG. 10 is a schematic cross-sectional view of a display device DD-c according to an embodiment.

Referring to FIG. 9, the display device DD-b according to an embodiment may include light emitting elements ED-1, ED-2, and ED-3 in which four emission layers are stacked. In comparison to the display device DD shown in FIG. 2, the embodiment shown in FIG. 9 is different at least in that in the first to third light emitting elements ED-1, ED-2, and ED-3 each include four emission layers that are stacked in a thickness direction. In each of the first to third light emitting elements ED-1, ED-2, and ED-3 of the display device DD-b, the four emission layers may emit light in a same wavelength region.

The first light emitting element ED-1 may include first red emission parts EML1-R₁ and EML2-R₁ having a structure in which two emission layers are stacked, and second red emission parts EML1-R₂ and EML2-R₂ having a structure in which two emission layers are stacked. The first red emission parts EML1-R₁ and EML2-R₁ may include a (1-1)-th red emission layer EML1-R₁ and a (2-1)-th red emission layer EML2-R₁. The second red emission parts EML1-R₂ and EML2-R₂ may include a (1-2)-th red emission layer EML1-R₂ and a (2-2)-th red emission layer EML2-R₂. An emission auxiliary part OG may be disposed between the first red emission parts EML1-R₁ and EML2-R₁ and the second red emission parts EML1-R₂ and EML2-R₂, which is between the (1-1)-th red emission layer EML1-R₁ and the (2-2)-th red emission layer EML2-R₂.

The second light emitting element ED-2 may include first green emission parts EML1-G1 and EML2-G1 having a structure in which two emission layers are stacked, and second green emission parts EML1-G2 and EML2-G2 having a structure in which two emission layers are stacked. The first green emission parts EML1-G1 and EML2-G1 may include a (1-1)-th green emission layer EML1-G1 and a (2-1)-th green emission layer EML2-G1. The second green emission parts EML1-G2 and EML2-G2 may include a (1-2)-th green emission layer EML1-G2 and a (2-2)-th green emission layer EML2-G2. An emission auxiliary part OG may be disposed between the first green emission parts EML1-G1 and EML2-G1 and the second green emission parts EML1-G2 and EML2-G2, which is between the (1-1)-th green emission layer EML1-G1 and the (2-2)-th green emission layer EML2-G2.

The third light emitting element ED-3 may include first blue emission parts EML1-B1 and EML2-B1 having a structure in which two emission layers are stacked, and second blue emission parts EML1-B2 and EML2-B2 having a structure in which two emission layers are stacked. The first blue emission parts EML1-B1 and EML2-B1 may include a (1-1)-th blue emission layer EML1-B1 and a (2-1)-th blue emission layer EML2-B1. The second blue emission parts EML1-B2 and EML2-B2 may include a (1-2)-th blue emission layer EML1-B2 and a (2-2)-th blue emission layer EML2-B2. An emission auxiliary part OG may be disposed between the first blue emission parts EML1-B1 and EML2-B1 and the second blue emission parts EML1-B2 and EML2-B2, which is between the (1-1)-th blue emission layer EML1-B1 and the (2-2)-th blue emission layer EML2-B2.

The emission auxiliary part OG may have a single-layered structure or a multilayered structure. The emission auxiliary part OG may include a charge generation layer. For example, the emission auxiliary part OG may include an electron transport region, a charge generation layer, and a hole transport region, which may be stacked in that order. The emission auxiliary part OG may be provided as a common layer for the first to third light emitting elements ED-1, ED-2, and ED-3. However, embodiments are not limited thereto, and the emission auxiliary part OG may be provided by being patterned within the openings OH defined in the pixel defining film PDL.

The first red emission parts EML1-R₁ and EML2-R₁, the first green emission parts EML1-G1 and EML2-G1, and the first blue emission parts EML1-B1 and EML2-B1 may be disposed between the emission auxiliary part OG and the electron transport region ETR. The second red emission parts EML1-R₂ and EML2-R₂, the second green emission parts EML1-G2 and EML2-G2, and the second blue emission parts EML1-B2 and EML2-B2 may be disposed between the hole transport region HTR and the emission auxiliary part OG.

The first light emitting element ED-1 may include the first electrode EL1, the hole transport region HTR, the second red emission parts EML1-R₂ and EML2-R₂, the emission auxiliary part OG, the first red emission parts EML1-R₁ and EML2-R₁, the electron transport region ETR, and the second electrode EL2, which are stacked in that order. The second light emitting element ED-2 may include the first electrode EL1, the hole transport region HTR, the second green emission parts EML1-G2 and EML2-G2, the emission auxiliary part OG, the first green emission parts EML1-G1 and EML2-G1, the electron transport region ETR, and the second electrode EL2, which are stacked in that order. The third light emitting element ED-3 may include the first electrode EL1, the hole transport region HTR, the second blue emission parts EML1-B2 and EML2-B2, the emission auxiliary part OG, the first blue emission parts EML1-B1 and EML2-B1, the electron transport region ETR, and the second electrode EL2, which are stacked in that order.

An optical auxiliary layer PL may be disposed on the display element layer DP-ED. The optical auxiliary layer PL may include a polarizing layer. The optical auxiliary layer PL may be disposed on the display panel DP and may control light that is reflected at the display panel DP from an external light. Although not shown in the drawings, in an embodiment, the optical auxiliary layer PL may be omitted from the display device DD-b.

The (1-1)-th red emission layer EML1-R₁, the (1-2)-th red emission layer EML1-R₂, the (1-1)-th green emission layer EML1-G1, the (1-2)-th green emission layer EML1-G2, the (1-1)-th blue emission layer EML1-B2, and the (1-2)-th blue emission layer EML1-B2 included in the display device DD-b shown in FIG. 9 may each correspond to the first emission layer EML1 (see FIG. 7) as described above. At least one of the (1-1)-th red emission layer EML1-R₁, the (1-2)-th red emission layer EML1-R₂, the (1-1)-th green emission layer EML1-G1, the (1-2)-th green emission layer EML1-G2, the (1-1)-th blue emission layer EML1-B1, and the (1-2)-th blue emission layer EML1-B2 may each independently include the (1-1)-th compound according to an embodiment as described above. In an embodiment, at least one of the (1-1)-th blue emission layer EML1-B1 and the (1-2)-th blue emission layer EML1-B2 may each independently include the (1-1)-th compound.

The (2-1)-th red emission layer EML2-R1, the (2-2)-th red emission layer EML2-R2, the (2-1)-th green emission layer EML2-G1, the (2-2)-th green emission layer EML2-G2, the (2-1)-th blue emission layer EML2-B2, and the (2-2)-th blue emission layer EML2-B2 included in the display device DD-b shown in FIG. 9 may each correspond to the second emission layer EML2 (see FIG. 7) as described above. At least one of the (2-1)-th red emission layer EML2-R1, the (2-2)-th red emission layer EML2-R2, the (2-1)-th green emission layer EML2-G1, the (2-2)-th green emission layer EML2-G2, the (2-1)-th blue emission layer EML2-B1, and the (2-2)-th blue emission layer EML2-B2 may each independently include the (2-1)-th compound according to an embodiment as described above. In an embodiment, at least one of the (2-1)-th blue emission layer EML2-B1 and the (2-2)-th blue emission layer EML2-B2 may each independently include the (2-1)-th compound.

In contrast to FIGS. 8 and 9, FIG. 10 shows a display device DD-c that is different at least in that it includes four light emitting structures OL-B1, OL-B2, OL-B3, and OL-C1. A light emitting element ED-CT may include a first electrode EL1 and a second electrode EL2 that face each other, and first to fourth light emitting structures OL-B1, OL-B2, OL-B3, and OL-C1 that are stacked in a thickness direction between the first electrode EL1 and the second electrode EL2.

Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light having wavelength regions that are different from each other.

Charge generation layers CGL1, CGL2, and CGL3 may each be disposed between two adjacent light emitting structures among the first to fourth light emitting structures OL-B1, OL-B2, OL-B3, and OL-C1. Charge generation layers CGL1, CGL2, and CGL3 may each independently include a p-type charge generation layer and/or an n-type charge generation layer.

The light emitting structures OL-B1, OL-B2, OL-B3, and OL-C1 included in the display device DD-c may each include the first emission layer EML1 (see FIG. 7) that includes the (1-1)-th compound as described above, and the second emission layer EML2 (see FIG. 7) that includes the (2-1)-th compound as described above.

In an embodiment, an electronic apparatus may include a display device that includes multiple light emitting elements, and a control part that controls the display device. The electronic apparatus may be a device that is activated by an electrical signal. The electronic apparatus may include display devices according to various embodiments. Examples of an electronic apparatus may include large, medium-sized, and small electronic apparatuses, such as a television set, a monitor, a billboard, a personal computer, a laptop computer, a personal digital terminal, a display device for a vehicle, a game console, a portable electronic device, or a camera.

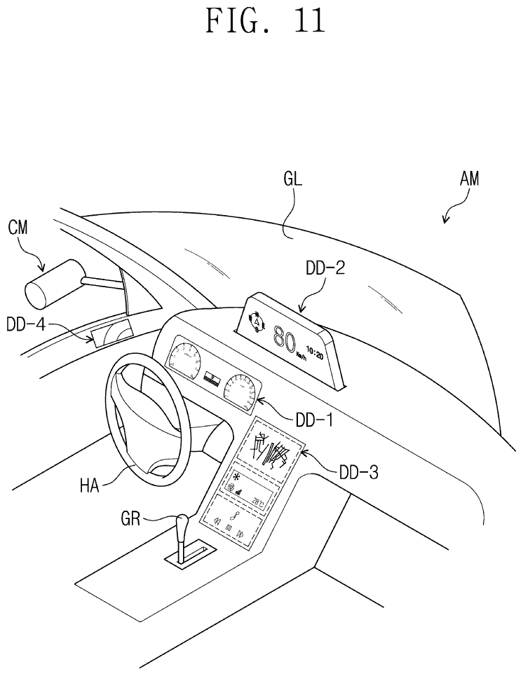

FIG. 11 is a schematic perspective view of a vehicle AM that includes first to fourth display devices DD-1, DD-2, DD-3, and DD-4. At least one of the first to fourth display devices DD-1, DD-2, DD-3, and DD-4 may each independently have a structure according to one of display devices DD, DD-TD, DD-a, DD-b, and DD-c, as described with reference to FIGS. 1, 2, and 7 to 10.

FIG. 11 illustrates a vehicle AM, but this is only an example, and the first to fourth display devices DD-1, DD-2, DD-3, and DD-4 may be disposed in various transportation means such as a bicycle, a motorcycle, a train, a ship, or an airplane. In an embodiment, at least one of the first to fourth display devices DD-1, DD-2, DD-3, and DD-4 having a structure according to one of display devices DD, DD-TD, DD-a, DD-b, and DD-c, may be included in a personal computer, a laptop computer, a personal digital terminal, a game console, a portable electronic device, a television, a monitor, a billboard, or the like. However, these are merely provided as examples, and the display device may be included in other electronic apparatuses.

At least one of the first to fourth display devices DD-1, DD-2, DD-3, and DD-4 may each independently include a light emitting element ED according to an embodiment as described with reference to any of FIGS. 3 to 6.

The light emitting element ED may include the first emission layer EML1 (see FIG. 7) that includes the (1-1)-th compound as described above, and the second emission layer EML2 (see FIG. 7) that includes the (2-1)-th compound as described above. At least one of the first to fourth display devices DD-1, DD-2, DD-3, and DD-4 may each independently include the light emitting element ED that includes the first emission layer EML1 (see FIG. 7) and the second emission layer EML2 (see FIG. 7), thereby exhibiting improved display service life.

Referring to FIG. 11, the vehicle AM may include a steering wheel HA and a gearshift GR for operating the vehicle AM. The vehicle AM may include a front window GL that is disposed so as to face the driver.

The first display device DD-1 may be disposed in a first region that overlaps the steering wheel HA. For example, the first display device DD-1 may be a digital cluster that displays first information of the vehicle AM. The first information may include a first scale that indicates a driving speed of the vehicle AM, a second scale that indicates an engine speed (for example, as revolutions per minute (RPM)), an image that represents a fuel gauge, etc. The first scale and the second scale may each be represented by a digital image.

The second display device DD-2 may be disposed in a second region facing the driver's seat that overlaps the front window GL. The driver's seat may be a seat where the steering wheel HA is disposed. For example, the second display device DD-2 may be a head up display (HUD) that shows second information of the vehicle AM. The second display device DD-2 may be optically transparent. The second information may include digital numbers that indicate a driving speed and may further include information such as the current time. Although not shown in the drawings, in an embodiment, the second information of the second display device DD-2 may be displayed by being projected onto the front window GL.

The third display device DD-3 may be disposed in a third region that is adjacent to the gearshift GR. For example, the third display device DD-3 may be disposed between the driver's seat and the passenger seat, and may be a center information display (CID) for the vehicle AM that displays third information. The passenger seat may be a seat that is spaced apart from the driver's seat, and the gearshift GR may be disposed between the driver's seat and the passenger seat. The third information may include information about traffic (e.g., navigation information), about music or radio that is playing, about a video (or an image) that is displayed, about temperatures inside the vehicle AM, etc.

The fourth display device DD-4 may be disposed in a fourth region that is spaced apart from the steering wheel HA and the gearshift GR and adjacent to a side of the vehicle AM. For example, the fourth display device DD-4 may be a digital side-view mirror that displays fourth information. The fourth display device DD-4 may display an image that is external to the vehicle AM, which may be taken by a camera module CM that is disposed on the exterior of the vehicle AM. The fourth information may include an exterior image of the vehicle AM.

The first to fourth information as described above are only provided as examples, and the first to fourth display devices DD-1, DD-2, DD-3, and DD-4 may further display information about the interior and exterior of the vehicle AM. The first to fourth information may include information that is different from each other. However, embodiments are not limited thereto, and a portion of the first to fourth information may include a same information.

Hereinafter, a light emitting element according to an embodiment will be described in detail with reference to the Examples and the Comparative Examples. The Examples described below are only provided to assist in understanding the disclosure, and the scope thereof is not limited thereto.

### 1. Manufacture of Light Emitting Element

A light emitting element that includes the (1-1)-th compound according to an embodiment in the first emission layer and the (2-1)-th compound according to an embodiment in the second emission layer was manufactured by the following method. The light emitting elements of Examples 1 to 15, which will be described below, were manufactured using Compounds A2, A17, A21, A31, and A33, which are the (1-1)-th compounds, as dopant materials for the first emission layer, and Compounds B4, B24, B26, B37, and B38, which are the (2-1)-th compounds, as dopant materials for the second emission layer. Comparative Examples 1 to 4 do not include the second emission layer in the structure of the light emitting element, Comparative Examples 5 to 7 correspond to a light emitting element that uses other materials without using the (1-1)-th compound as a dopant material for the first emission layer, Comparative Example 8 corresponds to a light emitting element that does not include the (2-1)-th compound as a dopant material for the second emission layer, and Comparative Examples 9 and 10 correspond to a light emitting element that does not include the (1-1)-th compound as a dopant material for the first emission layer and does not include the (2-1)-th compound as a dopant material for the second emission layer.

(1) Synthesis of (1-1)-th Compound

A synthesis method of the (1-1)-th compound according to an embodiment will be described in detail by explaining synthesis methods for Compounds A2, A17, A21, A31, and A33. In the following descriptions, the synthesis method of the (1-1)-th compound is only provided as an example, and the synthesis method of the (1-1)-th compound is not limited to the Examples below.

### 1) Synthesis of Compound A2

### (Synthesis of Intermediate A2-a)

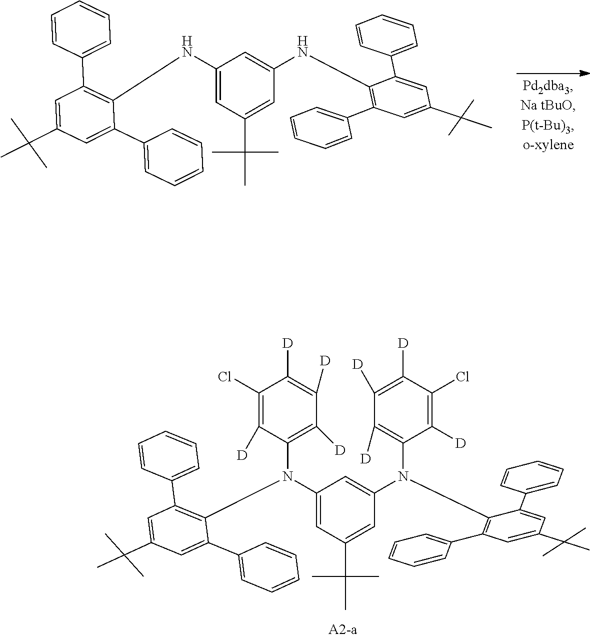

In an argon atmosphere, to a 2-L flask, 5-(tert-butyl)-N1,N3-bis(5′-(tert-butyl)-[1,1′:3′,1″-terphenyl]-2′-yl)benzene-1,3-diamine (10 g, 13.5 mmol), 1-chloro-3-iodobenzene-2,4,5,6-d4 (6.5 g, 27 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and the reaction solution was stirred at about 140° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂C12 and hexane as eluent to obtain Intermediate Compound 2-a (white solid, 9.2 g, yield: 70%).

ESI-LCMS: [M]⁺: C66H54D8C12N2. 960.4814.

### (Synthesis of Intermediate Compound A2-b)

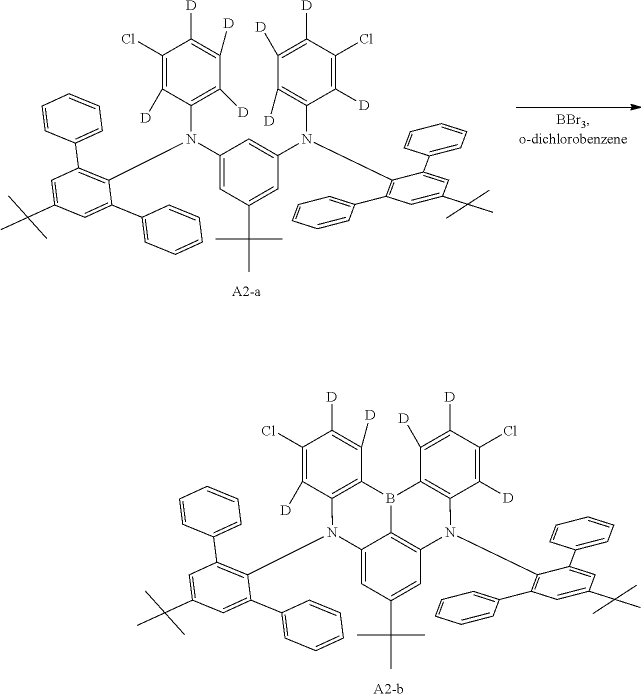

In an argon atmosphere, to a 1-L flask, Intermediate Compound 2-a (9 g, 9.3 mmol) was added and dissolved in 100 mL of o-dichlorobenzene, and BBr₃ (1.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography using CH₂C12 and hexane as eluent to obtain Intermediate Compound 2-b (yellow solid, 2.3 g, yield: 25%).

ESI-LCMS: [M]⁺: C66H53D6BCl2N2. 966.4205

### (Synthesis of Compound A2)

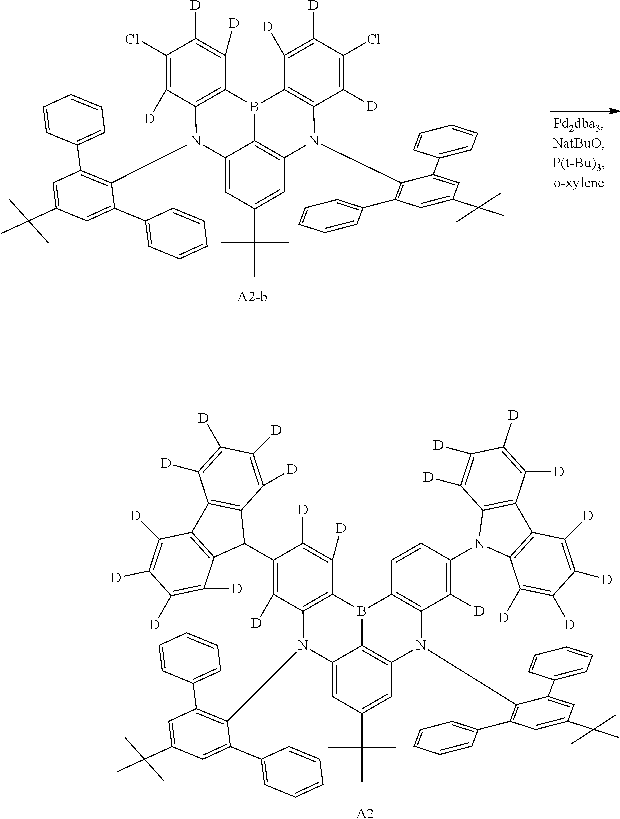

In an argon atmosphere, to a 1-L flask, Intermediate Compound 2-b (2 g, 2 mmol), 9H-carbazole-1,2,3,4,5,6,7,8-d8 (0.72 g, 4 mmol), Pd₂dba₃ (0.06 g, 0.12 mmol), tris-tert-butyl phosphine (0.06 mL, 0.24 mmol), and sodium tert-butoxide (0.5 g, 5.1 mmol) were added and dissolved in 100 mL of xylene, and the reaction solution was stirred at about 140° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂C12 and hexane as eluent to obtain Compound 2 (yellow solid, 2 g, yield: 80%).

ESI-LCMS: [M]⁺: C90H53D22BN4. 1244.7715

### 2) Synthesis of Compound A17

### (Synthesis of Intermediate A17-a)

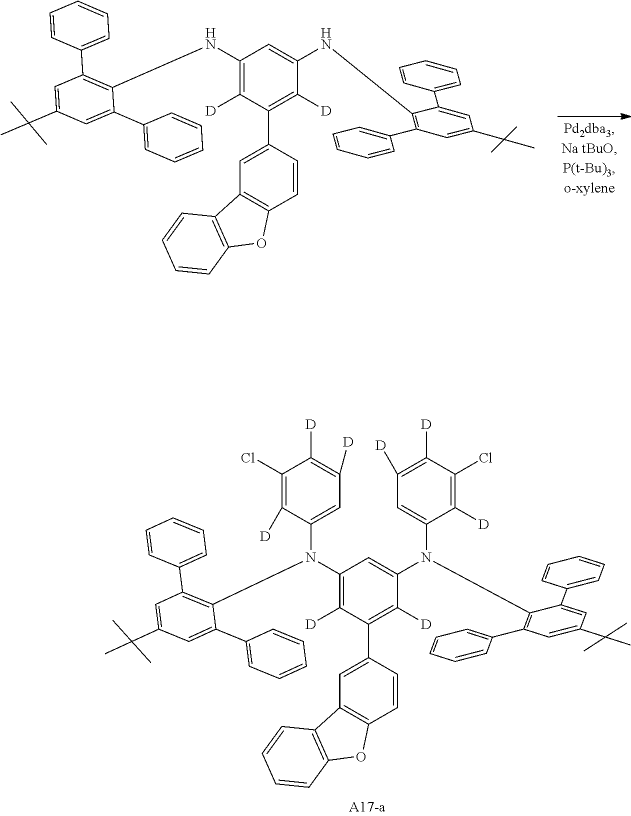

In an argon atmosphere, to a 2-L flask, N1,N3-bis(5′-(tert-butyl)-[1,1′:3′,1″-terphenyl]-2′-yl)-5-(dibenzo[b,d]furan-2-yl)benzene-4,6-d2-1,3-diamine (10 g, 12 mmol), 1-chloro-3-iodobenzene-2,4,5,6-d4 (6.5 g, 27 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and the reaction solution was stirred at about 140° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂C12 and hexane as eluent to obtain Intermediate Compound A17-a (white solid, 9.1 g, yield: 72%).

ESI-LCMS: [M]⁺: C74H50D10C12N2O. 1072.4743

### (Synthesis of Intermediate Compound A17-b)

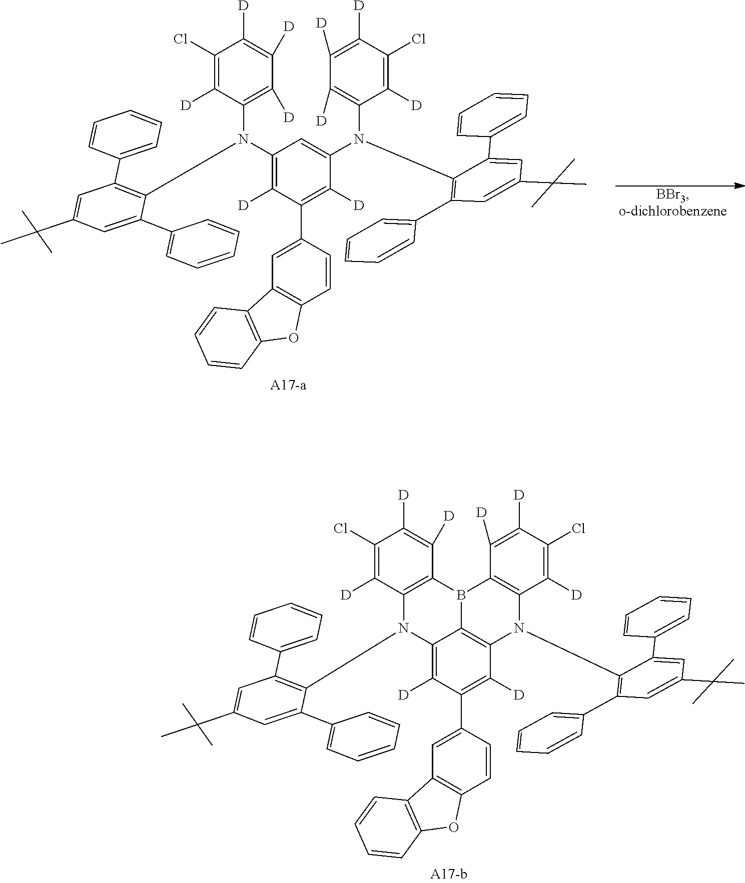

In an argon atmosphere, to a 1-L flask, Intermediate Compound A17-a (9 g, 8.4 mmol) was added and dissolved in 100 mL of o-dichlorobenzene, and BBr₃ (1.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography using CH₂C12 and hexane as eluent to obtain Intermediate Compound A17-b (yellow solid, 2.9 g, yield: 32%).

ESI-LCMS: [M]⁺: C74H49D8BCl2N2O. 1078.4417

### (Synthesis of Compound A17)

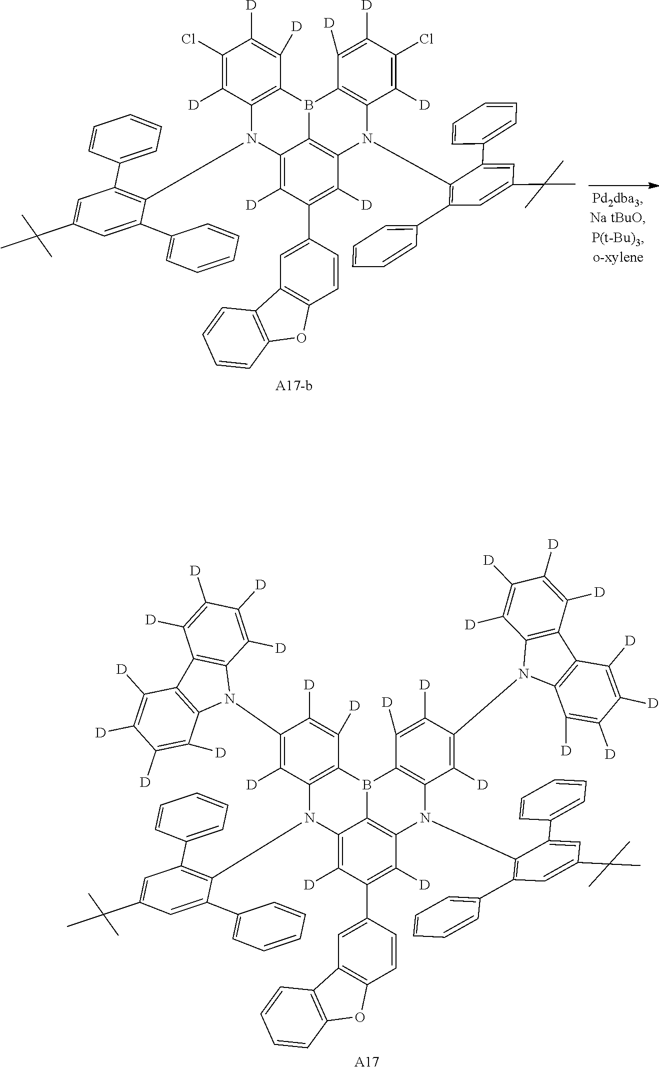

In an argon atmosphere, to a 1-L flask, Intermediate Compound A17-b (2 g, 1.9 mmol), 9H-carbazole-1,2,3,4,5,6,7,8-d8 (0.72 g, 4 mmol), Pd₂dba₃ (0.06 g, 0.12 mmol), tris-tert-butyl phosphine (0.06 mL, 0.24 mmol), and sodium tert-butoxide (0.5 g, 5.1 mmol) were added and dissolved in 100 mL of xylene, and the reaction solution was stirred at about 140° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂C12 and hexane as eluent to obtain Compound A17 (yellow solid, 1.7 g, yield: 68%).

ESI-LCMS: [M]⁺: C98H49D24BN40. 1356.7473

### 3) Synthesis of Compound A21

### (Synthesis of Intermediate A21-a)

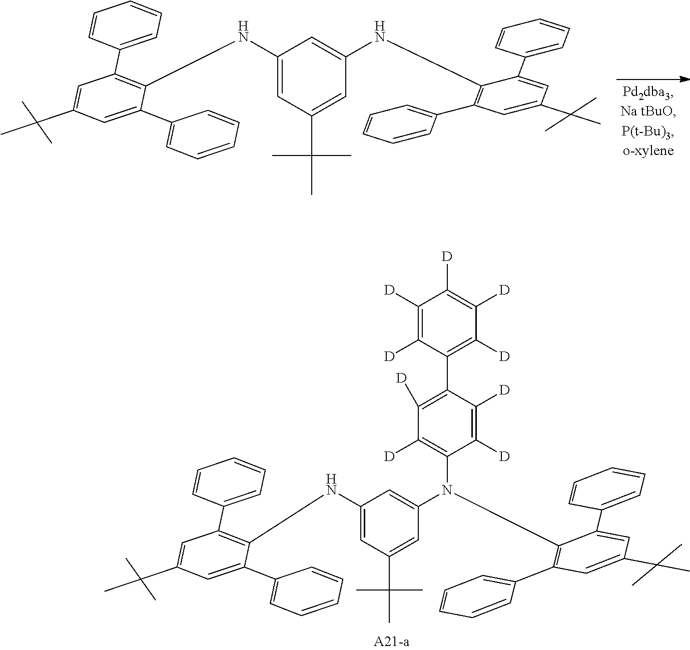

In an argon atmosphere, to a 2-L flask, N1,N3-bis(5′-(tert-butyl)-[1,1′:3′,1″-terphenyl]-2′-yl)-5-(dibenzo[b,d]furan-2-yl)benzene-4,6-d2-1,3-diamine (10 g, 12 mmol), 4-iodo-1,1′-biphenyl-2,2′,3,3′,4′,5,5′,6,6′-d9 (3.5 g, 12 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and the reaction solution was stirred at about 140° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂C12 and hexane as eluent to obtain Intermediate Compound A21-a (white solid, 6 g, yield: 56%).

ESI-LCMS: [M]⁺: C66H55D9N2. 894.3165

### (Synthesis of Intermediate Compound A21-b)

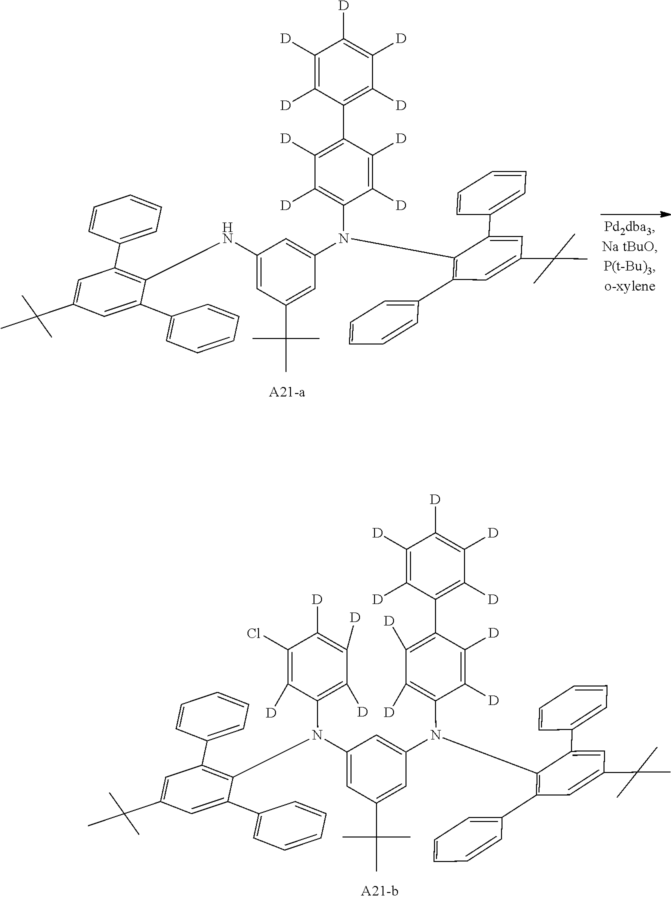

In an argon atmosphere, to a 2-L flask, Intermediate Compound A21-a (6 g, 6.7 mmol), 1-chloro-3-iodobenzene-2,4,5,6-d4 (1.7 g, 6.7 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and the reaction solution was stirred at about 140° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂C12 and hexane as eluent to obtain Intermediate Compound A21-b (white solid, 4.6 g, yield: 68%).

ESI-LCMS: [M]⁺: C72H54D13C1N2. 1008.8756

### (Synthesis of Intermediate Compound A21-c)

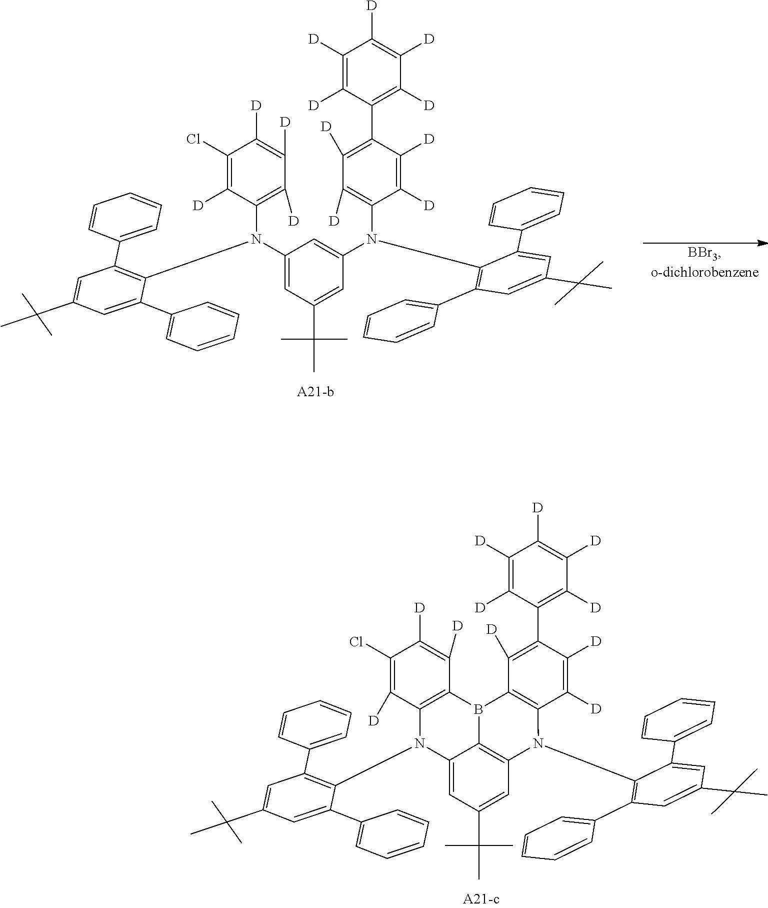

In an argon atmosphere, to a 1-L flask, Intermediate Compound A21-b (4.6 g, 4.5 mmol) was added and dissolved in 100 mL of o-dichlorobenzene, and BBr₃ (1.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography using CH₂C12 and hexane as eluent to obtain Intermediate Compound A21-c (yellow solid, 1.2 g, yield: 26%).

ESI-LCMS: [M]⁺: C72H53D11BClN2. 1014.6531

### (Synthesis of Compound A21)

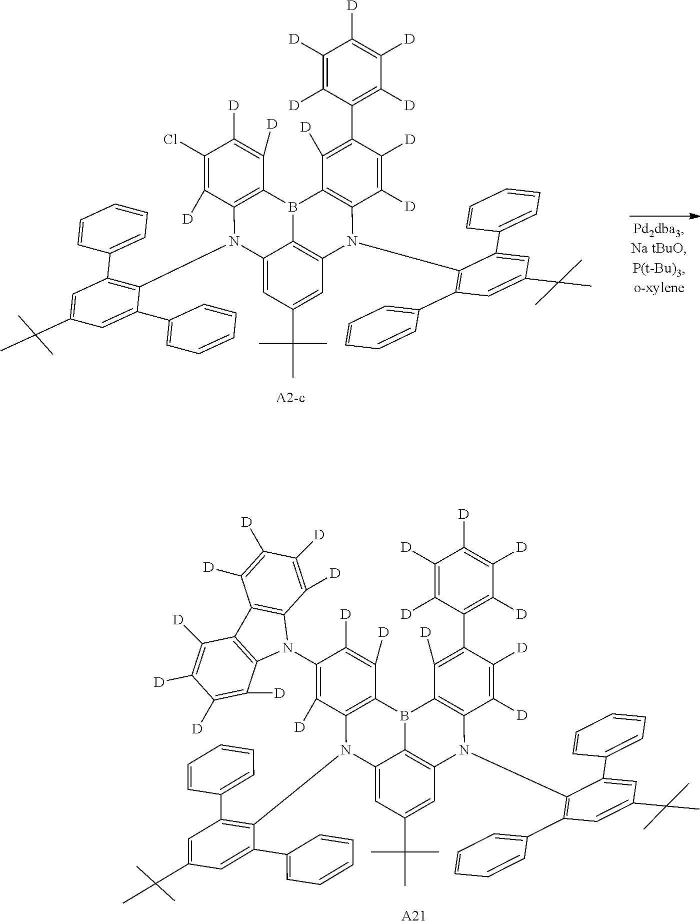

In an argon atmosphere, to a 1-L flask, Intermediate Compound A 21-c (1.2 g, 1.2 mmol), 9H-carbazole-1,2,3,4,5,6,7,8-d8 (0.22 g, 1.2 mmol), Pd₂dba₃ (0.06 g, 0.12 mmol), tris-tert-butyl phosphine (0.06 mL, 0.24 mmol), and sodium tert-butoxide (0.5 g, 5.1 mmol) were added and dissolved in 100 mL of xylene, and the reaction solution was stirred at about 140° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂C12 and hexane as eluent to obtain Compound A21 (yellow solid, 1 g, yield: 75%).

ESI-LCMS: [M]⁺: C84H53D19BN3. 1152.7002

### 4) Synthesis of Compound A31

### (Synthesis of Intermediate A31-a)

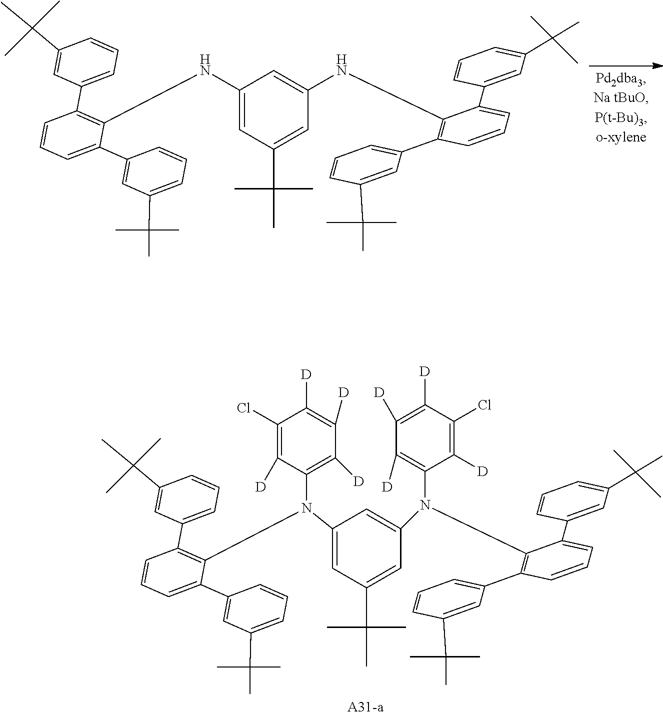

In an argon atmosphere, to a 2-L flask, 5-(tert-butyl)-N1,N3-bis(5′-(tert-butyl-[1,1′:3′,1″-terphenyl]-2′-yl)benzene-1,3-diamine (10 g, 12 mmol), 1-chloro-3-iodobenzene-2,4,5,6-d4 (3.5 g, 12 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and the reaction solution was stirred at about 140° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂C12 and hexane as eluent to obtain Intermediate Compound A31-a (white solid, 8.8 g, yield: 69%).

ESI-LCMS: [M]⁺: C74H70D8Cl2N2. 1072.6027

### (Synthesis of Intermediate Compound A31-b)

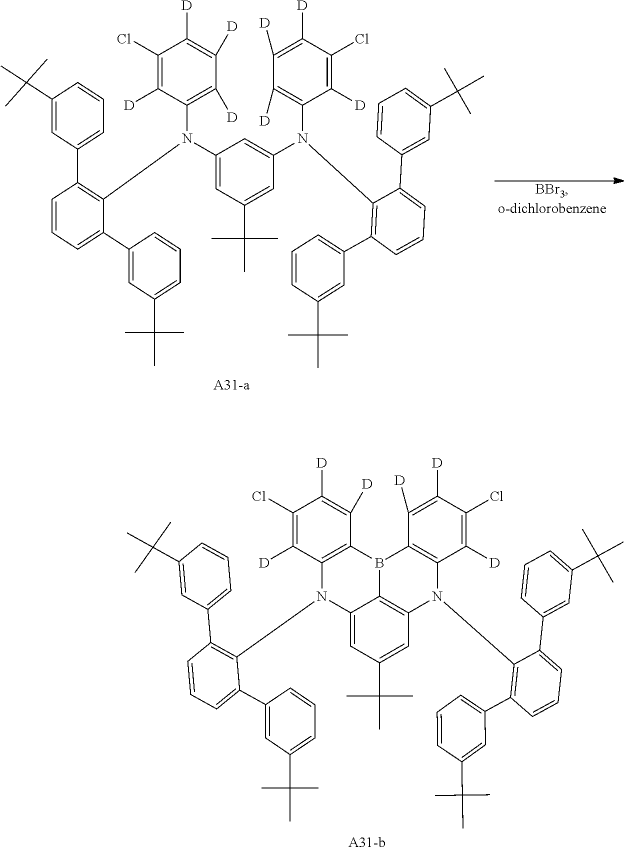

In an argon atmosphere, to a 1-L flask, Intermediate Compound A31-a (8.8 g, 8.2 mmol) was added and dissolved in 100 mL of o-dichlorobenzene, and BBr₃ (1.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography using CH₂Cl₂ and hexane as eluent to obtain Intermediate

ESI-LCMS: [M]⁺: C74H69D6BCl2N2. 1087.5812

### (Synthesis of Compound A31)

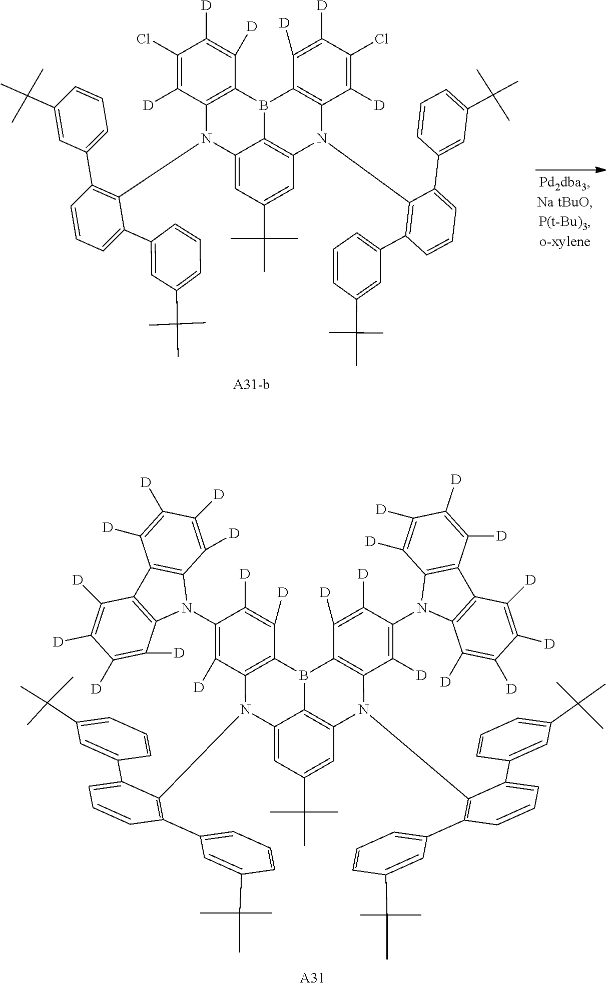

In an argon atmosphere, to a 1-L flask, Intermediate Compound A31-b (2.2 g, 2 mmol), 9H-carbazole-1,2,3,4,5,6,7,8-d8 (0.72 g, 4 mmol), Pd₂dba₃ (0.06 g, 0.12 mmol), tris-tert-butyl phosphine (0.06 mL, 0.24 mmol), and sodium tert-butoxide (0.5 g, 5.1 mmol) were added and dissolved in 100 mL of xylene, and the reaction solution was stirred at about 140° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂C12 and hexane as eluent to obtain Compound A31 (yellow solid, 2 g, yield: 77%).

ESI-LCMS: [M]⁺: C98H69D22BN4. 1356.8783

### 5) Synthesis of Compound A33

### (Synthesis of Intermediate A33-a)

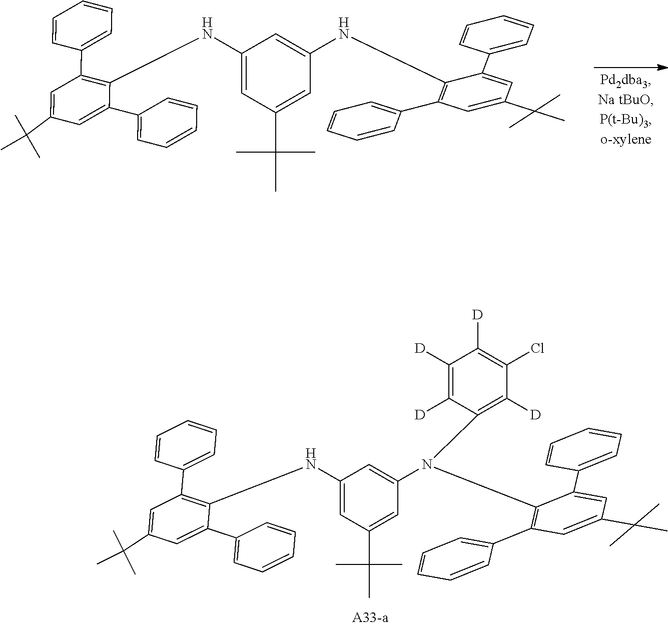

In an argon atmosphere, to a 2-L flask, 5-(tert-butyl)-N1,N3-bis(5′-(tert-butyl)-[1,1′:3′,1″-terphenyl]-2′-yl)benzene-1,3-diamine (10 g, 13.6 mmol), 1-chloro-3-iodobenzene-2,4,5,6-d4 (3.2 g, 13.6 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and the reaction solution was stirred at about 140° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂C12 and hexane as eluent to obtain Intermediate Compound A33-a (white solid, 6.7 g, yield: 58%).

ESI-LCMS: [M]⁺: C60H55D4ClN2. 846.4655

### (Synthesis of Intermediate Compound A33-b)

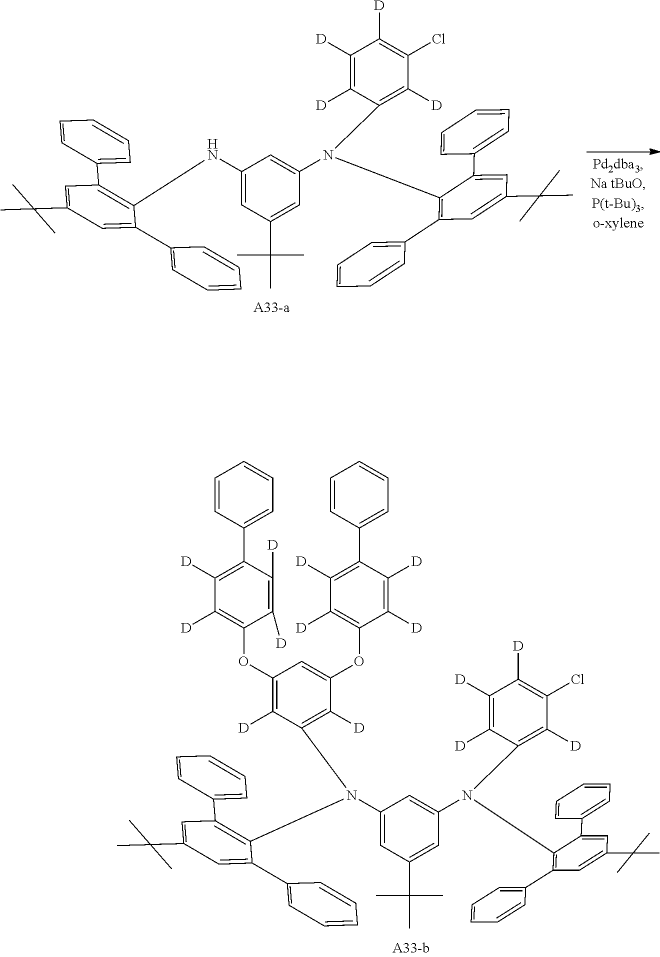

In an argon atmosphere, to a 2-L flask, Intermediate Compound A33-a (6.7 g, 7.9 mmol), 4,4″-((5-iodo-1,3-phenylene-4,6-d2)bis(oxy))bis((1,1′-biphenyl-2,3,5,6-d4)) (4.4 g, 7.9 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and the reaction solution was stirred at about 140° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate Compound A33-b (white solid, 7.2 g, yield: 72%).

ESI-LCMS: [M]⁺: C90H65D14ClN202. 1268.6746

### (Synthesis of Intermediate Compound A33-c)

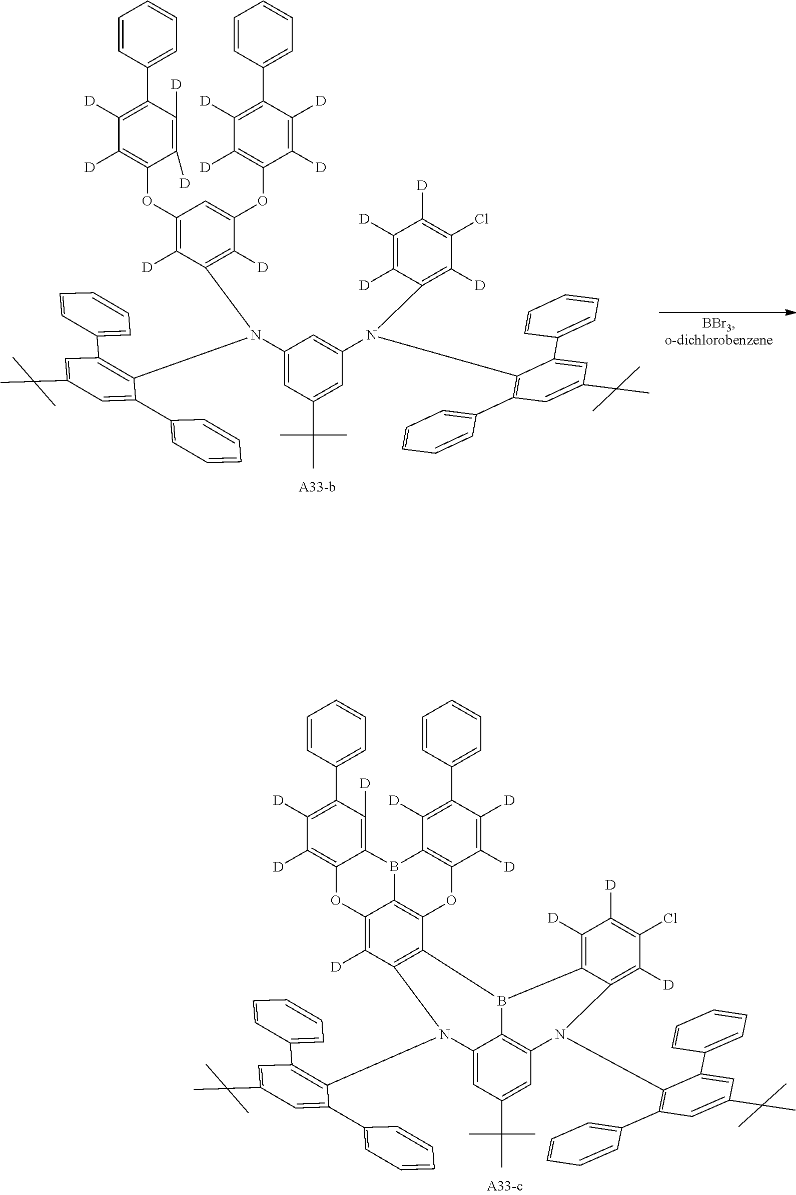

In an argon atmosphere, to a 1-L flask, Intermediate Compound A33-b (7.2 g, 5.6 mmol) was added and dissolved in 100 mL of o-dichlorobenzene, and BBr₃ (2.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography using CH₂C12 and hexane as eluent to obtain Intermediate Compound A33-c (yellow solid, 2.6 g, yield: 36%).

ESI-LCMS: [M]⁺: C90H63D10B2ClN202. 1280.6267

### (Synthesis of Compound A33)

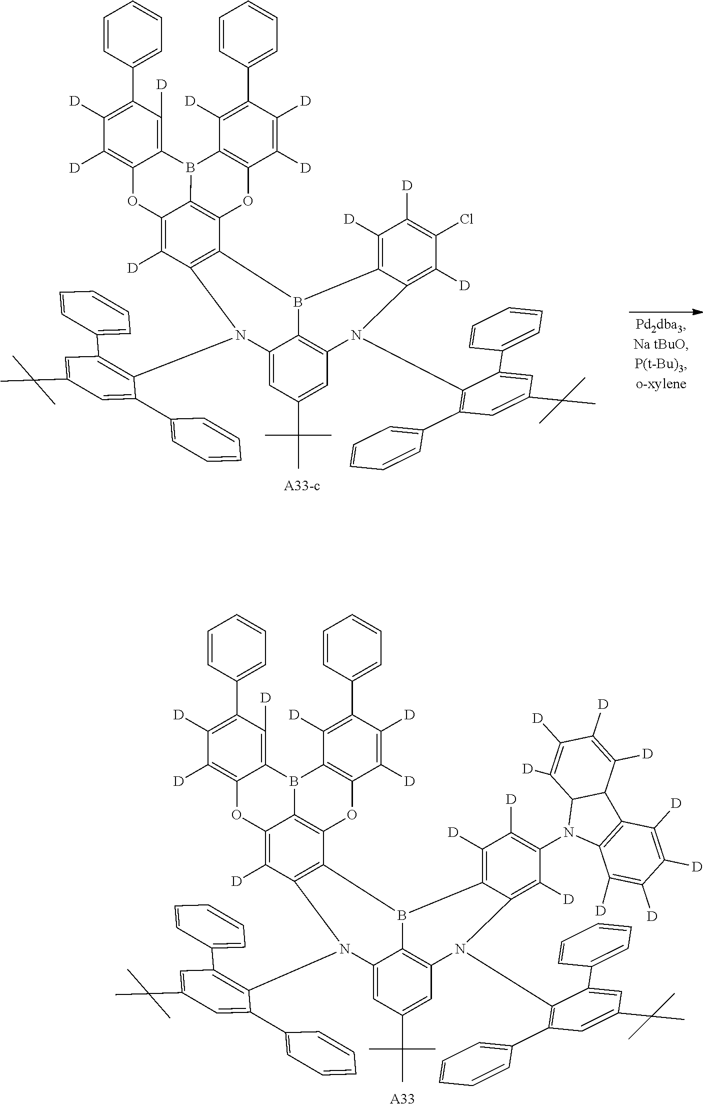

In an argon atmosphere, to a 1-L flask, Intermediate Compound A33-c (2 g, 1.5 mmol), 9H-carbazole-1,2,3,4,5,6,7,8-d8 (0.27 g, 1.5 mmol), Pd₂dba₃ (0.06 g, 0.12 mmol), tris-tert-butyl phosphine (0.06 mL, 0.24 mmol), and sodium tert-butoxide (0.5 g, 5.1 mmol) were added and dissolved in 100 mL of xylene, and the reaction solution was stirred at about 140° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂C12 and hexane as eluent to obtain Compound A33 (yellow solid, 1.6 g, yield: 77%).

ESI-LCMS: [M]⁺: C102H63D18B2N3O2. 1419.7611

(2) Synthesis of (2-1)-th Compound

A synthesis method of the (2-1)-th compound according to an embodiment will be described in detail by explaining synthesis methods for Compounds B4, B24, B26, B37, and B38. In the following descriptions, the synthesis method of the (2-1)-th compound is only provided as an example, and the synthesis method of the (2-1)-th compound is not limited to the Examples below.

### 1) Synthesis of Compound B4

### (Synthesis of Intermediate Compound B4-a)

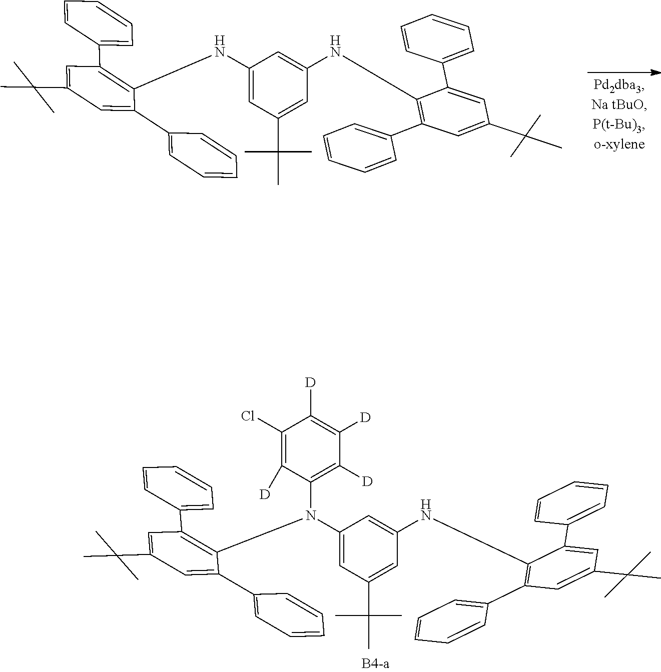

In an argon atmosphere, to a 2-L flask, 5-(tert-butyl)-N1,N3-bis(5′-(tert-butyl)-[1,1′:3′,1″-terphenyl]-2′-yl)benzene-1,3-diamine (10 g, 13.5 mmol), 1-chloro-3-iodobenzene-2,4,5,6-d4 (3.3 g, 13.5 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and the reaction solution was stirred at about 140° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂C12 and hexane as eluent to obtain Intermediate Compound 44-a (white solid, 8.3 g, yield: 73%).

ESI-LCMS: [M]⁺: C60H55D4ClN2. 846.4606.

### (Synthesis of Intermediate Compound B4-b)

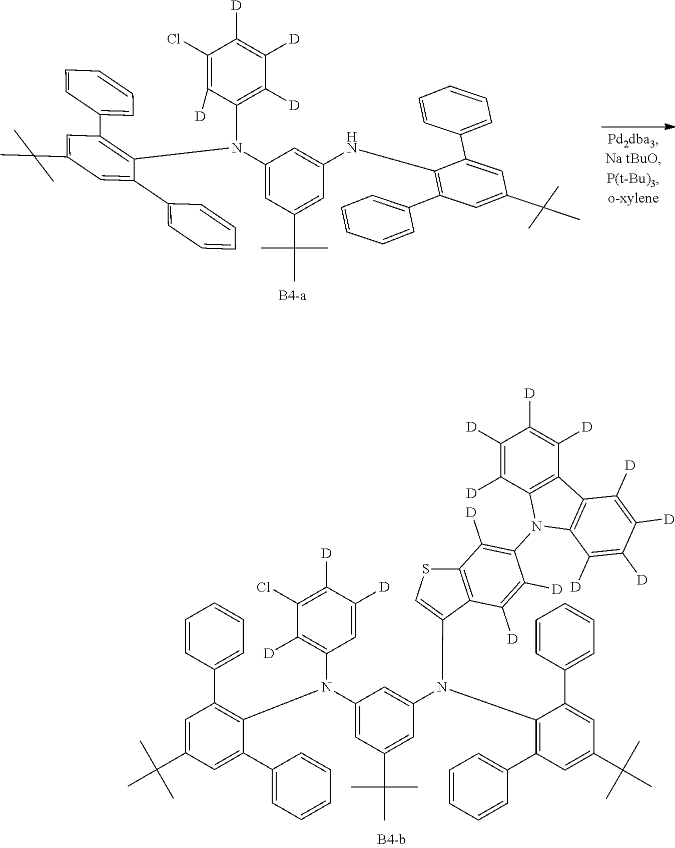

In an argon atmosphere, to a 2-L flask, Intermediate Compound 44-a (8 g, 9.5 mmol), 9-(3-bromobenzo[b]thiophen-6-yl-4,5,7-d3)-9H-carbazole-1,2,3,4,5,6,7,8-d8 (3.7 g, 9.5 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and the reaction solution was stirred at about 140° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂C12 and hexane as eluent to obtain Intermediate Compound 44-b (white solid, 8.4 g, yield: 77%).

ESI-LCMS: [M]⁺: C80H56D14ClN3S. 1153.5759.

### (Synthesis of Intermediate Compound B4-c)

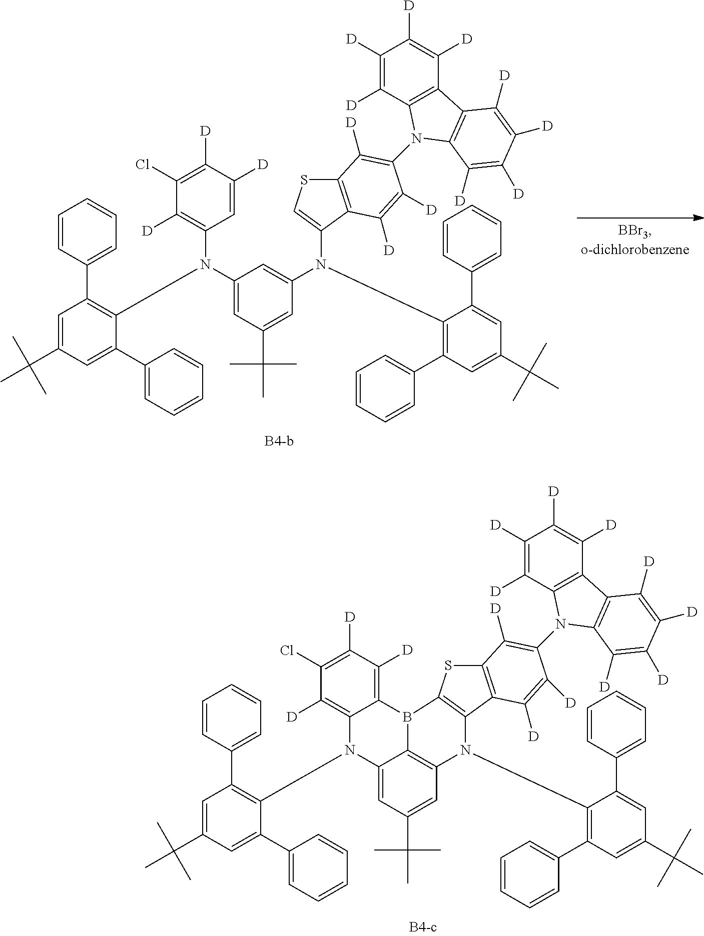

In an argon atmosphere, to a 1-L flask, Intermediate Compound 44-b (8.4 g, 7.3 mmol) was added and dissolved in 100 mL of o-dichlorobenzene, and BBr₃ (1.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography using CH₂C12 and hexane as eluent to obtain Intermediate Compound 44-c (yellow solid, 2 g, yield: 24%).

ESI-LCMS: [M]⁺: C80H53D14BClN3S. 1161.5117

### (Synthesis of Compound B4)

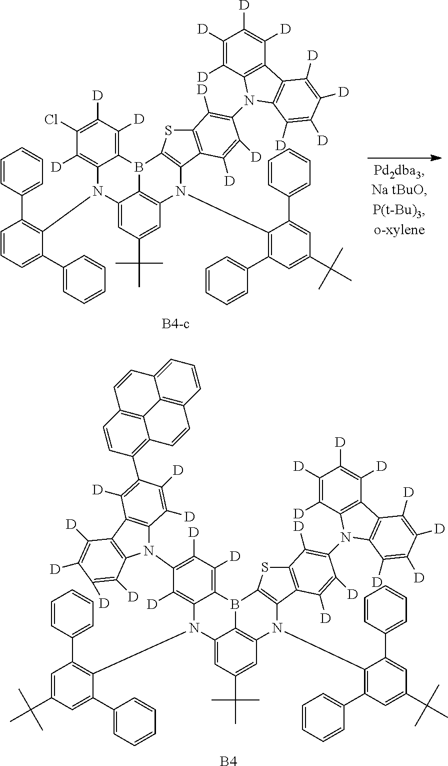

In an argon atmosphere, to a 1-L flask, Intermediate Compound 44-c (2 g, 1.2 mmol), 3-(pyren-1-yl)-9H-carbazole-1,2,4,5,6,7,8-d7 (0.64 g, 1.4 mmol), Pd₂dba₃ (0.06 g, 0.12 mmol), tris-tert-butyl phosphine (0.06 mL, 0.24 mmol), and sodium tert-butoxide (0.5 g, 5.1 mmol) were added and dissolved in 100 mL of xylene, and the reaction solution was stirred at about 140° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂C12 and hexane as eluent to obtain Compound 44 (yellow solid, 1.93 g, yield: 76%).

ESI-LCMS: [M]⁺: C108H62D21BN4S. 1499.7577

### 2) Synthesis of Compound B24

### (Synthesis of Intermediate B24-a)

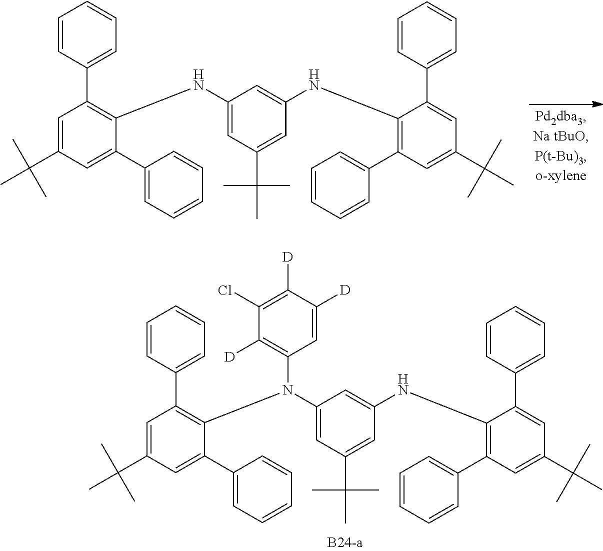

In an argon atmosphere, to a 2-L flask, 5-(tert-butyl)-N1,N3-bis(5′-(tert-butyl)-[1,1′:3′,1″-terphenyl]-2′-yl)benzene-1,3-diamine (10 g, 13.6 mmol), 1-chloro-3-iodobenzene-2,4,5,6-d4 (3.2 g, 13.6 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and the reaction solution was stirred at about 140° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂C12 and hexane as eluent to obtain Intermediate Compound B24-a (white solid, 6.7 g, yield: 58%).

ESI-LCMS: [M]⁺: C60H55D4ClN2. 846.4655

### (Synthesis of Intermediate Compound B24-b)

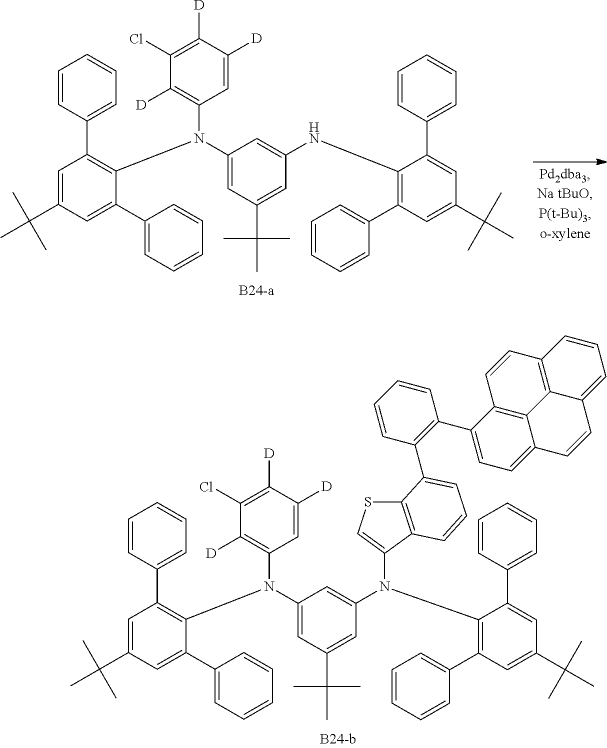

In an argon atmosphere, to a 2-L flask, Intermediate Compound B24-a (6.7 g, 7.9 mmol), 3-iodo-7-(2-(pyren-1-yl)phenyl)benzo[b]thiophene (4.2 g, 7.9 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and the reaction solution was stirred at about 140° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂C12 and hexane as eluent to obtain Intermediate Compound B24-b (white solid, 7.4 g, yield: 75%).

ESI-LCMS: [M]⁺: C90H72D3ClN2S. 1253.5546

### (Synthesis of Intermediate Compound B24-c)

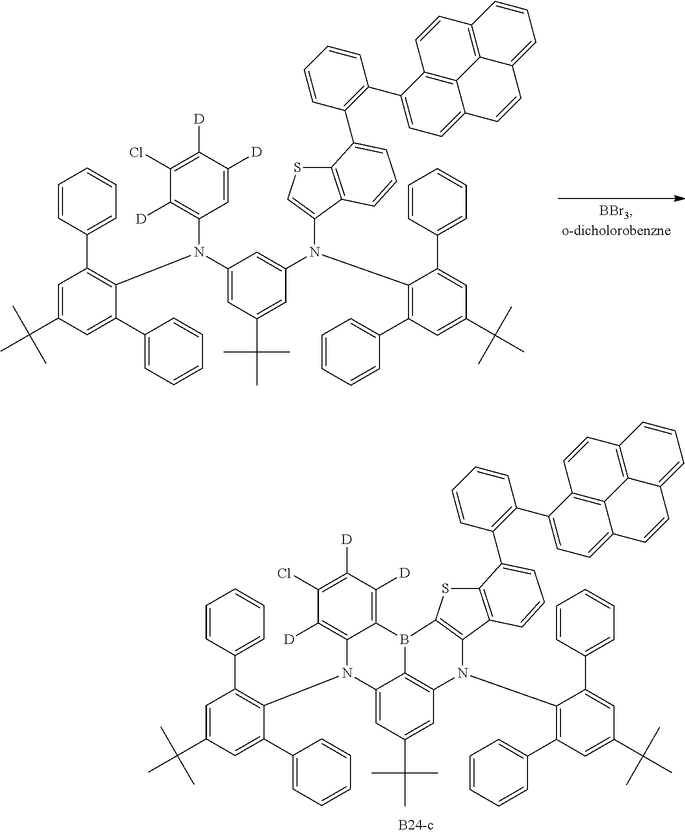 [SMILES: [2H]c1cc(N(c2cc(N(c3c(-c4ccccc4)cc(C(C)(C)C)cc3-c3ccccc3)c3csc4c(-c5ccccc5-c5ccc6ccc7cccc8ccc5c6c78)cccc34)cc(C(C)(C)C)c2)c2c(-c3ccccc3)cc(C(C)(C)C)cc2-c2ccccc2)c([2H])c(Cl)c1[2H] ; [2H]c1c([2H])c2c(c([2H])c1Cl)N(c1c(-c3ccccc3)cc(C(C)(C)C)cc1-c1ccccc1)c1cc(C(C)(C)C)cc3c1B2c1sc2c(-c4ccccc4-c4ccc5ccc6cccc7ccc4c5c67)cccc2c1N3c1c(-c2ccccc2)cc(C(C)(C)C)cc1-c1ccccc1]

In an argon atmosphere, to a 1-L flask, Intermediate Compound B24-b (7.4 g, 5.9 mmol) was added and dissolved in 100 mL of o-dichlorobenzene, and BBr₃ (1.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography using CH₂C12 and hexane as eluent to obtain Intermediate Compound B24-c (yellow solid, 2.2 g, yield: 29%).

ESI-LCMS: [M]⁺: C90H69D3BClN2S. 1261.5434

### (Synthesis of Compound B24)

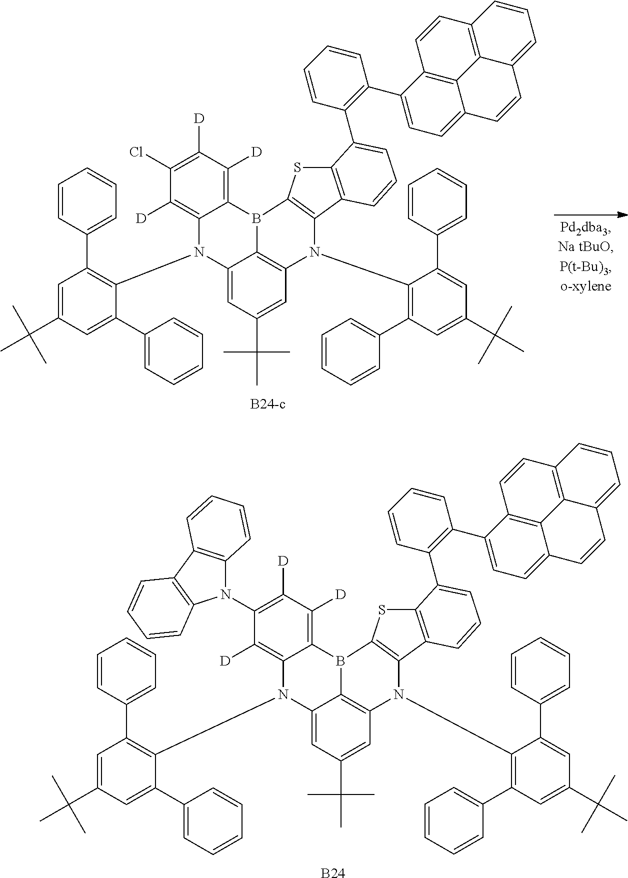

In an argon atmosphere, to a 1-L flask, Intermediate Compound B24-c (2 g, 1.6 mmol), 9H-carbazole-1,2,3,4,5,6,7,8-d8 (0.29 g, 1.6 mmol), Pd₂dba₃ (0.06 g, 0.12 mmol), tris-tert-butyl phosphine (0.06 mL, 0.24 mmol), and sodium tert-butoxide (0.5 g, 5.1 mmol) were added and dissolved in 100 mL of xylene, and the reaction solution was stirred at about 140° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂C12 and hexane as eluent to obtain Compound B24 (yellow solid, 1.7 g, yield: 77%).

ESI-LCMS: [M]⁺: C102H77D3BN3S. 1392.6461

### 3) Synthesis of Compound B26

### (Synthesis of Intermediate B26-a)

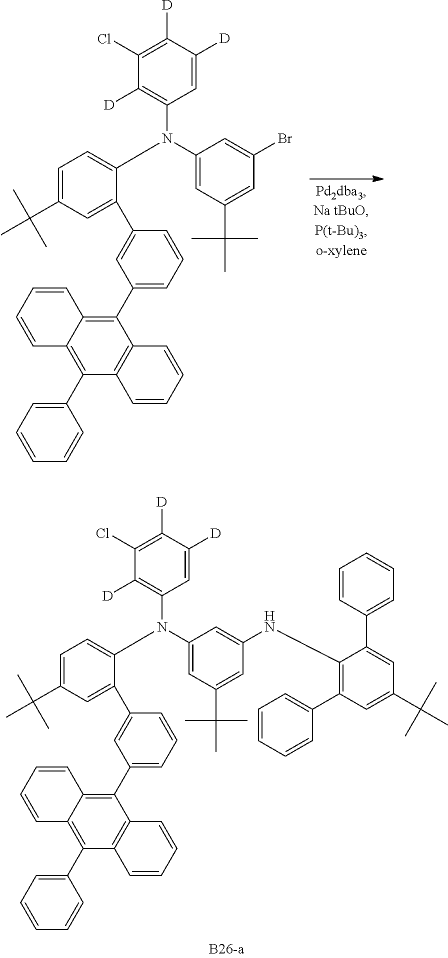 [SMILES: [2H]c1cc(N(c2cc(Br)cc(C(C)(C)C)c2)c2ccc(C(C)(C)C)cc2-c2cccc(-c3c4ccccc4c(-c4ccccc4)c4ccccc34)c2)c([2H])c(Cl)c1[2H] ; [2H]c1cc(N(c2cc(Nc3c(-c4ccccc4)cc(C(C)(C)C)cc3-c3ccccc3)cc(C(C)(C)C)c2)c2ccc(C(C)(C)C)cc2-c2cccc(-c3c4ccccc4c(-c4ccccc4)c4ccccc34)c2)c([2H])c(Cl)c1[2H]]

In an argon atmosphere, to a 2-L flask, N-(3-bromo-5-(tert-butyl)phenyl)-5-(tert-butyl)-N—(3-chlorophenyl-2,4,5-d3)-3′-(10-phenylanthracen-9-yl)-[1,1′-biphenyl]-2-amine (10 g, 12 mmol), 5′-(tert-butyl)-[1,1′:3′,1″-terphenyl]-2′-amine (3.75 g, 13.6 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and the reaction solution was stirred at about 140° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂C12 and hexane as eluent to obtain Intermediate Compound B26-a (white solid, 8.6 g, yield: 76%).

ESI-LCMS: [M]⁺: C74H64D3C1N2. 1021.5231

### (Synthesis of Intermediate Compound B26-b)

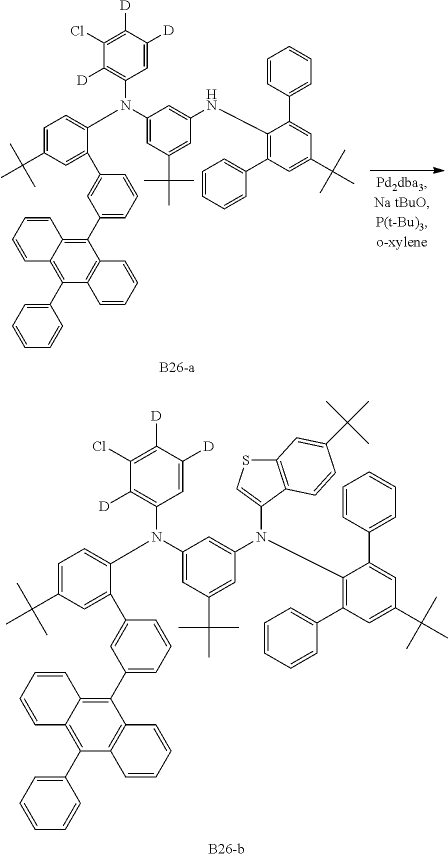

In an argon atmosphere, to a 2-L flask, Intermediate Compound B26-a (8.6 g, 8.4 mmol), 6-(tert-butyl)-3-iodobenzo[b]thiophene (2.7 g, 8.4 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and the reaction solution was stirred at about 140° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂C12 and hexane as eluent to obtain Intermediate Compound B26-b (white solid, 7.8 g, yield: 77%).

ESI-LCMS: [M]⁺: C86H76D3C1N2S. 1209.5851

### (Synthesis of Intermediate Compound B26-c)

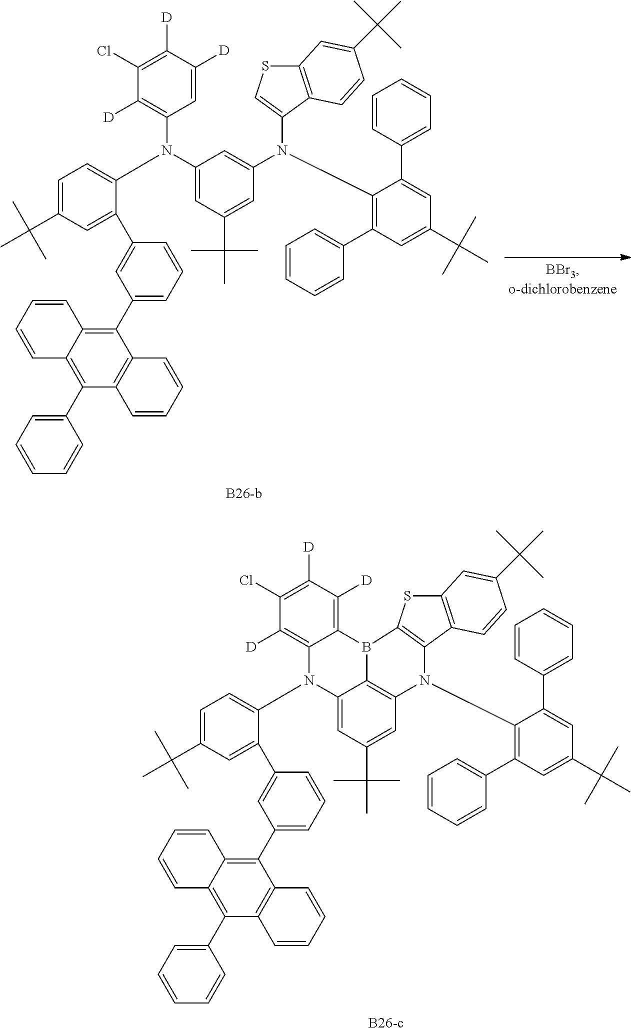

In an argon atmosphere, to a 1-L flask, Intermediate Compound B26-b (7.8 g, 5.9 mmol) was added and dissolved in 100 mL of o-dichlorobenzene, and BBr₃ (1.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography using CH₂C12 and hexane as eluent to obtain Intermediate Compound B26-c (yellow solid, 1.9 g, yield: 24%).

ESI-LCMS: [M]⁺: C86H73D3BClN2S. 1217.5711

### (Synthesis of Compound B26)

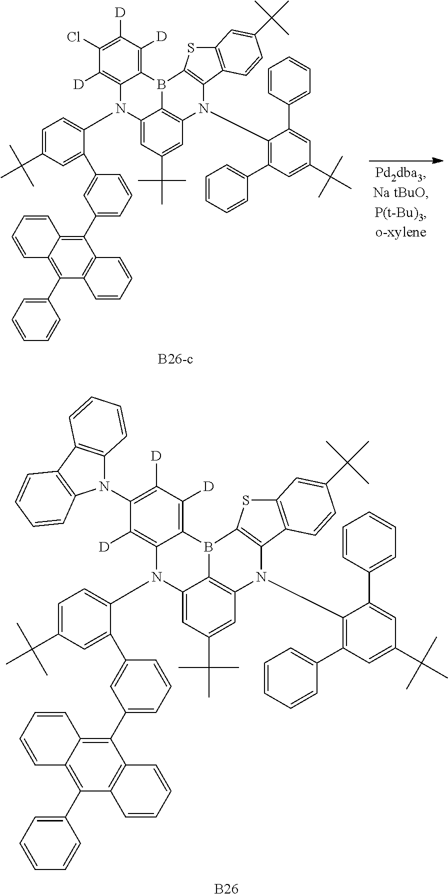

In an argon atmosphere, to a 1-L flask, Intermediate Compound B26-c (1.9 g, 1.6 mmol), 9H-carbazole (0.29 g, 1.6 mmol), Pd₂dba₃ (0.06 g, 0.12 mmol), tris-tert-butyl phosphine (0.06 mL, 0.24 mmol), and sodium tert-butoxide (0.5 g, 5.1 mmol) were added and dissolved in 100 mL of xylene, and the reaction solution was stirred at about 140° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂C12 and hexane as eluent to obtain Compound B26 (yellow solid, 1.6 g, yield: 74%).

ESI-LCMS: [M]⁺: C98H81D3BN3S. 1348.6717

### 4) Synthesis of Compound B37

### (Synthesis of Intermediate B37-a)

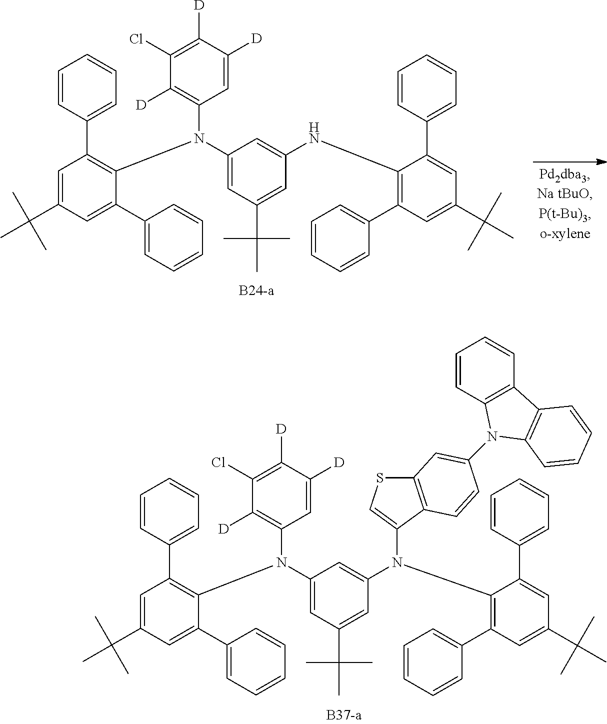

In an argon atmosphere, to a 2-L flask, Intermediate Compound B24-a (10 g, 12 mmol), 9-(3-iodobenzo[b]thiophen-6-yl)-9H-carbazole (5 g, 12 mmol), Pd₂dba₃ (1.6 g, 1.9 mmol), tris-tert-butylphosphine (1.6 mL, 3.8 mmol), and sodium tert-butoxide (11.5 g, 120 mmol) were added and dissolved in 300 mL of o-xylene, and the reaction solution was stirred at about 140° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂C12 and hexane as eluent to obtain Intermediate Compound B37-a (white solid, 9.7 g, yield: 79%).

ESI-LCMS: [M]⁺: C80H66D4ClN3S. 1143.5262

### (Synthesis of Intermediate Compound B37-b)

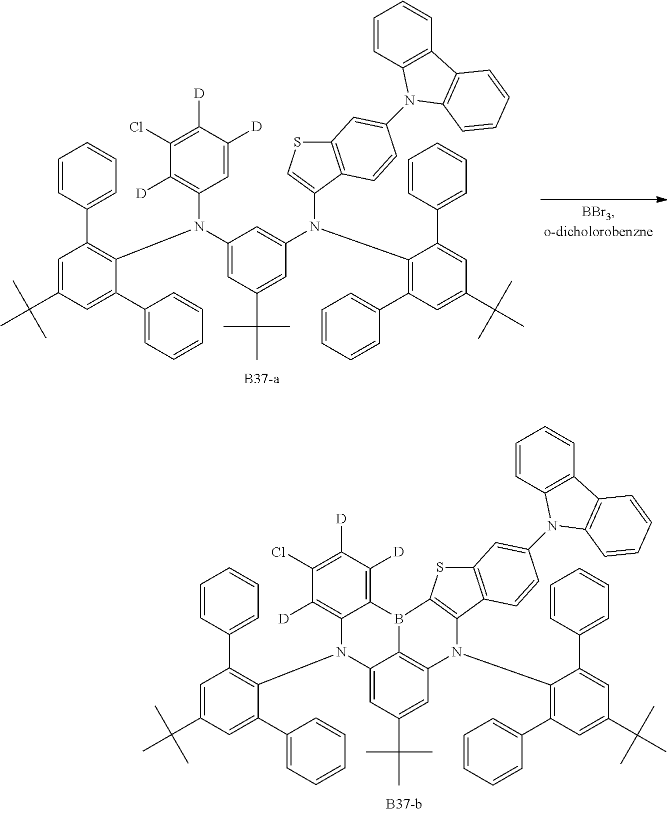

In an argon atmosphere, to a 1-L flask, Intermediate Compound B37-a (9.7 g, 8.5 mmol) was added and dissolved in 100 mL of o-dichlorobenzene, and BBr₃ (1.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography using CH₂C12 and hexane as eluent to obtain Intermediate Compound B37-b (yellow solid, 1.9 g, yield: 18%).

ESI-LCMS: [M]⁺: C80H64D3BClN3S. 1150.5002

### (Synthesis of Compound B37)

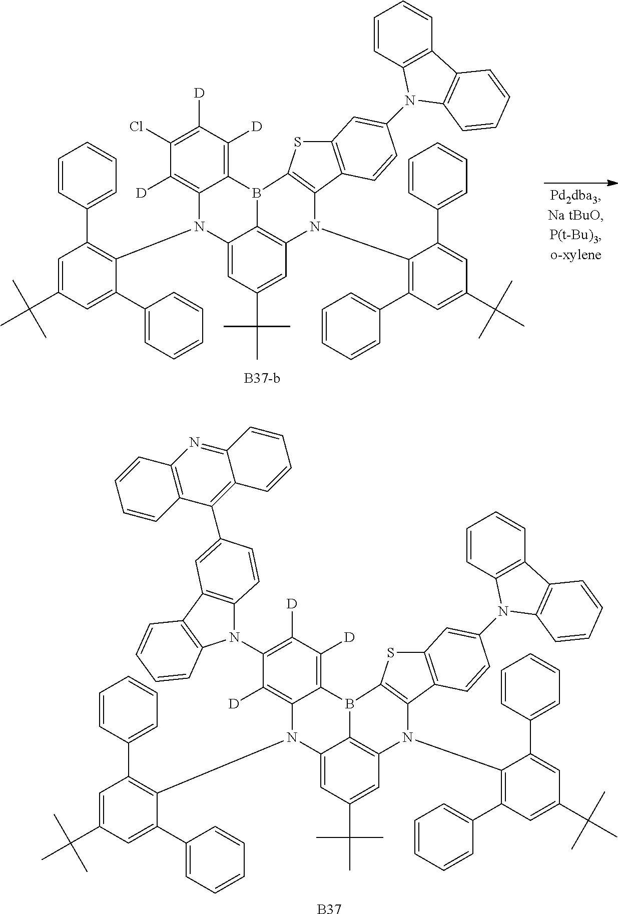

In an argon atmosphere, to a 1-L flask, Intermediate Compound B37-b (1.9 g, 1.6 mmol), 9-(9H-carbazol-3-yl)acridine (0.57 g, 1.6 mmol), Pd₂dba₃ (0.06 g, 0.12 mmol), tris-tert-butyl phosphine (0.06 mL, 0.24 mmol), and sodium tert-butoxide (0.5 g, 5.1 mmol) were added and dissolved in 100 mL of xylene, and the reaction solution was stirred at about 140° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂C12 and hexane as eluent to obtain Compound B37 (yellow solid, 1.7 g, yield: 73%).

ESI-LCMS: [M]⁺: C105H79D3BN5S. 1458.6642

### 5) Synthesis of Compound B38

### (Synthesis of Compound B38)

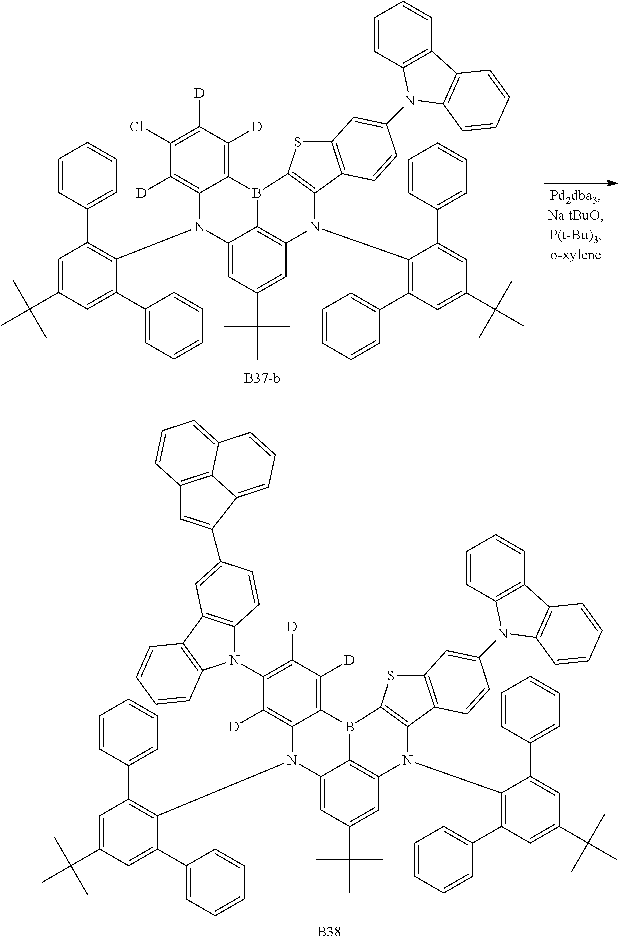

In an argon atmosphere, to a 1-L flask, Intermediate Compound B37-b (1.9 g, 1.6 mmol), 3-(acenaphthylen-1-yl)-9H-carbazole (0.5 g, 1.6 mmol), Pd)dba₃ (0.06 g, 0.12 mmol), tris-tert-butyl phosphine (0.06 mL, 0.24 mmol), and sodium tert-butoxide (0.5 g, 5.1 mmol) were added and dissolved in 100 mL of xylene, and the reaction solution was stirred at about 140° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂C12 and hexane as eluent to obtain Compound B38 (yellow solid, 1.7 g, yield: 74%).

ESI-LCMS: [M]⁺: C104H78D3BN4S. 1431.6539

¹H NMR of the synthesized (1-1)-th compounds of Examples 1 to 5 and ¹H NMR of the synthesized (2-1)-th compounds of Examples 1 to 5 are shown in Table 1 below. The synthesis methods of other compounds may be readily recognized by those skilled in the art with reference to the above synthesis paths and raw materials.

TABLE 1

| Compound | |
|---|---|
| number | ¹H NMR chemical shift (CDCl₃) |
| A2 | 7.45 (s, 4H), 7.18 (m, 12H), 7.01 (m, 8H), 6.88 (s, 2H), |
| | 1.39 (s, 18H), 1.22 (s, 9H) |
| A17 | 7.98 (d, 1H), 7.83 (d, 2H), 7.79 (d, 1H), 7.54 (d, 1H), 7.43 |
| | (m, 13H), 7.39 (s, 4H), 7.31 (m, 1H), 7.08 (m, 8H), 1.33 |
| | (s, 18H) |
| A21 | 7.47 (m, 12H), 7.42 (s, 4H), 7.12 (m, 8H), 6.88 (s, 2H), |
| | 1.33 (s, 18H), 1.21 (s, 9H) |
| A31 | 7.93 (s, 4H), 7.55 (m, 8H), 7.45 (m, 2H), 7.40 (m, 4H), |
| | 7.31 (m, 4H), 7.03 (s, 2H), 1.44 (s, 36H), 1.25 (s, 9H) |
| A33 | 7.55 (m, 4H), 7.49 (m, 6H), 7.43 (s, 4H), 7.32 (m, 12H), |
| | 7.03 (m, 8H), 6.93 (s, 2H), 1.38 (s, 18H), 1.22 (s, 9H) |
| B4 | 8.52 (d, 1H), 8.31 (d, 1H), 8.15 (d, 1H), 8.04 (m, 4H), 7.92 |
| | (d, 1H), 7.70 (d, 1H), 7.44 (s, 4H), 7.22 (m, 12H), 7.07 |
| | (m, 8H), 6.92 (s, 2H), 1.31 (s, 18H), 1.21 (s, 9H) |
| B24 | 8.52 (d, 1H), 8.33 (d, 1H), 8.17 (m, 2H), 8.08 (m, 4H), |
| | 7.92 (m, 4H), 7.70 (d, 1H), 7.60 (m, 2H), 7.51 (t, 2H), 7.46 |
| | (m, 12H), 7.40 (s, 4H), 7.12 (m, 2H), 7.02 (m, 8H), 6.93 |
| | (s, 2H), 1.38 (s, 18H), 1.27 (s, 9H) |
| B26 | 8.55 (d, 2H), 8.22 (m, 4H), 7.94 (d, 2H), 7.81 (m, 3H), |
| | 7.73 (m, 1H), 7.55 (m, 5H), 7.47 (t, 2H), 7.42 (m, 2H), |
| | 7.38 (s, 1H), 7.29 (m, 11H), 7.18 (m, 4H), 7.03 (m, 4H), |
| | 6.91 (s, 2H), 1.39 (s, 18H), 1.22 (s, 9H) |
| B37 | 8.55 (d, 2H), 8.19 (s, 2H), 8.01 (d, 2H), 7.95 (m, 4H), 7.89 |
| | (m, 3H), 7.77 (d, 1H), 7.62 (m, 4H), 7.50 (m, 4H), 7.43 |
| | (m, 12H), 7.38 (s, 4H), 7.21 (m, 4H), 7.11 (m, 8H), 7.00 |
| | (s, 2H), 1.39 (s, 18H), 1.25 (s, 9H) |
| B38 | 8.55 (d, 1H), 8.19 (d, 1H), 8.11 (s, 1H), 7.94 (d, 2H), 7.80 |
| | (m, 2H), 7.69 (m, 2H), 7.55 (m, 5H), 7.48 (m, 12H), 7.43 |
| | (m, 1H), 7.40 (s, 4H), 7.32 (m, 2H), 7.16 (m, 5H), 7.03 |
| | (m, 8H), 6.89 (s, 2H), 1.36 (s, 18H), 1.22 (s, 9H) |

### (3) Manufacture of Light Emitting Elements

In a light emitting element of Example 1, a glass substrate (made by Corning Co.), on which an ITO electrode of about 15 Ω/cm² (about 1200 Å) had been formed as an anode, was cut to a size of about 50 mm×50 mm×0.7 mm, cleansed by ultrasonic waves using isopropyl alcohol and pure water for about five minutes each, and irradiated with ultraviolet rays for about 30 minutes and exposed to ozone and cleansed. The glass substrate was installed on a vacuum deposition apparatus.

NPD was deposited on the upper portion of the anode to form a 300-A thick hole injection layer, Compound H-1-19 was deposited on the upper portion of the hole injection layer to form a 200-Å thick hole transport layer, and CzSi was deposited on the upper portion of the hole transport layer to form a 100-Å thick emission-auxiliary layer.

A host in which a first host (HT) and a second host (ET) were mixed at a weight ratio of 1:1, a sensitizer (PS), and Compound A2 were co-deposited at a weight ratio of 85:14:1 to form a 200-Å thick first emission layer, and a third host (BH) and Compound B4 were co-deposited at a weight ratio of 98:2 on the upper portion of the first emission layer to form a 100-Å thick second emission layer, thereby manufacturing an emission layer. TSPO1 was deposited on the upper portion of the emission layer to form a 200-Å thick hole blocking layer. On the upper portion of the hole blocking layer, TPBI was deposited to form a 300-Å thick electron transport layer, and on the upper portion of the electron transport layer, LiF was deposited to form a 10-Å thick electron injection layer. On the electron injection layer, A1 was deposited to form a 3,000-Å thick cathode. Compound P4 was deposited on the upper portion of the cathode to form a 700-Å thick capping layer, thereby manufacturing a light emitting element. Each layer was formed by a vacuum deposition method.

The light emitting element of Example 2 was manufactured in the same manner as the light emitting element of Example 1, except that the thickness of the second emission layer was different from that of the second emission layer in Example 1. The light emitting element of Comparative Example 1 was manufactured in the same manner as the light emitting element of Example 1, except that the structure of the emission layer was different from that of the emission layer in Example 1. The light emitting elements of Comparative Examples 2 to 4 were manufactured in the same manner as the light emitting element of Example 1, except that the structure of the emission layer and the compounds used in the forming of the first emission layer were different from those in Example 1. The light emitting elements of Comparative Examples 5 to 10 were manufactured in the same manner as the light emitting element of Example 1, except that the compounds used in the forming of the first and/or second emission layers were different from those in Example 1. The structure of the light emitting elements of the Examples and the Comparative Examples, the types of compounds used in the manufacture, and the thickness of the second emission layer are shown in Table 3 below.

The compounds used for manufacturing the light emitting elements of the Examples and the Comparative Examples are shown below. The materials below were used to manufacture the elements by subjecting commercial products to sublimation purification.

[(1-1)-th Compounds in the Examples]

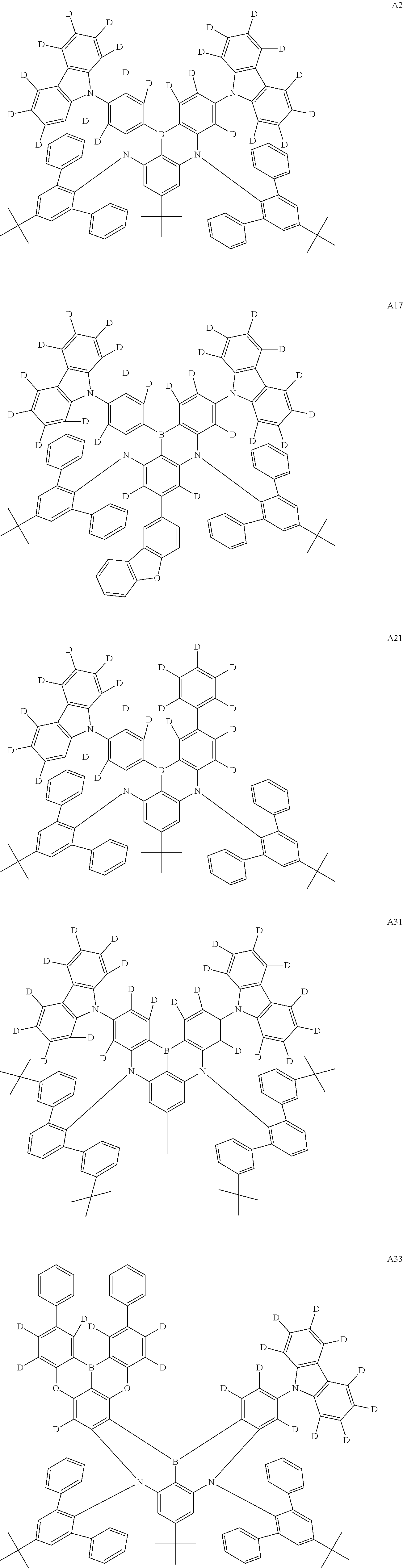

[(2-1)-th Compounds in the Examples]

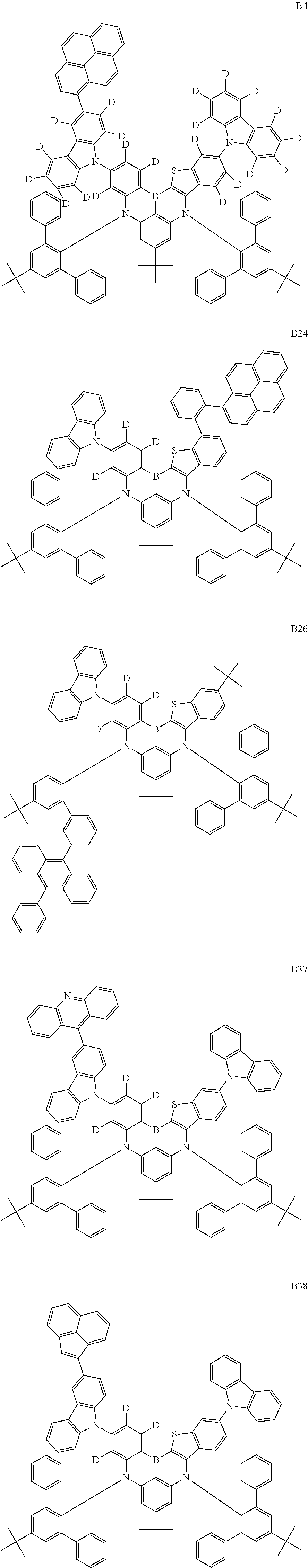

### [Comparative Example Compounds]

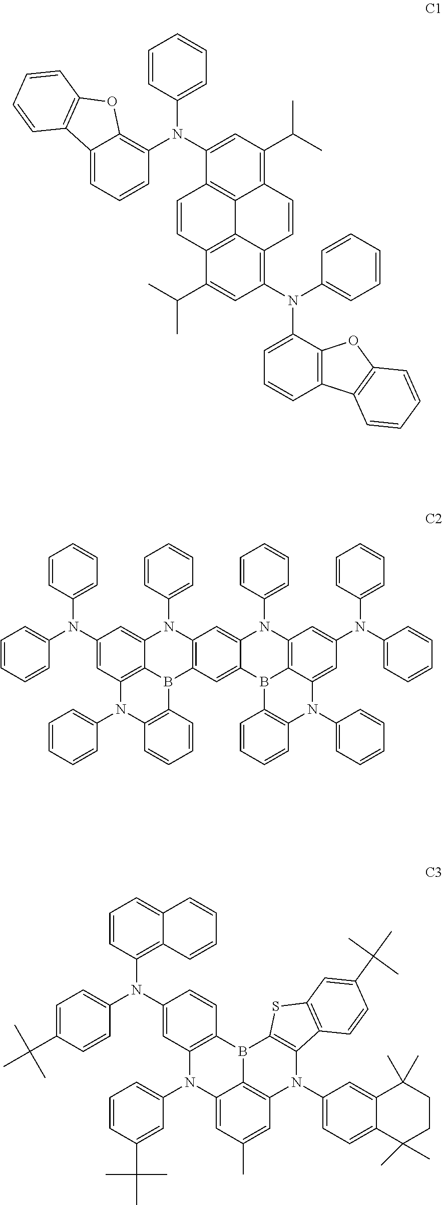 [SMILES: CC(C)c1cc(N(c2ccccc2)c2cccc3c2oc2ccccc23)c2ccc3c(C(C)C)cc(N(c4ccccc4)c4cccc5c4oc4ccccc45)c4ccc1c2c34 ; c1ccc(N(c2ccccc2)c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)cc(c32)N5c2ccccc2)cc1 ; Cc1cc2c3c(c1)N(c1ccc4c(c1)C(C)(C)CCC4(C)C)c1c(sc4cc(C(C)(C)C)ccc14)B3c1ccc(N(c3ccc(C(C)(C)C)cc3)c3cccc4ccccc34)cc1N2c1cccc(C(C)(C)C)c1]

### [Compounds Used to Manufacture Light Emitting Elements]

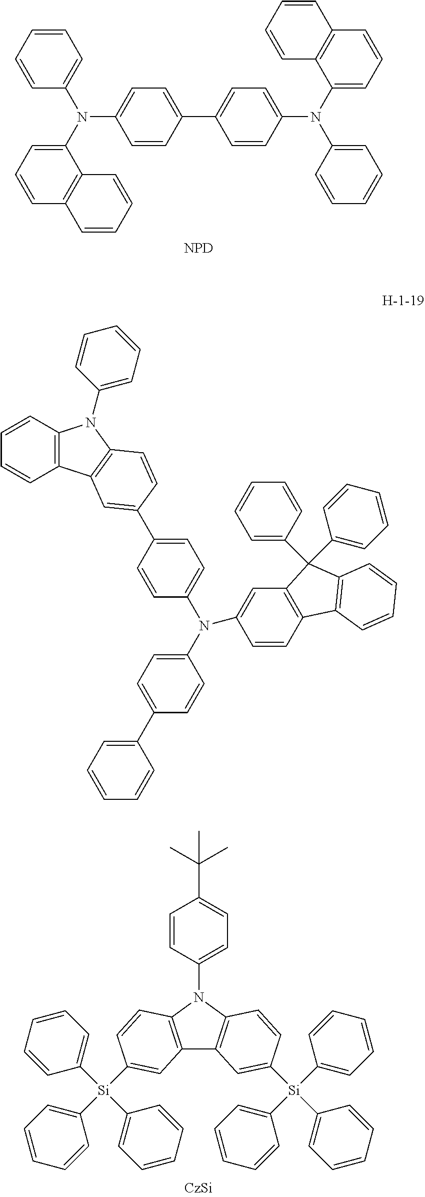

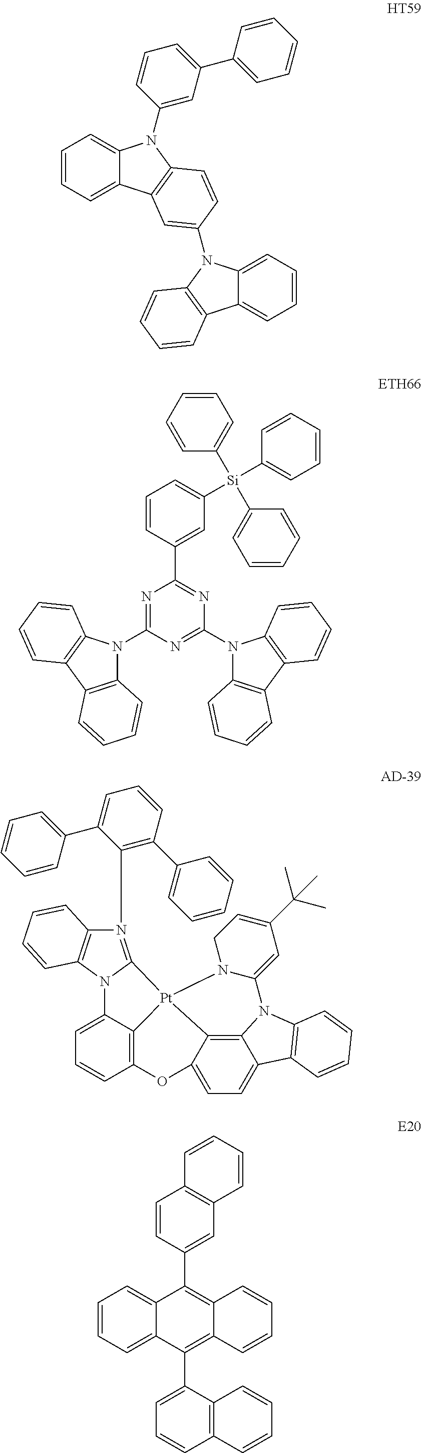

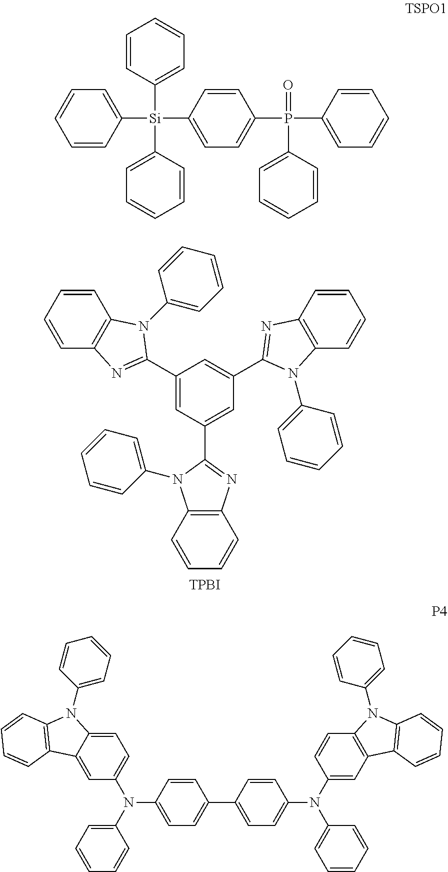

### 2. Evaluation of Compound and Light Emitting Element Characteristics

### (Evaluation of Compound Characteristics)

The highest occupied molecular orbital (HOMO) energy levels of the (1-1)-th compounds A2, A17, A21, A31, and A33 of Example Compounds as described above, the (2-1)-th compounds B4, B24, B26, B37, and B38 of Example Compounds, and Comparative Example Compounds C1 to C3 were measured using Smart Manager software of the SP2 electrochemical workstation equipment from ZIVE LAB. The lowest excited singlet energy level (S1), the lowest excited triplet energy level (T1), FWQM (full width at quarter maximum), and the maximum emission wavelength (λₘₐₓ) were measured by using FluorEssence software with a xenon light source and a monochromator mounted on fluoromax+ spectrometer equipment from HORIBA. The second excited triplet energy level (T2) was determined by calculating the structure of the second stable triplet excitation state and the corresponding energy through the calculation of the unrestricted density functional theory (UDFT), and the UDFT calculation was performed with the commercial program Gaussian09, and the 6-311G(d,p) base function and the B3LYP exchange-correlation function were used. The maximum absorption wavelength (λ_{abs}) was measured using Labsolution UV-Vis software with a deuterium/tungsten-halogen light source and a silicon photodiode mounted on UV-1800 UV/Visible Scanning Spectrophotometer equipment (from SHIMADZU). Stokes-shift was calculated through the difference between the maximum absorption wavelength (λ_{abs}) and the maximum emission wavelength (λₘₐₓ). The results from the measurement and calculation are listed in Table 2.

TABLE 2

| | | | | | | Maximum | Maximum | |
|---|---|---|---|---|---|---|---|---|
| | | | | | | absorption | emission | Stokes- |
| | HOMO | S1 | T1 | T2 | FWQM | wavelength | wavelength | shift |
| Compound | (eV) | (eV) | (eV) | (eV) | (nm) | (λ_{abs}, nm) | (λₘₐₓ, nm) | (nm) |
| Compound A2 | −5.38 | 2.70 | 2.59 | 2.72 | 37 | 447 | 458 | 11 |
| Compound A17 | −5.45 | 2.69 | 2.59 | 2.70 | 33 | 450 | 459 | 9 |
| Compound A21 | −5.40 | 2.68 | 2.57 | 2.71 | 34 | 449 | 460 | 11 |
| Compound A31 | −5.43 | 2.71 | 2.60 | 2.73 | 36 | 447 | 457 | 10 |
| Compound A33 | −5.41 | 2.73 | 2.68 | 2.75 | 35 | 445 | 455 | 10 |
| Compound B4 | −5.38 | 2.69 | 2.10 | 2.35 | 35 | 450 | 460 | 10 |
| Compound B24 | −5.35 | 2.70 | 2.10 | 2.33 | 33 | 448 | 458 | 10 |
| Compound B26 | −5.43 | 2.71 | 1.85 | 2.25 | 34 | 445 | 455 | 10 |
| Compound B37 | −5.49 | 2.70 | 2.00 | 2.21 | 35 | 450 | 458 | 8 |
| Compound B38 | −5.37 | 2.70 | 2.05 | 2.30 | 37 | 448 | 457 | 9 |
| Comparative Example | −4.69 | 2.71 | 2.30 | 2.70 | 56 | 428 | 463 | 35 |
| Compound C1 | | | | | | | | |
| Comparative Example | −5.05 | 2.65 | 2.59 | 2.70 | 25 | 455 | 465 | 10 |
| Compound C2 | | | | | | | | |
| Comparative Example | −5.01 | 2.72 | 2.40 | 2.79 | 40 | 448 | 459 | 11 |
| Compound C3 | | | | | | | | |

### (Evaluation of Flight Emitting Element Characteristics)

Luminous efficiency and element service life of the light emitting elements manufactured with the (1-1)-th compounds A2, A17, A21, A31, and A33 of the Example Compounds as described above, the (2-1)-th compounds B4, B24, B26, B37, and B38 of the Example Compounds, and Comparative Example Compounds C1 to C3 were evaluated. Evaluation results of the light emitting elements of Examples 1 to 15 and Comparative Examples 1 to 10 are listed in Table 3. To evaluate the characteristics of the light emitting elements manufactured in Examples 1 to 15 and Comparative Examples 1 to 10 above, each of driving voltages (V), luminous efficiencies (Cd/A/y), and emission colors at a current density of 1,000 cd/m² was measured by using Keithley MU 236 and a luminance meter PR650, and the time taken to reach 95% brightness relative to an initial brightness was measured as a service life (T95), and a relative service life was calculated on the basis of the element of Comparative Example 1, and the results are listed in Table 3.

TABLE 3

| | | | | Second emission layer EML2 | | | | | | |
|---|---|---|---|---|---|---|---|---|---|---|
| | | | | | | Thickness | Element characteristic evaluation | | | |
| | Host ((1-2)-th | First emission layer EML1 | | | | of second | Driving | Color | Luminous | Relative |
| | compound: (1-3)-th | (1-4)-th | (1-1)-th | (2-1)-th | (2-2)-th | emission | voltage | purity | efficiency | service life |
| | compound = 5:5) | compound | compound | compound | compound | layer (Å) | (V) | (CIEy) | (cd/A/y) | (T95, %) |
| Example 1 | HT59/ETH66 | AD-39 | Compound A2 | Compound B4 | E20 | 100 | 3.8 | 0.051 | 450 | 350 |
| Example 2 | HT59/ETH66 | AD-39 | Compound A2 | Compound B4 | E20 | 200 | 3.7 | 0.050 | 410 | 420 |
| Example 3 | HT59/ETH66 | AD-39 | Compound A2 | Compound B24 | E20 | 200 | 3.8 | 0.048 | 480 | 390 |
| Example 4 | HT59/ETH66 | AD-39 | Compound A2 | Compound B26 | E20 | 200 | 3.6 | 0.045 | 400 | 520 |
| Example 5 | HT59/ETH66 | AD-39 | Compound A2 | Compound B37 | E20 | 200 | 3.5 | 0.048 | 500 | 320 |
| Example 6 | HT59/ETH66 | AD-39 | Compound A2 | Compound B38 | E20 | 200 | 3.7 | 0.049 | 390 | 350 |
| Example 7 | HT59/ETH66 | AD-39 | Compound A17 | Compound B4 | E20 | 200 | 3.8 | 0.053 | 430 | 400 |
| Example 8 | HT59/ETH66 | AD-39 | Compound A21 | Compound B4 | E20 | 200 | 3.8 | 0.055 | 410 | 350 |
| Example 9 | HT59/ETH66 | AD-39 | Compound A31 | Compound B4 | E20 | 200 | 3.7 | 0.049 | 450 | 370 |
| Example 10 | HT59/ETH66 | AD-39 | Compound A33 | Compound B4 | E20 | 200 | 3.8 | 0.043 | 520 | 350 |
| Example 11 | HT59/ETH66 | AD-39 | Compound A2 | Compound B26 | E20 | 100 | 3.4 | 0.050 | 480 | 630 |
| Example 12 | HT59/ETH66 | AD-39 | Compound A17 | Compound B26 | E20 | 100 | 3.5 | 0.052 | 450 | 580 |
| Example 13 | HT59/ETH66 | AD-39 | Compound A21 | Compound B26 | E20 | 100 | 3.3 | 0.053 | 430 | 590 |
| Example 14 | HT59/ETH66 | AD-39 | Compound A31 | Compound B26 | E20 | 100 | 3.5 | 0.050 | 500 | 600 |
| Example 15 | HT59/ETH66 | AD-39 | Compound A33 | Compound B26 | E20 | 100 | 3.4 | 0.045 | 520 | 550 |
| Comparative | HT59/ETH66 | AD-39 | Compound A2 | — | — | — | 3.8 | 0.053 | 580 | 100 |
| Example 1 | | | | | | | | | | |
| Comparative | HT59/ETH66 | AD-39 | Comparative | — | — | — | 4.2 | 0.077 | 150 | 65 |
| Example 2 | | | Example | | | | | | | |
| | | | Compound C1 | | | | | | | |
| Comparative | HT59/ETH66 | AD-39 | Comparative | — | — | — | 4.0 | 0.060 | 480 | 35 |
| Example 3 | | | Example | | | | | | | |
| | | | Compound C2 | | | | | | | |
| Comparative | HT59/ETH66 | AD-39 | Comparative | — | — | — | 4.5 | 0.050 | 250 | 7 |
| Example 4 | | | Example | | | | | | | |
| | | | Compound C3 | | | | | | | |
| Comparative | HT59/ETH66 | AD-39 | Compound A2 | Comparative | E20 | 200 | 4.0 | 0.068 | 190 | 150 |
| Example 5 | | | | Example | | | | | | |
| | | | | Compound C1 | | | | | | |
| Comparative | HT59/ETH66 | AD-39 | Compound A2 | Comparative | E20 | 200 | 4.0 | 0.059 | 500 | 85 |
| Example 6 | | | | Example | | | | | | |
| | | | | Compound C2 | | | | | | |
| Comparative | HT59/ETH66 | AD-39 | Compound A2 | Comparative | E20 | 200 | 4.3 | 0.050 | 320 | 15 |
| Example 7 | | | | Example | | | | | | |
| | | | | Compound C3 | | | | | | |
| Comparative | HT59/ETH66 | AD-39 | Comparative | Compound B4 | E20 | 200 | 4.2 | 0.052 | 350 | 75 |
| Example 8 | | | Example | | | | | | | |
| | | | Compound C2 | | | | | | | |
| Comparative | HT59/ETH66 | AD-39 | Comparative | Comparative | E20 | 200 | 4.1 | 0.063 | 330 | 33 |
| Example 9 | | | Example | Example | | | | | | |
| | | | Compound C2 | Compound C2 | | | | | | |
| Comparative | HT59/ETH66 | AD-39 | Comparative | Comparative | E20 | 200 | 4.4 | 0.050 | 280 | 5 |
| Example 10 | | | Example | Example | | | | | | |
| | | | Compound C3 | Compound C3 | | | | | | |

Referring to the results of Table 3, it may be confirmed that the light emitting elements of Examples according to an embodiment have characteristics of low driving voltage, excellent blue color purity, and luminous efficiency, and at the same time, relatively improved service life characteristics, as compared to the light emitting elements of the Comparative Examples.

Since the light emitting elements of the Examples each include an emission layer having a structure in which the first emission layer and the second emission layer are stacked, a long service life may be achieved. The first emission layer included in the light emitting element of Examples includes the (1-1)-th compound, and the second emission layer includes the (2-1)-th compound. The (1-1)-th compound may have a structure that includes a first fused ring core fused via a boron atom and two nitrogen atoms, and in which a terphenyl substituent is each linked to a nitrogen atom of the first fused ring core. The (2-1)-th compound may have a structure that includes a second fused ring core fused via a boron atom, two nitrogen atoms, and a heteroatom from Group 16 and in which a carbazole substituent is linked to the second fused ring core and a terphenyl substituent is linked to the second nitrogen atom. The lowest triplet energy of the (2-1)-th compound may be in a range of about 1.5 eV to about 2.1 eV. In the light emitting element according to an embodiment, the (1-1)-th compound and the (2-1)-th compound are used as dopants for the delayed fluorescence light emitting element in the first and second emission layers, respectively, thereby achieving excellent color purity in a short wavelength region such as a blue light wavelength region, high luminous efficiency, and high element efficiency with long service life.

Referring to the results of Tables 2 and 3, it may be confirmed that Comparative Example 1 has relative deterioration in element service life as compared to the Examples. It is understood that Comparative Example 1 includes, as a component of the emission layer, the first emission layer including the (1-1)-th compound, but does not include the second emission layer, and thus element service life is deteriorated compared to the Examples.

It may be confirmed that Comparative Examples 2 to 4 have relative deterioration in the element service life and a decrease in luminous efficiency as compared to the Examples. It is understood that Comparative Examples 2 to 4 do not include the second emission layer as a component of the emission layer, and thus element service life is deteriorated compared to the Examples. It is understood that Comparative Examples 2 to 4 do not include the (1-1)-th compound as a material for the first emission layer, and thus luminous efficiency is deteriorated compared to the Examples.

It may be confirmed that Comparative Example 5 has a relative deterioration in element service life and a decrease in luminous efficiency as compared to the Examples. Comparative Example 5 includes the first emission layer including the (1-1)-th compound, but does not include the (2-1)-th compound as a material for the second emission layer but instead includes Comparative Example Compound C1. Unlike the (2-1)-th compound according to embodiments, Comparative Example Compound C1 does not include a planar skeleton structure centered on a boron atom and two nitrogen atoms. Accordingly, it is understood that the FWQM and the Stokes-shift value of Comparative Example Compound C1 are relatively large, and Comparative Example 5 including Comparative Example Compound C1 in the first emission layer has deterioration in element service life and a decrease in luminous efficiency compared to the Examples. Unlike the (2-1)-th compound, Comparative Example Compound C1 has a value of the lowest triplet energy (T1) greater than about 2.1 eV. Accordingly, it is understood that Comparative Example 5 including Comparative Example Compound C1 in the first emission layer has deterioration in element service life and a decrease in luminous efficiency compared to the Examples.

It may be confirmed that Comparative Examples 6 and 7 have relative deterioration in element service life and a decrease in luminous efficiency as compared to the Examples. Comparative Example 6 and Comparative Example 7 include the first emission layer including the (1-1)-th compound, but do not include the (2-1)-th compound as a material for the second emission layer but instead include Comparative Example Compound C2 and Comparative Example Compound C3, respectively. Comparative Example Compound C2 and Comparative Example Compound C3 partially include a planar skeleton structure centered on a boron atom and two nitrogen atoms, but do not include a terphenyl substituent. Accordingly, it is understood that Dexter energy transition control of Comparative Example Compounds C2 and C3 is relatively poor, the HOMO energy level is relatively high, and element service life of Comparative Examples 6 and 7 including Comparative Example Compounds C2 and C3, respectively, in the first emission layer is deteriorated and luminous efficiency is decreased. Comparative Example Compound C2 and Comparative Example Compound C3 each have a value of the lowest triplet energy (T1) greater than about 2.1 eV, unlike the (2-1)-th compound according to embodiments. Accordingly, it is understood that Comparative Examples 6 and 7 including Comparative Example Compounds C2 and C3, respectively, in the first emission layer have deterioration in element service life and a decrease in luminous efficiency compared to the Examples.

It may be confirmed that Comparative Example 8 has relative deterioration in element service life and a decrease in luminous efficiency as compared to the Examples. Comparative Example 8 includes the second emission layer including the (2-1)-th compound, but does not include the (1-1)-th compound as a material for the first emission layer but instead includes Comparative Example Compound C2. Accordingly, it is understood that the HOMO energy level of Comparative Example Compound C2 is relatively high, and element service life of Comparative Example 8 including Comparative Example Compound C2 in the second emission layer is deteriorated and luminous efficiency is decreased.

It may be confirmed that Comparative Examples 9 and 10 have relative deterioration in element service life and a decrease in luminous efficiency as compared to the Examples.

Comparative Example 9 and Comparative Example 10 do not include the (1-1)-th compound as a material for the first emission layer, but instead include Comparative Example Compound C2 and Comparative Example Compound C3, respectively, and do not include the (2-1)-th compound as a material for the second emission layer, but instead include Comparative Example Compound C2 and Comparative Example Compound C3, respectively. Accordingly, it is understood that Comparative Example 9 and Comparative Example 10 do not include the (1-1)-th compound as a material for the first emission layer and the (2-1)-th compound as a material for the second emission layer, and thus element service life is deteriorated and luminous efficiency is decreased.

The light emitting element according to an embodiment may exhibit improved element characteristics with high efficiency and a long service life.

The display device according to an embodiment may provide a display device having improved reliability by including the light emitting element according to an embodiment.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting element comprising:
a first electrode;
a first emission layer disposed on the first electrode and comprising a (1-1)-th compound represented by Formula 1;
a second emission layer disposed on the first emission layer and comprising a (2-1)-th compound represented by Formula 2; and
a second electrode disposed on the second emission layer, wherein
the (2-1)-th compound has a lowest excited triplet energy level (T1) in a range of about 1.5 eV to about 2.1 eV: 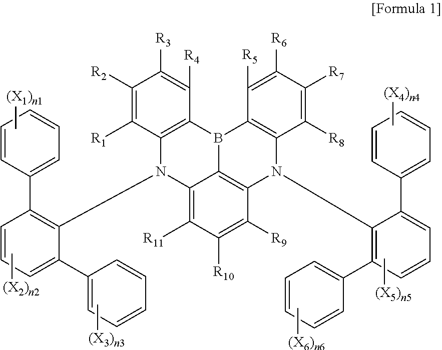
wherein in Formula 1,
R₁ to R₁₁ are each independently a hydrogen atom, a deuterium atom, a halogen atom, a cyano group, a hydroxy group, a substituted or unsubstituted oxy group, a substituted or unsubstituted thio group, a substituted or unsubstituted selenyl group, a substituted or unsubstituted tellanyl group, a substituted or unsubstituted boron group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring,
X₁ to X₆ are each independently a hydrogen atom, a deuterium atom, a halogen atom, a cyano group, a hydroxy group, a substituted or unsubstituted oxy group, a substituted or unsubstituted thio group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring,
n1, n3, n4, and n6 are each independently an integer from 0 to 5, and
n2 and n5 are each independently an integer from 0 to 3, 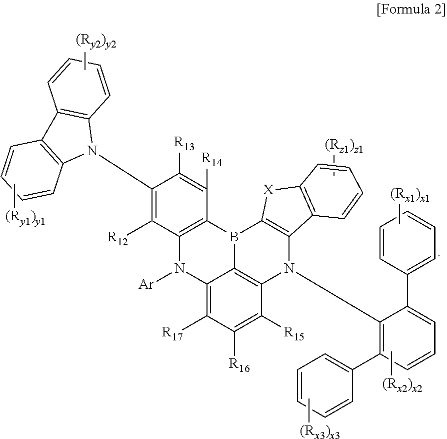
wherein in Formula 2,
X is O, S, Se, or Te,
Ar is a substituted or unsubstituted aryl group having 6 to 30 ring-forming carbon atoms or a substituted or unsubstituted heteroaryl group having 2 to 30 ring-forming carbon atoms,
R₁₂ to R₁₇ and Rₓ₁ to Rₓ₃ are each independently a hydrogen atom, a deuterium atom, a halogen atom, a cyano group, a hydroxy group, a substituted or unsubstituted silyl group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
R_{y1}, R_{y2}, and R_{z1} are each independently a hydrogen atom, a deuterium atom, a halogen atom, a cyano group, a hydroxy group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring,
x1 and x3 are each independently an integer from 0 to 5,
x2 is an integer from 0 to 3, and
y1, y2, and z1 are each independently an integer from 0 to 4.

2. The light emitting element of claim 1, further comprising:
a hole transport region disposed between the first electrode and the first emission layer; and
an electron transport region disposed between the second emission layer and the second electrode.

3. The light emitting element of claim 1, wherein
the first emission layer emits fluorescence by thermally activated delayed fluorescence (TADF), and
the second emission layer emits fluorescence by triplet-triplet annihilation (TTA).

4. The light emitting element of claim 1, wherein
the second emission layer is directly disposed on the first emission layer, and
the first emission layer and the second emission layer each independently emit fluorescence having a central wavelength in a range of about 430 nm to about 490 nm.

5. The light emitting element of claim 1, wherein the (1-1)-th compound has a lowest excited triplet energy level (T1) in a range of about 2.5 eV to about 3.1 eV.

6. The light emitting element of claim 1, wherein
the first emission layer comprises:
a first light emitting host; and
a first light emitting dopant that is doped into the first light emitting host and comprises the (1-1)-th compound,
the second emission layer comprises:
a second light emitting host; and
a second light emitting dopant that is doped into the second light emitting host and comprises the (2-1)-th compound, and
a material included in the first light emitting host is different from a material included in the second light emitting host.

7. The light emitting element of claim 1, wherein the first emission layer further comprises:
at least one of a (1-2)-th compound represented by Formula HT-1, a (1-3)-th compound represented by Formula ET-1, and a (1-4)-th compound represented by Formula D-1: 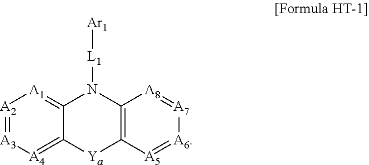
wherein in Formula HT-1,
A₁ to A₈ are each independently N or C(R₅₁),
L₁ is a direct linkage, a substituted or unsubstituted arylene group having 6 to 30 ring-forming carbon atoms, or a substituted or unsubstituted heteroarylene group having 2 to 30 ring-forming carbon atoms,
Yₐ is a direct linkage, C(R₅₂)(R₅₃), or Si(R₅₄)(R₅₅),
Ar₁ is a substituted or unsubstituted aryl group having 6 to 30 ring-forming carbon atoms or a substituted or unsubstituted heteroaryl group having 2 to 30 ring-forming carbon atoms, and
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring; 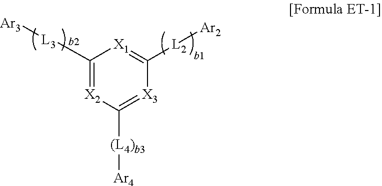
wherein in Formula ET-1,
at least one of X₁ to X₃ is each N,
the remainder of X₁ to X₃ are each independently C(R₅₆),
R₅₆ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group of 2 to 60 ring-forming carbon atoms,
b1 to b3 are each independently an integer from 0 to 10,
Ar₂ to Ar₄ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
L₂ to L₄ are each independently a direct linkage, a substituted or unsubstituted arylene group having 6 to 30 ring-forming carbon atoms, or a substituted or unsubstituted heteroarylene group having 2 to 30 ring-forming carbon atoms; 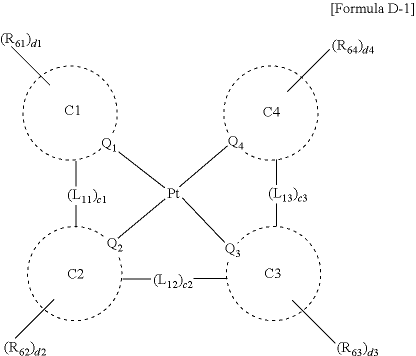
wherein in Formula D-1,
Q₁ to Q₄t are each independently C or N,
C1 to C4 are each independently a substituted or unsubstituted hydrocarbon ring having 5 to 30 ring-forming carbon atoms or a substituted or unsubstituted heterocycle having 2 to 30 ring-forming carbon atoms,
L₁₁ to L₁₃ are each independently a direct linkage, *—O—*, *—S—*, 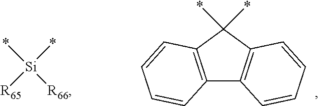
a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
c1 to c3 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring, and
d1 to d4 are each independently an integer from 0 to 4.

8. The light emitting element of claim 7, wherein the first emission layer comprises the (1-1)-th compound, the (1-2)-th compound, the (1-3)-th compound, and the (1-4)-th compound.

9. The light emitting element of claim 1, wherein the second emission layer further comprises a (2-2)-th compound represented by Formula E-1: 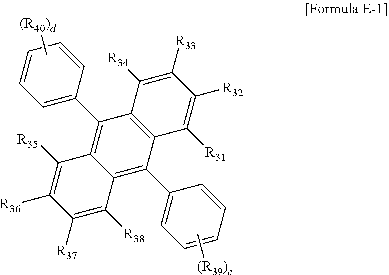
wherein in Formula E-1,
R₃₁ to R₄₀ are each independently a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

10. The light emitting element of claim 9, wherein the second emission layer consists of the (2-1)-th compound and the (2-2)-th compound.

11. The light emitting element of claim 1, wherein the (1-1)-th compound is represented by one of Formula 1-1 to Formula 1-3: 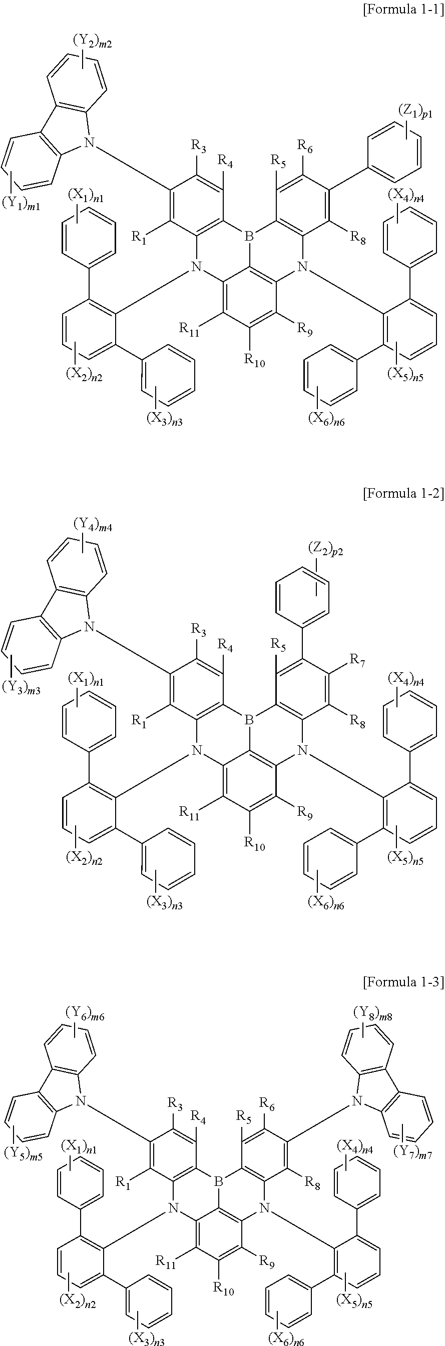
wherein in Formula 1-1 to Formula 1-3,
Y₁ to Y₈, Z₁, and Z₂ are each independently a hydrogen atom, a deuterium atom, a halogen atom, a cyano group, a hydroxy group, a substituted or unsubstituted oxy group, a substituted or unsubstituted thio group, a substituted or unsubstituted selenyl group, a substituted or unsubstituted tellanyl group, a substituted or unsubstituted germyl group, a substituted or unsubstituted boron group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring,
m1 to m8 are each independently an integer from 0 to 4,
p1 and p2 are each independently an integer from 0 to 5, and
R₁, R₃ to R₁₁, X₁ to X₆, and n1 to n6 are the same as defined in Formula 1.

12. The light emitting element of claim 1, wherein the (1-1)-th compound is represented by Formula 1-4: 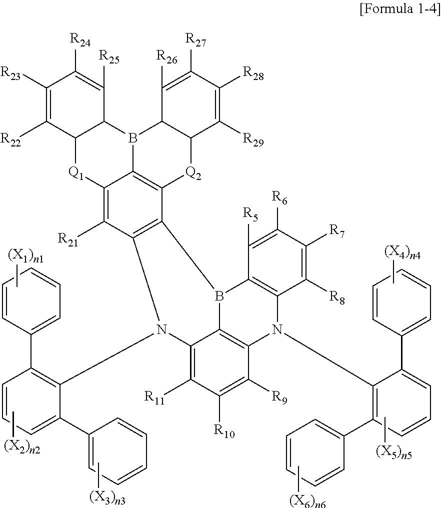
wherein in Formula 1-4,
Q₁ and Q₂ are each independently O, S, Se, Te, or N(R₃₀),
R₂₁ to R₃₀ are each independently a hydrogen atom, a deuterium atom, a halogen atom, a cyano group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring, and
R₅ to R₁₁, X₁ to X₆, and n1 to n6 are the same as defined in Formula 1.

13. The light emitting element of claim 1, wherein the (1-1)-th compound is represented by one of Formula 1-5 to Formula 1-11: 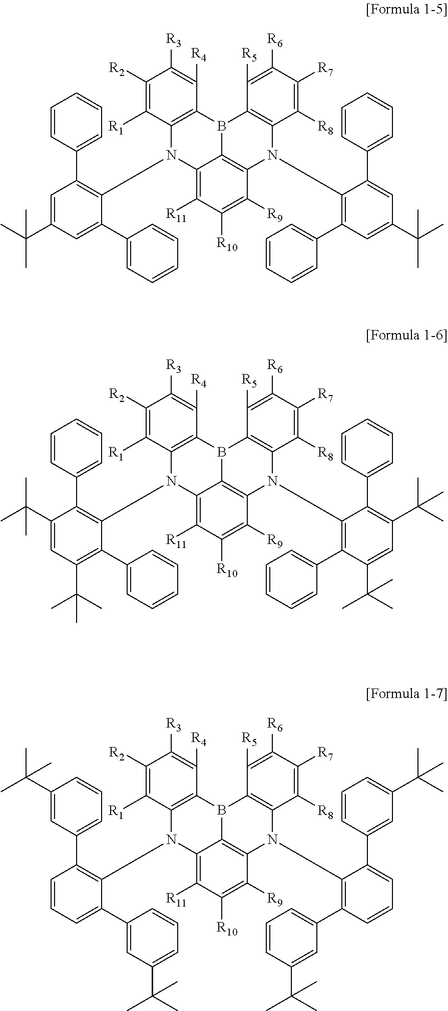 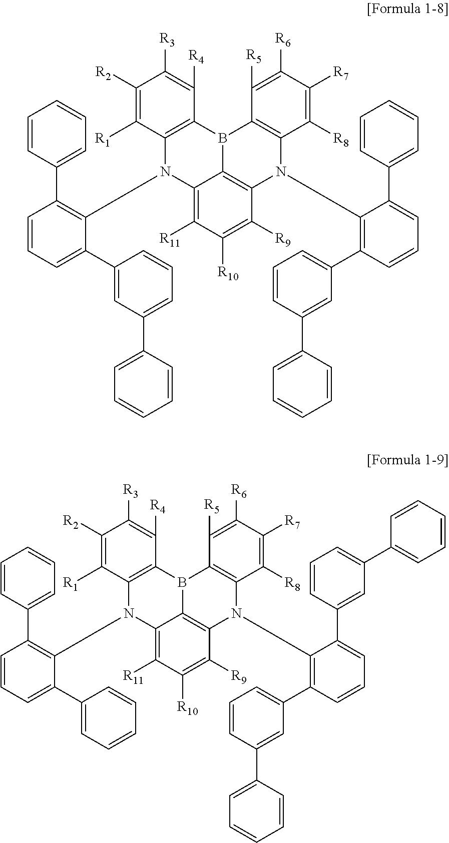 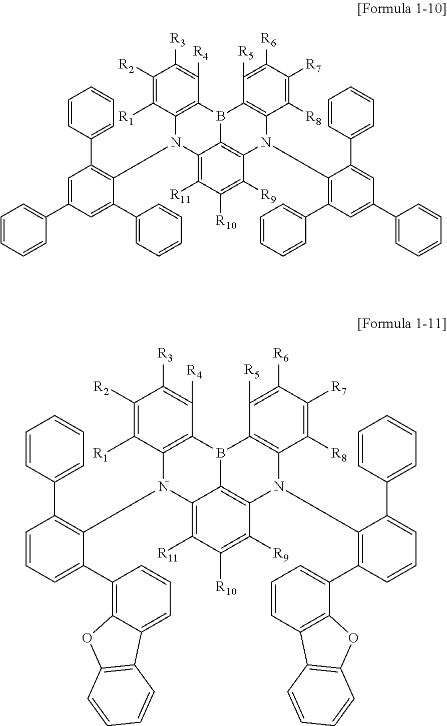
wherein in Formula 1-5 to Formula 1-11,
R₁ to R₁ are the same as defined in Formula 1.

14. The light emitting element of claim 1, wherein in Formula 1, R₁₀ is a group represented by one of Formula 3-1 to Formula 3-6: 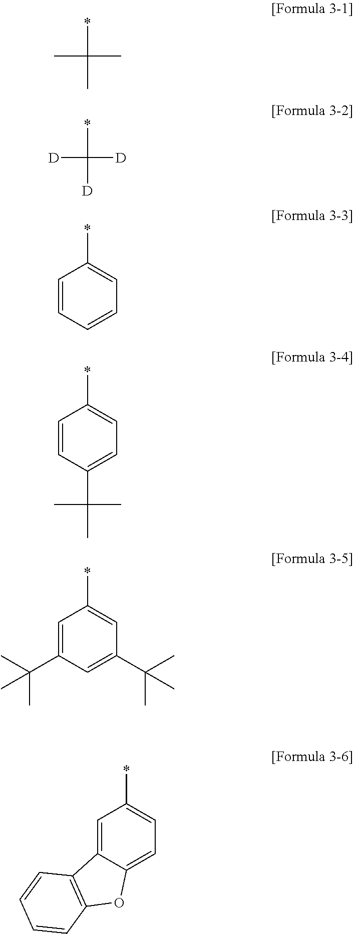
wherein in Formula 3-1 to Formula 3-6,
*— represents a bond to Formula 1, and
D represents a deuterium atom.

15. The light emitting element of claim 1, wherein in Formula 2, at least one of R₁₆, R_{y1}, R_{y2}, R_{z1}, and Ar₁ is each independently a group represented by one of Formula 4-1 to Formula 4-4: 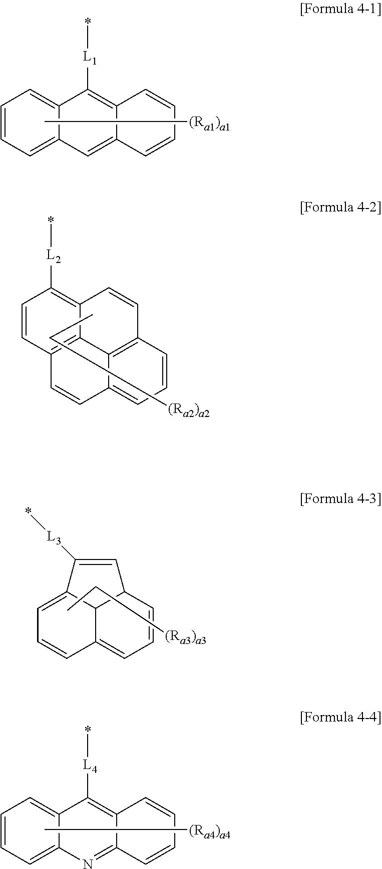
wherein in Formula 4-1 to Formula 4-4,
L₁ to L₄ are each independently a direct linkage or a substituted or unsubstituted arylene group having 6 to 30 ring-forming carbon atoms,
Rₐ₁ to Rₐ₄ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring,
a1 and a2 are each independently an integer from 0 to 9,
a3 is an integer from 0 to 7,
a4 is an integer from 0 to 8, and
*— represents a bond to Formula 2.

16. The light emitting element of claim 15, wherein in Formula 4-1 to Formula 4-4,
L₁ to L₄ are each independently a direct linkage, a substituted or unsubstituted phenylene group, or a substituted or unsubstituted biphenylene group, and
Rₐ₁ to Rₐ₄ are each independently a hydrogen atom or a substituted or unsubstituted phenyl group.

17. The light emitting element of claim 15, wherein the (2-1)-th compound is 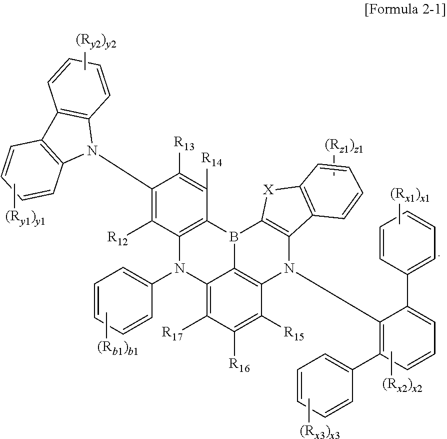
wherein in Formula 2-1,
R_{b1} is a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
at least one of R_{y1}, R_{y2}, R_{z1}, and R_{b1} is each independently a group represented by one of Formula 4-1 to Formula 4-4,
b1 is an integer from 0 to 5, and
X, R₁₂ to R₁₇, Rₓ₁ to Rₓ₃, R_{y1}, R_{y2}, R_{z1}, x1 to x3, y1, y2, and z1 are the same as defined in Formula 2.

18. The light emitting element of claim 15, wherein the (2-1)-th compound is represented by one of Formula 2-2 to Formula 2-4: 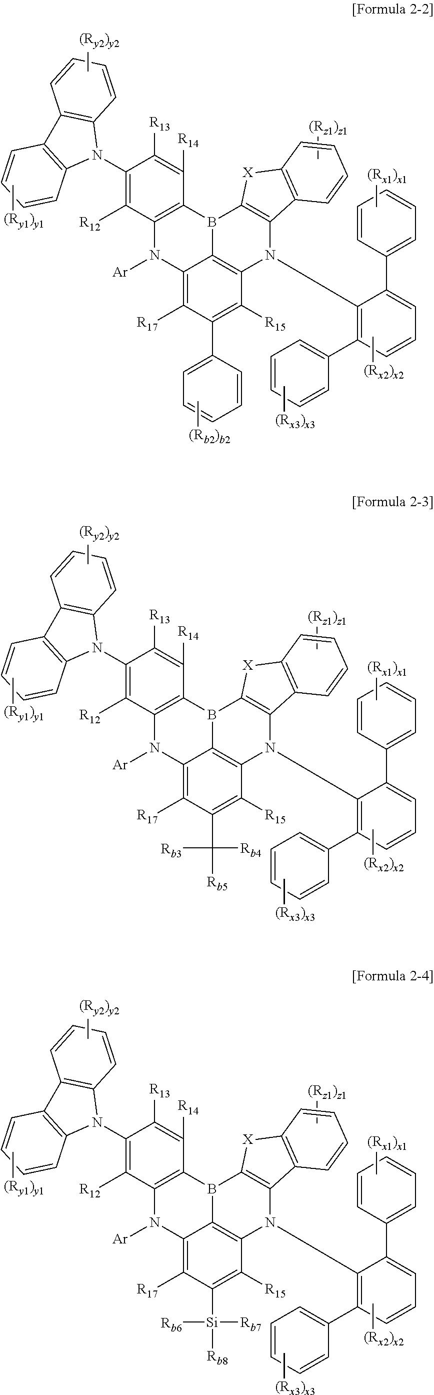
wherein in Formula 2-2 to Formula 2-4,
R_{b2} to R_{b8} are each independently a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
b2 is an integer from 0 to 5,
X, Ar, R₁₂ to R₁₅, R₁₇, Rₓ₁ to Rₓ₃, R_{y1}, R_{y2}, R_{z1}, x1 to x3, y1, y2, and z1 are the same as defined in Formula 2,
when the (2-1)-th compound is represented by Formula 2-2, at least one of R_{y1}, R_{y2}, R_{z1}, and R_{b2} is each independently a group represented by one of Formula 4-1 to Formula 4-4,
when the (2-1)-th compound is represented by Formula 2-3, at least one of R_{y1}, R_{y2}, R_{z1}, R_{b3}, R_{b4}, and R_{b8} is each independently a group represented by one of Formula 4-1 to Formula 4-4, and
when the (2-1)-th compound is represented by Formula 2-4, at least one of R_{y1}, R_{y2}, R_{z1}, R_{b6}, R_{b7}, and R_{b8} is each independently a group represented by one of Formula 4-1 to Formula 4-4.

19. The light emitting element of claim 15, wherein the (2-1)-th compound is represented by Formula 2-5: 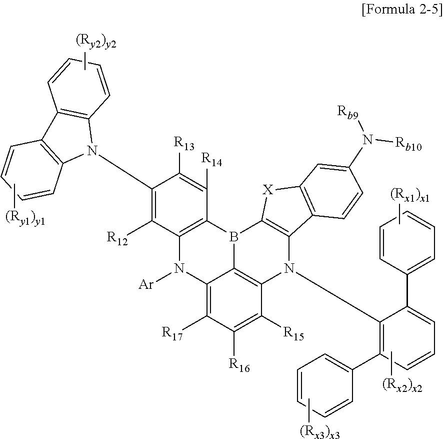
wherein in Formula 2-5,
R_{b9} and R_{b10} are each independently a hydrogen atom, a deuterium atom, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring,
at least one of R_{y1}, R_{y2}, R_{z1}, R_{b9}, and R_{b10} is each independently a group represented by one of Formula 4-1 to Formula 4-4, and
X, Ar, R₁₂ to R₁₇, Rₓ₁ to Rₓ₃, R_{y1}, R_{y2}, x1 to x3, y1, and y2 are the same as defined in Formula 2.

20. The light emitting element of claim 1, wherein the (2-1)-th compound is represented by one of Formula 2-6 to Formula 2-8: 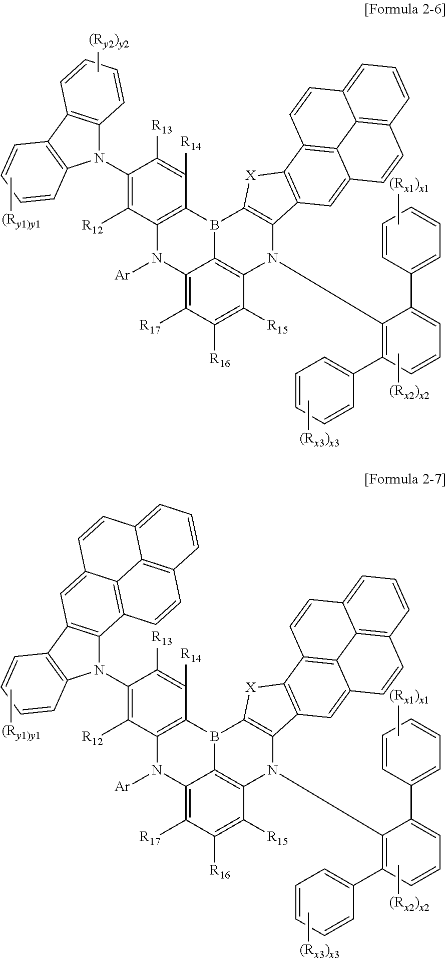 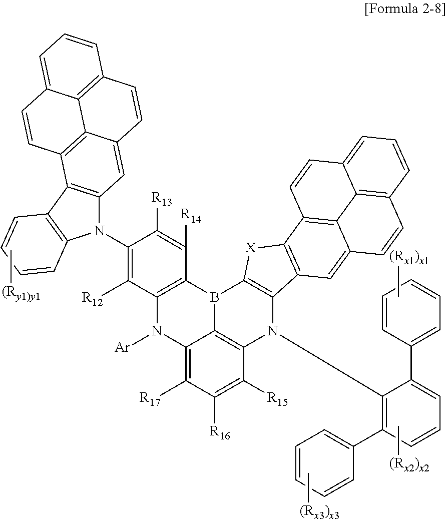
wherein in Formula 2-6 to Formula 2-8,
X, Ar, R₁₂ to R₁₇, Rₓ₁ to Rₓ₃, R_{y1}, R_{y2}, R_{z1}, x1 to x3, y1, y2, and z1 are the same as defined in Formula 2.

21. The light emitting element of claim 1, wherein the (1-1)-th compound comprises at least one compound selected from Compound Group 1-1: 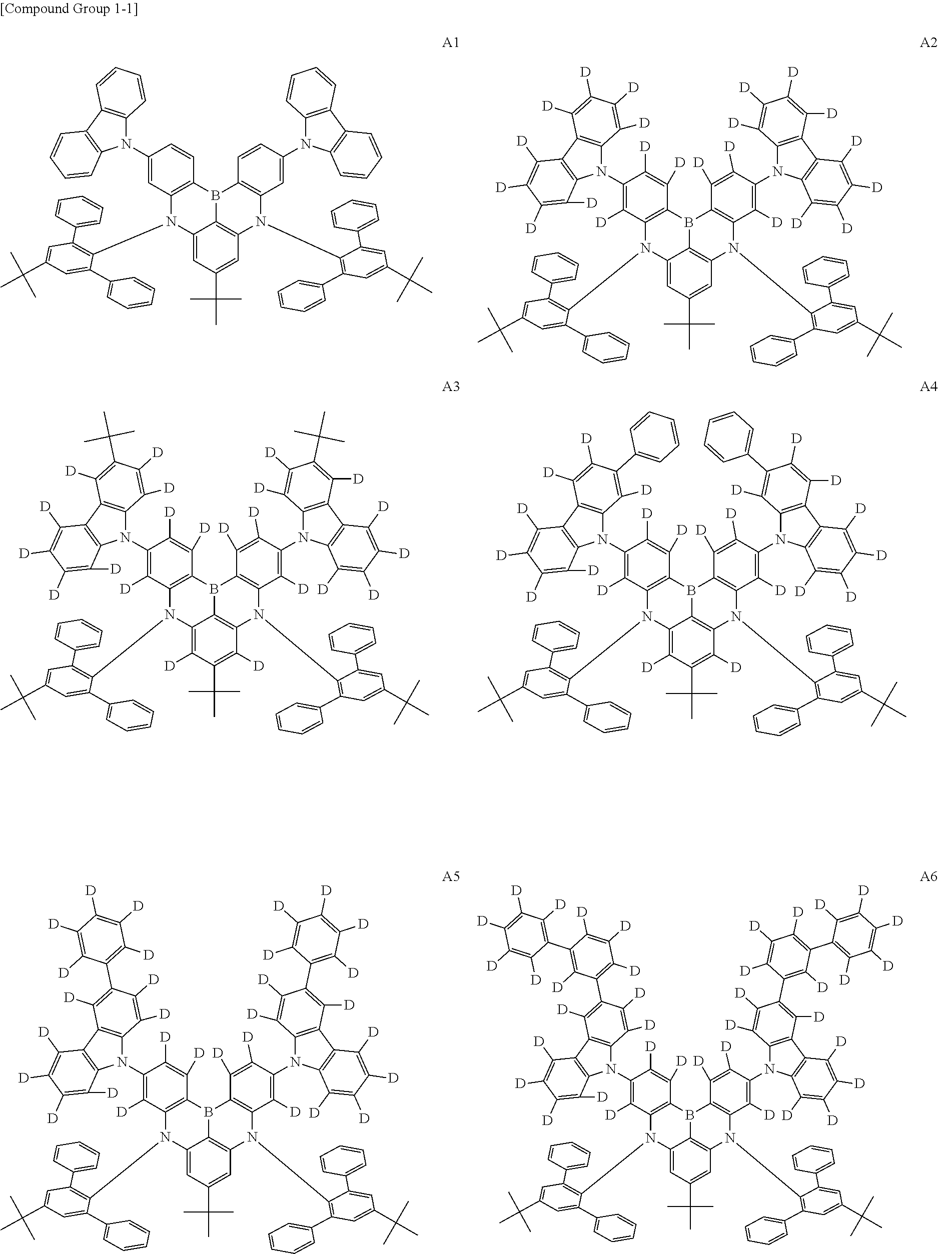 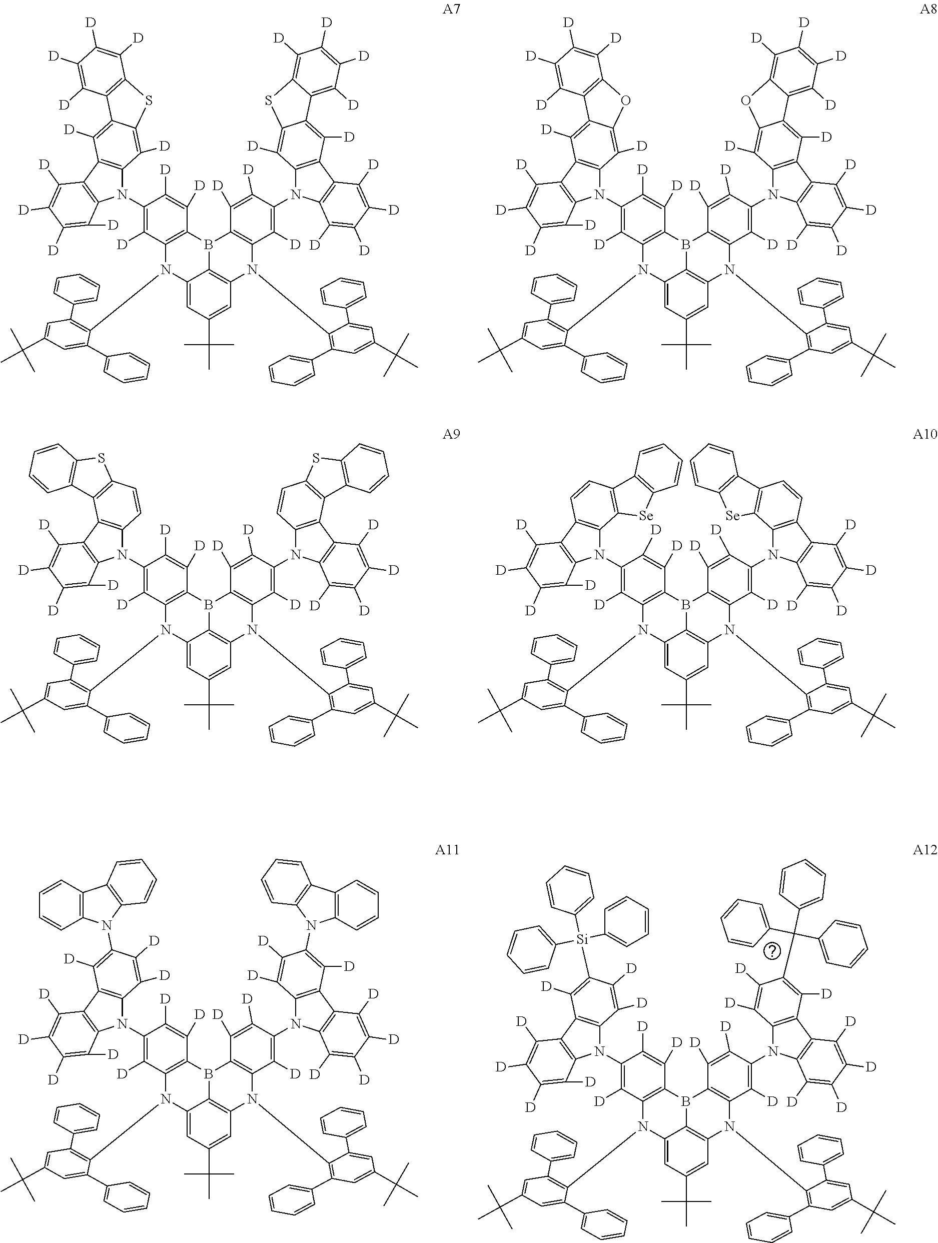 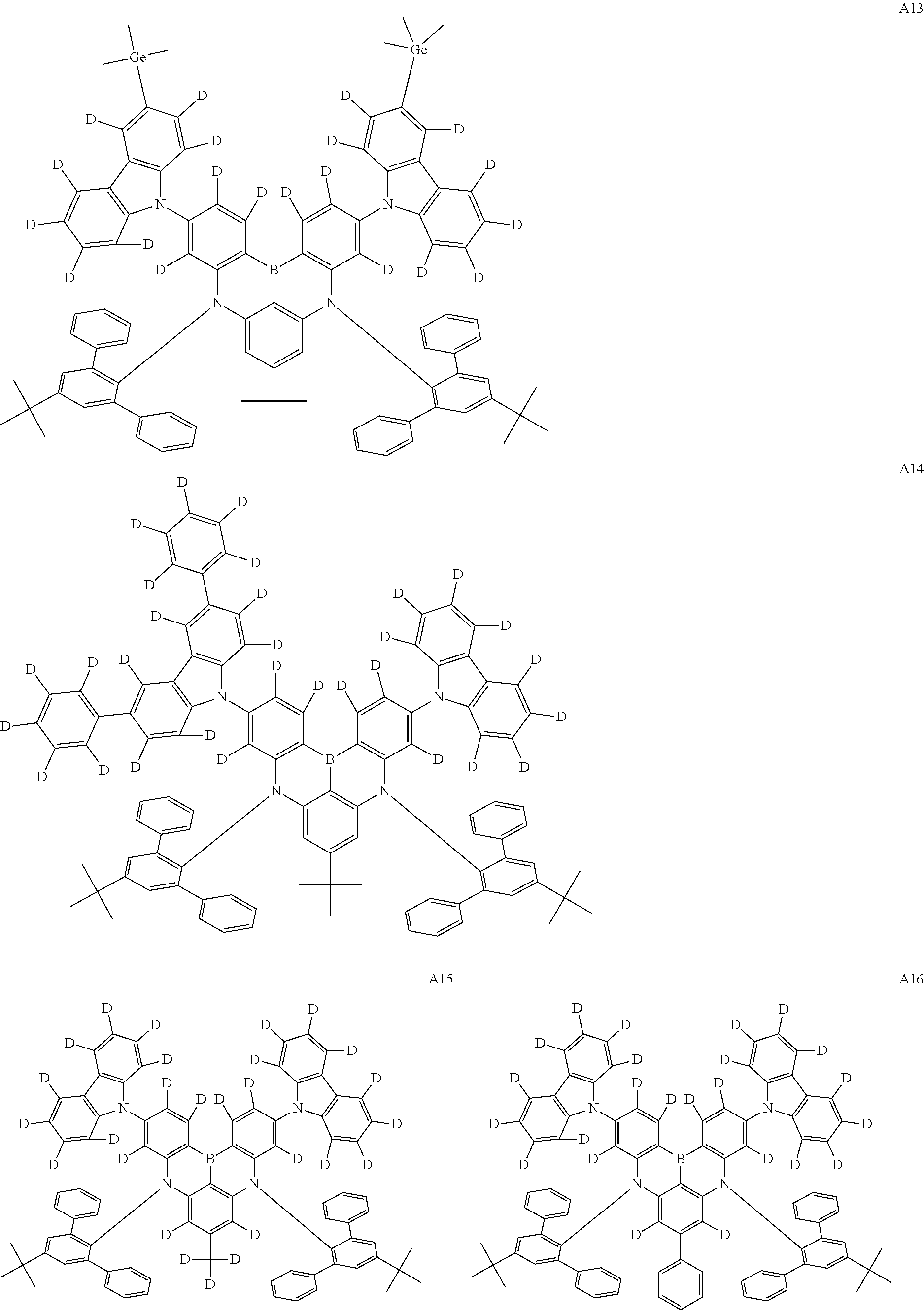 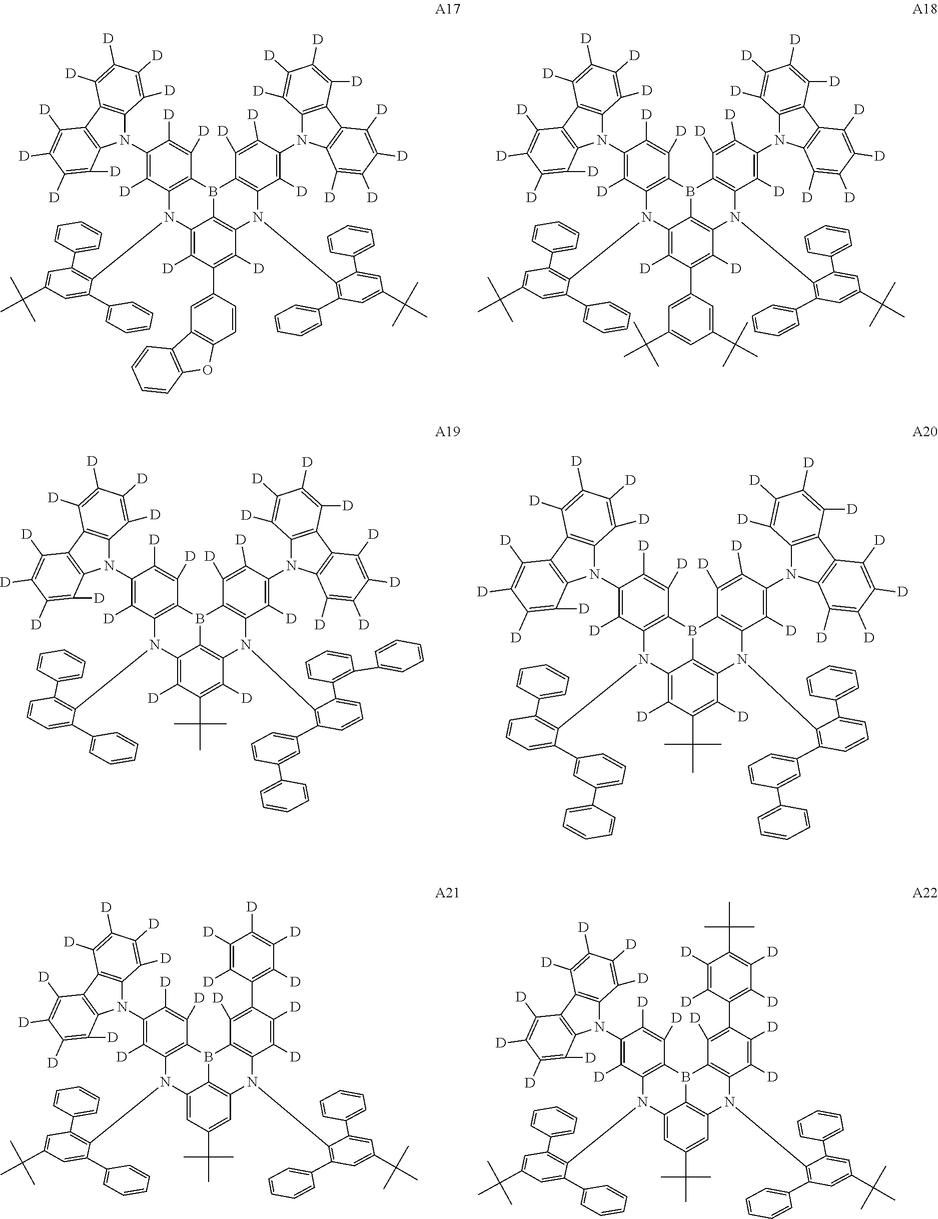 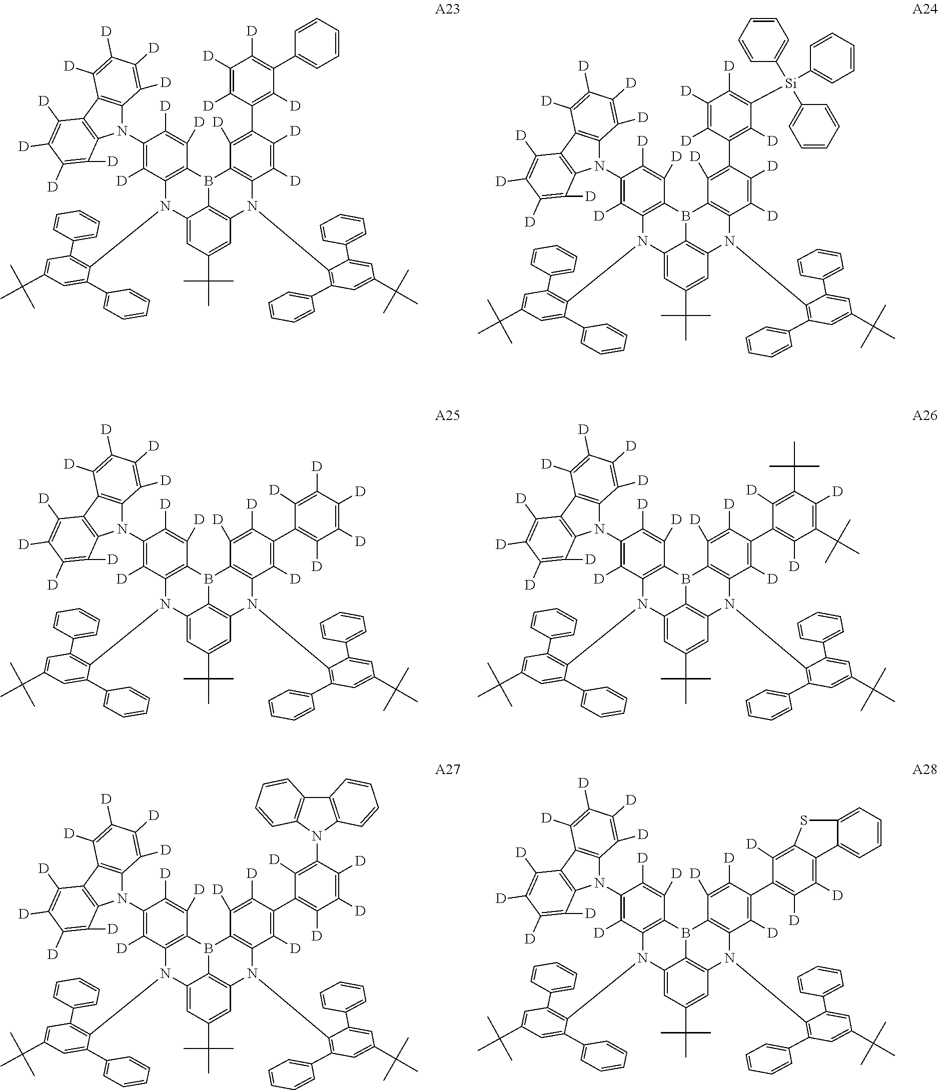 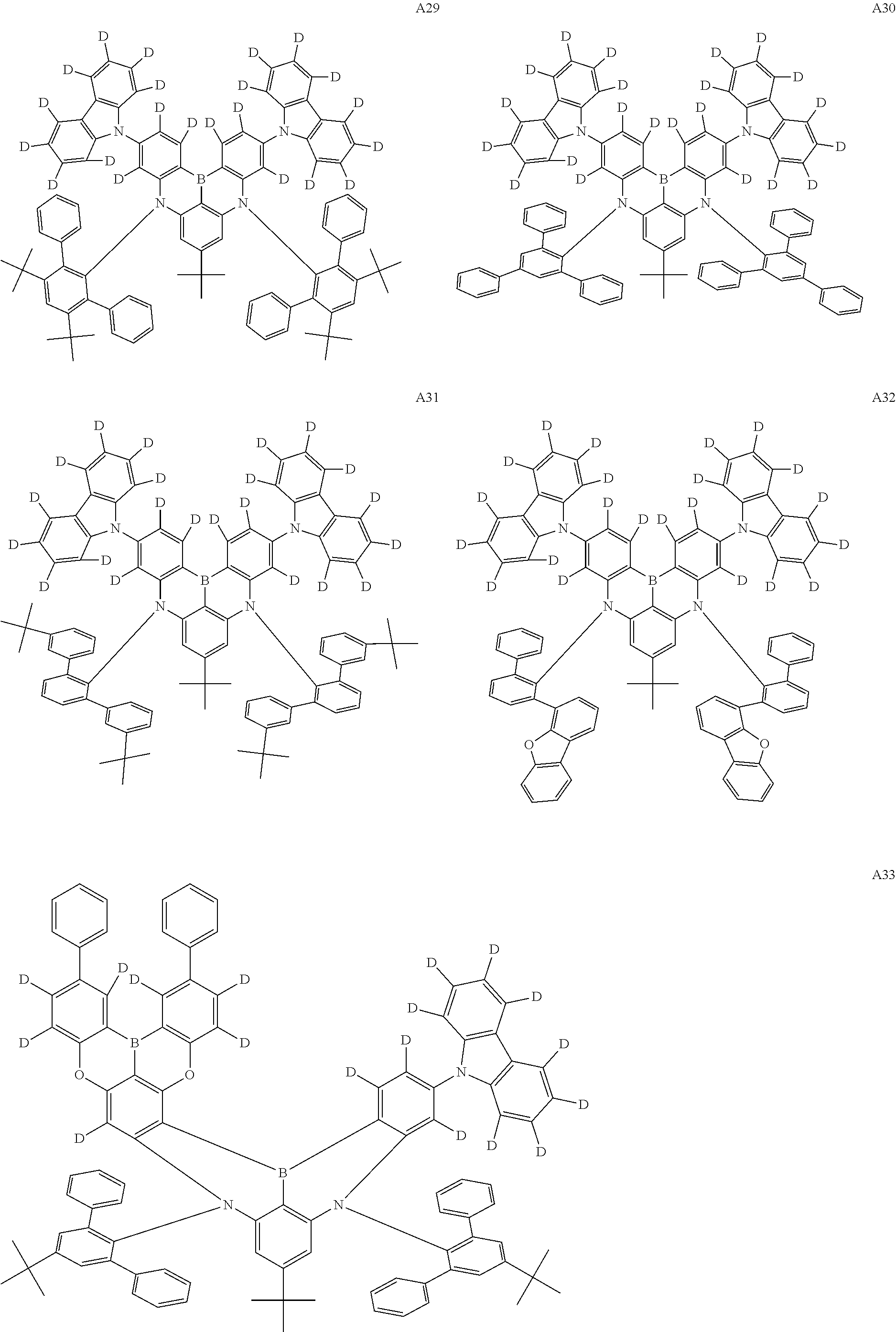 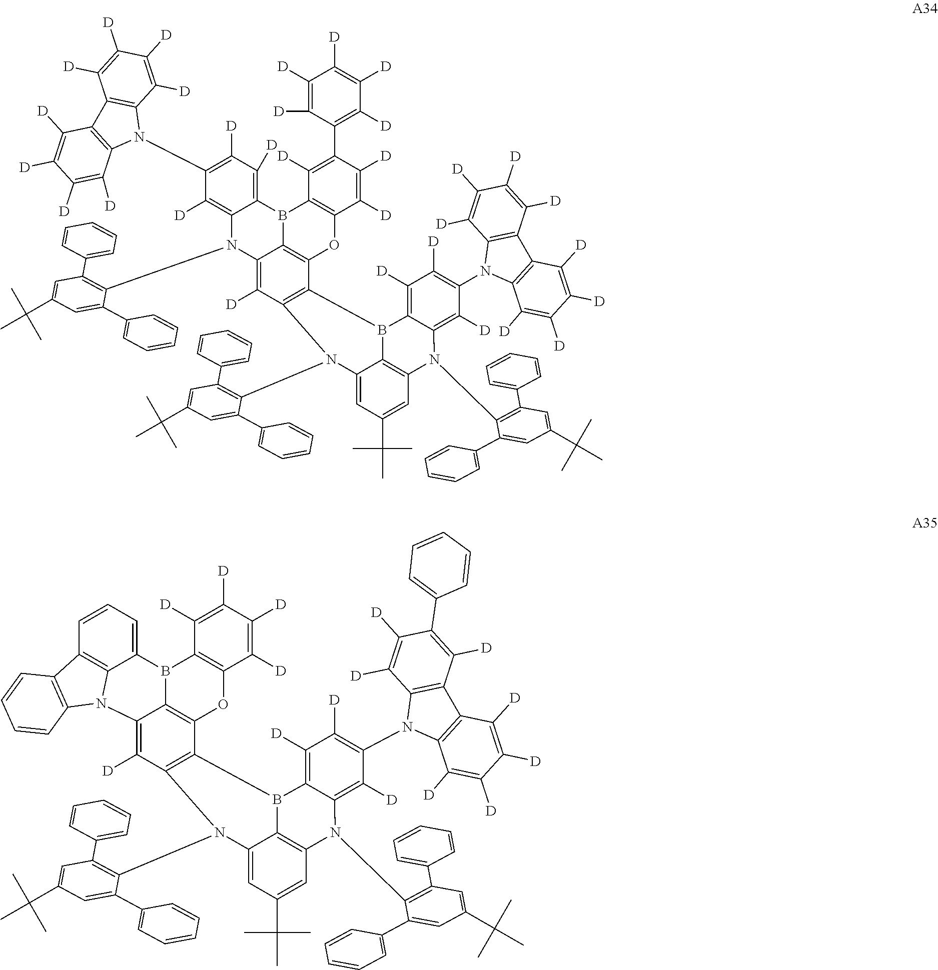 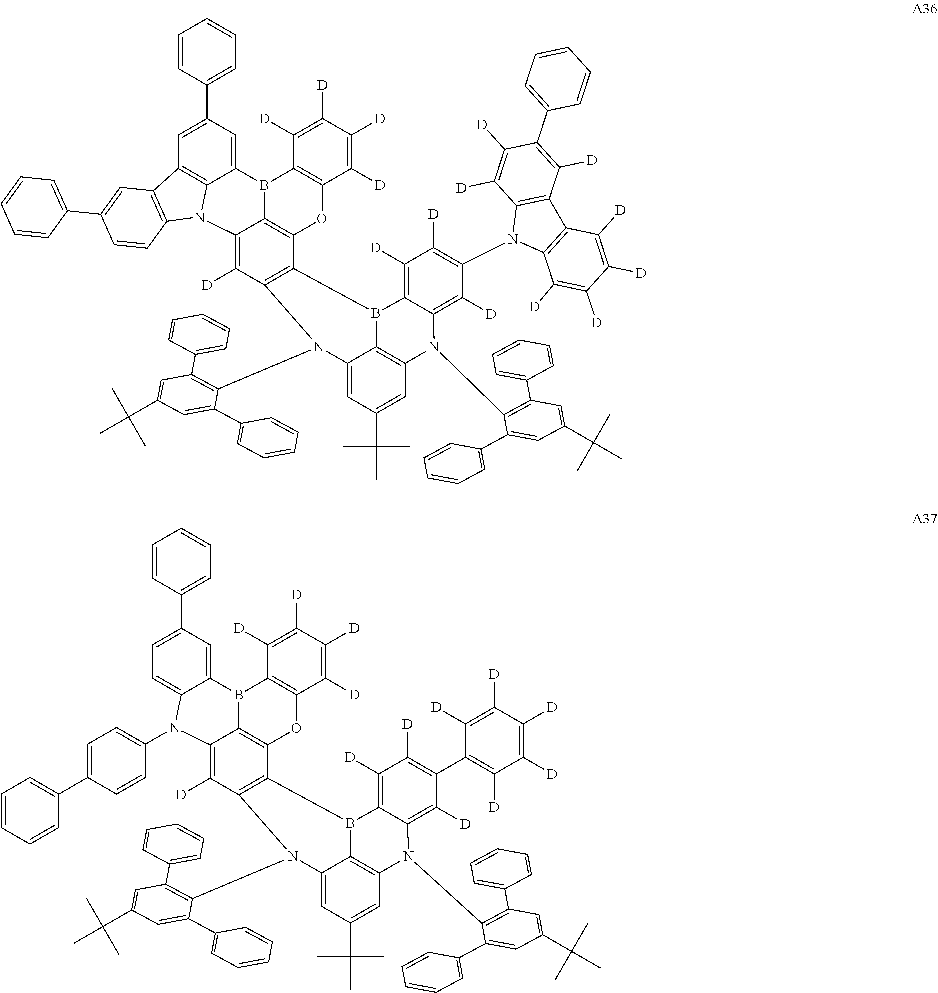 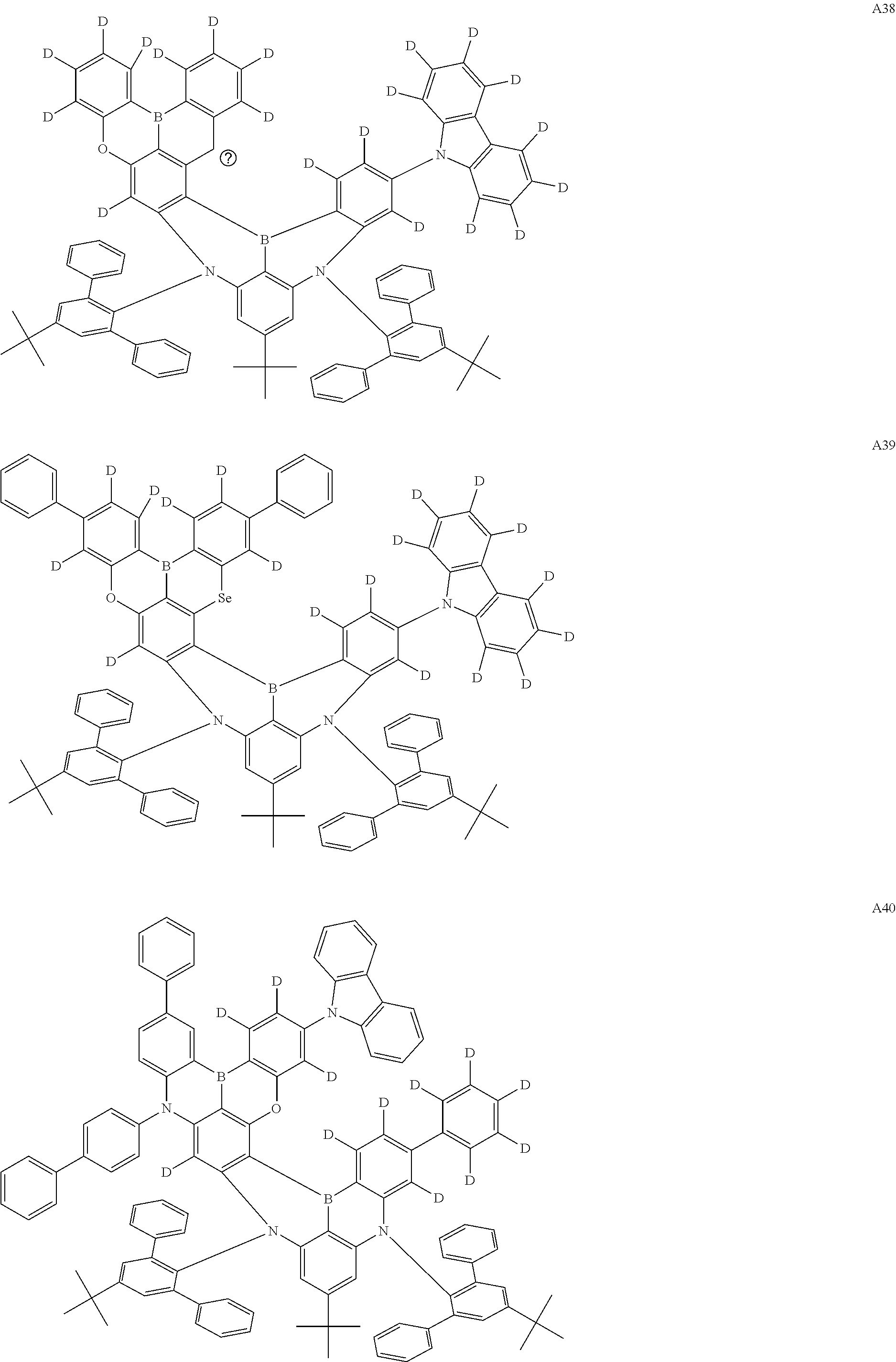 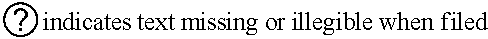
wherein in Compound Group 1-1,
D represents a deuterium atom.

22. The light emitting element of claim 1, wherein the (2-1)-th compound comprises at least one compound selected from Compound Group 2-1: 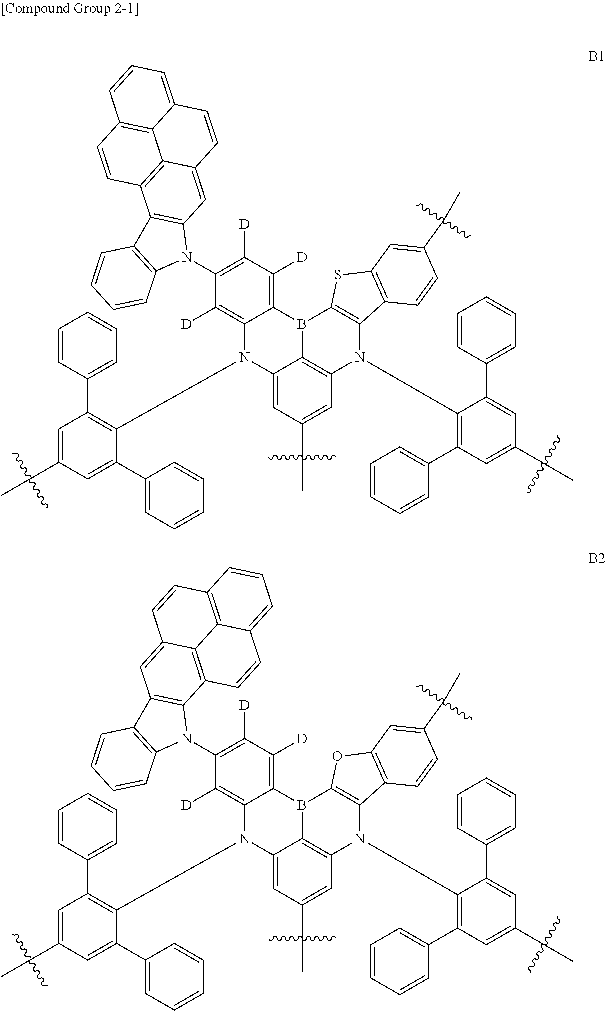 [SMILES: *c1cc(-c2ccccc2)c(N2c3cc(*)cc4c3B(c3sc5cc(*)ccc5c3N4c3c(-c4ccccc4)cc(*)cc3-c3ccccc3)c3c([2H])c([2H])c(-n4c5ccccc5c5c6ccc7cccc8ccc(cc54)c6c87)c([2H])c32)c(-c2ccccc2)c1 ; *c1cc(-c2ccccc2)c(N2c3cc(*)cc4c3B(c3oc5cc(*)ccc5c3N4c3c(-c4ccccc4)cc(*)cc3-c3ccccc3)c3c([2H])c([2H])c(-n4c5ccccc5c5cc6ccc7cccc8ccc(c6c78)c54)c([2H])c32)c(-c2ccccc2)c1] 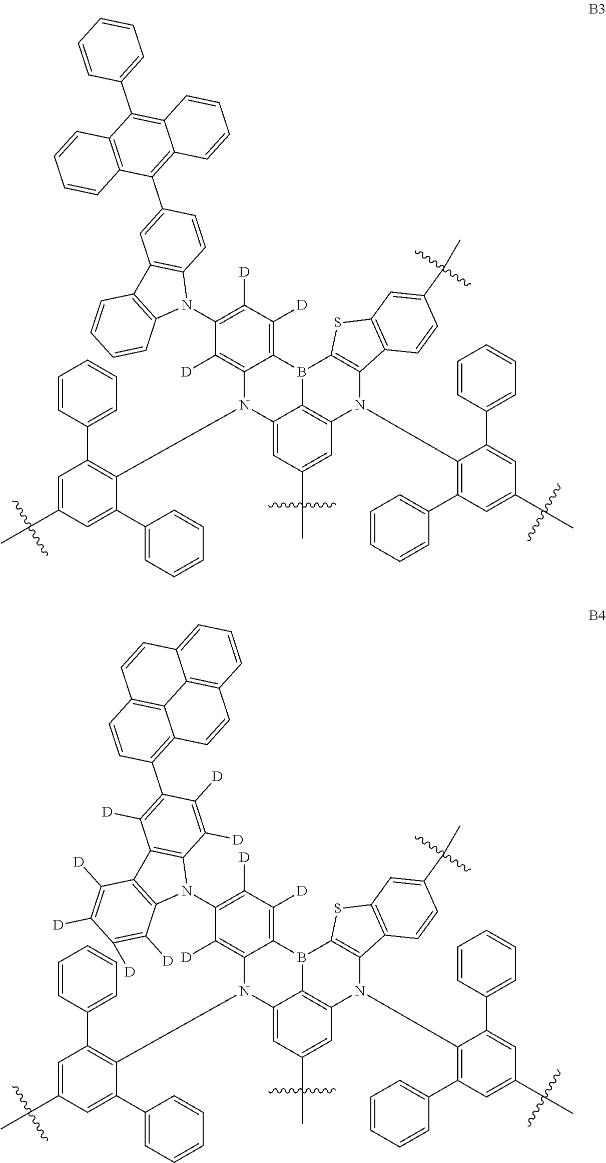 [SMILES: *c1cc(-c2ccccc2)c(N2c3cc(*)cc4c3B(c3sc5cc(*)ccc5c3N4c3c(-c4ccccc4)cc(*)cc3-c3ccccc3)c3c([2H])c([2H])c(-n4c5ccccc5c5cc(-c6c7ccccc7c(-c7ccccc7)c7ccccc67)ccc54)c([2H])c32)c(-c2ccccc2)c1 ; *c1cc(-c2ccccc2)c(N2c3cc(*)cc4c3B(c3sc5cc(*)ccc5c3N4c3c(-c4ccccc4)cc(*)cc3-c3ccccc3)c3c([2H])c([2H])c(-n4c5c([2H])c([2H])c([2H])c([2H])c5c5c([2H])c(-c6ccc7ccc8cccc9ccc6c7c89)c([2H])c([2H])c54)c([2H])c32)c(-c2ccccc2)c1] 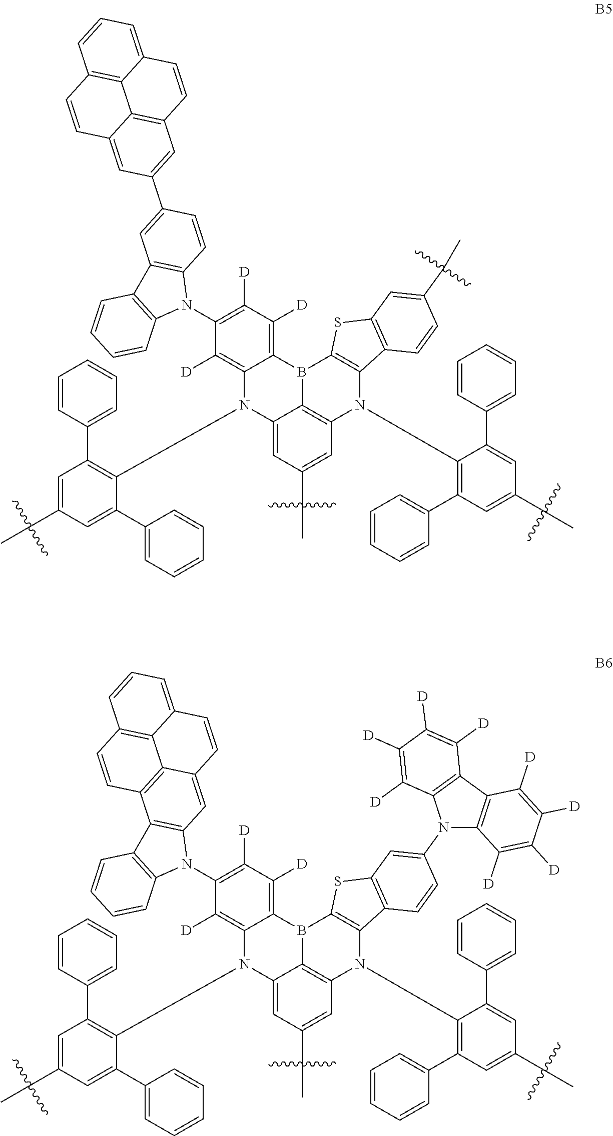 [SMILES: *c1cc(-c2ccccc2)c(N2c3cc(*)cc4c3B(c3sc5cc(*)ccc5c3N4c3c(-c4ccccc4)cc(*)cc3-c3ccccc3)c3c([2H])c([2H])c(-n4c5ccccc5c5cc(-c6cc7ccc8cccc9ccc(c6)c7c89)ccc54)c([2H])c32)c(-c2ccccc2)c1 ; *c1cc(-c2ccccc2)c(N2c3cc(*)cc4c3B(c3sc5cc(-n6c7c([2H])c([2H])c([2H])c([2H])c7c7c([2H])c([2H])c([2H])c([2H])c76)ccc5c3N4c3c(-c4ccccc4)cc(*)cc3-c3ccccc3)c3c([2H])c([2H])c(-n4c5ccccc5c5c6ccc7cccc8ccc(cc54)c6c87)c([2H])c32)c(-c2ccccc2)c1] 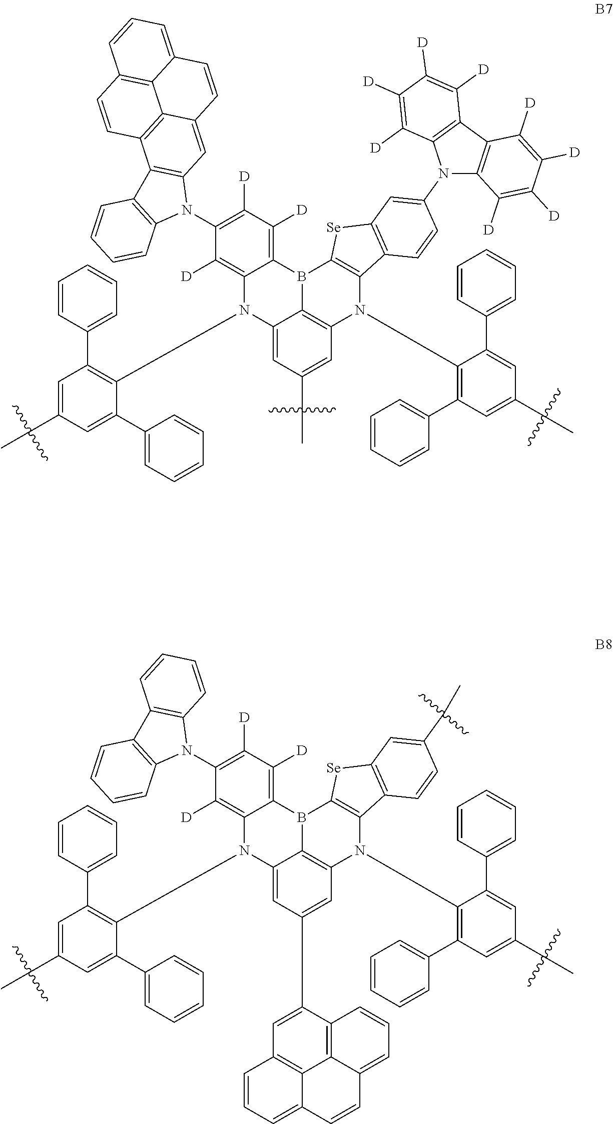 [SMILES: *c1cc(-c2ccccc2)c(N2c3cc(*)cc4c3B(c3[se]c5cc(-n6c7c([2H])c([2H])c([2H])c([2H])c7c7c([2H])c([2H])c([2H])c([2H])c76)ccc5c3N4c3c(-c4ccccc4)cc(*)cc3-c3ccccc3)c3c([2H])c([2H])c(-n4c5ccccc5c5c6ccc7cccc8ccc(cc54)c6c87)c([2H])c32)c(-c2ccccc2)c1 ; *c1cc(-c2ccccc2)c(N2c3cc(-c4cc5cccc6ccc7cccc4c7c65)cc4c3B(c3[se]c5cc(*)ccc5c3N4c3c(-c4ccccc4)cc(*)cc3-c3ccccc3)c3c([2H])c([2H])c(-n4c5ccccc5c5ccccc54)c([2H])c32)c(-c2ccccc2)c1] 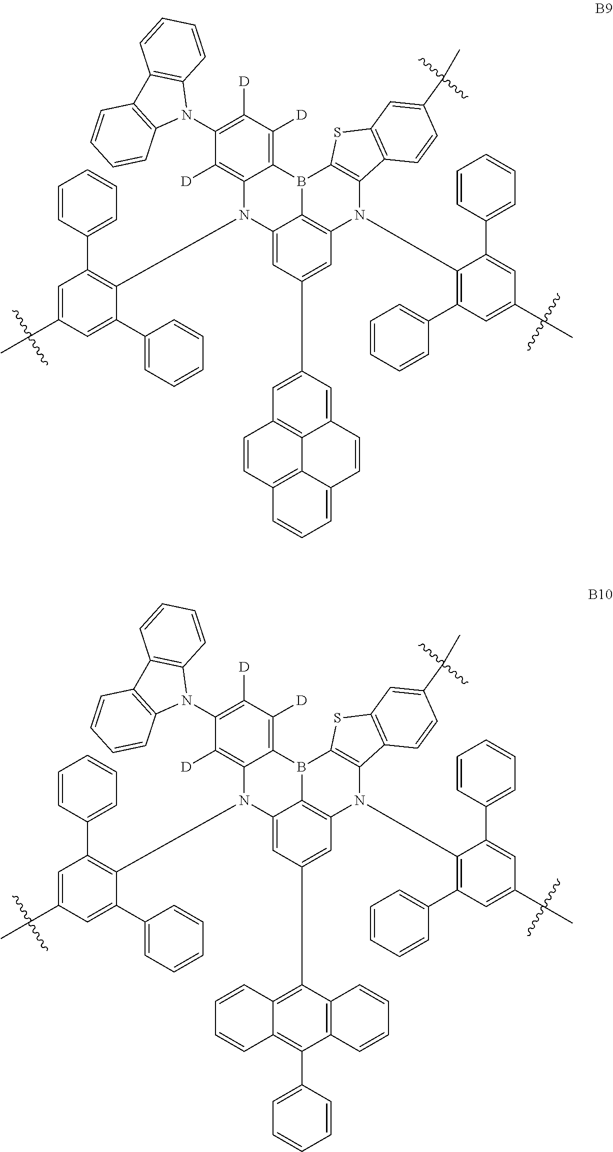 [SMILES: *c1cc(-c2ccccc2)c(N2c3cc(-c4cc5ccc6cccc7ccc(c4)c5c67)cc4c3B(c3sc5cc(*)ccc5c3N4c3c(-c4ccccc4)cc(*)cc3-c3ccccc3)c3c([2H])c([2H])c(-n4c5ccccc5c5ccccc54)c([2H])c32)c(-c2ccccc2)c1 ; *c1cc(-c2ccccc2)c(N2c3cc(-c4c5ccccc5c(-c5ccccc5)c5ccccc45)cc4c3B(c3sc5cc(*)ccc5c3N4c3c(-c4ccccc4)cc(*)cc3-c3ccccc3)c3c([2H])c([2H])c(-n4c5ccccc5c5ccccc54)c([2H])c32)c(-c2ccccc2)c1] 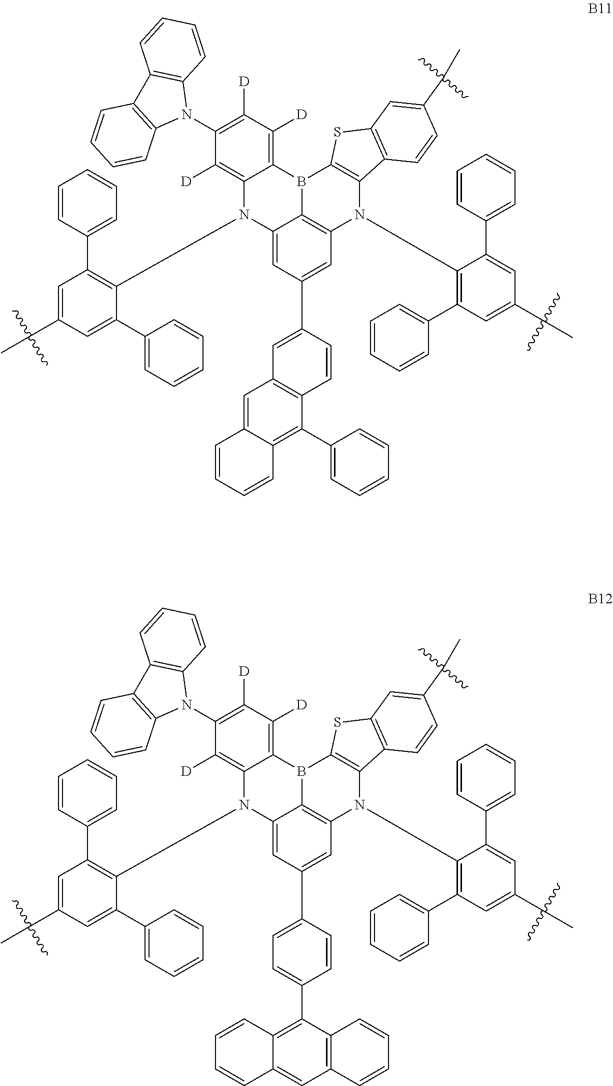 [SMILES: *c1cc(-c2ccccc2)c(N2c3cc(-c4ccc5c(-c6ccccc6)c6ccccc6cc5c4)cc4c3B(c3sc5cc(*)ccc5c3N4c3c(-c4ccccc4)cc(*)cc3-c3ccccc3)c3c([2H])c([2H])c(-n4c5ccccc5c5ccccc54)c([2H])c32)c(-c2ccccc2)c1 ; *c1cc(-c2ccccc2)c(N2c3cc(-c4ccc(-c5c6ccccc6cc6ccccc56)cc4)cc4c3B(c3sc5cc(*)ccc5c3N4c3c(-c4ccccc4)cc(*)cc3-c3ccccc3)c3c([2H])c([2H])c(-n4c5ccccc5c5ccccc54)c([2H])c32)c(-c2ccccc2)c1] 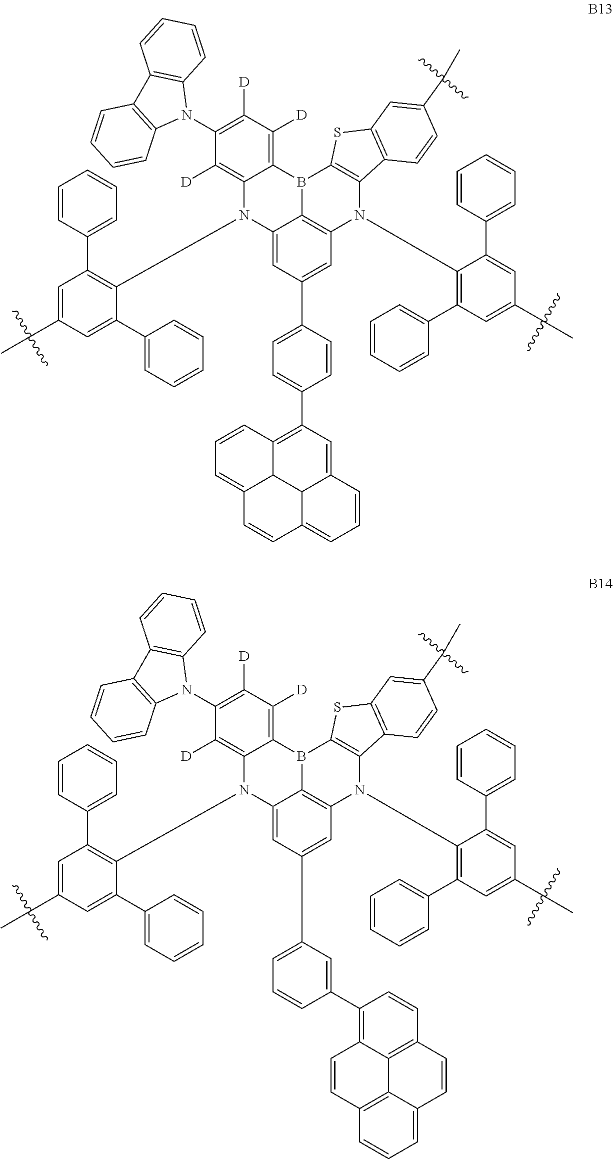 [SMILES: *c1cc(-c2ccccc2)c(N2c3cc(-c4ccc(C5=C6C=CC=C7C=CC8=CC=CC(=C5)C8C76)cc4)cc4c3B(c3sc5cc(*)ccc5c3N4c3c(-c4ccccc4)cc(*)cc3-c3ccccc3)c3c([2H])c([2H])c(-n4c5ccccc5c5ccccc54)c([2H])c32)c(-c2ccccc2)c1 ; *c1cc(-c2ccccc2)c(N2c3cc(-c4cccc(-c5ccc6ccc7cccc8ccc5c6c78)c4)cc4c3B(c3sc5cc(*)ccc5c3N4c3c(-c4ccccc4)cc(*)cc3-c3ccccc3)c3c([2H])c([2H])c(-n4c5ccccc5c5ccccc54)c([2H])c32)c(-c2ccccc2)c1] 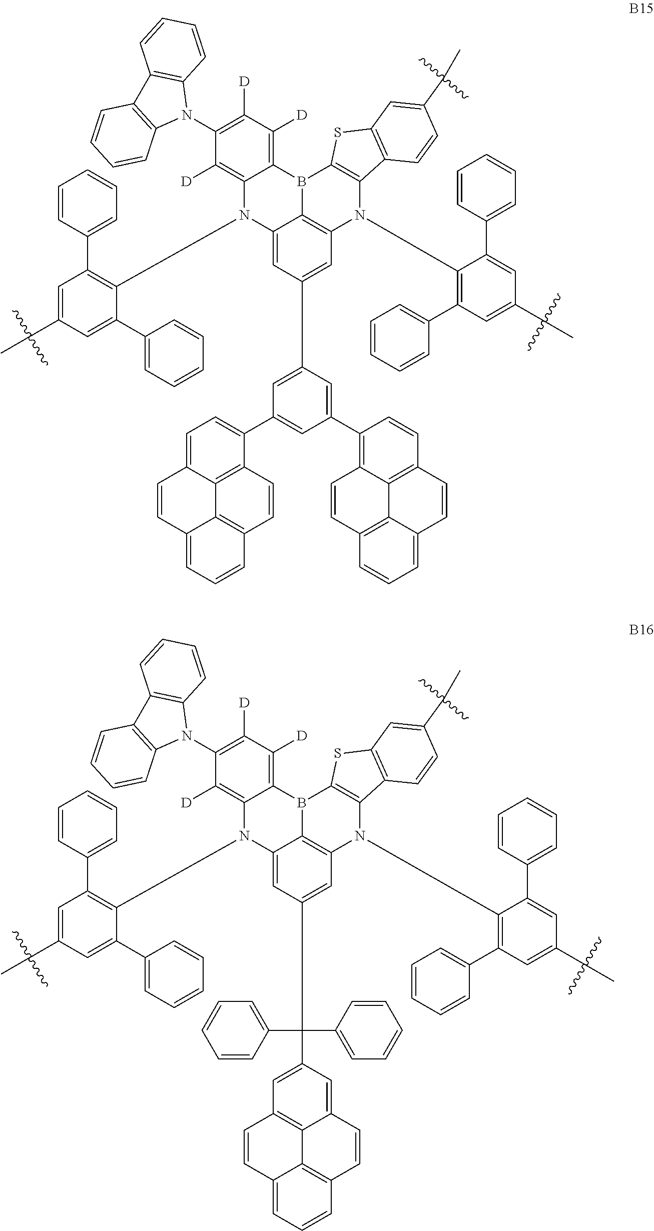 [SMILES: *c1cc(-c2ccccc2)c(N2c3cc(-c4cc(-c5ccc6ccc7cccc8ccc5c6c78)cc(-c5ccc6ccc7cccc8ccc5c6c78)c4)cc4c3B(c3sc5cc(*)ccc5c3N4c3c(-c4ccccc4)cc(*)cc3-c3ccccc3)c3c([2H])c([2H])c(-n4c5ccccc5c5ccccc54)c([2H])c32)c(-c2ccccc2)c1 ; *c1cc(-c2ccccc2)c(N2c3cc(C(c4ccccc4)(c4ccccc4)c4cc5ccc6cccc7ccc(c4)c5c67)cc4c3B(c3sc5cc(*)ccc5c3N4c3c(-c4ccccc4)cc(*)cc3-c3ccccc3)c3c([2H])c([2H])c(-n4c5ccccc5c5ccccc54)c([2H])c32)c(-c2ccccc2)c1] 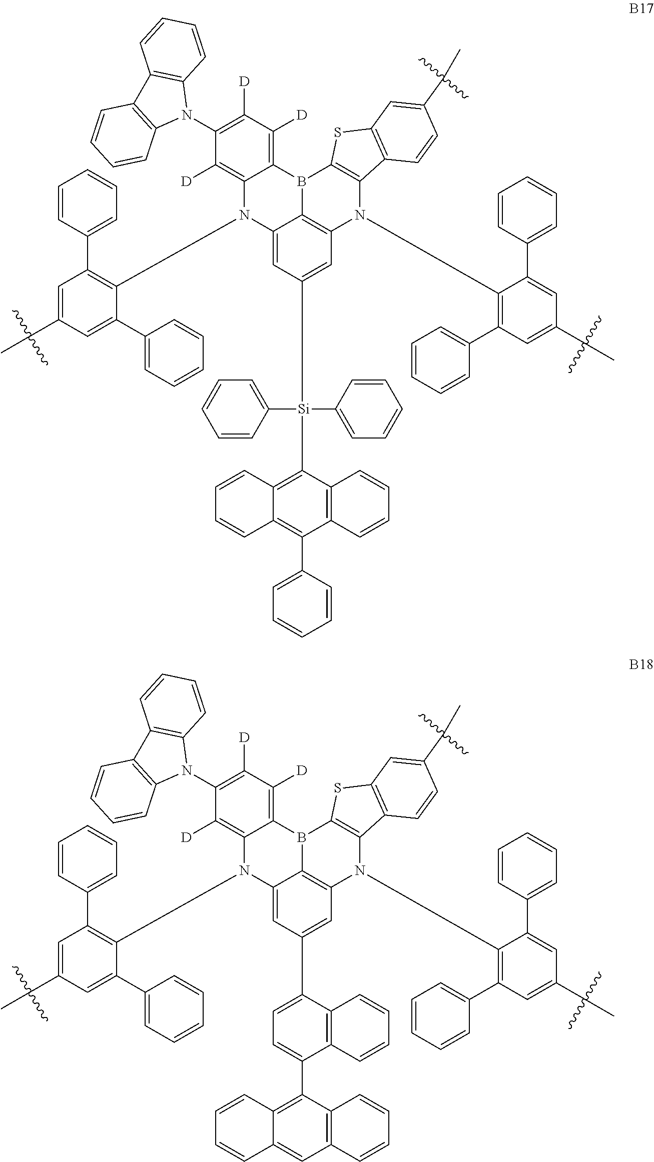 [SMILES: *c1cc(-c2ccccc2)c(N2c3cc([Si](c4ccccc4)(c4ccccc4)c4c5ccccc5c(-c5ccccc5)c5ccccc45)cc4c3B(c3sc5cc(*)ccc5c3N4c3c(-c4ccccc4)cc(*)cc3-c3ccccc3)c3c([2H])c([2H])c(-n4c5ccccc5c5ccccc54)c([2H])c32)c(-c2ccccc2)c1 ; *c1cc(-c2ccccc2)c(N2c3cc(-c4ccc(-c5c6ccccc6cc6ccccc56)c5ccccc45)cc4c3B(c3sc5cc(*)ccc5c3N4c3c(-c4ccccc4)cc(*)cc3-c3ccccc3)c3c([2H])c([2H])c(-n4c5ccccc5c5ccccc54)c([2H])c32)c(-c2ccccc2)c1] 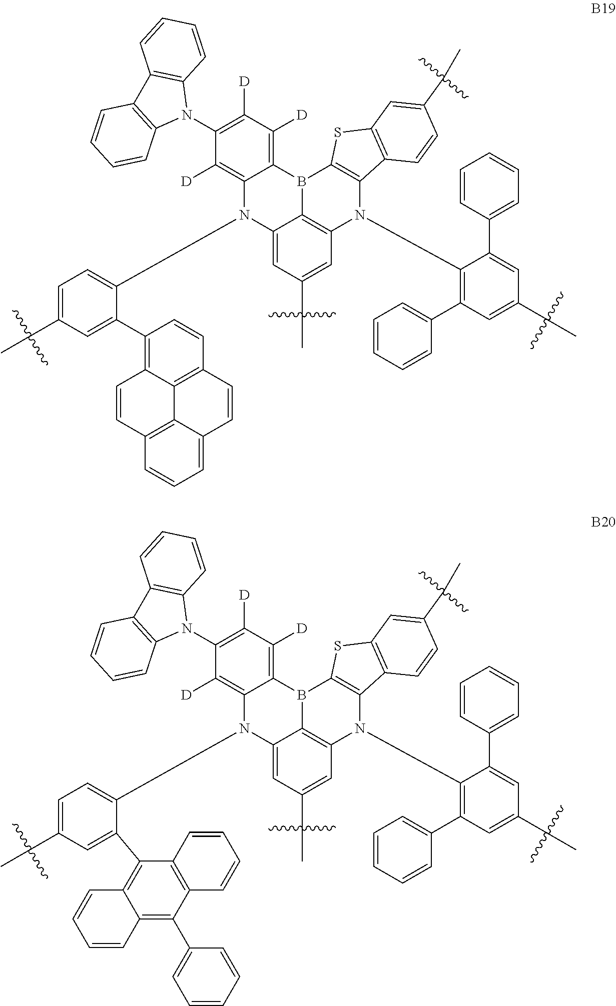 [SMILES: *c1ccc(N2c3cc(*)cc4c3B(c3sc5cc(*)ccc5c3N4c3c(-c4ccccc4)cc(*)cc3-c3ccccc3)c3c([2H])c([2H])c(-n4c5ccccc5c5ccccc54)c([2H])c32)c(-c2ccc3ccc4cccc5ccc2c3c45)c1 ; *c1ccc(N2c3cc(*)cc4c3B(c3sc5cc(*)ccc5c3N4c3c(-c4ccccc4)cc(*)cc3-c3ccccc3)c3c([2H])c([2H])c(-n4c5ccccc5c5ccccc54)c([2H])c32)c(-c2c3ccccc3c(-c3ccccc3)c3ccccc23)c1] 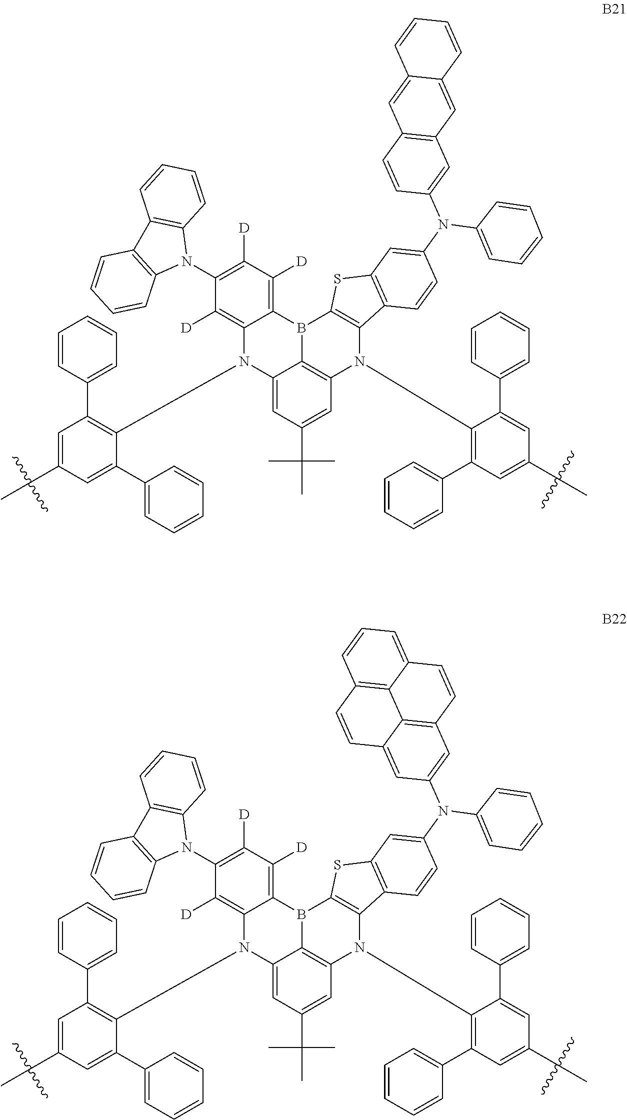 [SMILES: *c1cc(-c2ccccc2)c(N2c3cc(C(C)(C)C)cc4c3B(c3sc5cc(N(c6ccccc6)c6ccc7cc8ccccc8cc7c6)ccc5c3N4c3c(-c4ccccc4)cc(*)cc3-c3ccccc3)c3c([2H])c([2H])c(-n4c5ccccc5c5ccccc54)c([2H])c32)c(-c2ccccc2)c1 ; *c1cc(-c2ccccc2)c(N2c3cc(C(C)(C)C)cc4c3B(c3sc5cc(N(c6ccccc6)c6cc7ccc8cccc9ccc(c6)c7c89)ccc5c3N4c3c(-c4ccccc4)cc(*)cc3-c3ccccc3)c3c([2H])c([2H])c(-n4c5ccccc5c5ccccc54)c([2H])c32)c(-c2ccccc2)c1] 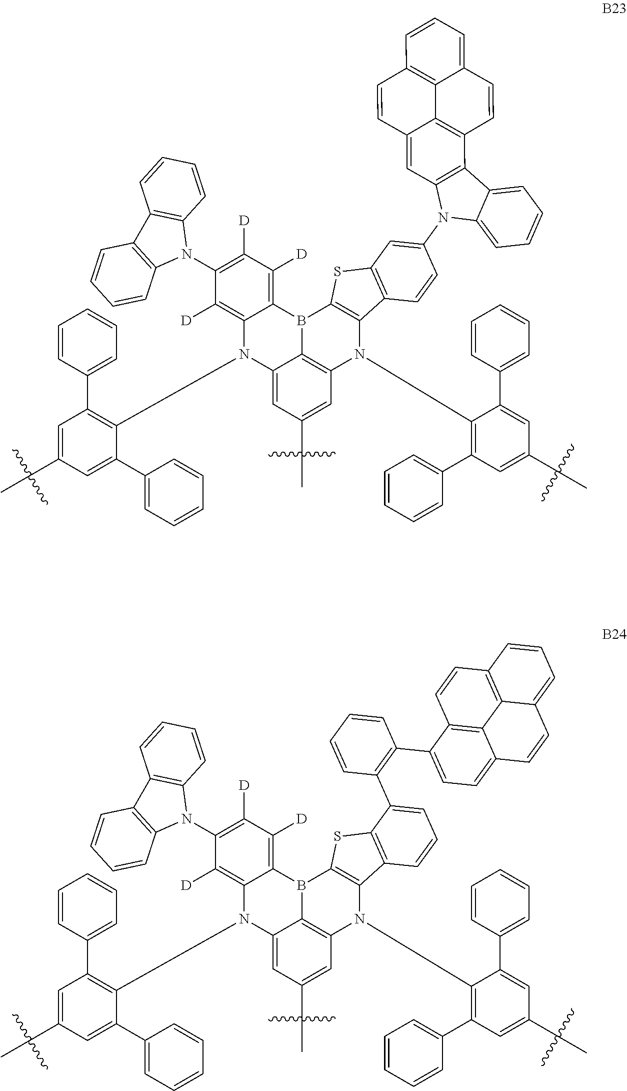 [SMILES: *c1cc(-c2ccccc2)c(N2c3cc(*)cc4c3B(c3sc5cc(-n6c7ccccc7c7c8ccc9cccc%10ccc(cc76)c8c%109)ccc5c3N4c3c(-c4ccccc4)cc(*)cc3-c3ccccc3)c3c([2H])c([2H])c(-n4c5ccccc5c5ccccc54)c([2H])c32)c(-c2ccccc2)c1 ; *c1cc(-c2ccccc2)c(N2c3cc(*)cc4c3B(c3sc5c(-c6ccccc6-c6ccc7ccc8cccc9ccc6c7c89)cccc5c3N4c3c(-c4ccccc4)cc(*)cc3-c3ccccc3)c3c([2H])c([2H])c(-n4c5ccccc5c5ccccc54)c([2H])c32)c(-c2ccccc2)c1] 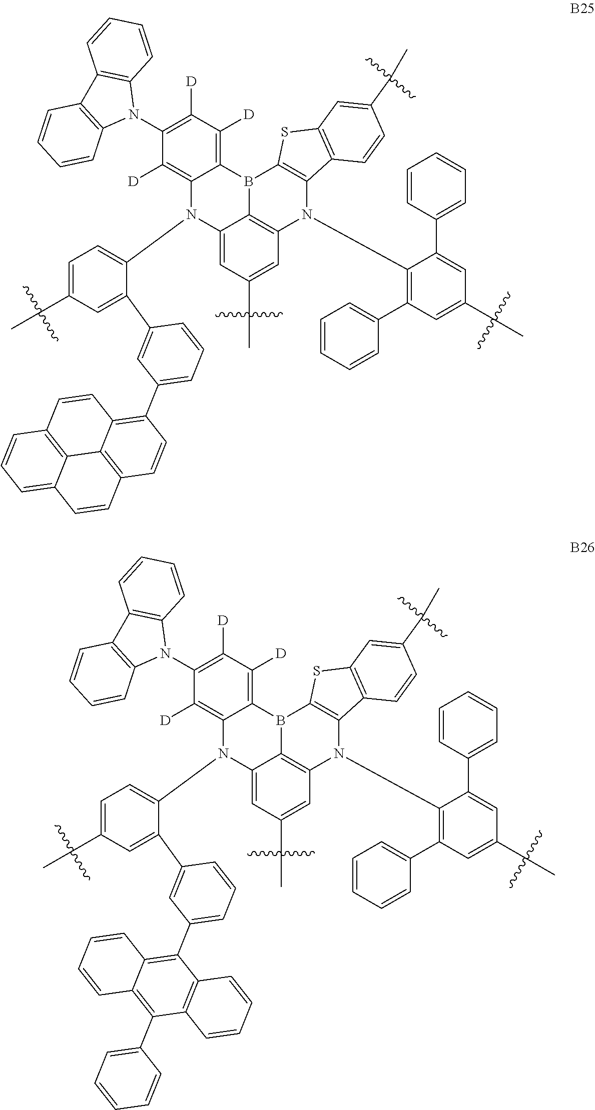 [SMILES: *c1ccc(N2c3cc(*)cc4c3B(c3sc5cc(*)ccc5c3N4c3c(-c4ccccc4)cc(*)cc3-c3ccccc3)c3c([2H])c([2H])c(-n4c5ccccc5c5ccccc54)c([2H])c32)c(-c2cccc(-c3ccc4ccc5cccc6ccc3c4c56)c2)c1 ; *c1ccc(N2c3cc(*)cc4c3B(c3sc5cc(*)ccc5c3N4c3c(-c4ccccc4)cc(*)cc3-c3ccccc3)c3c([2H])c([2H])c(-n4c5ccccc5c5ccccc54)c([2H])c32)c(-c2cccc(-c3c4ccccc4c(-c4ccccc4)c4ccccc34)c2)c1] 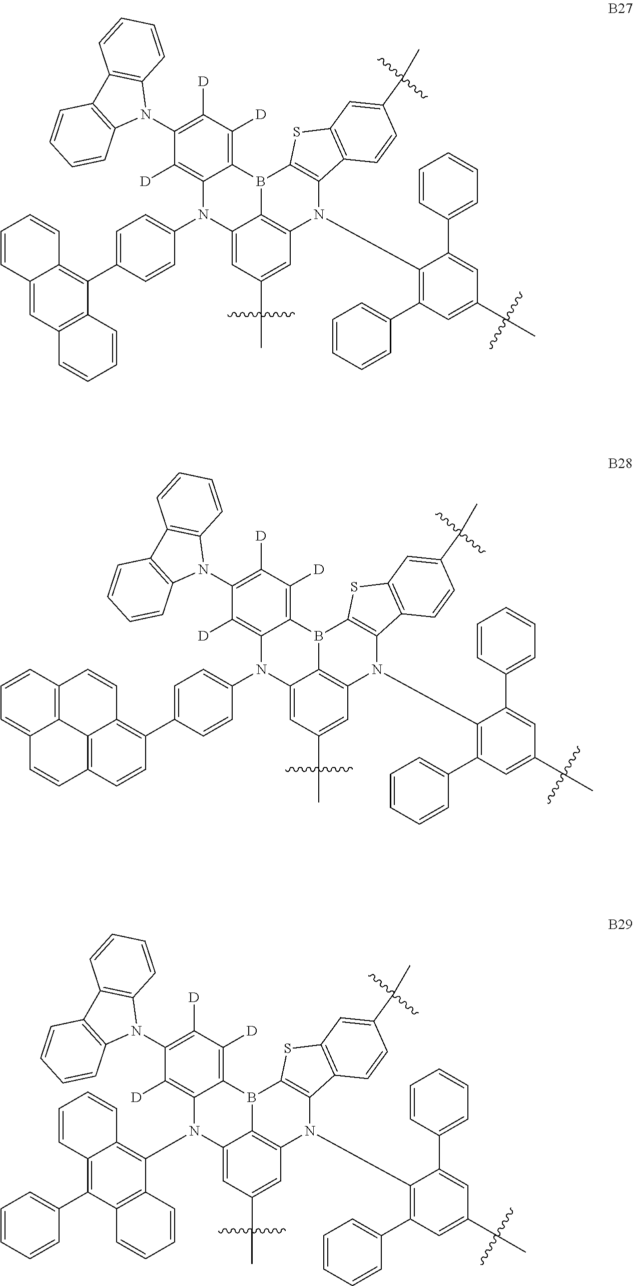 [SMILES: *c1cc(-c2ccccc2)c(N2c3cc(*)cc4c3B(c3sc5cc(*)ccc5c32)c2c([2H])c([2H])c(-n3c5ccccc5c5ccccc53)c([2H])c2N4c2ccc(-c3c4ccccc4cc4ccccc34)cc2)c(-c2ccccc2)c1 ; *c1cc(-c2ccccc2)c(N2c3cc(*)cc4c3B(c3sc5cc(*)ccc5c32)c2c([2H])c([2H])c(-n3c5ccccc5c5ccccc53)c([2H])c2N4c2ccc(-c3ccc4ccc5cccc6ccc3c4c56)cc2)c(-c2ccccc2)c1 ; *c1cc(-c2ccccc2)c(N2c3cc(*)cc4c3B(c3sc5cc(*)ccc5c32)c2c([2H])c([2H])c(-n3c5ccccc5c5ccccc53)c([2H])c2N4c2c3ccccc3c(-c3ccccc3)c3ccccc23)c(-c2ccccc2)c1] 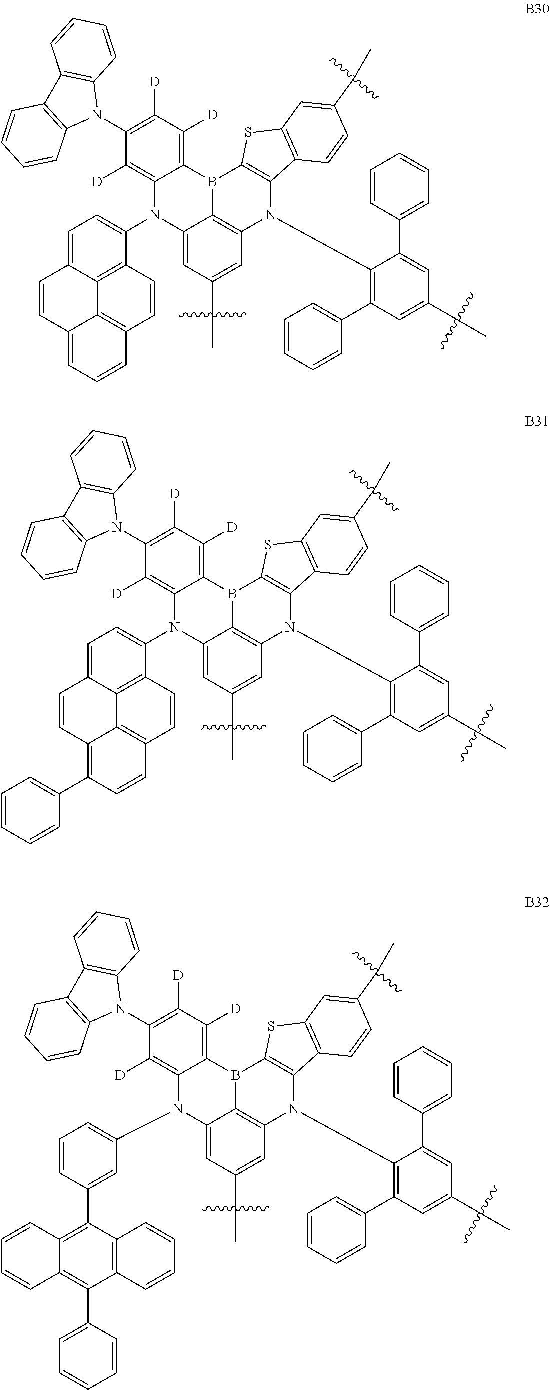 [SMILES: *c1cc(-c2ccccc2)c(N2c3cc(*)cc4c3B(c3sc5cc(*)ccc5c32)c2c([2H])c([2H])c(-n3c5ccccc5c5ccccc53)c([2H])c2N4c2ccc3ccc4cccc5ccc2c3c45)c(-c2ccccc2)c1 ; *c1cc(-c2ccccc2)c(N2c3cc(*)cc4c3B(c3sc5cc(*)ccc5c32)c2c([2H])c([2H])c(-n3c5ccccc5c5ccccc53)c([2H])c2N4c2ccc3ccc4c(-c5ccccc5)ccc5ccc2c3c54)c(-c2ccccc2)c1 ; *c1cc(-c2ccccc2)c(N2c3cc(*)cc4c3B(c3sc5cc(*)ccc5c32)c2c([2H])c([2H])c(-n3c5ccccc5c5ccccc53)c([2H])c2N4c2cccc(-c3c4ccccc4c(-c4ccccc4)c4ccccc34)c2)c(-c2ccccc2)c1] 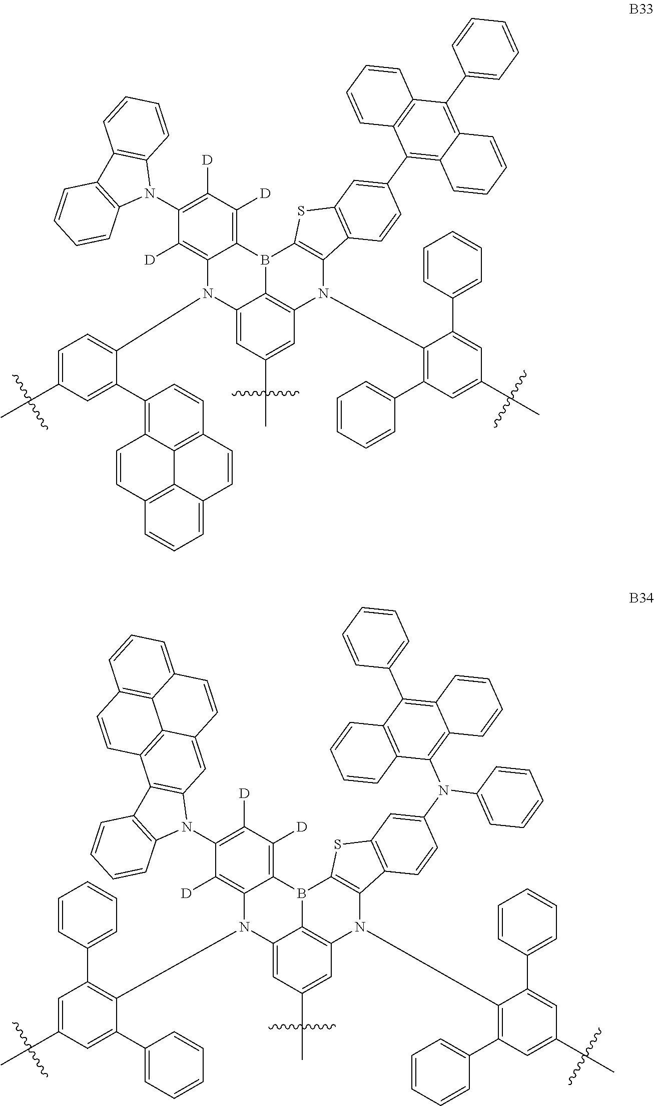 [SMILES: *c1ccc(N2c3cc(*)cc4c3B(c3sc5cc(-c6c7ccccc7c(-c7ccccc7)c7ccccc67)ccc5c3N4c3c(-c4ccccc4)cc(*)cc3-c3ccccc3)c3c([2H])c([2H])c(-n4c5ccccc5c5ccccc54)c([2H])c32)c(-c2ccc3ccc4cccc5ccc2c3c45)c1 ; *c1cc(-c2ccccc2)c(N2c3cc(*)cc4c3B(c3sc5cc(N(c6ccccc6)c6c7ccccc7c(-c7ccccc7)c7ccccc67)ccc5c3N4c3c(-c4ccccc4)cc(*)cc3-c3ccccc3)c3c([2H])c([2H])c(-n4c5ccccc5c5c6ccc7cccc8ccc(cc54)c6c87)c([2H])c32)c(-c2ccccc2)c1] 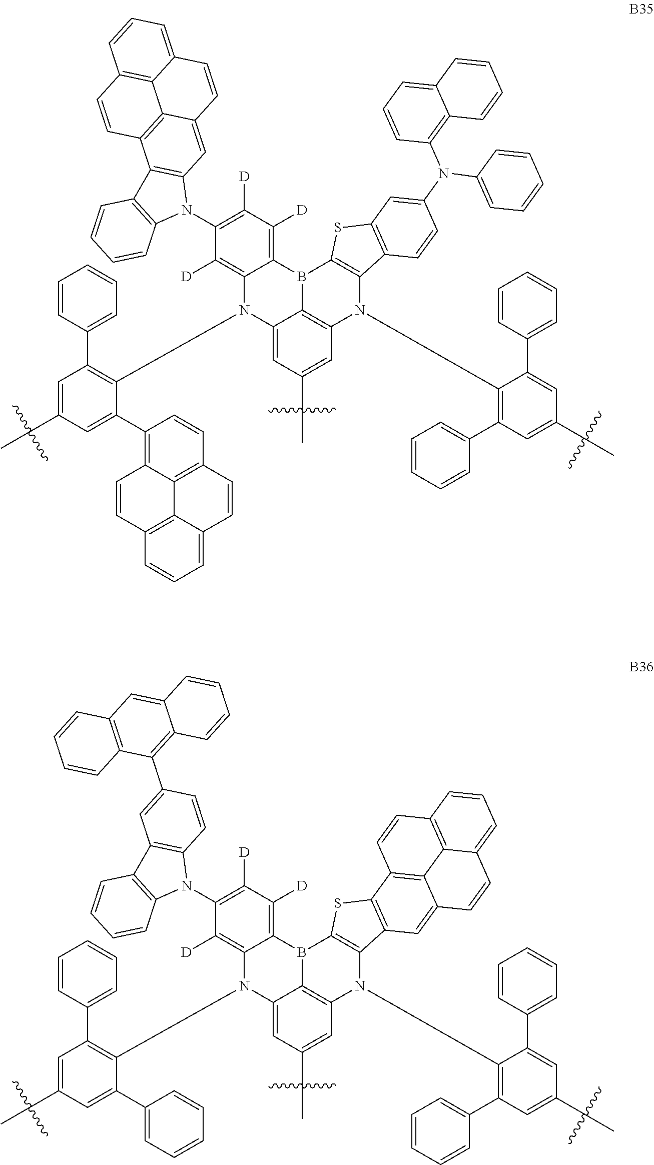 [SMILES: *c1cc(-c2ccccc2)c(N2c3cc(*)cc4c3B(c3sc5cc(N(c6ccccc6)c6cccc7ccccc67)ccc5c3N4c3c(-c4ccccc4)cc(*)cc3-c3ccccc3)c3c([2H])c([2H])c(-n4c5ccccc5c5c6ccc7cccc8ccc(cc54)c6c87)c([2H])c32)c(-c2ccc3ccc4cccc5ccc2c3c45)c1 ; *c1cc(-c2ccccc2)c(N2c3cc(*)cc4c3B(c3sc5c(cc6ccc7cccc8ccc5c6c78)c3N4c3c(-c4ccccc4)cc(*)cc3-c3ccccc3)c3c([2H])c([2H])c(-n4c5ccccc5c5cc(-c6c7ccccc7cc7ccccc67)ccc54)c([2H])c32)c(-c2ccccc2)c1] 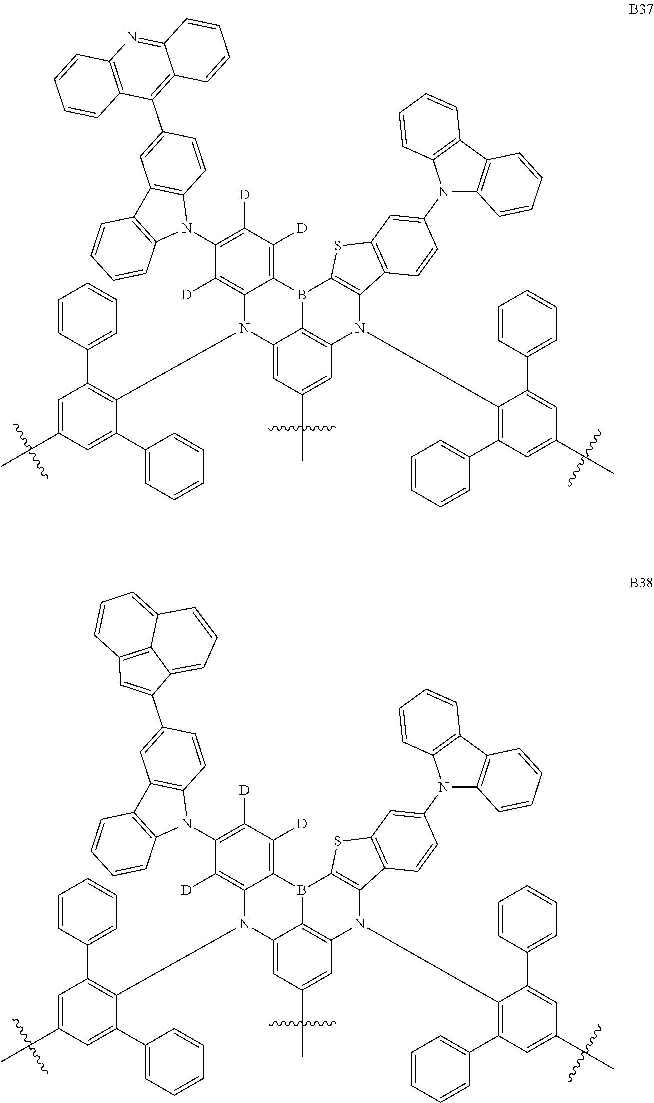 [SMILES: *c1cc(-c2ccccc2)c(N2c3cc(*)cc4c3B(c3sc5cc(-n6c7ccccc7c7ccccc76)ccc5c3N4c3c(-c4ccccc4)cc(*)cc3-c3ccccc3)c3c([2H])c([2H])c(-n4c5ccccc5c5cc(-c6c7ccccc7nc7ccccc67)ccc54)c([2H])c32)c(-c2ccccc2)c1 ; *c1cc(-c2ccccc2)c(N2c3cc(*)cc4c3B(c3sc5cc(-n6c7ccccc7c7ccccc76)ccc5c3N4c3c(-c4ccccc4)cc(*)cc3-c3ccccc3)c3c([2H])c([2H])c(-n4c5ccccc5c5cc(C6=Cc7cccc8cccc6c78)ccc54)c([2H])c32)c(-c2ccccc2)c1] 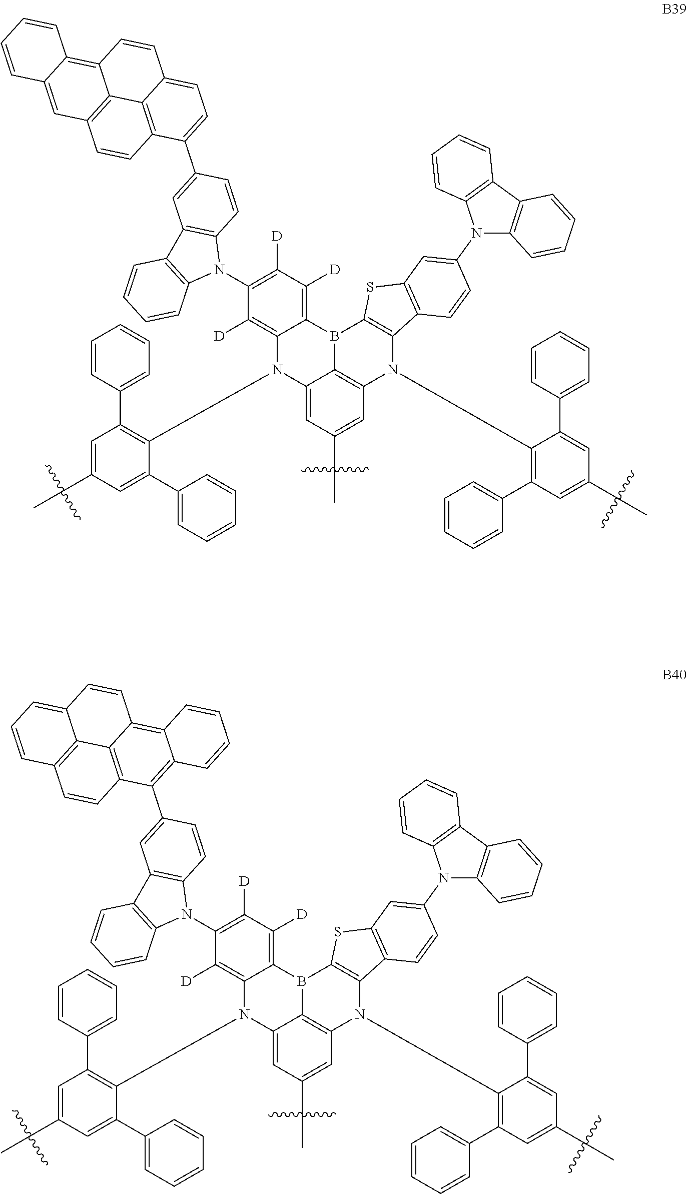 [SMILES: *c1cc(-c2ccccc2)c(N2c3cc(*)cc4c3B(c3sc5cc(-n6c7ccccc7c7ccccc76)ccc5c3N4c3c(-c4ccccc4)cc(*)cc3-c3ccccc3)c3c([2H])c([2H])c(-n4c5ccccc5c5cc(-c6ccc7ccc8c9ccccc9cc9ccc6c7c98)ccc54)c([2H])c32)c(-c2ccccc2)c1 ; *c1cc(-c2ccccc2)c(N2c3cc(*)cc4c3B(c3sc5cc(-n6c7ccccc7c7ccccc76)ccc5c3N4c3c(-c4ccccc4)cc(*)cc3-c3ccccc3)c3c([2H])c([2H])c(-n4c5ccccc5c5cc(-c6c7ccccc7c7ccc8cccc9ccc6c7c98)ccc54)c([2H])c32)c(-c2ccccc2)c1] 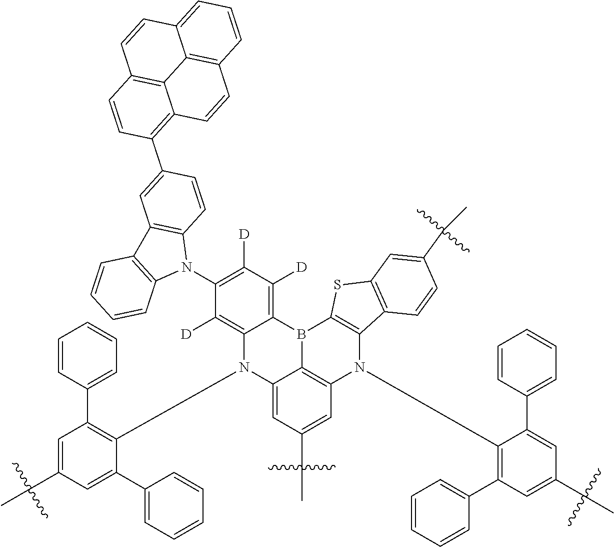 [SMILES: *c1cc(-c2ccccc2)c(N2c3cc(*)cc4c3B(c3sc5cc(*)ccc5c3N4c3c(-c4ccccc4)cc(*)cc3-c3ccccc3)c3c([2H])c([2H])c(-n4c5ccccc5c5cc(-c6ccc7ccc8cccc9ccc6c7c89)ccc54)c([2H])c32)c(-c2ccccc2)c1]
wherein in Compound Group 2-1,
D represents a deuterium atom.

23. A display device comprising:
a circuit layer disposed on a base layer; and
a display element layer disposed on the circuit layer and comprising a light emitting element, wherein
the light emitting element comprises:
a first electrode;
a first emission layer disposed on the first electrode and comprising a (1-1)-th compound represented by Formula 1;
a second emission layer disposed on the first emission layer and comprising a (2-1)-th compound represented by Formula 2; and
a second electrode disposed on the second emission layer, and
the (2-1)-th compound has a lowest excited triplet energy level (T1) in a range of about 1.5 eV to about 2.1 eV: 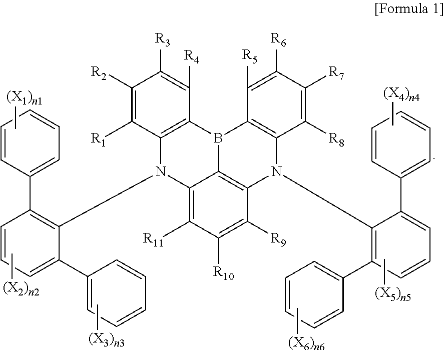
wherein in Formula 1,
R₁ to R₁₁ are each independently a hydrogen atom, a deuterium atom, a halogen atom, a cyano group, a hydroxy group, a substituted or unsubstituted oxy group, a substituted or unsubstituted thio group, a substituted or unsubstituted selenyl group, a substituted or unsubstituted tellanyl group, a substituted or unsubstituted boron group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring,
X₁ to X₆ are each independently a hydrogen atom, a deuterium atom, a halogen atom, a cyano group, a hydroxy group, a substituted or unsubstituted oxy group, a substituted or unsubstituted thio group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring,
n1, n3, n4, and n6 are each independently an integer from 0 to 5, and
n2 and n5 are each independently an integer from 0 to 3; 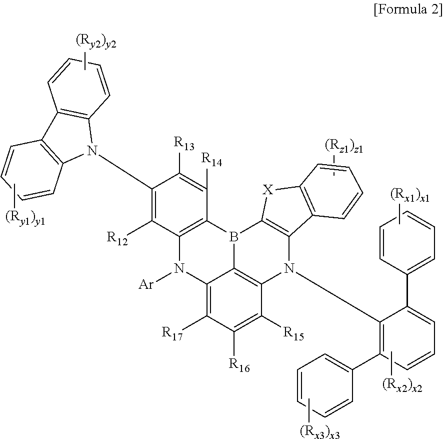
wherein in Formula 2,
X is O, S, Se, or Te,
Ar is a substituted or unsubstituted aryl group having 6 to 30 ring-forming carbon atoms or a substituted or unsubstituted heteroaryl group having 2 to 30 ring-forming carbon atoms,
R₁₂ to R₁₇ and Rₓ₁ to Rₓ₃ are each independently a hydrogen atom, a deuterium atom, a halogen atom, a cyano group, a hydroxy group, a substituted or unsubstituted silyl group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
R_{y1}, R_{y2}, and R_{z1} are each independently a hydrogen atom, a deuterium atom, a halogen atom, a cyano group, a hydroxy group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring,
x1 and x3 are each independently an integer from 0 to 5,
x2 is an integer from 0 to 3, and
y1, y2, and z1 are each independently an integer from 0 to 4.
